(19) United States
(12) Patent Application Publication
(10) Pub. No.: US 2023/0110346 A1
(43) Pub. Date: Apr. 13, 2023

(54) POLYCYCLIC AROMATIC DERIVATIVE COMPOUND AND ORGANOELECTROLUMINESCENT DEVICE USING SAME

(71) Applicant: SFC CO., LTD, Cheongju-si (KR)

(72) Inventors: Bong-ki SHIN, Cheongju-si (KR); Sung-hoon JOO, Cheongju-si (KR); Byung-sun YANG, Cheongju-si (KR); Ji-hwan KIM, Cheongju-si (KR); Hyeon-jun JO, Cheongju-si (KR); Sung-eun CHOI, Cheongju-si (KR)

(73) Assignee: SFC CO., LTD, Cheongju-si (KR)

(21) Appl. No.: 17/791,034

(22) PCT Filed: Jan. 6, 2021
(86) PCT No.: PCT/KR2021/000122

§ 371 Date: Jul. 6, 2022

(30) Foreign Application Priority Data
Jan. 6, 2020 (KR) 10-2020-0001561

(51) Int. Cl. C07F 5/02; C07F 7/08; C07F 9/576; C07F 5/06; H01L 51/00

(52) U.S. Cl. CPC C07F 5/027; C07F 7/0812; C07F 9/5765; C07F 5/062; H01L 51/008; H01L 51/0081

(57) ABSTRACT

The present invention relates to a polycyclic aromatic derivative compound that can be employed in an organic layer in a device, and an organoelectroluminescent device with high-efficiency and a long-life, including same and having remarkably improved luminous efficiency, and the device employing same can be efficiently utilized in a variety of displays and lighting devices, such as a flat panel display device, a flexible display device, a single color or white flat lighting device, and a single color or white flexible lighting device.

### TECHNICAL FIELD

The present invention relates to a polycyclic aromatic derivative and a highly efficient and long-lasting organic electroluminescent device with significantly improved luminous efficiency using the polycyclic aromatic derivative.

### BACKGROUND ART

Organic electroluminescent devices are self-luminous devices in which electrons injected from an electron injecting electrode (cathode) recombine with holes injected from a hole injecting electrode (anode) in a light emitting layer to form excitons, which emit light while releasing energy. Such organic electroluminescent devices have the advantages of low driving voltage, high luminance, large viewing angle, and short response time and can be applied to full-color light emitting flat panel displays. Due to these advantages, organic electroluminescent devices have received attention as next-generation light sources.

The above characteristics of organic electroluminescent devices are achieved by structural optimization of organic layers of the devices and are supported by stable and efficient materials for the organic layers, such as hole injecting materials, hole transport materials, light emitting materials, electron transport materials, electron injecting materials, and electron blocking materials. However, more research still needs to be done to develop structurally optimized organic layers for organic electroluminescent devices and stable and efficient materials for organic layers of organic electroluminescent devices.

As such, there is a continued need to develop structures of organic electroluminescent devices optimized to improve their luminescent properties and new materials capable of supporting the optimized structures of organic electroluminescent devices.

### DISCLOSURE

### Technical Problem

Accordingly, the present invention intends to provide an organic electroluminescent compound that is employed in an organic layer of an organic electroluminescent device to achieve high efficiency and long lifetime of the device, and an organic electroluminescent device including the organic electroluminescent compound.

### Technical Solution

One aspect of the present invention provides an organic electroluminescent compound represented by Formula A-1 or A-2:

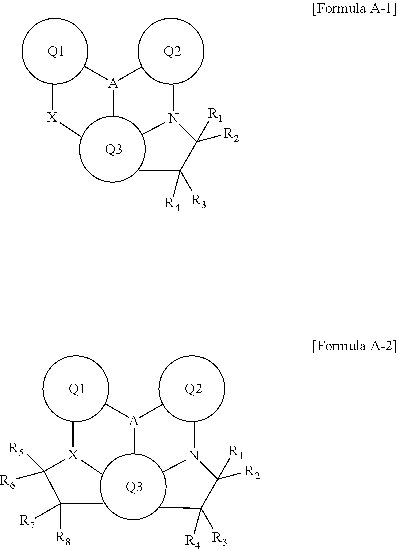

More specific structures of Formulae A-1 and A-2, definitions of Q1 to Q3, A, X, and R₁ to R₈ in Formulae A-1 and A-2, and specific polycyclic aromatic compounds that can be represented by Formulae A-1 and A-2 are described below.

A further aspect of the present invention provides an organic electroluminescent device including a first electrode, a second electrode opposite to the first electrode, and one or more organic layers interposed between the first and second electrodes wherein one of the organic layers includes at least one of the specific polycyclic aromatic compounds that can be represented by Formulae A-1 and A-2.

### Advantageous Effects

The polycyclic aromatic derivative of the present invention can be employed in an organic layer of an organic electroluminescent device to achieve high efficiency and long lifetime of the device.

### BEST MODE

The present invention will now be described in more detail.

The present invention is directed to a polycyclic aromatic derivative represented by Formula A-1 or A-2:

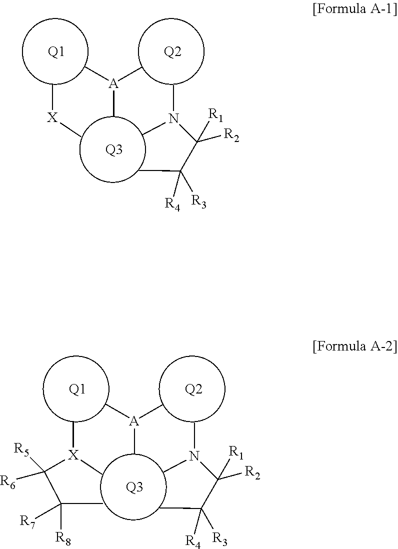

wherein Q1 to Q3 are identical to or different from each other and are each independently selected from substituted or unsubstituted C₆-C₃₀ aromatic hydrocarbon rings, substituted or unsubstituted C₂-C₅₀ aromatic heterocyclic rings, and substituted or unsubstituted C₃-C₃₀ mixed aliphatic-aromatic rings, with the proviso that Q1 and Q2 are optionally linked to each other via a single bond, O, S, Se, NR, CRR, SiRR, S═O, PR, P(═O)R or P(═S)R, X is a single bond or is selected from N—R₉, CR₁₀R₁₁, O, S, Se, and SiR₁₂R₁₃, A is selected from B, P, Al, P═S, and P═O, and R and R₁ to R₁₃ are identical to or different from each other and are each independently selected from hydrogen, deuterium, substituted or unsubstituted C₁-C₃₀ alkyl, substituted or unsubstituted C₆-C₅₀ aryl, substituted or unsubstituted C₃-C₃₀ cycloalkyl, substituted or unsubstituted C₂-C₅₀ heteroaryl, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted C₁-C₃₀ alkylamine, substituted or unsubstituted C₅-C₃₀ arylamine, substituted or unsubstituted C₁-C₃₀ alkylsilyl, substituted or unsubstituted C₅-C₃₀ arylsilyl, nitro, cyano, and halogen, with the proviso that adjacent ones of R and R₁ to R₁₃ optionally form an alicyclic or aromatic monocyclic or polycyclic ring, each of R₉ to R₁₃ optionally forms an alicyclic or aromatic monocyclic or polycyclic ring with one or more of Q1 to Q3, R₁₀ and R₁₁ together optionally form an alicyclic or aromatic monocyclic or polycyclic ring, and R₁₂ and R₁₃ together optionally form an alicyclic or aromatic monocyclic or polycyclic ring.

According to a preferred embodiment of the present invention, A in each of Formulae A-1 and A-2 is boron (B). The structure of the polycyclic aromatic derivative represented by Formula A-1 or A-2 wherein A is boron (B) enables the fabrication of a highly efficient and long-lasting organic electroluminescent device.

The polycyclic aromatic derivative of the present invention can be employed in an organic electroluminescent device to achieve high efficiency and long lifetime of the device.

According to one embodiment of the present invention, the polycyclic aromatic derivatives represented by Formulae A-1 and A-2 may have various polycyclic aromatic backbone structures, including those represented by Formulae A-3 to A-11:

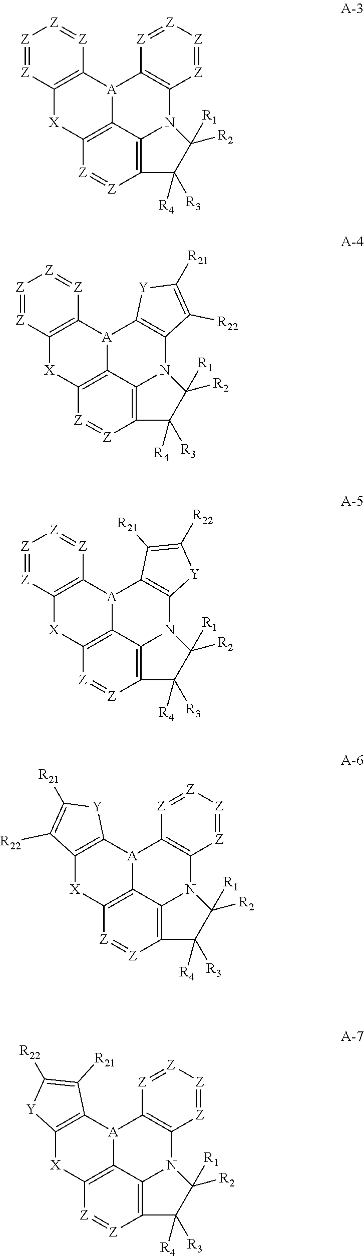

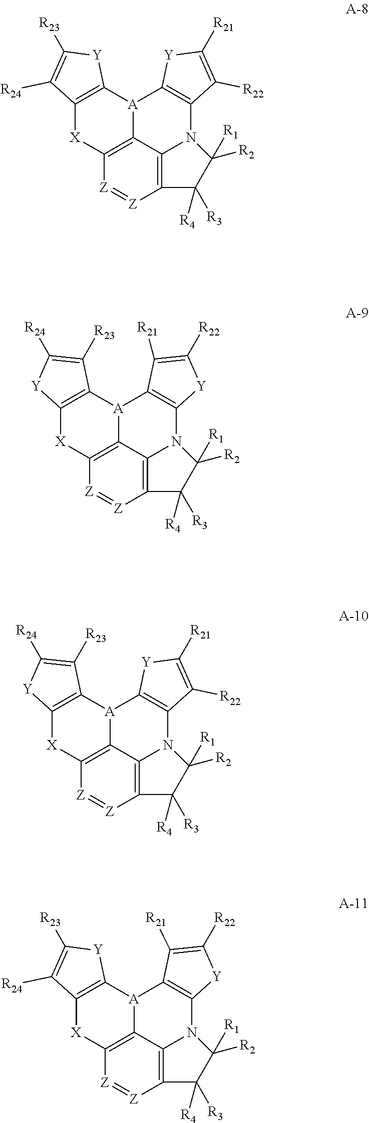

wherein the moieties Z are identical to or different from each other and are each independently CR′ or N, R₁ to R₄, R₂₁ to R₂₄, and R′ are each independently selected from hydrogen, deuterium, substituted or unsubstituted C₁-C₃₀ alkyl, substituted or unsubstituted C₆-C₅₀ aryl, substituted or unsubstituted C₃-C₃₀ cycloalkyl, substituted or unsubstituted C₂-C₅₀ heteroaryl, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted C₁-C₃₀ alkylamine, substituted or unsubstituted C₅-C₃₀ arylamine, substituted or unsubstituted C₁-C₃₀ alkylsilyl, substituted or unsubstituted C₅-C₃₀ arylsilyl, nitro, cyano, and halogen, the groups R′ are identical to or different from each other and are optionally bonded to each other or combined with an adjacent substituent to form an alicyclic or aromatic monocyclic or polycyclic ring optionally substituted with one or more heteroatoms selected from N, S, and O, A and X are as defined in Formula A-1, and the moieties Y are identical to or different from each other and are as defined for X in Formula A-1.

The use of the backbone structures meets the desired requirements of various organic layers of organic electroluminescent devices to achieve high efficiency and long lifetime of the devices.

According to one embodiment of the present invention, the polycyclic aromatic derivatives represented by Formulae A-1 and A-2 may have various polycyclic aromatic backbone structures, including those represented by Formulae A-12 to A-17:

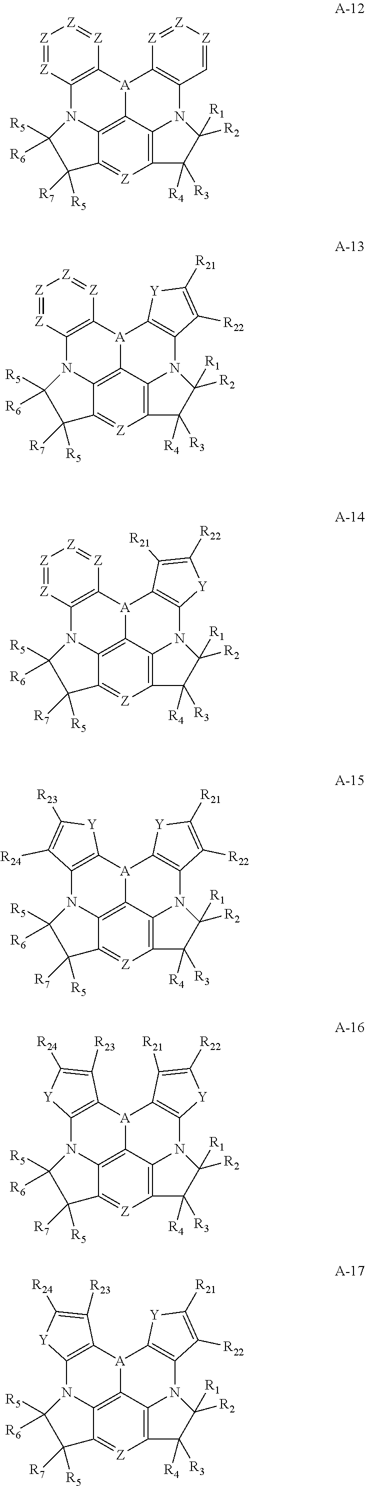

wherein the moieties Z are identical to or different from each other and are each independently CR′ or N, R₁ to R₈, R₂₁ to R₂₄, and R′ are each independently selected from hydrogen, deuterium, substituted or unsubstituted C₁-C₃₀ alkyl, substituted or unsubstituted C₆-C₅₀ aryl, substituted or unsubstituted C₃-C₃₀ cycloalkyl, substituted or unsubstituted C₂-C₅₀ heteroaryl, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted C₁-C₃₀ alkylamine, substituted or unsubstituted C₅-C₃₀ arylamine, substituted or unsubstituted C₁-C₃₀ alkylsilyl, substituted or unsubstituted C₅-C₃₀ arylsilyl, nitro, cyano, and halogen, the groups R′ are identical to or different from each other and are optionally bonded to each other or combined with an adjacent substituent to form an alicyclic or aromatic monocyclic or polycyclic ring optionally substituted with one or more heteroatoms selected from N, S, and O, A and X are as defined in Formula A-1, and the moieties Y are identical to or different from each other and are as defined for X in Formula A-1.

The use of the backbone structures meets the desired requirements of various organic layers of organic electroluminescent devices to achieve high efficiency and long lifetime of the devices.

As used herein, the term “substituted” in the definition of Q1 to Q3, R, R′, R₁ to R₁₃, and R₂₁ to R₂₄ in Formulae A-1 and A-2 indicates substitution with one or more substituents selected from deuterium, cyano, halogen, hydroxyl, nitro, C₁-C₂₄ alkyl, C₃-C₂₄ cycloalkyl, C₁-C₂₄ haloalkyl, C₁-C₂₄ alkenyl, C₁-C₂₄ alkynyl, C₁-C₂₄ heteroalkyl, C₁-C₂₄ heterocycloalkyl, C₆-C₂₄ aryl, C₆-C₂₄ arylalkyl, C₂-C₂₄ hetero aryl, C₂-C₂₄ heteroarylalkyl, C₁-C₂₄ alkoxy, C₁-C₂₄ alkylamino, C₁-C₂₄ arylamino, C₁-C₂₄ heteroarylamino, C₁-C₂₄ alkylsilyl, C₁-C₂₄ arylsilyl, and C₁-C₂₄ aryloxy, or a combination thereof. As used herein, the term “unsubstituted” indicates having no substituent.

In the “substituted or unsubstituted C₁-C₁₀ alkyl”, “substituted or unsubstituted C₆-C₃₀ aryl”, etc., the number of carbon atoms in the alkyl or aryl group indicates the number of carbon atoms constituting the unsubstituted alkyl or aryl moiety without considering the number of carbon atoms in the substituent(s). For example, a phenyl group substituted with a butyl group at the para-position corresponds to a C₆ aryl group substituted with a C₄ butyl group.

As used herein, the expression “form a ring with an adjacent substituent” means that the corresponding substituent combines with an adjacent substituent to form a substituted or unsubstituted alicyclic or aromatic ring and the term “adjacent substituent” may mean a substituent on an atom directly attached to an atom substituted with the corresponding substituent, a substituent disposed sterically closest to the corresponding substituent or another substituent on an atom substituted with the corresponding substituent. For example, two substituents substituted at the ortho position of a benzene ring or two substituents on the same carbon in an aliphatic ring may be considered “adjacent” to each other.

The alkyl groups may be straight or branched, and the numbers of carbon atoms therein are not particularly limited but are preferably 1 to 20. Specific examples of the alkyl groups include, but are not limited to, methyl, ethyl, propyl, n-propyl, isopropyl, butyl, n-butyl, isobutyl, tert-butyl, sec-butyl, 1-methylbutyl, 1-ethylbutyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, n-heptyl, 1-methylhexyl, cyclopentylmethyl, cyclohexylmethyl, octyl, n-octyl, tert-octyl, 1-methylheptyl, 2-ethylhexyl, 2-propylpentyl, n-nonyl, 2,2-dimethylheptyl, 1-ethylpropyl, 1,1-dimethylpropyl, isohexyl, 2-methylpentyl, 4-methylhexyl, and 5-methylhexyl groups.

The alkenyl group is intended to include straight and branched ones and may be optionally substituted with one or more other substituents. The alkenyl group may be specifically a vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl- 1-yl, 2-phenyl-2-(naphthyl- 1-yl)vinyl-1-yl, 2,2-bis(diphenyl-1-yl)vinyl-1-yl, stilbenyl or styrenyl group but is not limited thereto.

The alkynyl group is intended to include straight and branched ones and may be optionally substituted with one or more other substituents. The alkynyl group may be, for example, ethynyl or 2-propynyl but is not limited thereto.

The cycloalkyl group is intended to include monocyclic and polycyclic ones and may be optionally substituted with one or more other substituents. As used herein, the term “polycyclic” means that the cycloalkyl group may be directly attached or fused to one or more other cyclic groups. The other cyclic groups may be cycloalkyl groups and other examples thereof include heterocycloalkyl, aryl, and heteroaryl groups. The cycloalkyl group may be specifically a cyclopropyl, cyclobutyl, cyclopentyl, 3-methylcyclopentyl, 2,3-dimethylcyclopentyl, cyclohexyl, 3-methylcyclohexyl, 4-methylcyclohexyl, 2,3-dimethylcyclohexyl, 3,4,5-trimethylcyclohexyl, 4-tert-butylcyclohexyl, cycloheptyl or cyclooctyl group but is not limited thereto.

The heterocycloalkyl group is intended to include monocyclic and polycyclic ones interrupted by a heteroatom such as O, S, Se, N or Si and may be optionally substituted with one or more other substituents. As used herein, the term “polycyclic” means that the heterocycloalkyl group may be directly attached or fused to one or more other cyclic groups. The other cyclic groups may be heterocycloalkyl groups and other examples thereof include cycloalkyl, aryl, and heteroaryl groups.

The aryl groups may be monocyclic or polycyclic ones. Examples of the monocyclic aryl groups include, but are not limited to, phenyl, biphenyl, terphenyl, and stilbenyl groups. Examples of the polycyclic aryl groups include naphthyl, anthracenyl, phenanthrenyl, pyrenyl, perylenyl, tetracenyl, chrysenyl, fluorenyl, acenaphathcenyl, triphenylene, and fluoranthrene groups but the scope of the present invention is not limited thereto.

The heteroaryl groups refer to heterocyclic groups interrupted by one or more heteroatoms. Examples of the heteroaryl groups include, but are not limited to, thiophene, furan, pyrrole, imidazole, triazole, oxazole, oxadiazole, triazole, pyridyl, bipyridyl, pyrimidyl, triazine, triazole, acridyl, pyridazine, pyrazinyl, quinolinyl, quinazoline, quinoxalinyl, phthalazinyl, pyridopyrimidinyl, pyridopyrazinyl, pyrazinopyrazinyl, isoquinoline, indole, carbazole, benzoxazole, benzimidazole, benzothiazole, benzocarbazole, benzothiophene, dibenzothiophene, benzofuranyl, dibenzofuranyl, phenanthroline, thiazolyl, isoxazolyl, oxadiazolyl, thiadiazolyl, benzothiazolyl, and phenothiazinyl groups.

The mixed aliphatic-aromatic ring refers to a ring in which at least one aliphatic ring and at least one aromatic ring are linked or fused together and which is overall non-aromatic. The mixed aliphatic-aromatic polycyclic ring may contain one or more heteroatoms selected from N, O, P, and S other than carbon atoms (C).

The alkoxy group may be specifically a methoxy, ethoxy, propoxy, isobutyloxy, sec-butyloxy, pentyloxy, iso-amyloxy or hexyloxy group but is not limited thereto.

The silyl group is intended to include alkyl-substituted silyl groups and aryl-substituted silyl groups. Specific examples of such silyl groups include trimethylsilyl, triethylsilyl, triphenylsilyl, trimethoxysilyl, dimethoxyphenylsilyl, diphenylmethylsilyl, diphenylvinylsilyl, methylcyclobutylsilyl, and dimethylfurylsilyl.

The amine groups may be, for example, —NH₂, alkylamine groups, and arylamine groups. The arylamine groups are aryl-substituted amine groups and the alkylamine groups are alkyl-substituted amine groups. Examples of the arylamine groups include substituted or unsubstituted monoarylamine groups, substituted or unsubstituted diarylamine groups, and substituted or unsubstituted triarylamine groups. The aryl moieties in the arylamine groups may be monocyclic or polycyclic ones. The arylamine groups may include two or more aryl moieties. In this case, the aryl moieties may be monocyclic or polycyclic ones. Alternatively, the aryl moieties may consist of a monocyclic aryl moiety and a polycyclic aryl moiety. The aryl moieties in the arylamine groups may be selected from those exemplified above.

The aryl moieties in the aryloxy group and the arylthioxy group are the same as those described above for the aryl groups. Specific examples of the aryloxy groups include, but are not limited to, phenoxy, p-tolyloxy, m-tolyloxy, 3,5-dimethylphenoxy, 2,4,6-trimethylphenoxy, p-tert-butylphenoxy, 3-biphenyloxy, 4-biphenyloxy, 1-naphthyloxy, 2-naphthyloxy, 4-methyl-1-naphthyloxy, 5-methyl-2-naphthyloxy, 1-anthryloxy, 2-anthryloxy, 9-anthryloxy, 1-phenanthryloxy, 3-phenanthryloxy, and 9-phenanthryloxy groups. The arylthioxy group may be, for example, a phenylthioxy, 2-methylphenylthioxy or 4-tert-butylphenylthioxy group but is not limited thereto.

The halogen group may be, for example, fluorine, chlorine, bromine or iodine.

More specifically, the polycyclic aromatic derivative represented by Formula A-1 or A-2 according to the present invention may be selected from, but not limited to, the following compounds 1 to 183:

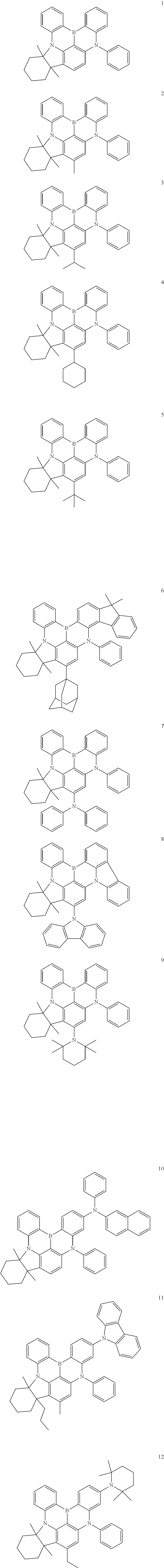

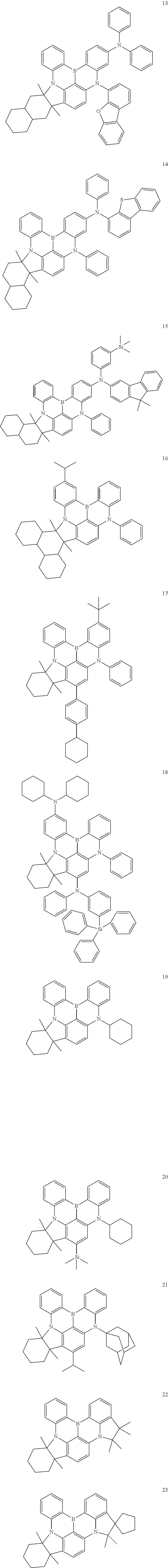

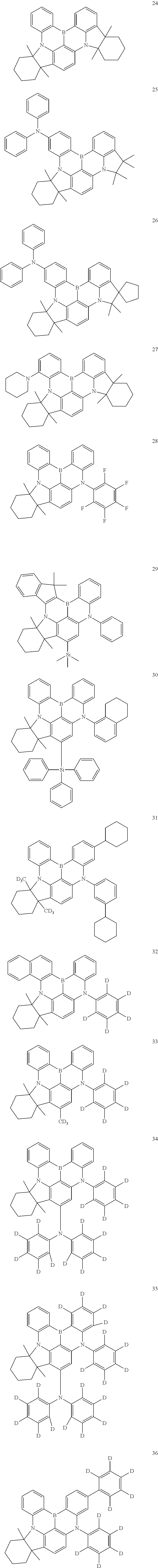

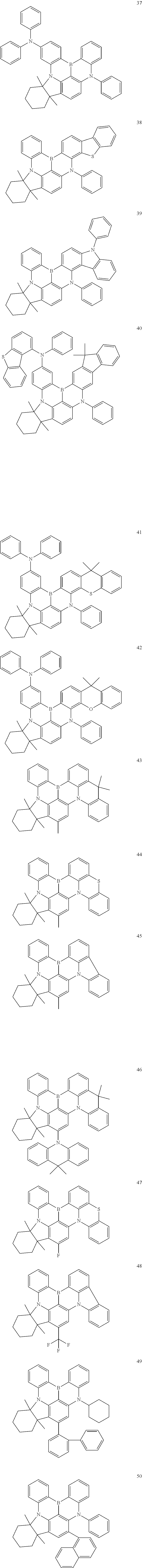

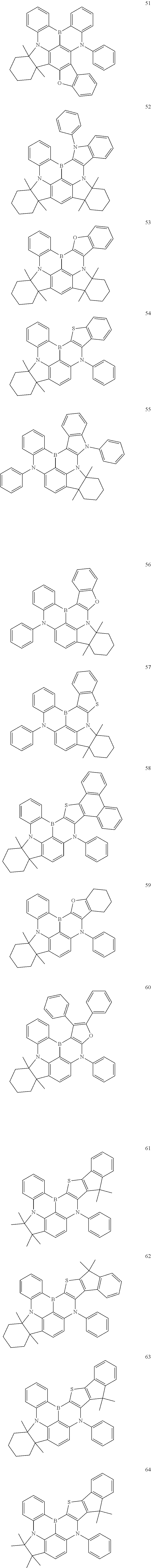

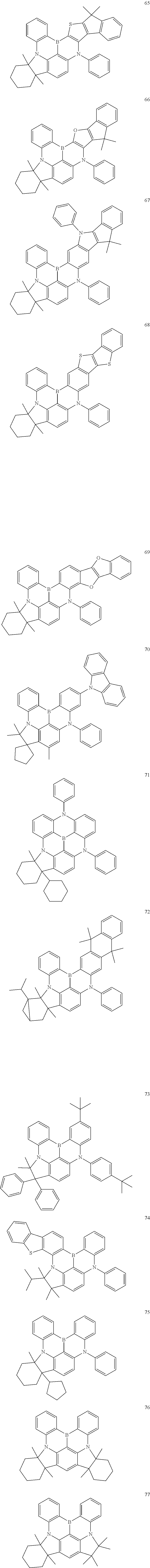

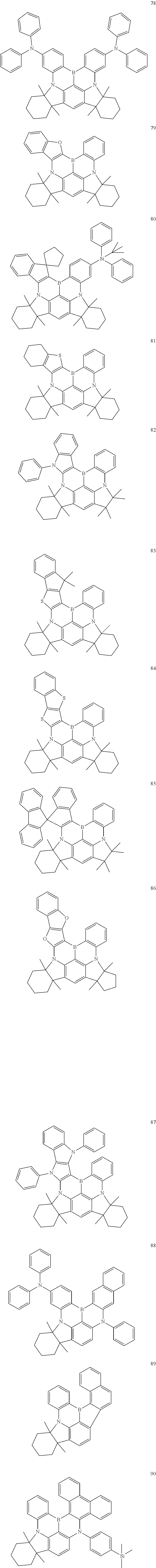

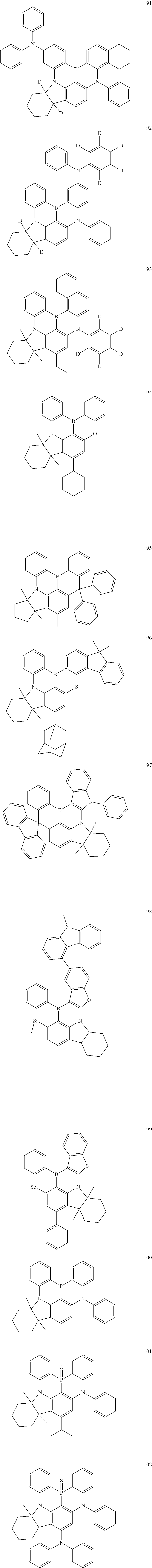

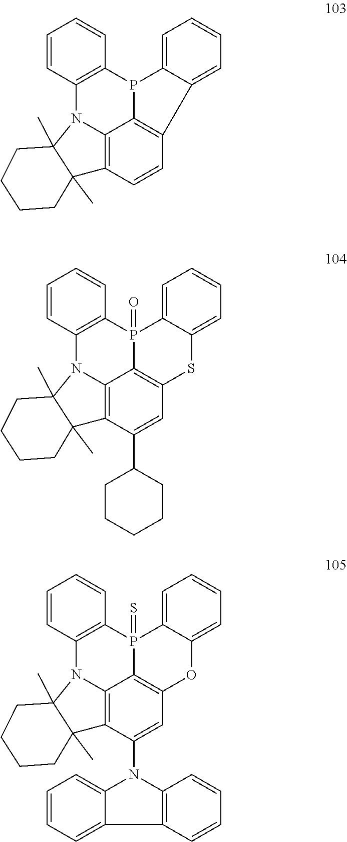 [SMILES: CC12CCCCC1(C)N1c3ccccc3-p3c4ccccc4c4ccc2c1c43 ; CC12CCCCC1(C)N1c3ccccc3P3(=O)c4ccccc4Sc4cc(C5CCCCC5)c2c1c43 ; CC12CCCCC1(C)N1c3ccccc3P3(=S)c4ccccc4Oc4cc(-n5c6ccccc6c6ccccc65)c2c1c43]

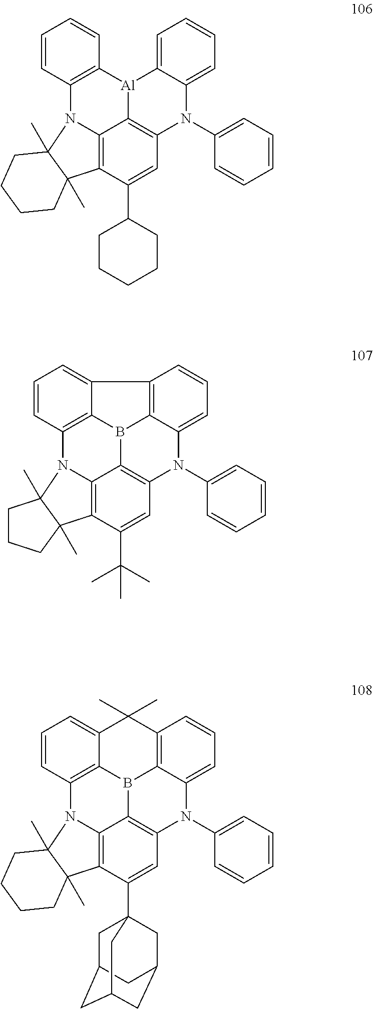

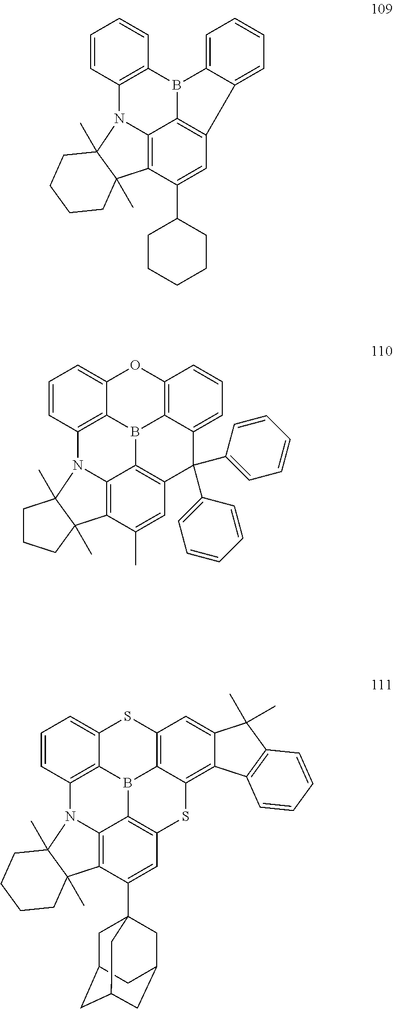 [SMILES: CC12CCCCC1(C)N1c3ccccc3B3c4ccccc4-c4cc(C5CCCCC5)c2c1c43 ; Cc1cc2c3c4c1C1(C)CCCC1(C)N4c1cccc4c1B3c1c(cccc1C2(c1ccccc1)c1ccccc1)O4 ; CC1(C)c2ccccc2-c2c1cc1c3c2Sc2cc(C45CC6CC(CC(C6)C4)C5)c4c5c2B3c2c(cccc2N5C2(C)CCCCC42C)S1]

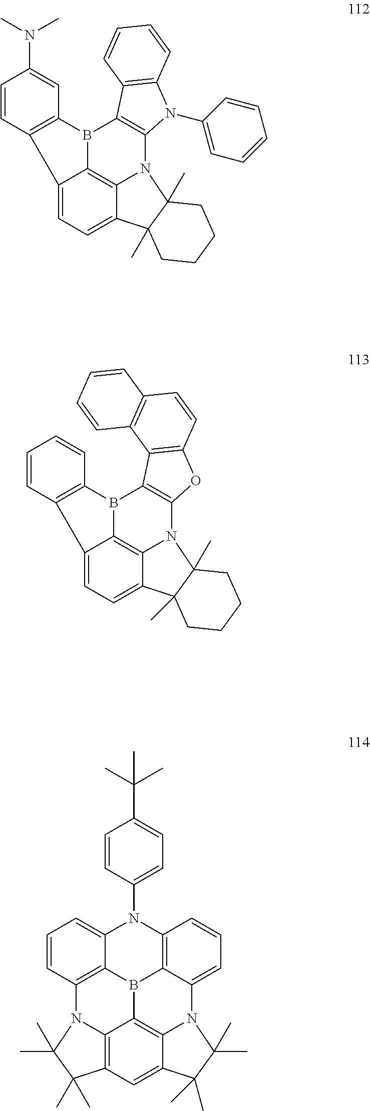

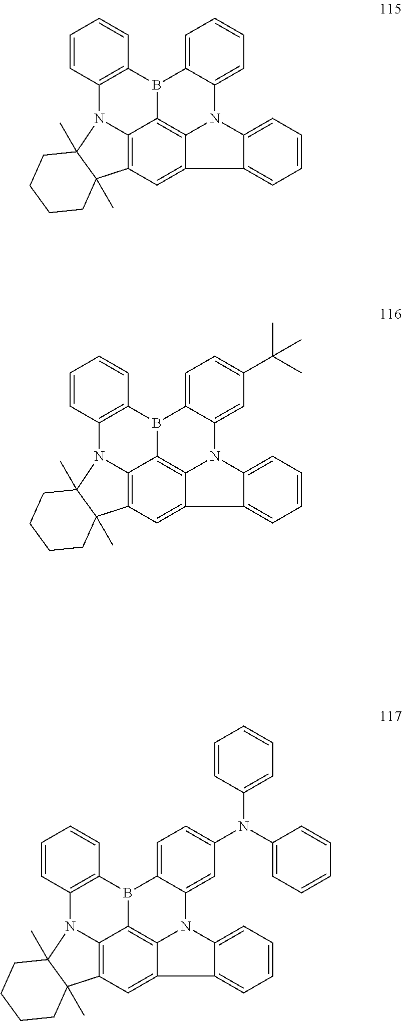 [SMILES: CC12CCCCC1(C)N1c3ccccc3B3c4ccccc4-n4c5ccccc5c5cc2c1c3c54 ; CC(C)(C)c1ccc2c(c1)-n1c3ccccc3c3cc4c5c(c31)B2c1ccccc1N5C1(C)CCCCC41C ; CC12CCCCC1(C)N1c3ccccc3B3c4ccc(N(c5ccccc5)c5ccccc5)cc4-n4c5ccccc5c5cc2c1c3c54]

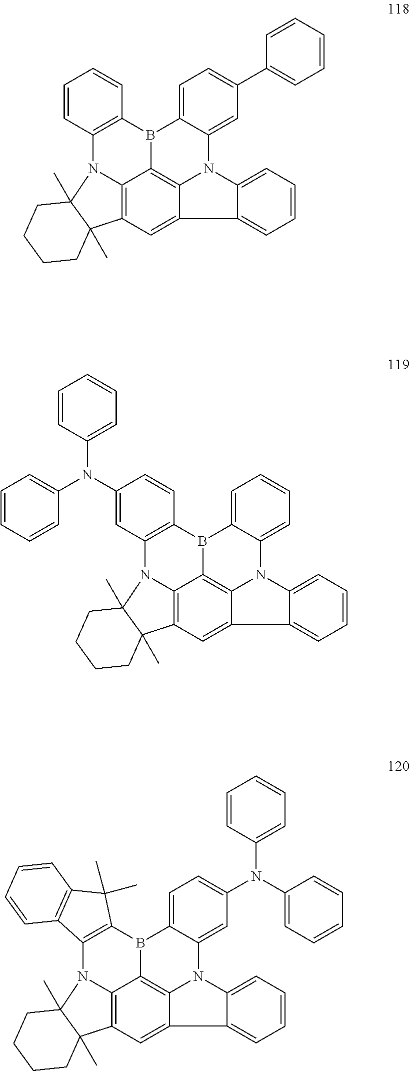 [SMILES: CC12CCCCC1(C)N1c3ccccc3B3c4ccc(-c5ccccc5)cc4-n4c5ccccc5c5cc2c1c3c54 ; CC12CCCCC1(C)N1c3cc(N(c4ccccc4)c4ccccc4)ccc3B3c4ccccc4-n4c5ccccc5c5cc2c1c3c54 ; CC1(C)C2=C(c3ccccc31)N1c3c(cc4c5ccccc5n5c4c3B2c2ccc(N(c3ccccc3)c3ccccc3)cc2-5)C2(C)CCCCC12C]

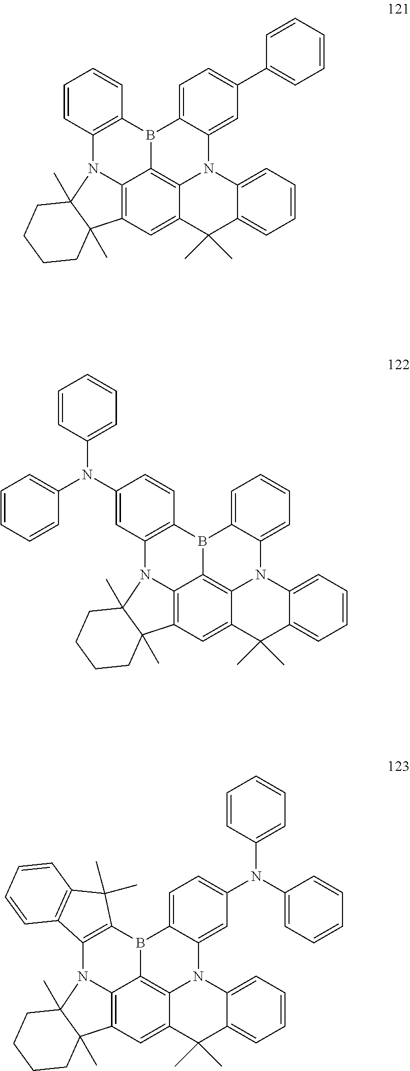 [SMILES: CC1(C)c2ccccc2N2c3cc(-c4ccccc4)ccc3B3c4ccccc4N4c5c(cc1c2c53)C1(C)CCCCC41C ; CC1(C)c2ccccc2N2c3ccccc3B3c4ccc(N(c5ccccc5)c5ccccc5)cc4N4c5c(cc1c2c53)C1(C)CCCCC41C ; CC1(C)C2=C(c3ccccc31)N1c3c(cc4c5c3B2c2ccc(N(c3ccccc3)c3ccccc3)cc2N5c2ccccc2C4(C)C)C2(C)CCCCC12C]

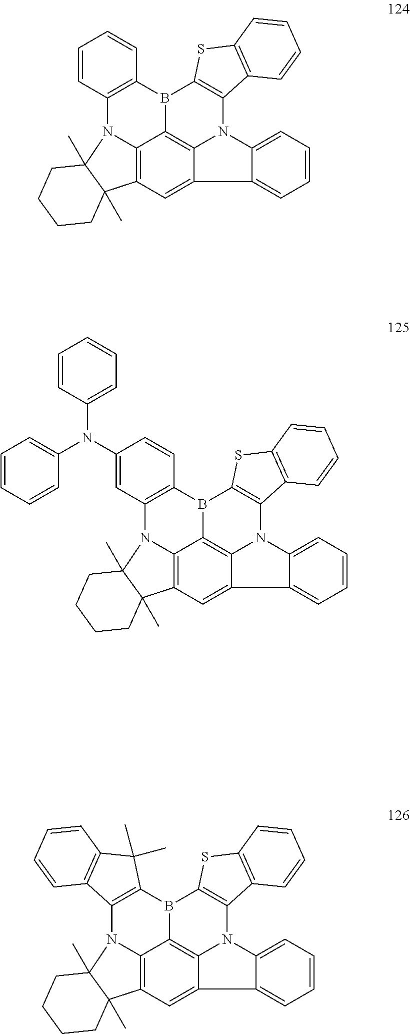 [SMILES: CC12CCCCC1(C)N1c3ccccc3B3c4sc5ccccc5c4-n4c5ccccc5c5cc2c1c3c54 ; CC12CCCCC1(C)N1c3cc(N(c4ccccc4)c4ccccc4)ccc3B3c4sc5ccccc5c4-n4c5ccccc5c5cc2c1c3c54 ; CC1(C)C2=C(c3ccccc31)N1c3c(cc4c5ccccc5n5c4c3B2c2sc3ccccc3c2-5)C2(C)CCCCC12C]

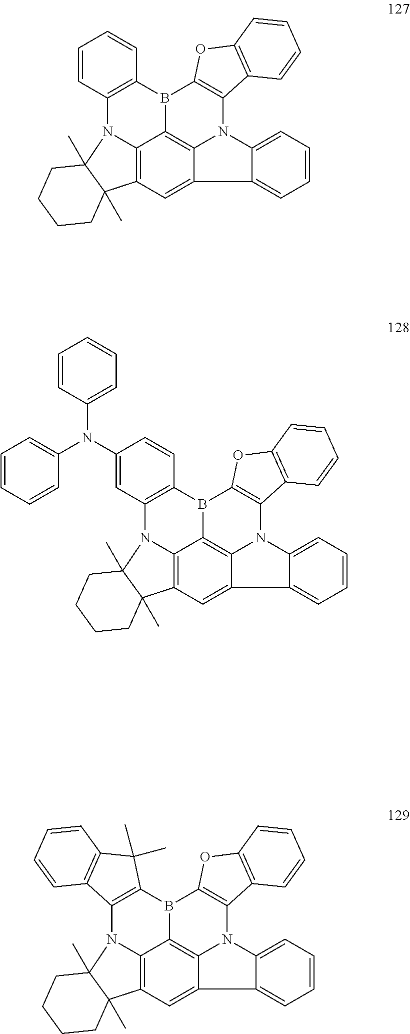 [SMILES: CC12CCCCC1(C)N1c3ccccc3B3c4oc5ccccc5c4-n4c5ccccc5c5cc2c1c3c54 ; CC12CCCCC1(C)N1c3cc(N(c4ccccc4)c4ccccc4)ccc3B3c4oc5ccccc5c4-n4c5ccccc5c5cc2c1c3c54 ; CC1(C)C2=C(c3ccccc31)N1c3c(cc4c5ccccc5n5c4c3B2c2oc3ccccc3c2-5)C2(C)CCCCC12C]

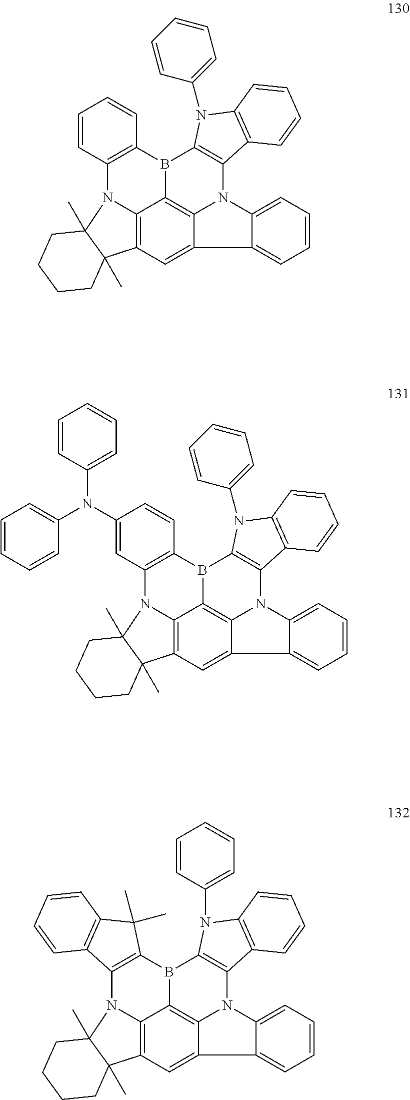 [SMILES: CC12CCCCC1(C)N1c3ccccc3B3c4c1c2cc1c2ccccc2n(c41)-c1c3n(-c2ccccc2)c2ccccc12 ; CC12CCCCC1(C)N1c3cc(N(c4ccccc4)c4ccccc4)ccc3B3c4c1c2cc1c2ccccc2n(c41)-c1c3n(-c2ccccc2)c2ccccc12 ; CC1(C)C2=C(c3ccccc31)N1c3c(cc4c5ccccc5n5c4c3B2c2c-5c3ccccc3n2-c2ccccc2)C2(C)CCCCC12C]

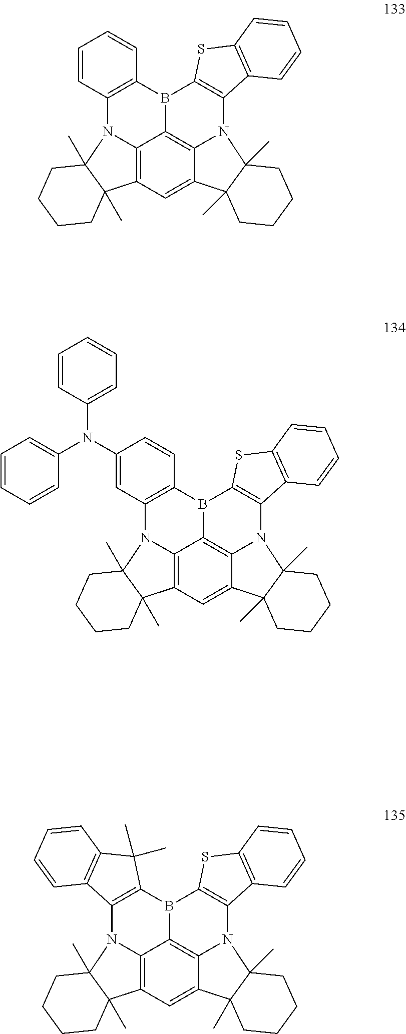 [SMILES: CC12CCCCC1(C)N1c3ccccc3B3c4sc5ccccc5c4N4c5c(cc2c1c53)C1(C)CCCCC41C ; CC12CCCCC1(C)N1c3cc(N(c4ccccc4)c4ccccc4)ccc3B3c4sc5ccccc5c4N4c5c(cc2c1c53)C1(C)CCCCC41C ; CC1(C)C2=C(c3ccccc31)N1c3c(cc4c5c3B2c2sc3ccccc3c2N5C2(C)CCCCC42C)C2(C)CCCCC12C]

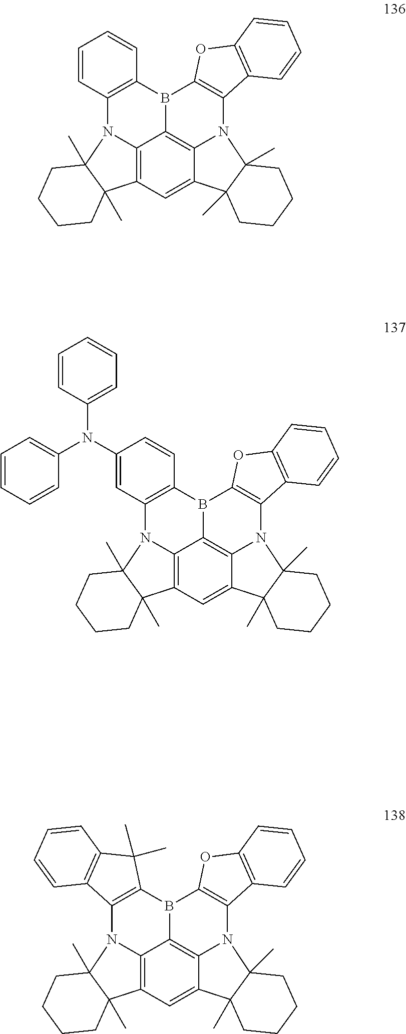 [SMILES: CC12CCCCC1(C)N1c3ccccc3B3c4oc5ccccc5c4N4c5c(cc2c1c53)C1(C)CCCCC41C ; CC12CCCCC1(C)N1c3cc(N(c4ccccc4)c4ccccc4)ccc3B3c4oc5ccccc5c4N4c5c(cc2c1c53)C1(C)CCCCC41C ; CC1(C)C2=C(c3ccccc31)N1c3c(cc4c5c3B2c2oc3ccccc3c2N5C2(C)CCCCC42C)C2(C)CCCCC12C]

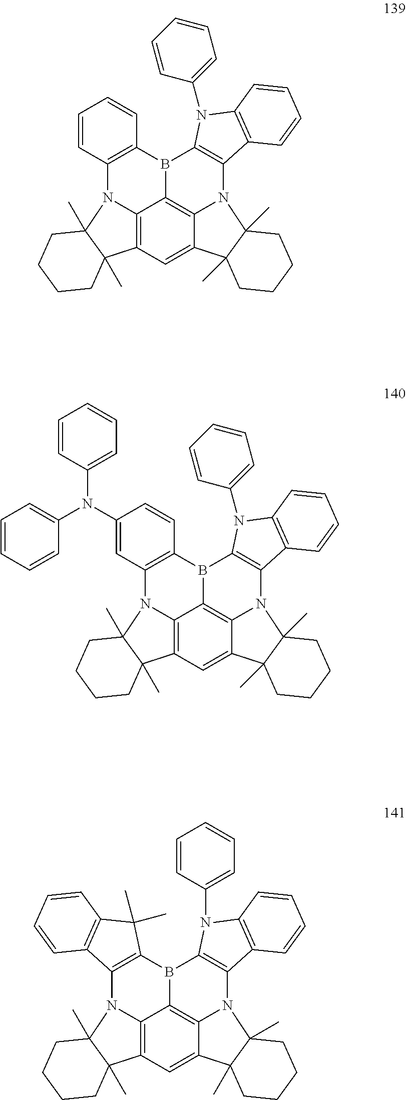 [SMILES: CC12CCCCC1(C)N1c3ccccc3B3c4c1c2cc1c4N(c2c3n(-c3ccccc3)c3ccccc23)C2(C)CCCCC12C ; CC12CCCCC1(C)N1c3cc(N(c4ccccc4)c4ccccc4)ccc3B3c4c1c2cc1c4N(c2c3n(-c3ccccc3)c3ccccc23)C2(C)CCCCC12C ; CC1(C)C2=C(c3ccccc31)N1c3c(cc4c5c3B2c2c(c3ccccc3n2-c2ccccc2)N5C2(C)CCCCC42C)C2(C)CCCCC12C]

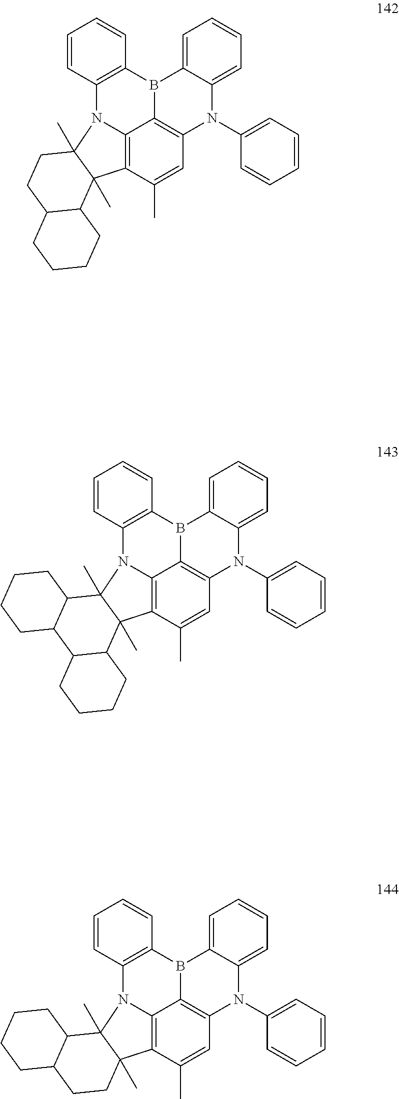 [SMILES: Cc1cc2c3c4c1C1(C)C5CCCCC5CCC1(C)N4c1ccccc1B3c1ccccc1N2c1ccccc1 ; Cc1cc2c3c4c1C1(C)C5CCCCC5C5CCCCC5C1(C)N4c1ccccc1B3c1ccccc1N2c1ccccc1 ; Cc1cc2c3c4c1C1(C)CCC5CCCCC5C1(C)N4c1ccccc1B3c1ccccc1N2c1ccccc1]

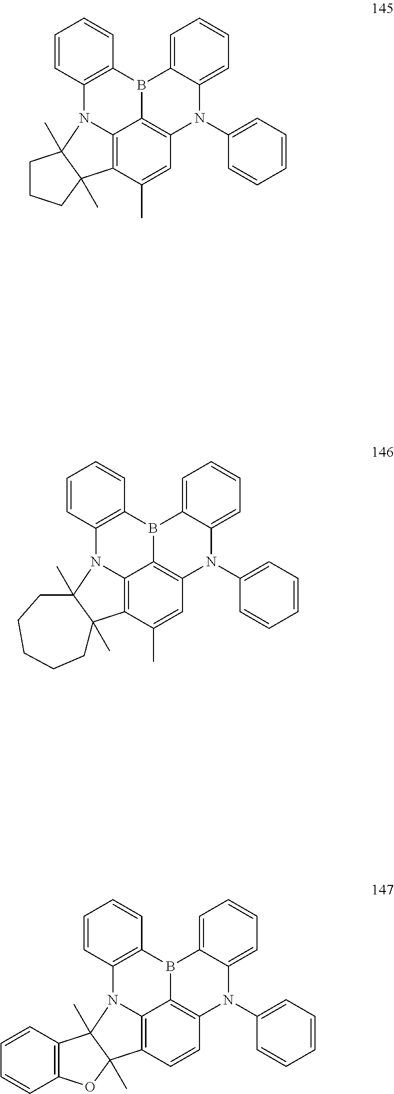 [SMILES: Cc1cc2c3c4c1C1(C)CCCC1(C)N4c1ccccc1B3c1ccccc1N2c1ccccc1 ; Cc1cc2c3c4c1C1(C)CCCCCC1(C)N4c1ccccc1B3c1ccccc1N2c1ccccc1 ; CC12Oc3ccccc3C1(C)N1c3ccccc3B3c4ccccc4N(c4ccccc4)c4ccc2c1c43]

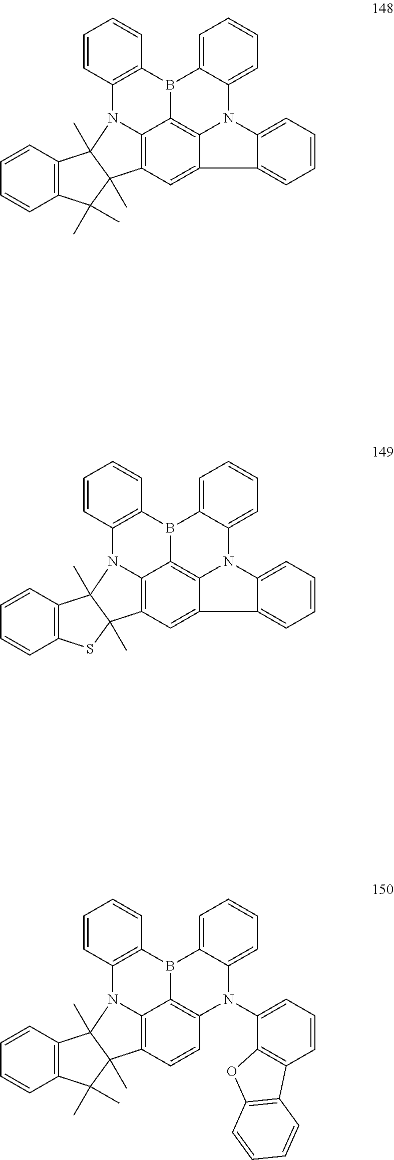 [SMILES: CC1(C)c2ccccc2C2(C)N3c4ccccc4B4c5ccccc5-n5c6ccccc6c6cc(c3c4c65)C12C ; CC12Sc3ccccc3C1(C)N1c3ccccc3B3c4ccccc4-n4c5ccccc5c5cc2c1c3c54 ; CC1(C)c2ccccc2C2(C)N3c4ccccc4B4c5ccccc5N(c5cccc6c5oc5ccccc56)c5ccc(c3c54)C12C]

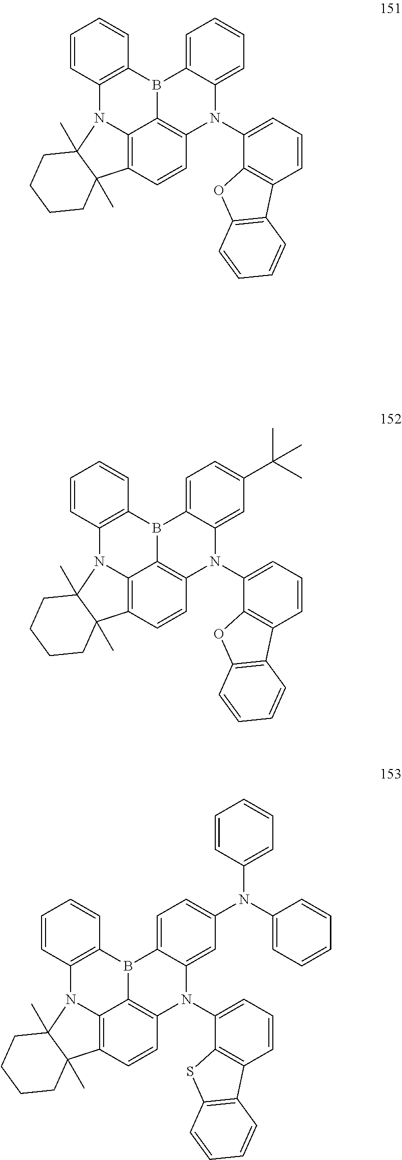 [SMILES: CC12CCCCC1(C)N1c3ccccc3B3c4ccccc4N(c4cccc5c4oc4ccccc45)c4ccc2c1c43 ; CC(C)(C)c1ccc2c(c1)N(c1cccc3c1oc1ccccc13)c1ccc3c4c1B2c1ccccc1N4C1(C)CCCCC31C ; CC12CCCCC1(C)N1c3ccccc3B3c4ccc(N(c5ccccc5)c5ccccc5)cc4N(c4cccc5c4sc4ccccc45)c4ccc2c1c43]

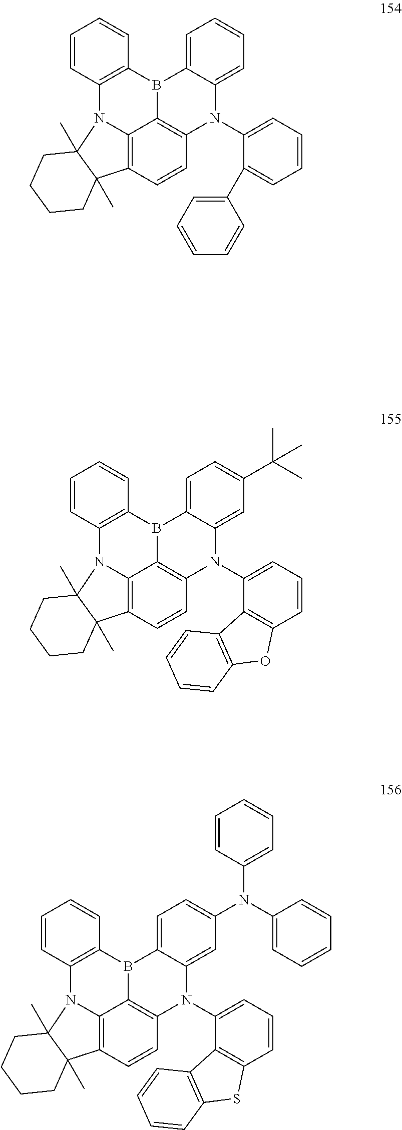 [SMILES: CC12CCCCC1(C)N1c3ccccc3B3c4ccccc4N(c4ccccc4-c4ccccc4)c4ccc2c1c43 ; CC(C)(C)c1ccc2c(c1)N(c1cccc3oc4ccccc4c13)c1ccc3c4c1B2c1ccccc1N4C1(C)CCCCC31C ; CC12CCCCC1(C)N1c3ccccc3B3c4ccc(N(c5ccccc5)c5ccccc5)cc4N(c4cccc5sc6ccccc6c45)c4ccc2c1c43]

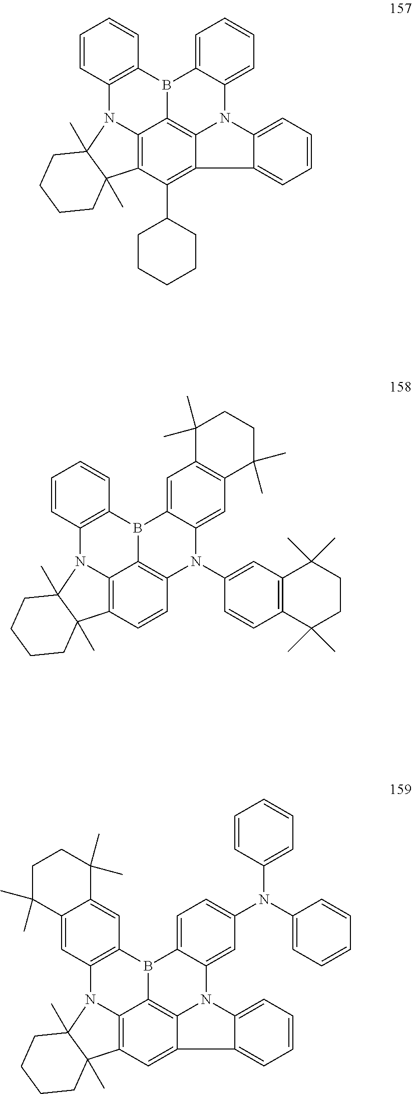 [SMILES: CC12CCCCC1(C)N1c3ccccc3B3c4ccccc4-n4c5ccccc5c5c(C6CCCCC6)c2c1c3c54 ; CC1(C)CCC(C)(C)c2cc(N3c4cc5c(cc4B4c6ccccc6N6c7c(ccc3c74)C3(C)CCCCC63C)C(C)(C)CCC5(C)C)ccc21 ; CC1(C)CCC(C)(C)c2cc3c(cc21)B1c2ccc(N(c4ccccc4)c4ccccc4)cc2-n2c4ccccc4c4cc5c(c1c42)N3C1(C)CCCCC51C]

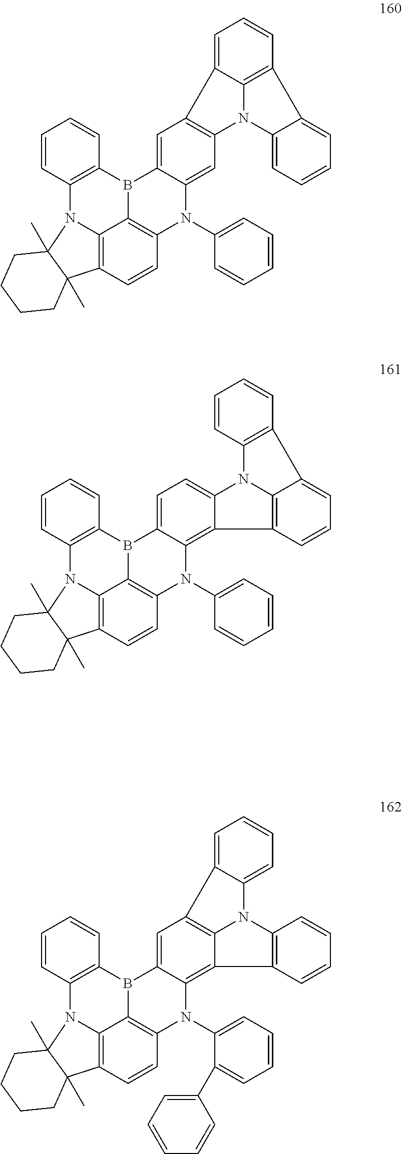 [SMILES: CC12CCCCC1(C)N1c3ccccc3B3c4cc5c6cccc7c8ccccc8n(c5cc4N(c4ccccc4)c4ccc2c1c43)c76 ; CC12CCCCC1(C)N1c3ccccc3B3c4ccc5c(c4N(c4ccccc4)c4ccc2c1c43)c1cccc2c3ccccc3n5c21 ; CC12CCCCC1(C)N1c3ccccc3B3c4cc5c6ccccc6n6c7ccccc7c(c4N(c4ccccc4-c4ccccc4)c4ccc2c1c43)c56]

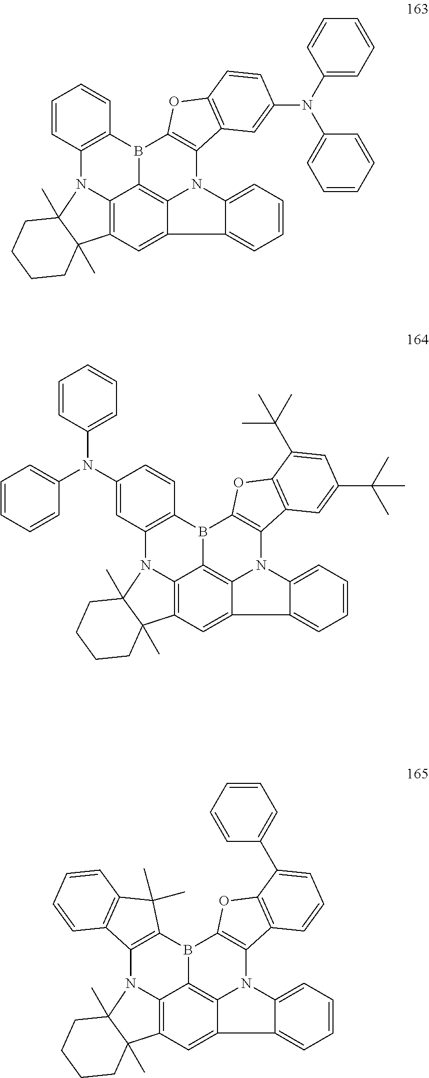 [SMILES: CC12CCCCC1(C)N1c3ccccc3B3c4oc5ccc(N(c6ccccc6)c6ccccc6)cc5c4-n4c5ccccc5c5cc2c1c3c54 ; CC(C)(C)c1cc(C(C)(C)C)c2oc3c(c2c1)-n1c2ccccc2c2cc4c5c(c21)B3c1ccc(N(c2ccccc2)c2ccccc2)cc1N5C1(C)CCCCC41C ; CC1(C)C2=C(c3ccccc31)N1c3c(cc4c5ccccc5n5c4c3B2c2oc3c(-c4ccccc4)cccc3c2-5)C2(C)CCCCC12C]

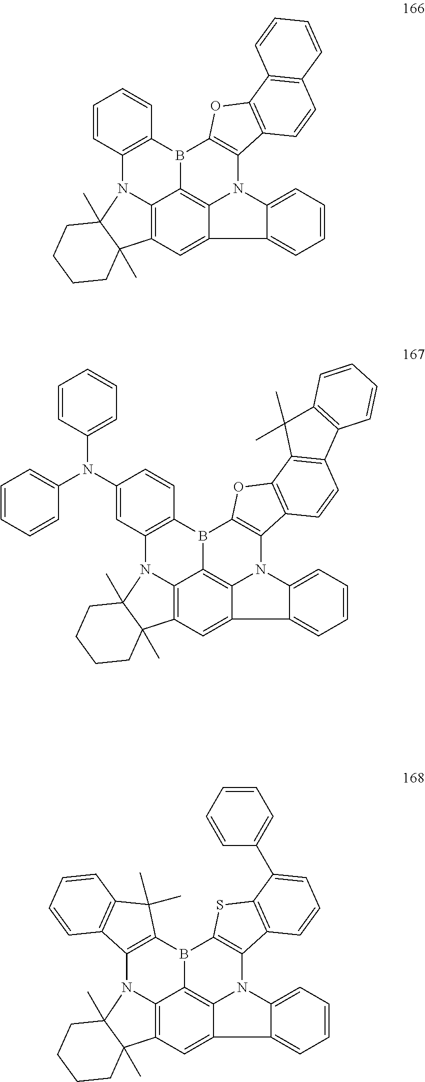 [SMILES: CC12CCCCC1(C)N1c3ccccc3B3c4oc5c(ccc6ccccc65)c4-n4c5ccccc5c5cc2c1c3c54 ; CC1(C)c2ccccc2-c2ccc3c4c(oc3c21)B1c2ccc(N(c3ccccc3)c3ccccc3)cc2N2c3c(cc5c6ccccc6n-4c5c31)C1(C)CCCCC21C ; CC1(C)C2=C(c3ccccc31)N1c3c(cc4c5ccccc5n5c4c3B2c2sc3c(-c4ccccc4)cccc3c2-5)C2(C)CCCCC12C]

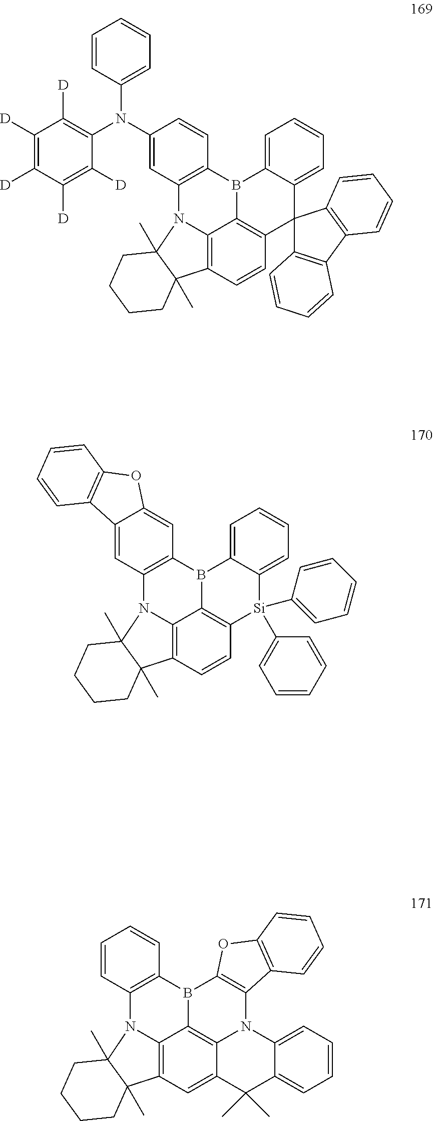 [SMILES: [2H]c1c([2H])c([2H])c(N(c2ccccc2)c2ccc3c(c2)N2c4c(ccc5c4B3c3ccccc3C53c4ccccc4-c4ccccc43)C3(C)CCCCC23C)c([2H])c1[2H] ; CC12CCCCC1(C)N1c3cc4c(cc3B3c5ccccc5[Si](c5ccccc5)(c5ccccc5)c5ccc2c1c53)oc1ccccc14 ; CC1(C)c2ccccc2N2c3c1cc1c4c3B(c3ccccc3N4C3(C)CCCCC13C)c1oc3ccccc3c12]

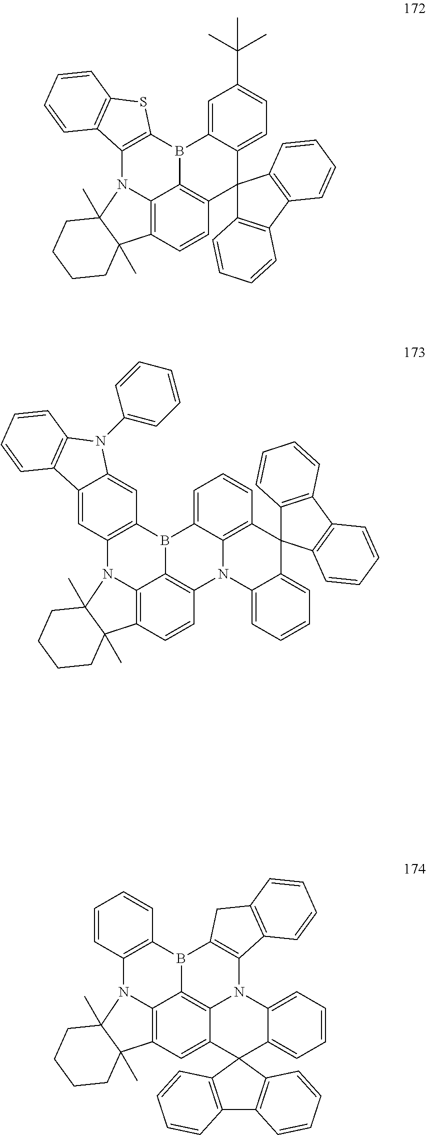 [SMILES: CC(C)(C)c1ccc2c(c1)B1c3sc4ccccc4c3N3c4c(ccc(c41)C21c2ccccc2-c2ccccc21)C1(C)CCCCC31C ; CC12CCCCC1(C)N1c3cc4c5ccccc5n(-c5ccccc5)c4cc3B3c4cccc5c4N(c4ccccc4C54c5ccccc5-c5ccccc54)c4ccc2c1c43 ; CC12CCCCC1(C)N1c3ccccc3B3C4=C(c5ccccc5C4)N4c5ccccc5C5(c6ccccc6-c6ccccc65)c5cc2c1c3c54]

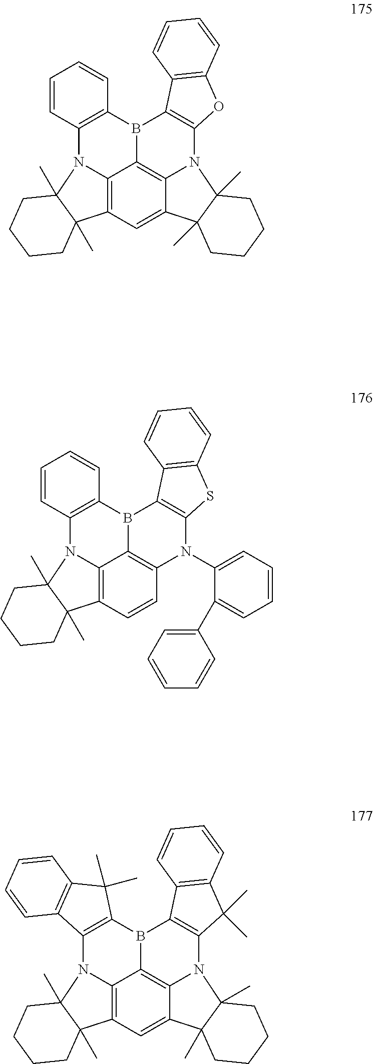 [SMILES: CC12CCCCC1(C)N1c3ccccc3B3c4c1c2cc1c4N(c2oc4ccccc4c23)C2(C)CCCCC12C ; CC12CCCCC1(C)N1c3ccccc3B3c4c(ccc2c41)N(c1ccccc1-c1ccccc1)c1sc2ccccc2c13 ; CC1(C)C2=C(c3ccccc31)N1c3c(cc4c5c3B2C2=C(N5C3(C)CCCCC43C)C(C)(C)c3ccccc32)C2(C)CCCCC12C]

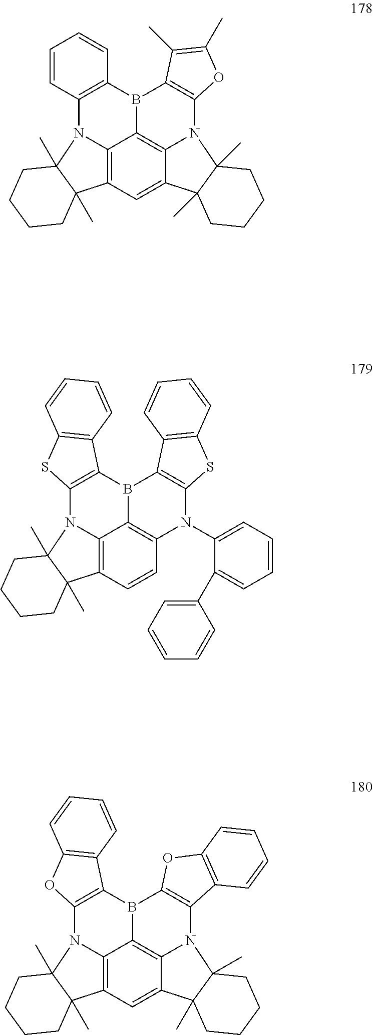 [SMILES: Cc1oc2c(c1C)B1c3ccccc3N3c4c(cc5c(c41)N2C1(C)CCCCC51C)C1(C)CCCCC31C ; CC12CCCCC1(C)N1c3sc4ccccc4c3B3c4c(ccc2c41)N(c1ccccc1-c1ccccc1)c1sc2ccccc2c13 ; CC12CCCCC1(C)N1c3oc4ccccc4c3B3c4oc5ccccc5c4N4c5c(cc2c1c53)C1(C)CCCCC41C]

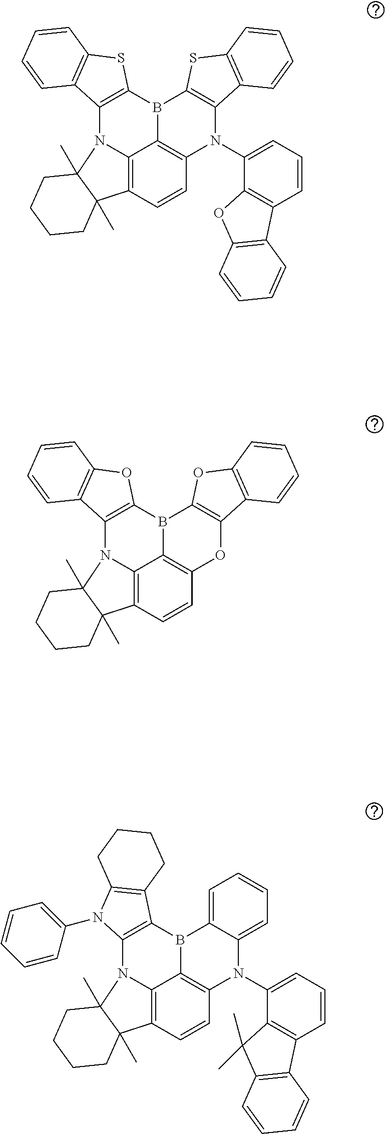 [SMILES: CC12CCCCC1(C)N1c3c2ccc2c3B(c3sc4ccccc4c3N2c2cccc3c2oc2ccccc23)c2sc3ccccc3c21 ; CC12CCCCC1(C)N1c3c2ccc2c3B(c3oc4ccccc4c3O2)c2oc3ccccc3c21 ; CC1(C)c2ccccc2-c2cccc(N3c4ccccc4B4c5c3ccc3c5N(c5c4c4c(n5-c5ccccc5)CCCC4)C4(C)CCCCC34C)c21]

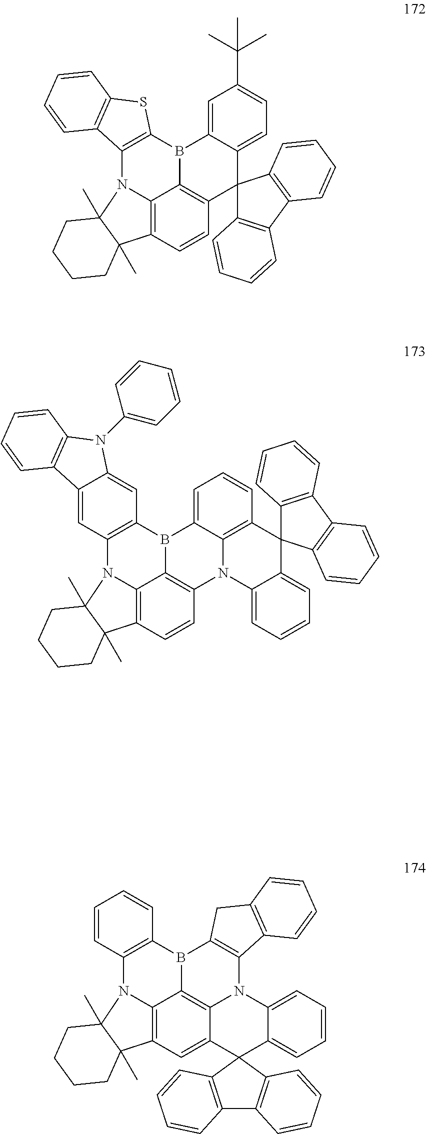 [SMILES: CC(C)(C)c1ccc2c(c1)B1c3sc4ccccc4c3N3c4c(ccc(c41)C21c2ccccc2-c2ccccc21)C1(C)CCCCC31C ; CC12CCCCC1(C)N1c3cc4c5ccccc5n(-c5ccccc5)c4cc3B3c4cccc5c4N(c4ccccc4C54c5ccccc5-c5ccccc54)c4ccc2c1c43 ; CC12CCCCC1(C)N1c3ccccc3B3C4=C(c5ccccc5C4)N4c5ccccc5C5(c6ccccc6-c6ccccc65)c5cc2c1c3c54]

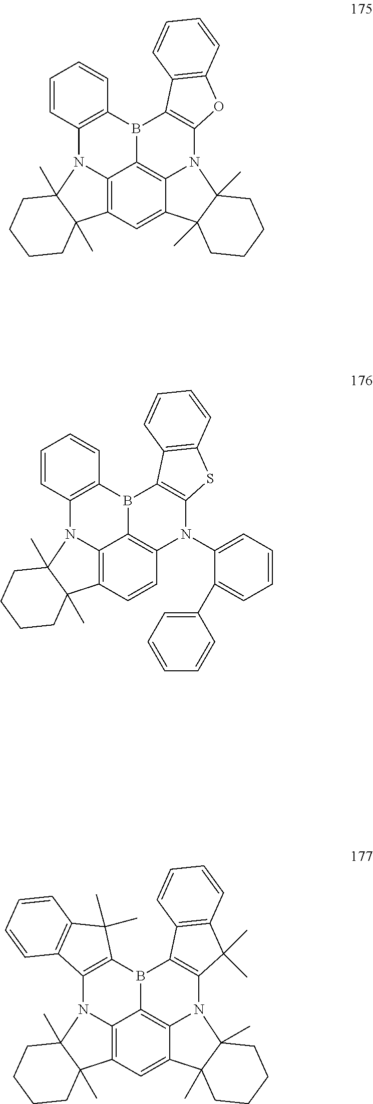 [SMILES: CC12CCCCC1(C)N1c3ccccc3B3c4c1c2cc1c4N(c2oc4ccccc4c23)C2(C)CCCCC12C ; CC12CCCCC1(C)N1c3ccccc3B3c4c(ccc2c41)N(c1ccccc1-c1ccccc1)c1sc2ccccc2c13 ; CC1(C)C2=C(c3ccccc31)N1c3c(cc4c5c3B2C2=C(N5C3(C)CCCCC43C)C(C)(C)c3ccccc32)C2(C)CCCCC12C]

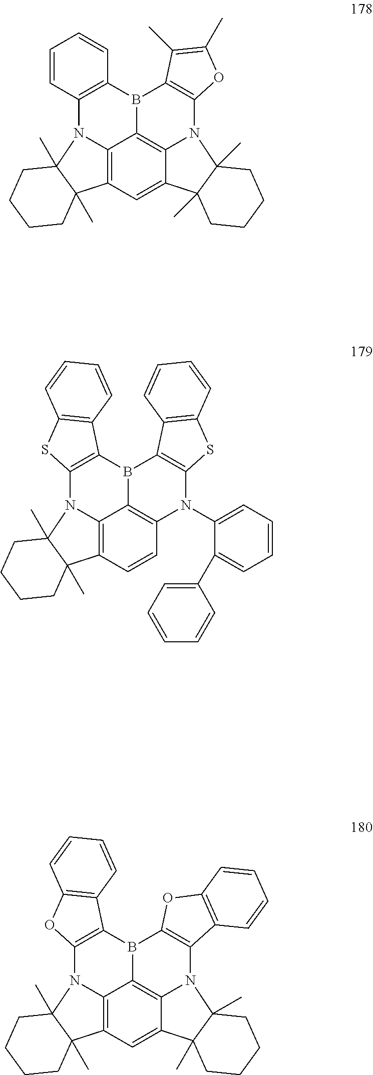 [SMILES: Cc1oc2c(c1C)B1c3ccccc3N3c4c(cc5c(c41)N2C1(C)CCCCC51C)C1(C)CCCCC31C ; CC12CCCCC1(C)N1c3sc4ccccc4c3B3c4c(ccc2c41)N(c1ccccc1-c1ccccc1)c1sc2ccccc2c13 ; CC12CCCCC1(C)N1c3oc4ccccc4c3B3c4oc5ccccc5c4N4c5c(cc2c1c53)C1(C)CCCCC41C]

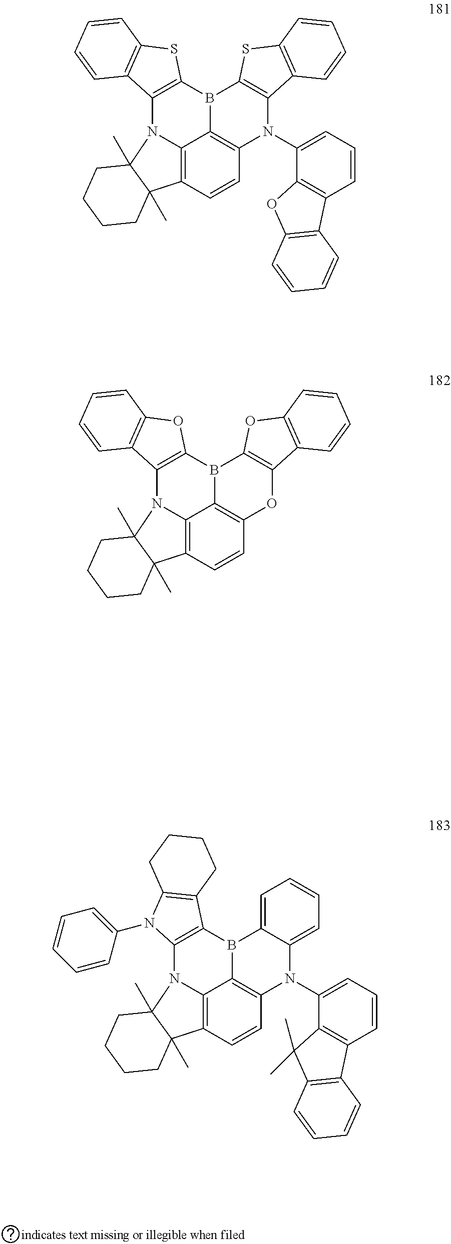 [SMILES: CC12CCCCC1(C)N1c3c2ccc2c3B(c3sc4ccccc4c3N2c2cccc3c2oc2ccccc23)c2sc3ccccc3c21 ; CC12CCCCC1(C)N1c3c2ccc2c3B(c3oc4ccccc4c3O2)c2oc3ccccc3c21 ; CC1(C)c2ccccc2-c2cccc(N3c4ccccc4B4c5c3ccc3c5N(c5c4c4c(n5-c5ccccc5)CCCC4)C4(C)CCCCC34C)c21]

The specific substituents in Formulae A-1 and A-2 can be clearly seen from the structures of the compounds 1 to 183 but are not intended to limit the scope of the compounds represented by Formulae A-1 and A-2.

As can be seen from the above specific compounds, the polycyclic aromatic derivative of the present invention contains B, P or P═O and has a polycyclic aromatic structure. The introduction of substituents into the polycyclic aromatic structure enables the synthesis of organic light emitting materials with inherent characteristics of the substituents. For example, the substituents are designed for use in materials for hole injecting layers, hole transport layers, light emitting layers, electron transport layers, electron injecting layers, electron blocking layers, and hole blocking layers of organic electroluminescent devices. This introduction meets the requirements of materials for the organic layers, enabling the fabrication of organic electroluminescent devices with high efficiency.

A further aspect of the present invention is directed to an organic electroluminescent device including a first electrode, a second electrode, and one or more organic layers interposed between the first and second electrodes wherein one of the organic layers includes at least one of the electroluminescent compounds that can be represented by Formulae A-1 and A-2.

That is, according to one embodiment of the present invention, the organic electroluminescent device has a structure in which one or more organic layers are arranged between a first electrode and a second electrode. The organic electroluminescent device of the present invention may be fabricated by a suitable method known in the art using suitable materials known in the art, except that the electroluminescent compound of Formula A-1 or A-2 is used to form the corresponding organic layer.

The organic layers of the organic electroluminescent device according to the present invention may form a monolayer structure. Alternatively, the organic layers may have a multilayer stack structure. For example, the organic layers may have a structure including a hole injecting layer, a hole transport layer, a hole blocking layer, a light emitting layer, an electron blocking layer, an electron transport layer, and an electron injecting layer but is not limited to this structure. The number of the organic layers is not limited and may be increased or decreased. Preferred structures of the organic layers of the organic electroluminescent device according to the present invention will be explained in more detail in the Examples section that follows.

The organic electroluminescent device of the present invention will be described in more detail with reference to exemplary embodiments.

The organic electroluminescent device of the present invention includes an anode, a hole transport layer, a light emitting layer, an electron transport layer, and a cathode. The organic electroluminescent device of the present invention may optionally further include a hole injecting layer between the anode and the hole transport layer and an electron injecting layer between the electron transport layer and the cathode. If necessary, the organic electroluminescent device of the present invention may further include one or two intermediate layers such as a hole blocking layer or an electron blocking layer. The organic electroluminescent device of the present invention may further include one or more organic layers that have various functions depending on the desired characteristics of the device.

The light emitting layer of the organic electroluminescent device according to the present invention includes, as a host compound, an anthracene derivative represented by Formula C.

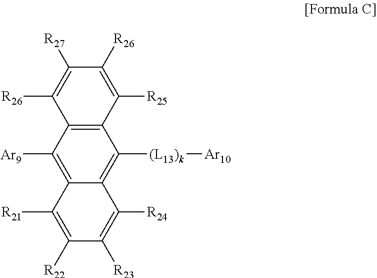

wherein R₂₁ to R₂₈ are identical to or different from each other and are as defined for R₁ to R₁₃ in Formula A-1 or A-2, Ar₉ and Ar₁₀ are identical to or different from each other and are each independently selected from hydrogen, deuterium, substituted or unsubstituted C₁-C₃₀ alkyl, substituted or unsubstituted C₆-C₅₀ aryl, substituted or unsubstituted C₂-C₃₀ alkenyl, substituted or unsubstituted C₂-C₂₀ alkynyl, substituted or unsubstituted C₃-C₃₀ cycloalkyl, substituted or unsubstituted C₅-C₃₀ cycloalkenyl, substituted or unsubstituted C₂-C₅₀ heteroaryl, substituted or unsubstituted C₂-C₃₀ heterocycloalkyl, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₆-C₃₀ arylthioxy, substituted or unsubstituted C₁-C₃₀ alkylamine, substituted or unsubstituted C₆-C₃₀ arylamine, substituted or unsubstituted C₁-C₃₀ alkylsilyl, and substituted or unsubstituted C₆-C₃₀ arylsilyl, Lia is a single bond or is selected from substituted or unsubstituted C₆-C₂₀ arylene and substituted or unsubstituted C₂-C₂₀ heteroarylene, preferably a single bond or substituted or unsubstituted C₆-C₂₀arylene, and k is an integer from 1 to 3, provided that when k is 2 or more, the linkers L13 are identical to or different from each other.

Ar₉ in Formula C is represented by Formula C-1:

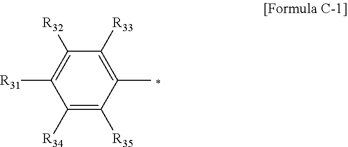

wherein R₃₁ to R₃₅ are identical to or different from each other and are as defined for R₁ to R₁₃ in Formula A-1 or A-2 and each of R₃₁ to R₃₅ is optionally bonded to an adjacent substituent to form a saturated or unsaturated ring.

The compound of Formula C employed in the organic electroluminescent device of the present invention may be specifically selected from the compounds of Formulae C1 to C48:

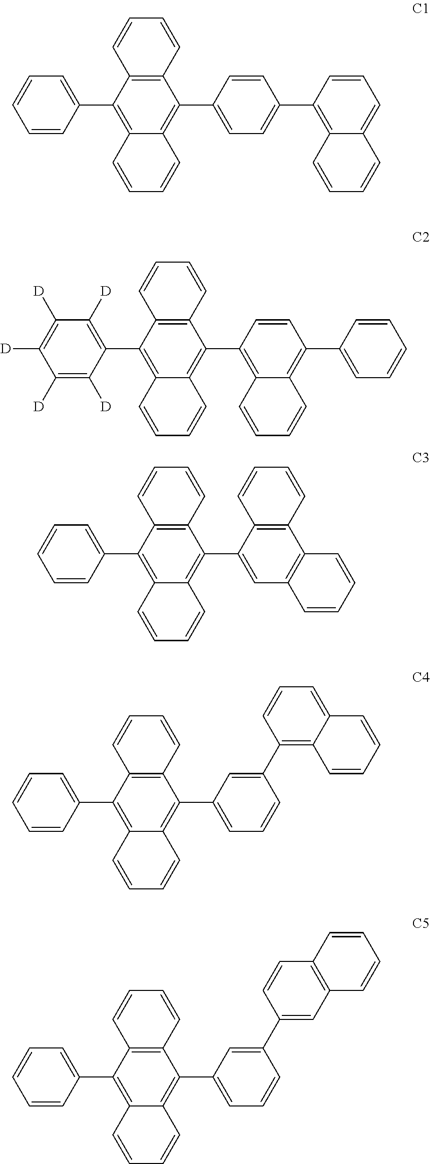

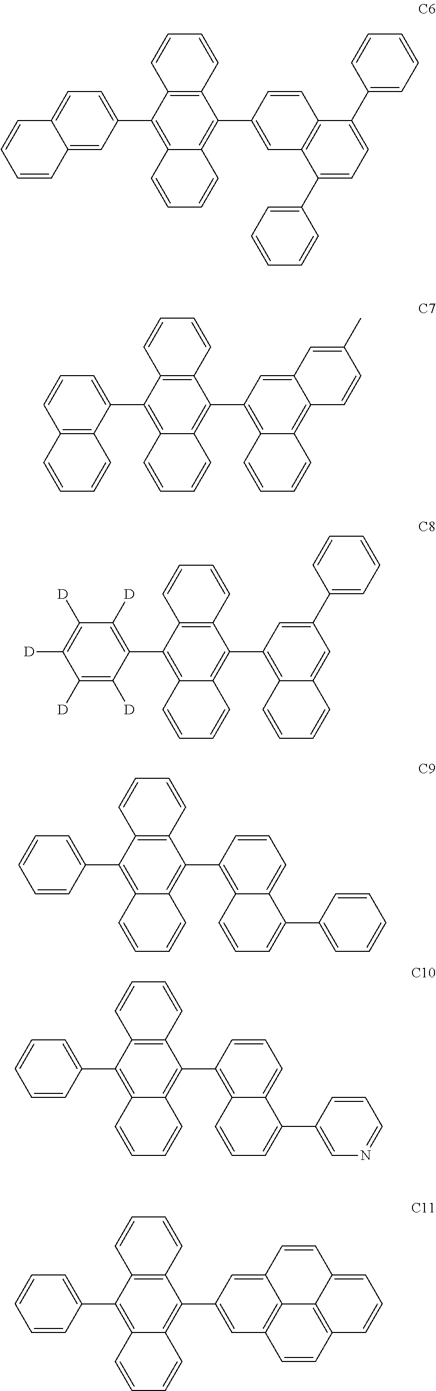

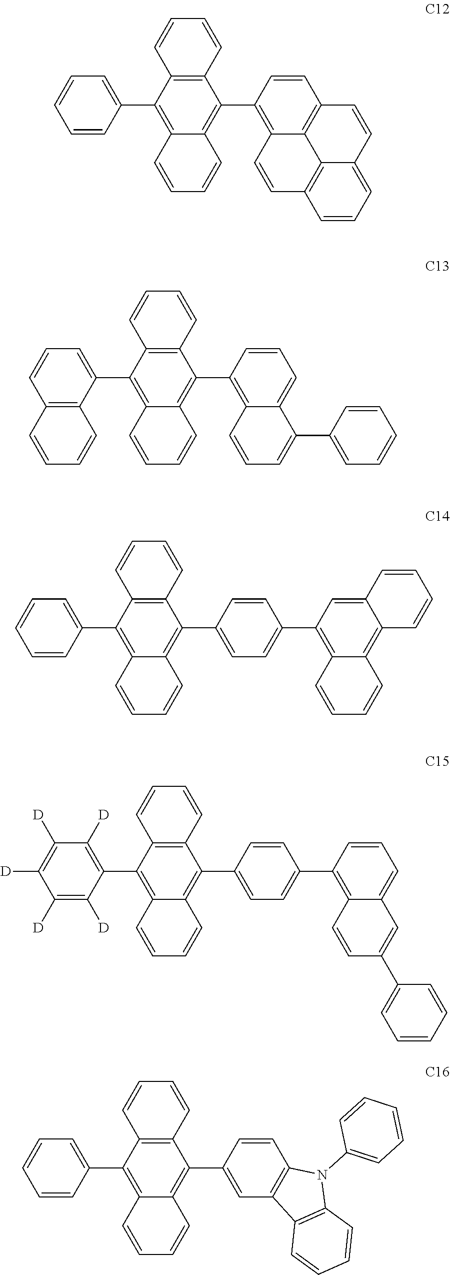

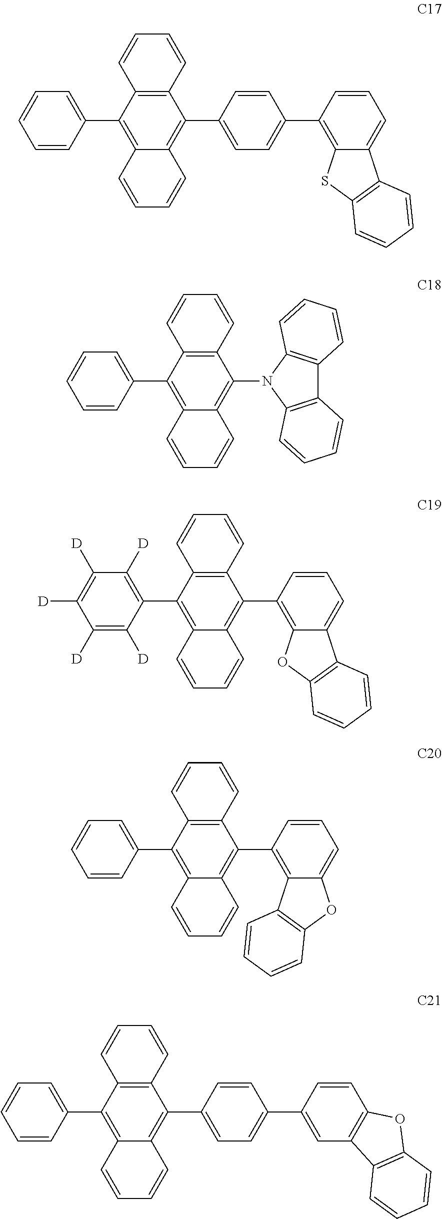 [SMILES: c1ccc(-c2c3ccccc3c(-c3ccc(-c4cccc5c4sc4ccccc45)cc3)c3ccccc23)cc1 ; c1ccc(-c2c3ccccc3c(-n3c4ccccc4c4ccccc43)c3ccccc23)cc1 ; [2H]c1c([2H])c([2H])c(-c2c3ccccc3c(-c3cccc4c3oc3ccccc34)c3ccccc23)c([2H])c1[2H] ; c1ccc(-c2c3ccccc3c(-c3cccc4oc5ccccc5c34)c3ccccc23)cc1 ; c1ccc(-c2c3ccccc3c(-c3ccc(-c4ccc5oc6ccccc6c5c4)cc3)c3ccccc23)cc1]

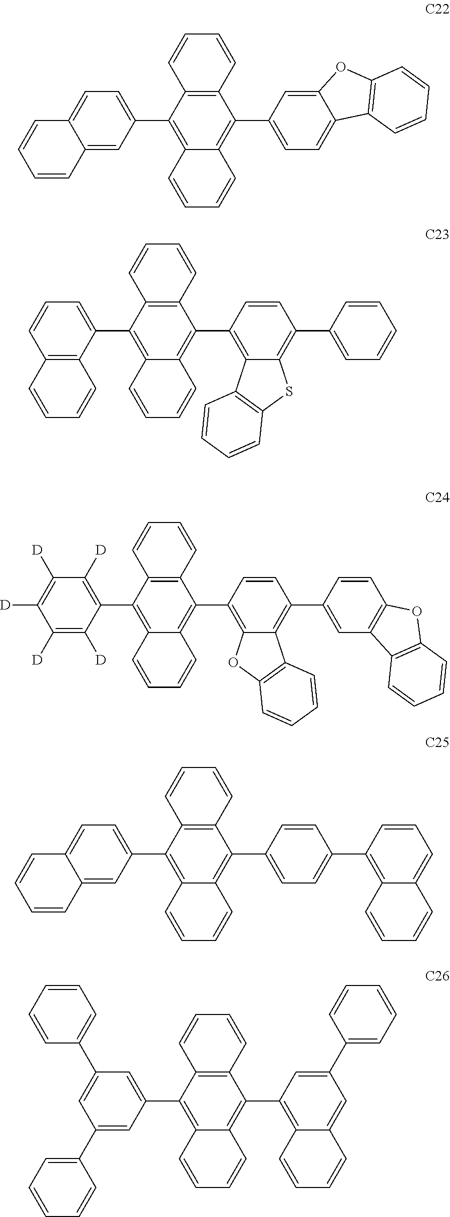

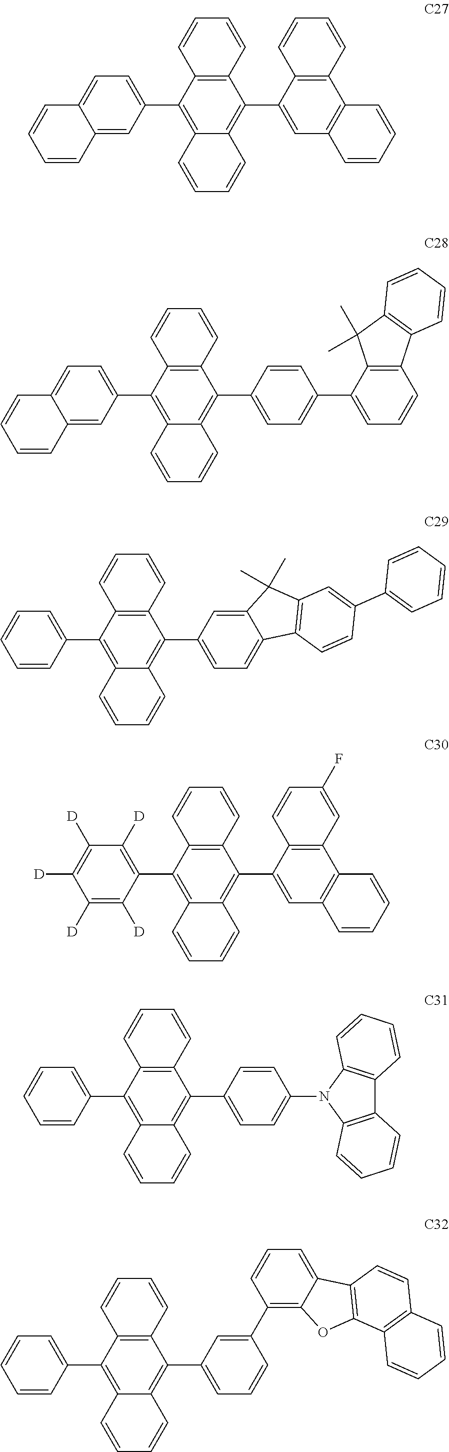

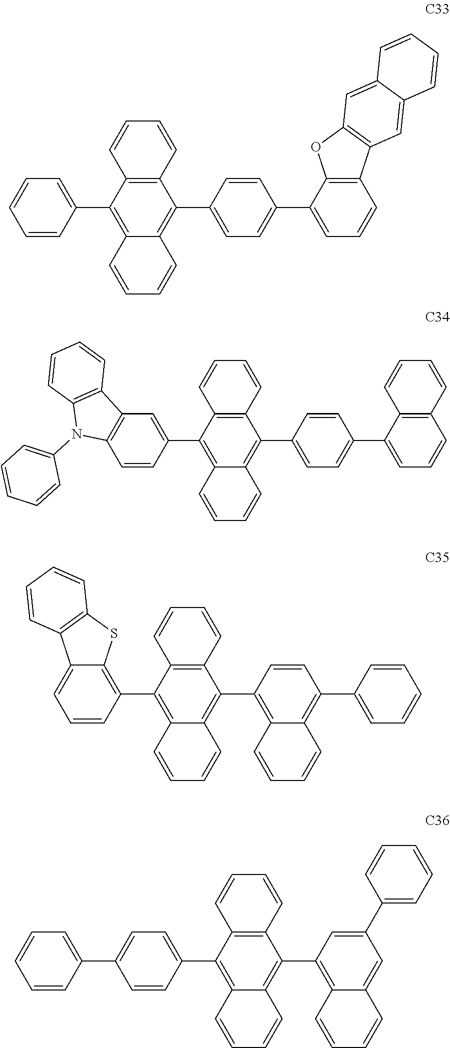

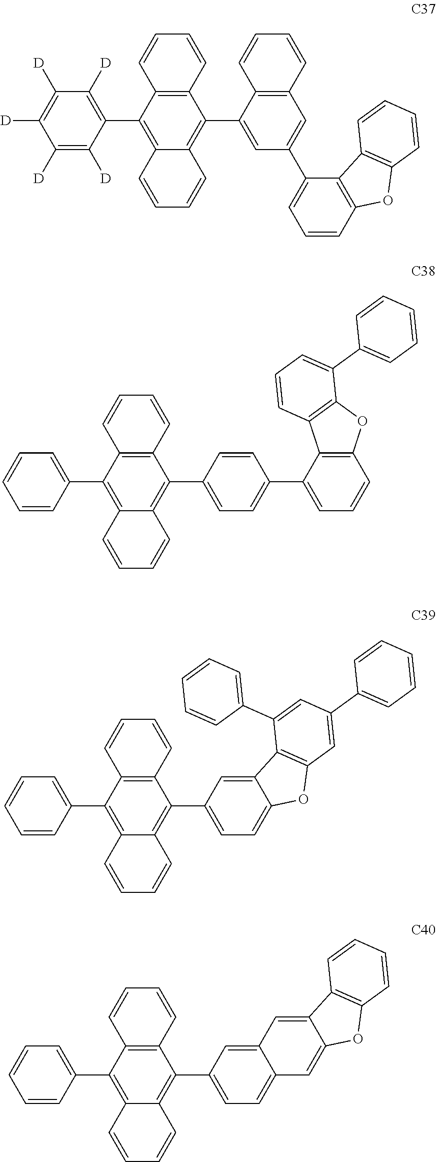 [SMILES: [2H]c1c([2H])c([2H])c(-c2c3ccccc3c(-c3cc(-c4cccc5oc6ccccc6c45)cc4ccccc34)c3ccccc23)c([2H])c1[2H] ; c1ccc(-c2c3ccccc3c(-c3ccc(-c4cccc5oc6c(-c7ccccc7)cccc6c45)cc3)c3ccccc23)cc1 ; c1ccc(-c2cc(-c3ccccc3)c3c(c2)oc2ccc(-c4c5ccccc5c(-c5ccccc5)c5ccccc45)cc23)cc1 ; c1ccc(-c2c3ccccc3c(-c3ccc4cc5oc6ccccc6c5cc4c3)c3ccccc23)cc1]

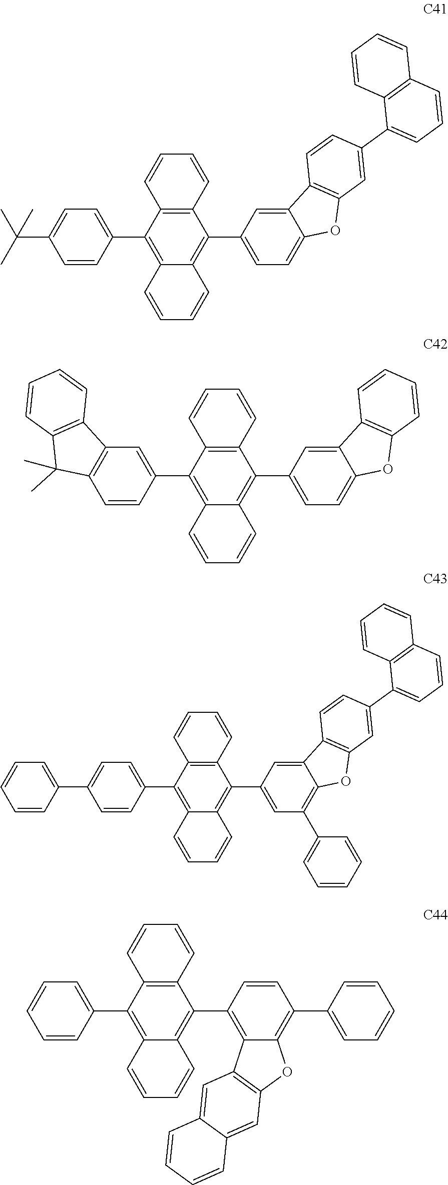 [SMILES: CC(C)(C)c1ccc(-c2c3ccccc3c(-c3ccc4oc5cc(-c6cccc7ccccc67)ccc5c4c3)c3ccccc23)cc1 ; CC1(C)c2ccccc2-c2cc(-c3c4ccccc4c(-c4ccc5oc6ccccc6c5c4)c4ccccc34)ccc21 ; c1ccc(-c2ccc(-c3c4ccccc4c(-c4cc(-c5ccccc5)c5oc6cc(-c7cccc8ccccc78)ccc6c5c4)c4ccccc34)cc2)cc1 ; c1ccc(-c2c3ccccc3c(-c3ccc(-c4ccccc4)c4oc5cc6ccccc6cc5c34)c3ccccc23)cc1]

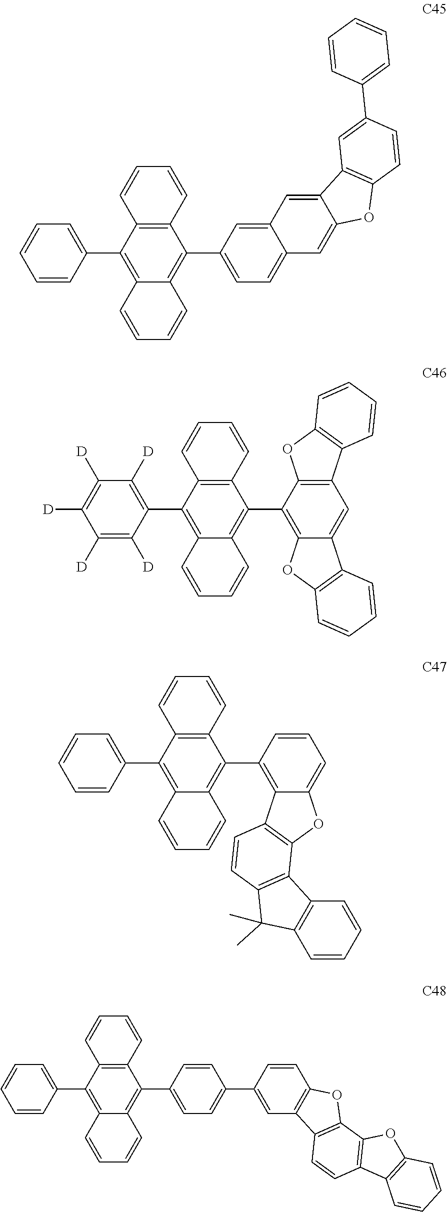 [SMILES: c1ccc(-c2ccc3oc4cc5ccc(-c6c7ccccc7c(-c7ccccc7)c7ccccc67)cc5cc4c3c2)cc1 ; [2H]c1c([2H])c([2H])c(-c2c3ccccc3c(-c3c4oc5ccccc5c4cc4c3oc3ccccc34)c3ccccc23)c([2H])c1[2H] ; CC1(C)c2ccccc2-c2c1ccc1c2oc2cccc(-c3c4ccccc4c(-c4ccccc4)c4ccccc34)c21 ; c1ccc(-c2c3ccccc3c(-c3ccc(-c4ccc5oc6c(ccc7c8ccccc8oc76)c5c4)cc3)c3ccccc23)cc1]

The organic electroluminescent device of the present invention may further include a hole transport layer and an electron blocking layer, each of which may include a compound represented by Formula D:

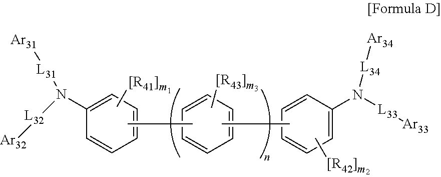

wherein R₄₁ to R₄₃ are identical to or different from each other and are each independently selected from hydrogen, deuterium, substituted or unsubstituted C₁-C₂₀ alkyl, substituted or unsubstituted C₆-C₅₀ aryl, substituted or unsubstituted C₇-C₅₀ arylalkyl, substituted or unsubstituted C₃-C₃₀ cycloalkyl, substituted or unsubstituted C₁-C₃₀ alkylsilyl, substituted or unsubstituted C₆-C₃₀ arylsilyl, and halogen, L₃₁ to L₃₄ are identical to or different from each other and are each independently single bonds or selected from substituted or unsubstituted C₆-C₅₀ arylene and substituted or unsubstituted C₂-C₅₀ heteroarylene, Ar₃₁ to Ar₃₄ are identical to or different from each other and are each independently selected from substituted or unsubstituted C₆-C₅₀ aryl and substituted or unsubstituted C₂-C₅₀ heteroaryl, n is an integer from 0 to 4, provided that when n is 2 or greater, the aromatic rings containing R₄₃ are identical to or different from each other, m₁ to m₃ are integers from 0 to 4, provided that when both mₗ and m₃ are 2 or more, the R₄₁, R₄₂, and R₄₃ groups are identical to or different from each other, and hydrogen or deuterium atoms are bonded to the carbon atoms of the aromatic rings to which R₄₁ to R₄₃ are not attached.

In Formula D, at least one of Ar₃₁ to Ar₃₄ is represented by Formula E:

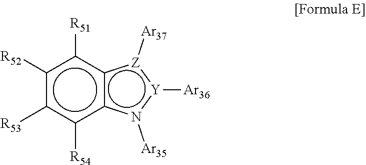

wherein R₅₁ to R₅₄ are identical to or different from each other and are each independently selected from hydrogen, deuterium, substituted or unsubstituted C₁-C₃₀ alkyl, substituted or unsubstituted C₆-C₅₀ aryl, substituted or unsubstituted C₂-C₃₀ alkenyl, substituted or unsubstituted C₂-C₂₀ alkynyl, substituted or unsubstituted C₃-C₃₀ cycloalkyl, substituted or unsubstituted C₅-C₃₀ cycloalkenyl, substituted or unsubstituted C₂-C₅₀ heteroaryl, substituted or unsubstituted C₂-C₃₀ heterocycloalkyl, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted C₁-C₃₀ alkylamine, substituted or unsubstituted C₅-C₃₀ arylamine, substituted or unsubstituted C₁-C₃₀ alkylsilyl, substituted or unsubstituted C₅-C₃₀ arylsilyl, nitro, cyano, and halogen, which are optionally linked to each other to form a ring, Y is a carbon or nitrogen atom, Z is a carbon, oxygen, sulfur or nitrogen atom, Ar₃₅ to Ar₃₇ are identical to or different from each other and are each independently selected from substituted or unsubstituted C₅-C₅₀ aryl and substituted or unsubstituted C₃-C₅₀ heteroaryl, provided that when Z is an oxygen or sulfur atom, Ar₃₇ is nothing, provided that when Y and Z are nitrogen atoms, only one of Ar₃₅, Ar₃₆, and Ar₃₇ is present, provided that when Y is a nitrogen atom and Z is a carbon atom, Ar₃₆ is nothing, with the proviso that one of R₅₁ to R₅₄ and Ar₃₅ to Ar₃₇ is a single bond linked to one of the linkers L₃₁ to L₃₄ in Formula D.

The compound of Formula D employed in the organic electroluminescent device of the present invention may be specifically selected from the compounds of Formulae D1 to D79:

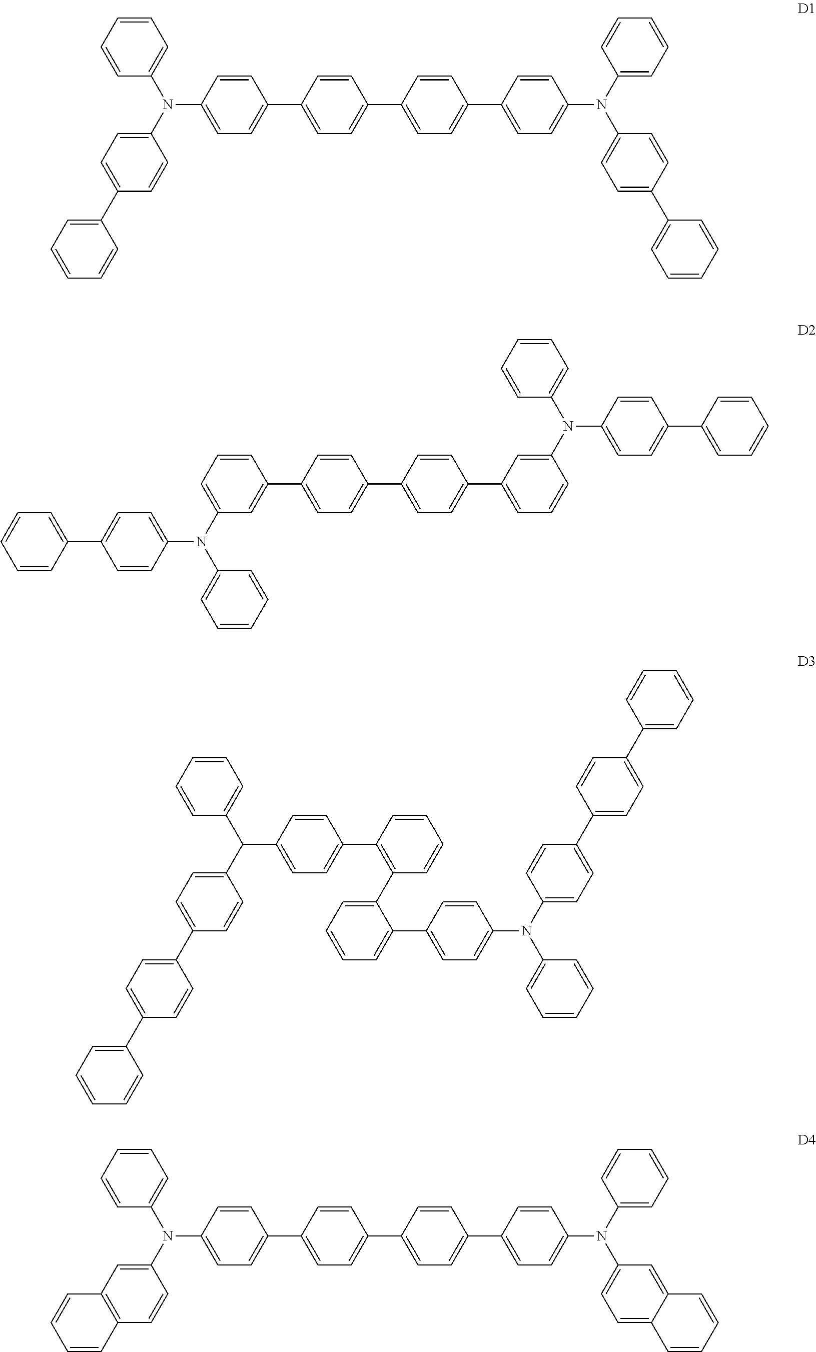

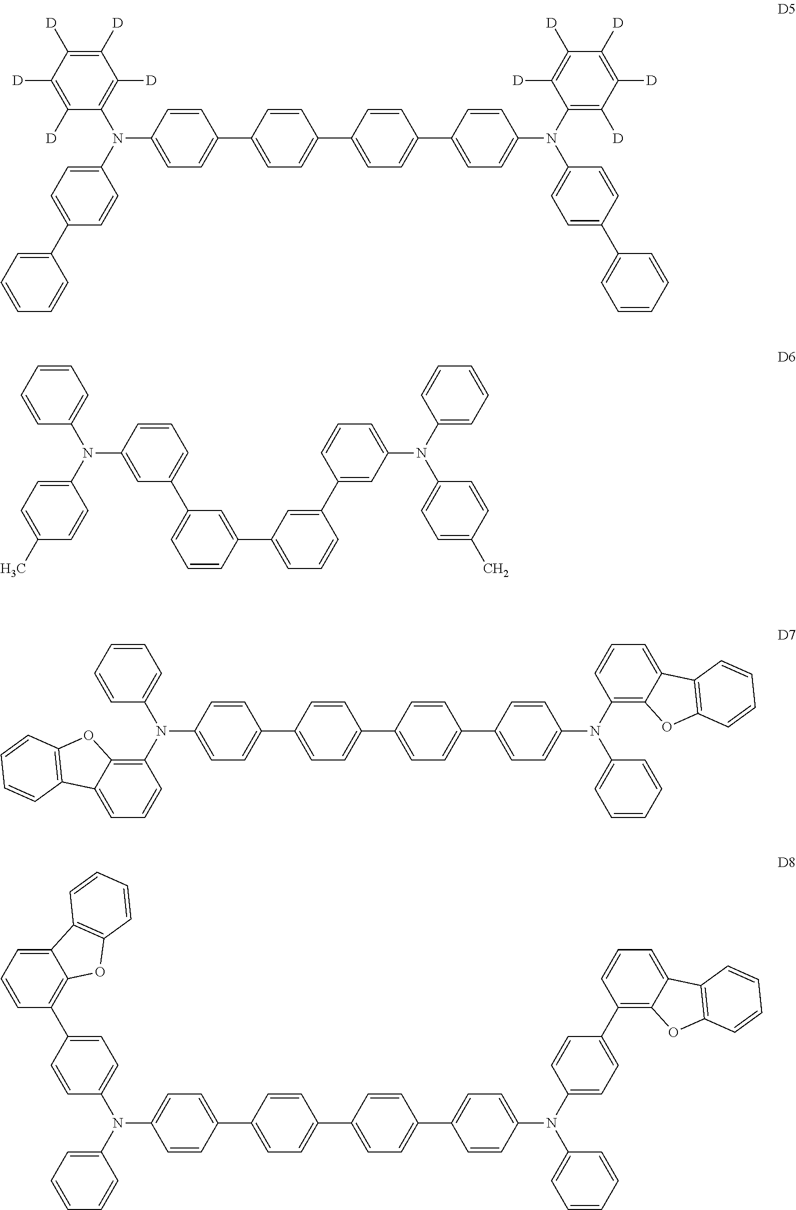 [SMILES: [2H]c1c([2H])c([2H])c(N(c2ccc(-c3ccccc3)cc2)c2ccc(-c3ccc(-c4ccc(-c5ccc(N(c6ccc(-c7ccccc7)cc6)c6c([2H])c([2H])c([2H])c([2H])c6[2H])cc5)cc4)cc3)cc2)c([2H])c1[2H] ; Cc1ccc(N(c2ccccc2)c2cccc(-c3cccc(-c4cccc(-c5cccc(N(c6ccccc6)c6ccc(C)cc6)c5)c4)c3)c2)cc1 ; c1ccc(N(c2ccc(-c3ccc(-c4ccc(-c5ccc(N(c6ccccc6)c6cccc7c6oc6ccccc67)cc5)cc4)cc3)cc2)c2cccc3c2oc2ccccc23)cc1 ; c1ccc(N(c2ccc(-c3ccc(-c4ccc(-c5ccc(N(c6ccccc6)c6ccc(-c7cccc8c7oc7ccccc78)cc6)cc5)cc4)cc3)cc2)c2ccc(-c3cccc4c3oc3ccccc34)cc2)cc1]

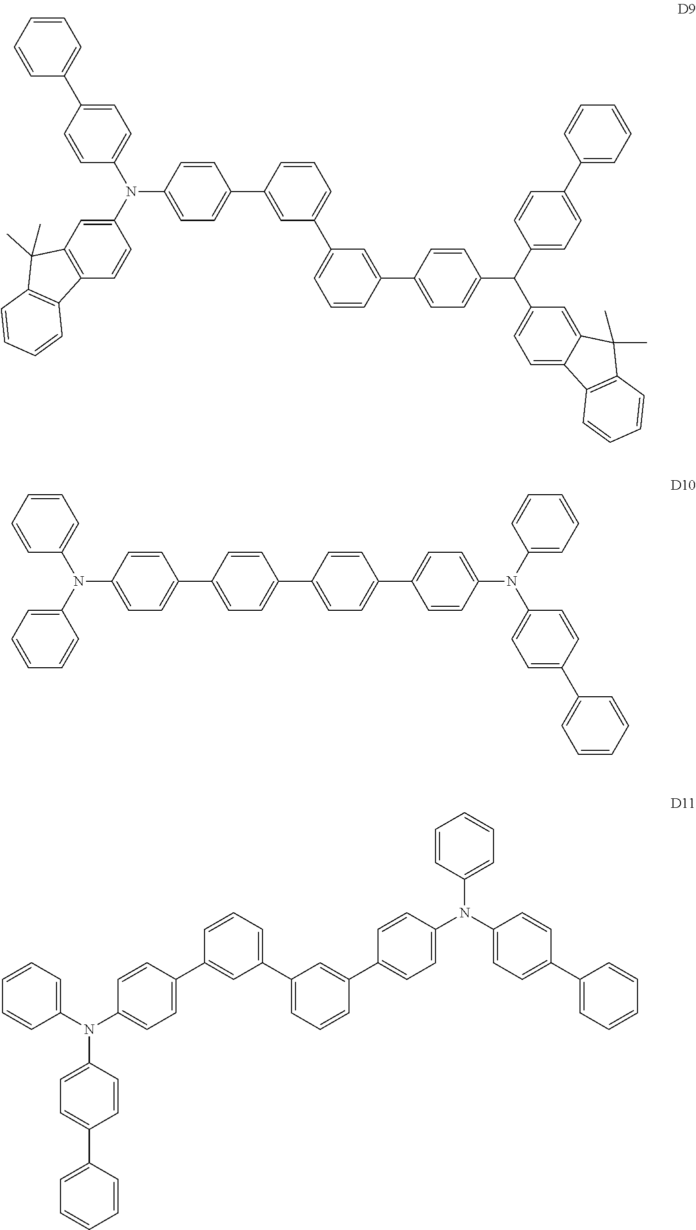 [SMILES: CC1(C)c2ccccc2-c2ccc(C(c3ccc(-c4ccccc4)cc3)c3ccc(-c4cccc(-c5cccc(-c6ccc(N(c7ccc(-c8ccccc8)cc7)c7ccc8c(c7)C(C)(C)c7ccccc7-8)cc6)c5)c4)cc3)cc21 ; c1ccc(-c2ccc(N(c3ccccc3)c3ccc(-c4ccc(-c5ccc(-c6ccc(N(c7ccccc7)c7ccccc7)cc6)cc5)cc4)cc3)cc2)cc1 ; c1ccc(-c2ccc(N(c3ccccc3)c3ccc(-c4cccc(-c5cccc(-c6ccc(N(c7ccccc7)c7ccc(-c8ccccc8)cc7)cc6)c5)c4)cc3)cc2)cc1]

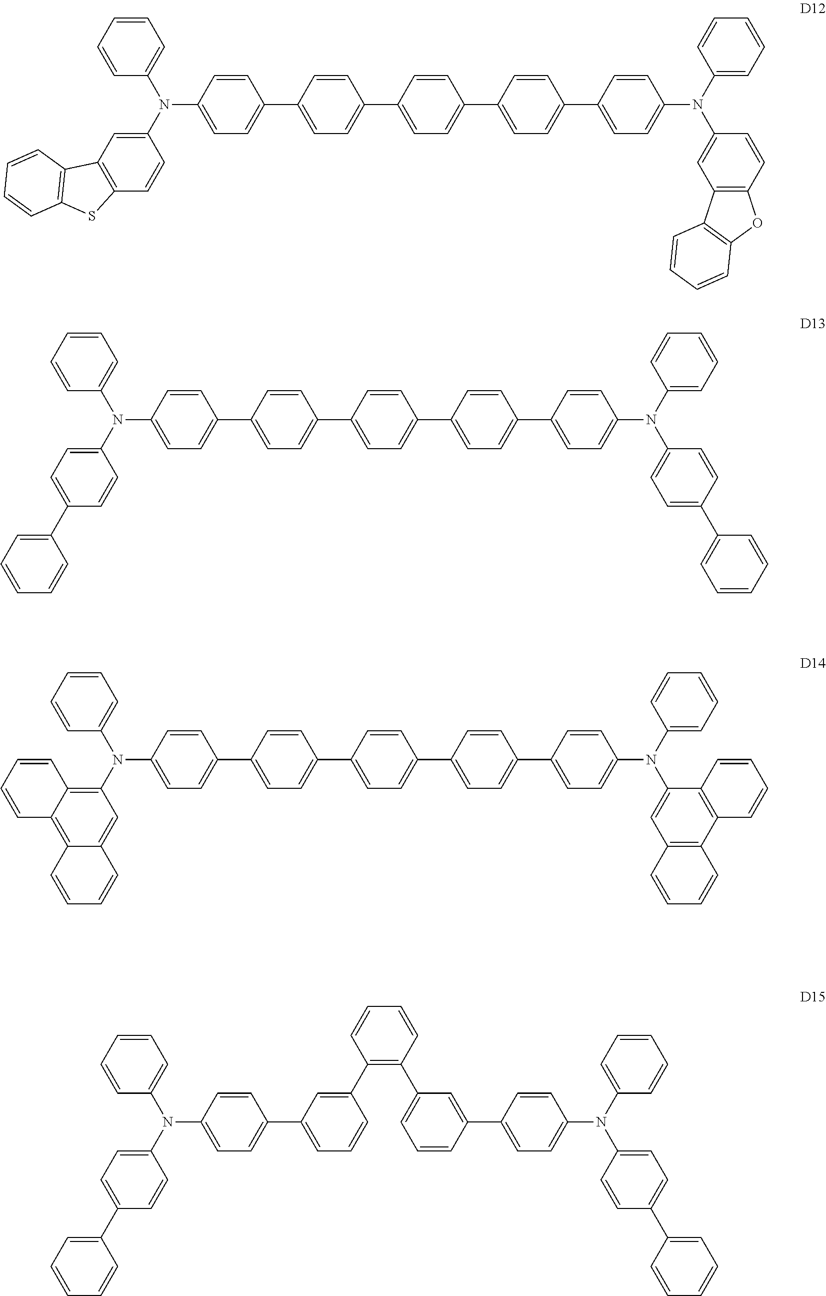

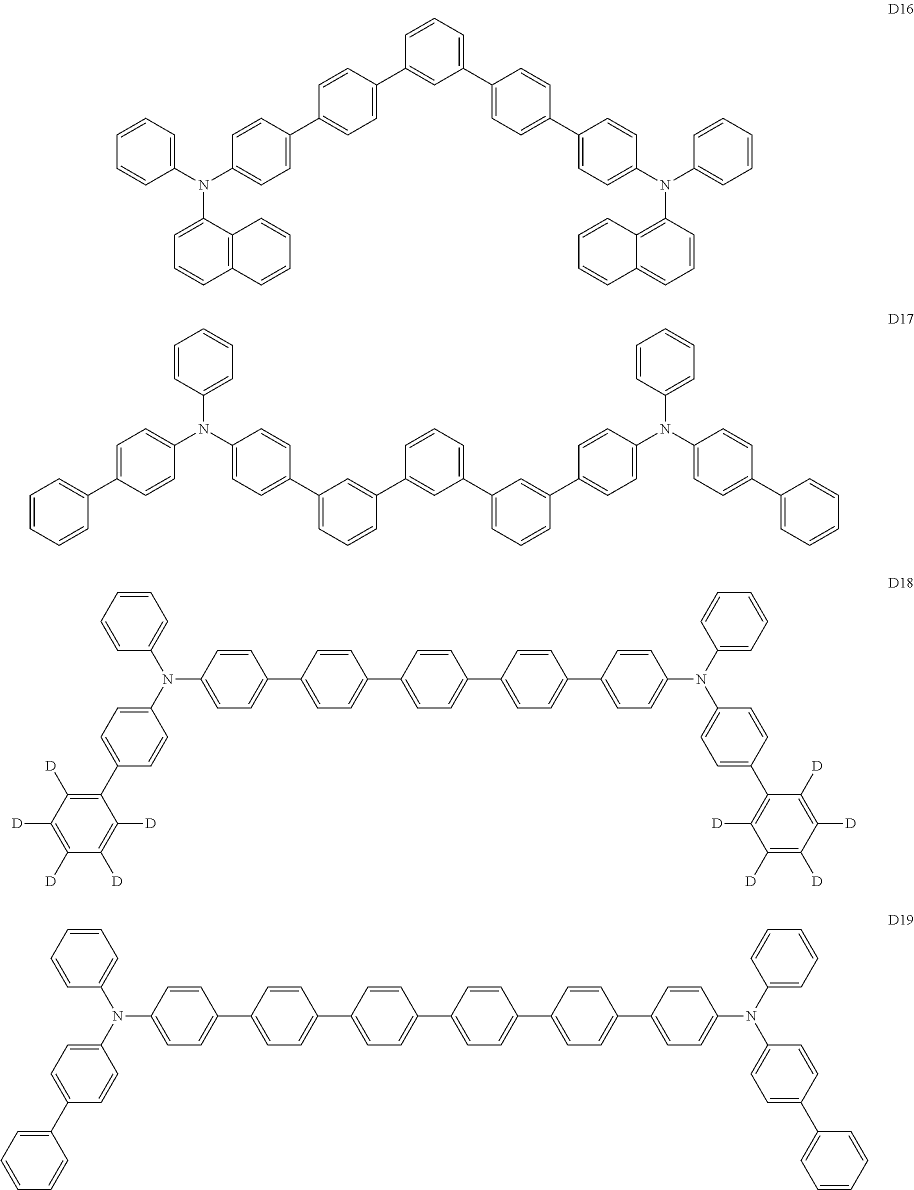

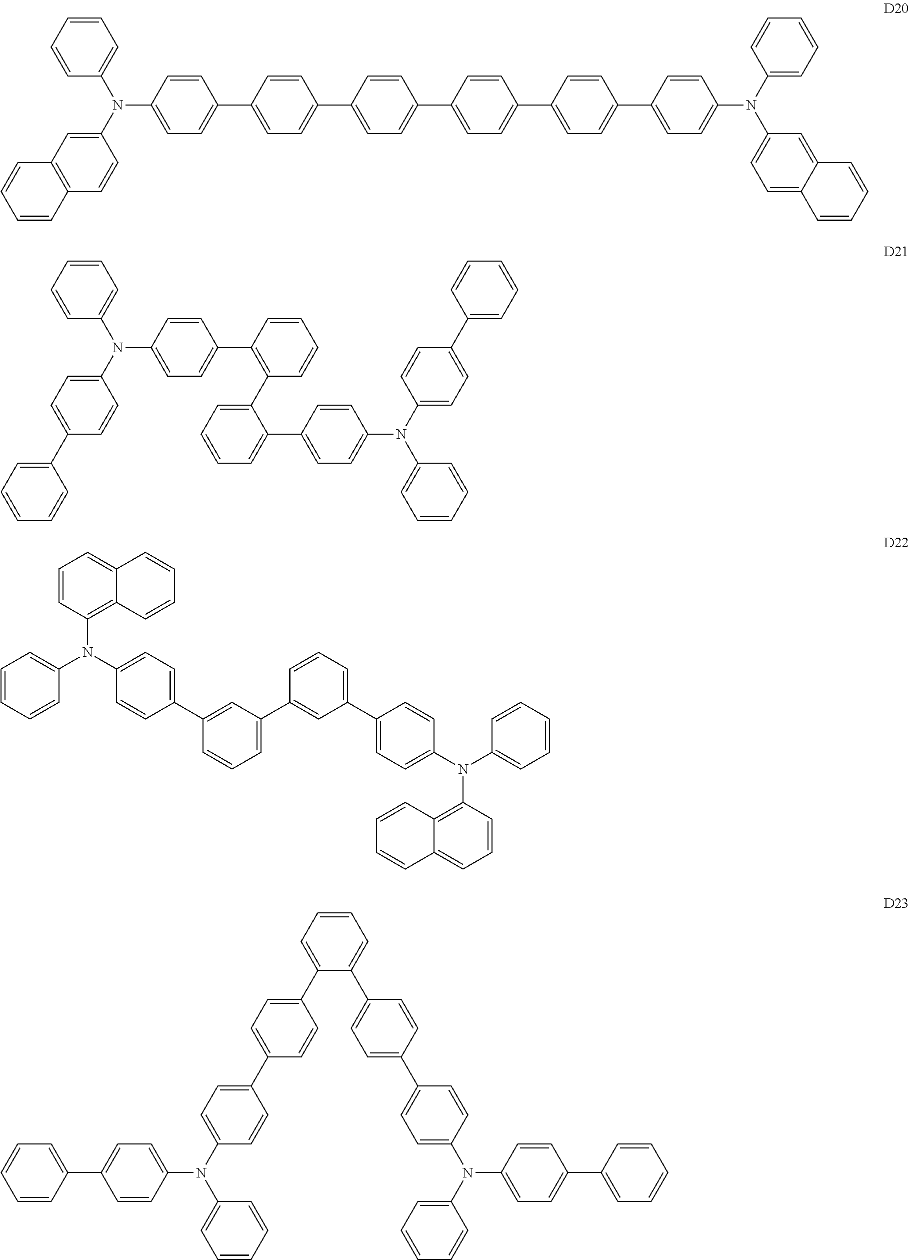

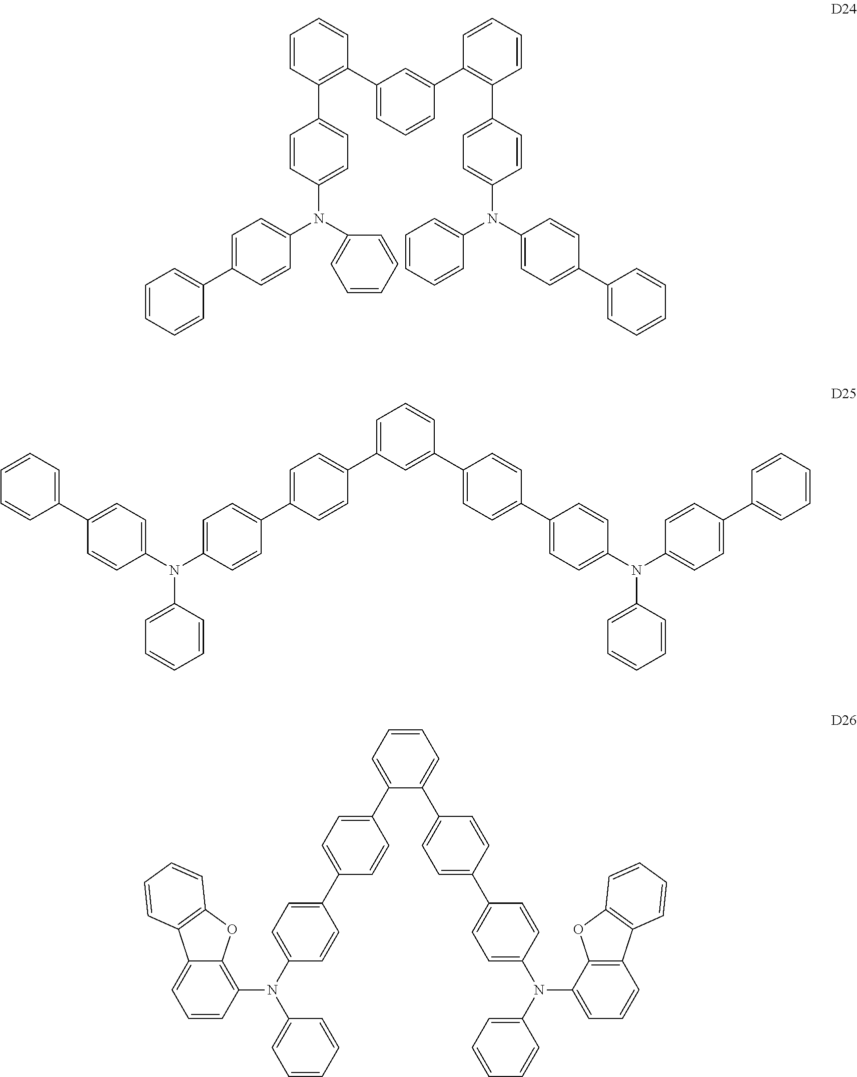 [SMILES: c1ccc(-c2ccc(N(c3ccccc3)c3ccc(-c4ccccc4-c4cccc(-c5ccccc5-c5ccc(N(c6ccccc6)c6ccc(-c7ccccc7)cc6)cc5)c4)cc3)cc2)cc1 ; c1ccc(-c2ccc(N(c3ccccc3)c3ccc(-c4ccc(-c5cccc(-c6ccc(-c7ccc(N(c8ccccc8)c8ccc(-c9ccccc9)cc8)cc7)cc6)c5)cc4)cc3)cc2)cc1 ; c1ccc(N(c2ccc(-c3ccc(-c4ccccc4-c4ccc(-c5ccc(N(c6ccccc6)c6cccc7c6oc6ccccc67)cc5)cc4)cc3)cc2)c2cccc3c2oc2ccccc23)cc1]

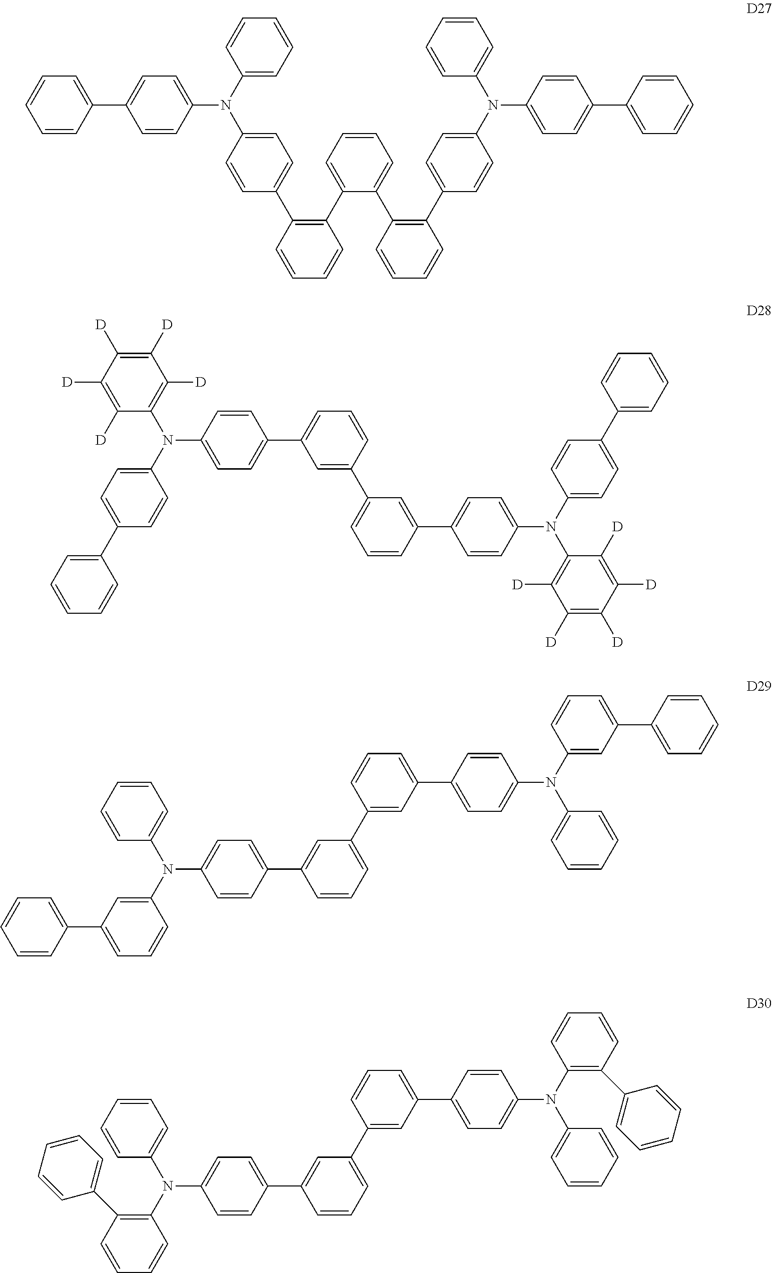 [SMILES: c1ccc(-c2ccc(N(c3ccccc3)c3ccc(-c4ccccc4-c4ccccc4-c4ccccc4-c4ccc(N(c5ccccc5)c5ccc(-c6ccccc6)cc5)cc4)cc3)cc2)cc1 ; [2H]c1c([2H])c([2H])c(N(c2ccc(-c3ccccc3)cc2)c2ccc(-c3cccc(-c4cccc(-c5ccc(N(c6ccc(-c7ccccc7)cc6)c6c([2H])c([2H])c([2H])c([2H])c6[2H])cc5)c4)c3)cc2)c([2H])c1[2H] ; c1ccc(-c2cccc(N(c3ccccc3)c3ccc(-c4cccc(-c5cccc(-c6ccc(N(c7ccccc7)c7cccc(-c8ccccc8)c7)cc6)c5)c4)cc3)c2)cc1 ; c1ccc(-c2ccccc2N(c2ccccc2)c2ccc(-c3cccc(-c4cccc(-c5ccc(N(c6ccccc6)c6ccccc6-c6ccccc6)cc5)c4)c3)cc2)cc1]

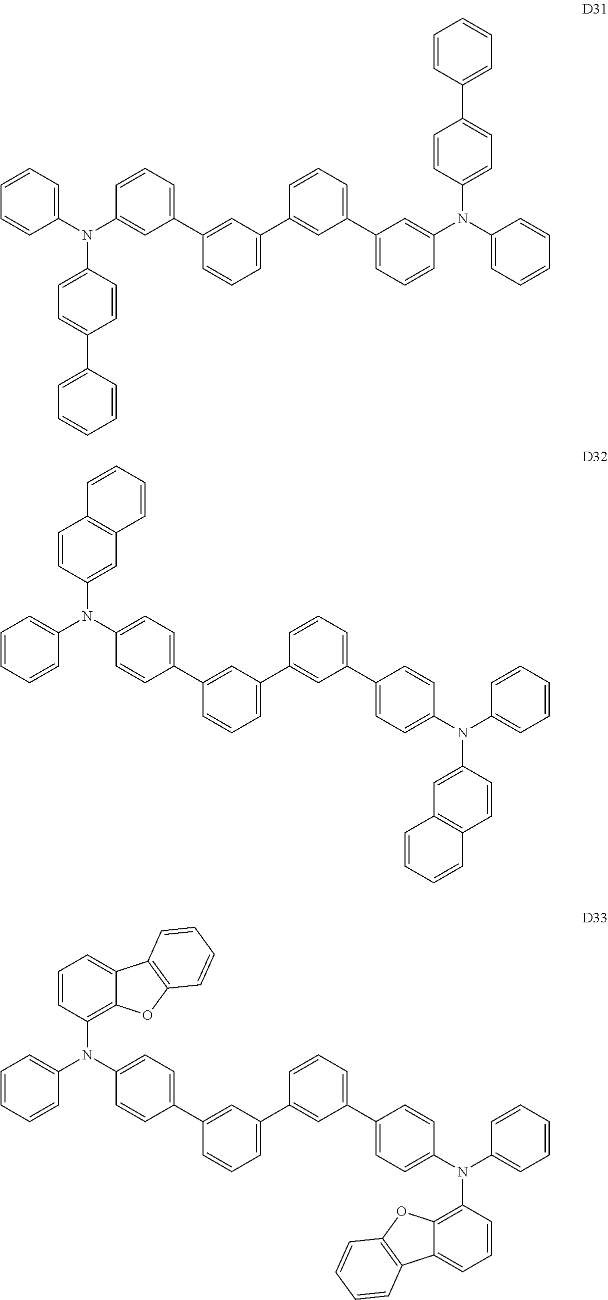

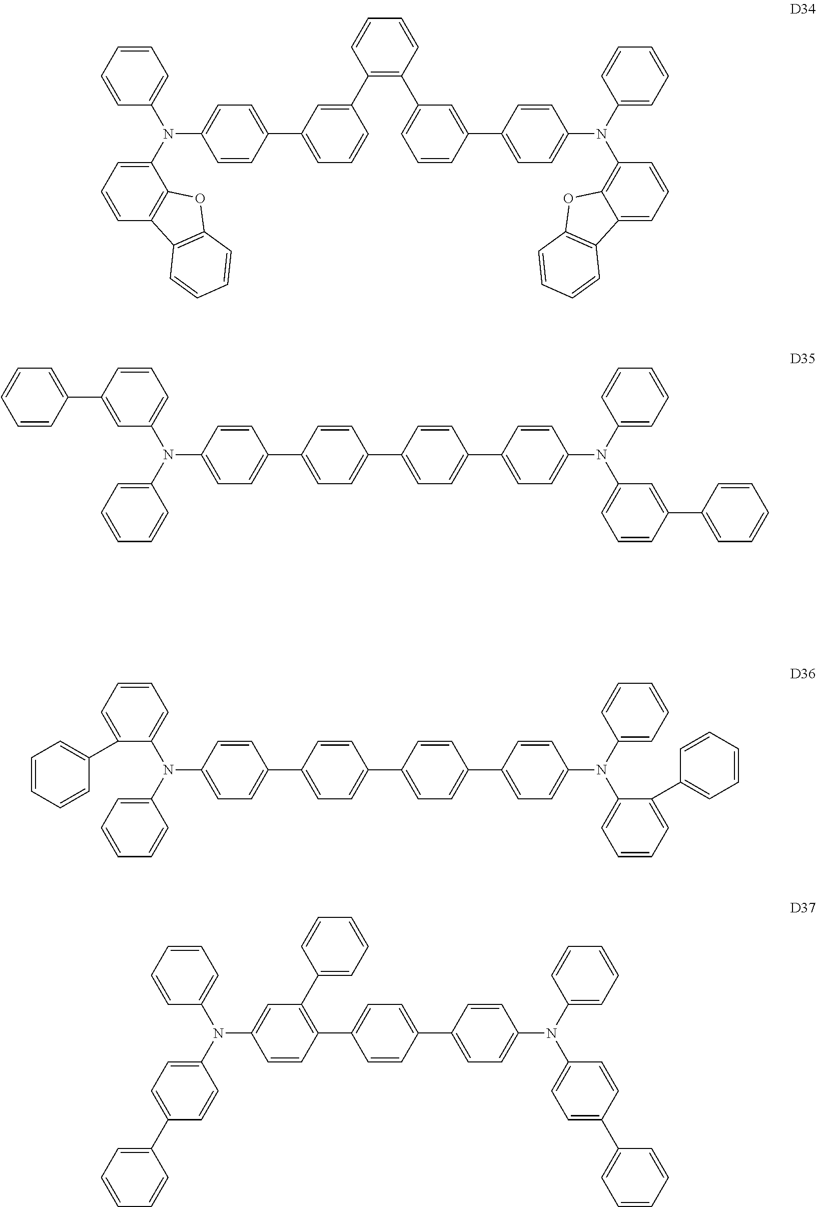 [SMILES: c1ccc(N(c2ccc(-c3cccc(-c4ccccc4-c4cccc(-c5ccc(N(c6ccccc6)c6cccc7c6oc6ccccc67)cc5)c4)c3)cc2)c2cccc3c2oc2ccccc23)cc1 ; c1ccc(-c2cccc(N(c3ccccc3)c3ccc(-c4ccc(-c5ccc(-c6ccc(N(c7ccccc7)c7cccc(-c8ccccc8)c7)cc6)cc5)cc4)cc3)c2)cc1 ; c1ccc(-c2ccccc2N(c2ccccc2)c2ccc(-c3ccc(-c4ccc(-c5ccc(N(c6ccccc6)c6ccccc6-c6ccccc6)cc5)cc4)cc3)cc2)cc1 ; c1ccc(-c2ccc(N(c3ccccc3)c3ccc(-c4ccc(-c5ccc(N(c6ccccc6)c6ccc(-c7ccccc7)cc6)cc5-c5ccccc5)cc4)cc3)cc2)cc1]

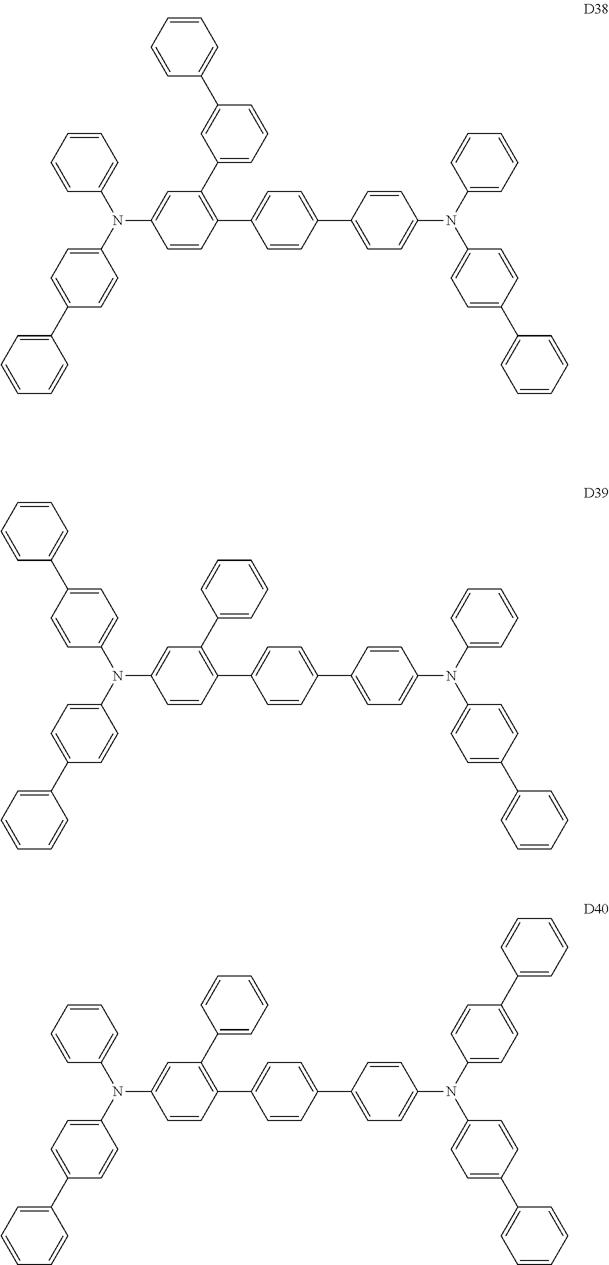 [SMILES: c1ccc(-c2ccc(N(c3ccccc3)c3ccc(-c4ccc(-c5ccc(N(c6ccccc6)c6ccc(-c7ccccc7)cc6)cc5-c5cccc(-c6ccccc6)c5)cc4)cc3)cc2)cc1 ; c1ccc(-c2ccc(N(c3ccccc3)c3ccc(-c4ccc(-c5ccc(N(c6ccc(-c7ccccc7)cc6)c6ccc(-c7ccccc7)cc6)cc5-c5ccccc5)cc4)cc3)cc2)cc1 ; c1ccc(-c2ccc(N(c3ccc(-c4ccccc4)cc3)c3ccc(-c4ccc(-c5ccc(N(c6ccccc6)c6ccc(-c7ccccc7)cc6)cc5-c5ccccc5)cc4)cc3)cc2)cc1]

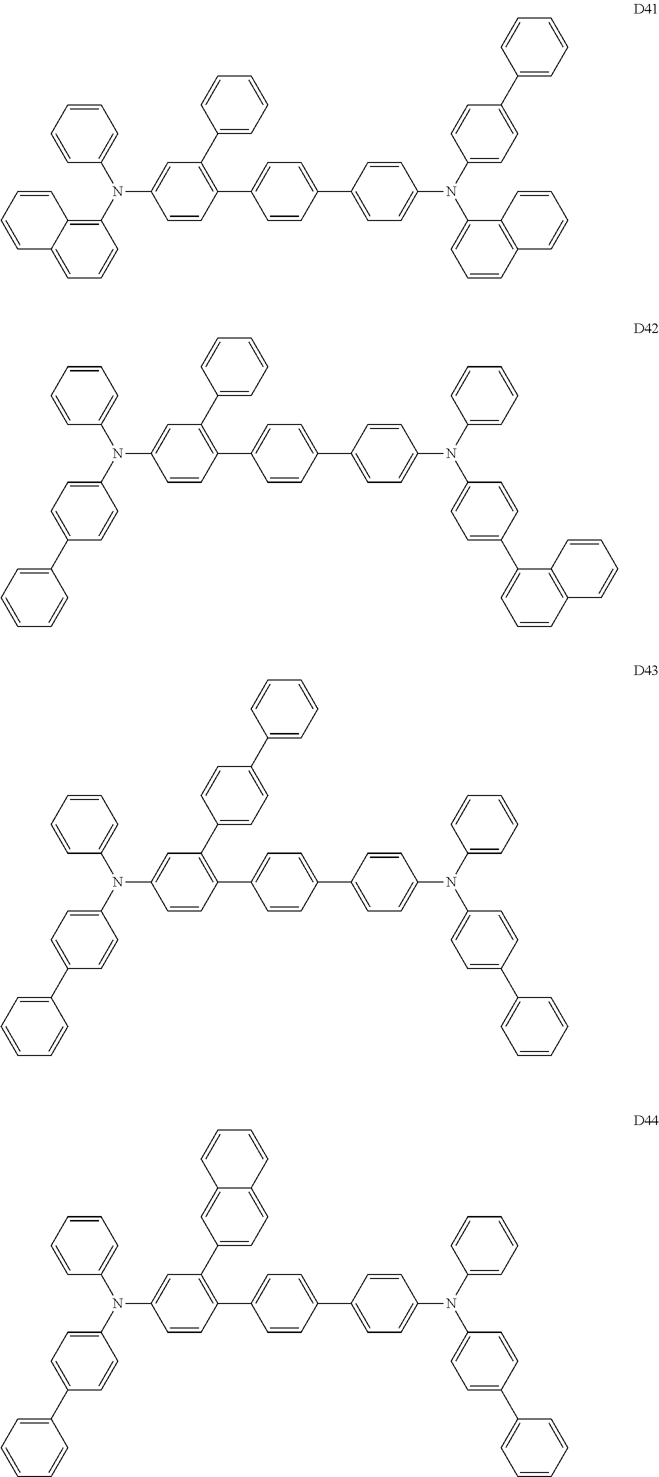 [SMILES: c1ccc(-c2ccc(N(c3ccc(-c4ccc(-c5ccc(N(c6ccccc6)c6cccc7ccccc67)cc5-c5ccccc5)cc4)cc3)c3cccc4ccccc34)cc2)cc1 ; c1ccc(-c2ccc(N(c3ccccc3)c3ccc(-c4ccc(-c5ccc(N(c6ccccc6)c6ccc(-c7cccc8ccccc78)cc6)cc5)cc4)c(-c4ccccc4)c3)cc2)cc1 ; c1ccc(-c2ccc(-c3cc(N(c4ccccc4)c4ccc(-c5ccccc5)cc4)ccc3-c3ccc(-c4ccc(N(c5ccccc5)c5ccc(-c6ccccc6)cc5)cc4)cc3)cc2)cc1 ; c1ccc(-c2ccc(N(c3ccccc3)c3ccc(-c4ccc(-c5ccc(N(c6ccccc6)c6ccc(-c7ccccc7)cc6)cc5-c5ccc6ccccc6c5)cc4)cc3)cc2)cc1]

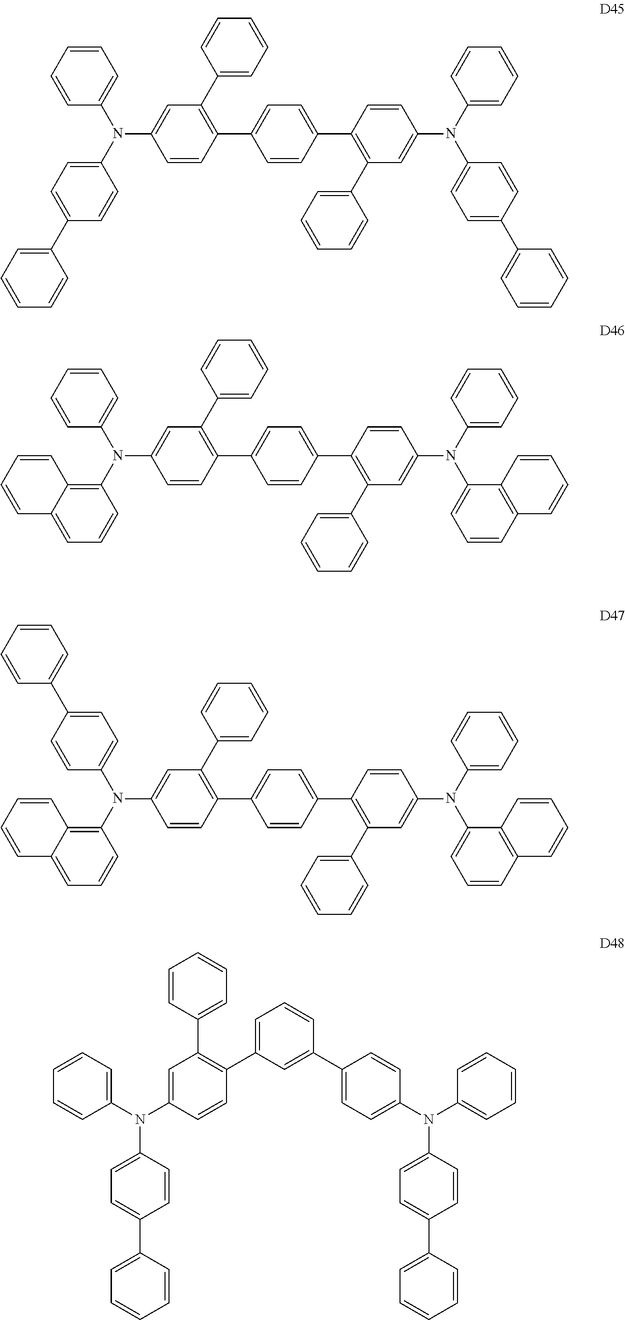 [SMILES: c1ccc(-c2ccc(N(c3ccccc3)c3ccc(-c4ccc(-c5ccc(N(c6ccccc6)c6ccc(-c7ccccc7)cc6)cc5-c5ccccc5)cc4)c(-c4ccccc4)c3)cc2)cc1 ; c1ccc(-c2cc(N(c3ccccc3)c3cccc4ccccc34)ccc2-c2ccc(-c3ccc(N(c4ccccc4)c4cccc5ccccc45)cc3-c3ccccc3)cc2)cc1 ; c1ccc(-c2ccc(N(c3ccc(-c4ccc(-c5ccc(N(c6ccccc6)c6cccc7ccccc67)cc5-c5ccccc5)cc4)c(-c4ccccc4)c3)c3cccc4ccccc34)cc2)cc1 ; c1ccc(-c2ccc(N(c3ccccc3)c3ccc(-c4cccc(-c5ccc(N(c6ccccc6)c6ccc(-c7ccccc7)cc6)cc5-c5ccccc5)c4)cc3)cc2)cc1]

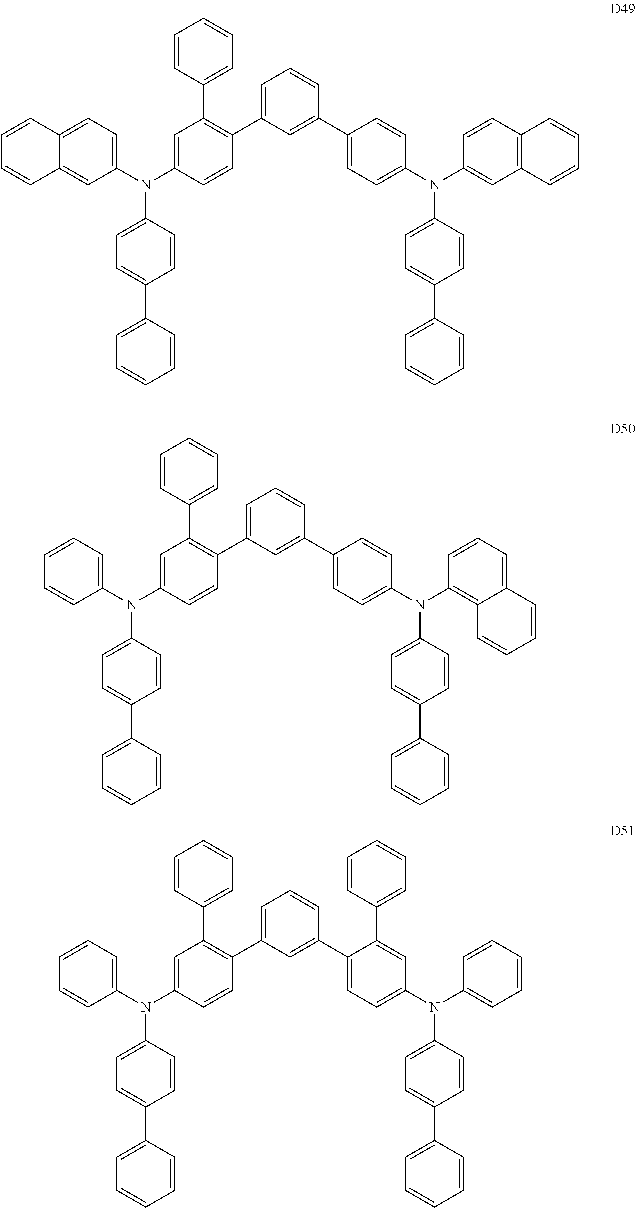 [SMILES: c1ccc(-c2ccc(N(c3ccc(-c4cccc(-c5ccc(N(c6ccc(-c7ccccc7)cc6)c6ccc7ccccc7c6)cc5-c5ccccc5)c4)cc3)c3ccc4ccccc4c3)cc2)cc1 ; c1ccc(-c2ccc(N(c3ccccc3)c3ccc(-c4cccc(-c5ccc(N(c6ccc(-c7ccccc7)cc6)c6cccc7ccccc67)cc5)c4)c(-c4ccccc4)c3)cc2)cc1 ; c1ccc(-c2ccc(N(c3ccccc3)c3ccc(-c4cccc(-c5ccc(N(c6ccccc6)c6ccc(-c7ccccc7)cc6)cc5-c5ccccc5)c4)c(-c4ccccc4)c3)cc2)cc1]

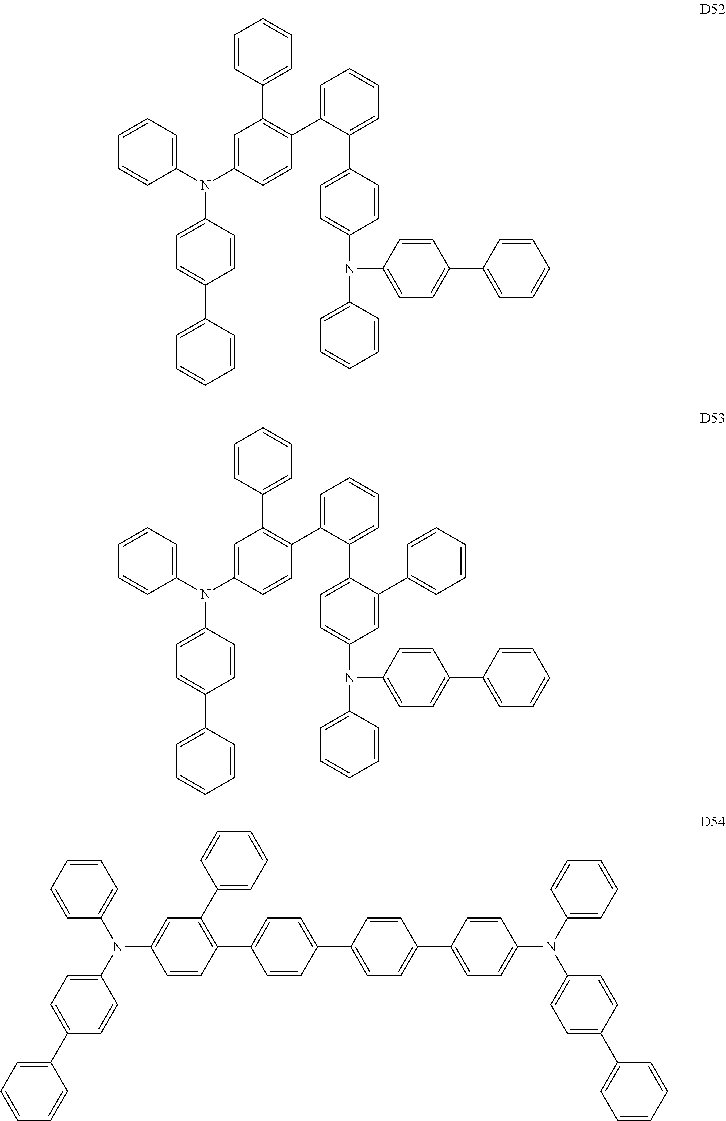

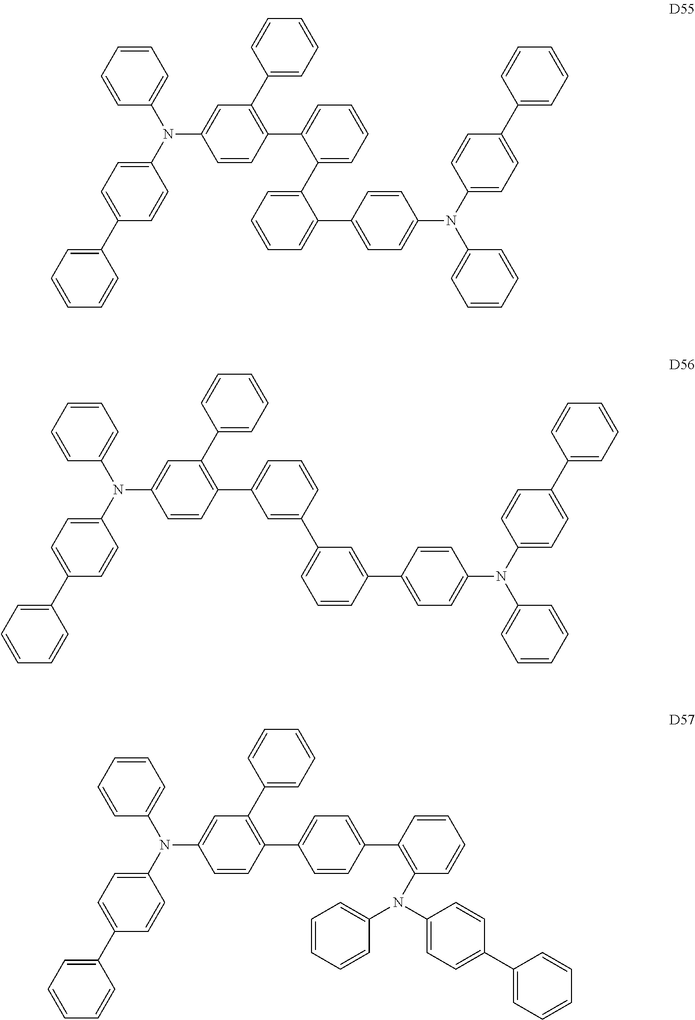 [SMILES: c1ccc(-c2ccc(N(c3ccccc3)c3ccc(-c4ccccc4-c4ccccc4-c4ccc(N(c5ccccc5)c5ccc(-c6ccccc6)cc5)cc4-c4ccccc4)cc3)cc2)cc1 ; c1ccc(-c2ccc(N(c3ccccc3)c3ccc(-c4cccc(-c5cccc(-c6ccc(N(c7ccccc7)c7ccc(-c8ccccc8)cc7)cc6-c6ccccc6)c5)c4)cc3)cc2)cc1 ; c1ccc(-c2ccc(N(c3ccccc3)c3ccc(-c4ccc(-c5ccccc5N(c5ccccc5)c5ccc(-c6ccccc6)cc5)cc4)c(-c4ccccc4)c3)cc2)cc1]

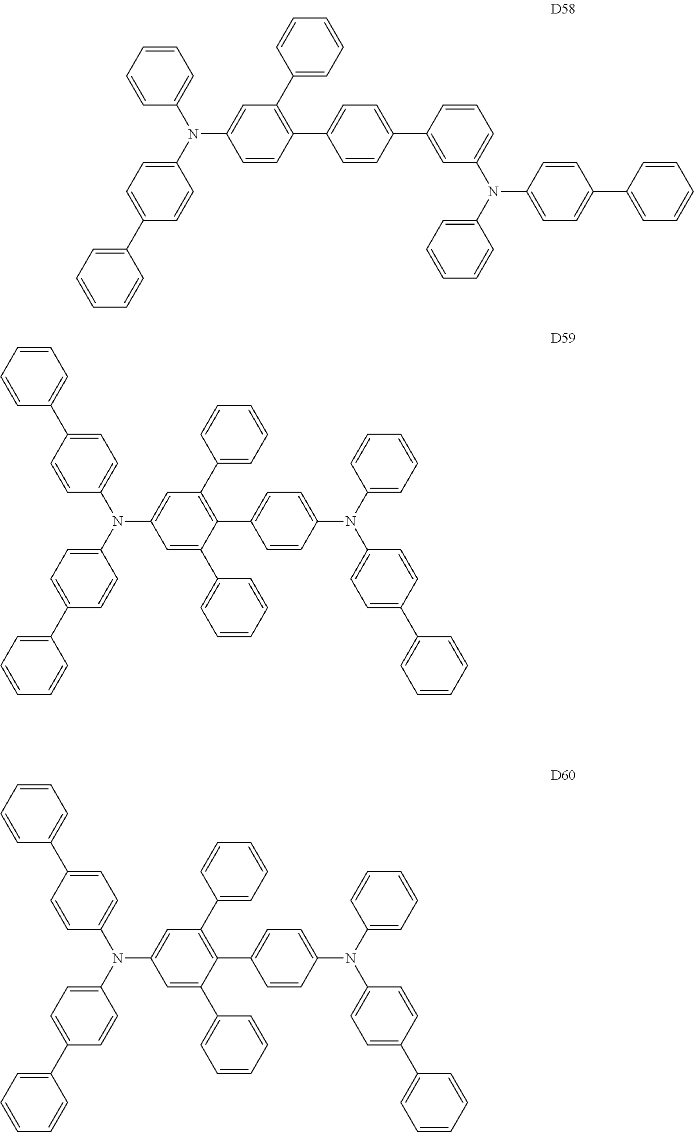 [SMILES: c1ccc(-c2ccc(N(c3ccccc3)c3cccc(-c4ccc(-c5ccc(N(c6ccccc6)c6ccc(-c7ccccc7)cc6)cc5-c5ccccc5)cc4)c3)cc2)cc1 ; c1ccc(-c2ccc(N(c3ccccc3)c3ccc(-c4c(-c5ccccc5)cc(N(c5ccc(-c6ccccc6)cc5)c5ccc(-c6ccccc6)cc5)cc4-c4ccccc4)cc3)cc2)cc1 ; c1ccc(-c2ccc(N(c3ccccc3)c3ccc(-c4c(-c5ccccc5)cc(N(c5ccc(-c6ccccc6)cc5)c5ccc(-c6ccccc6)cc5)cc4-c4ccccc4)cc3)cc2)cc1]

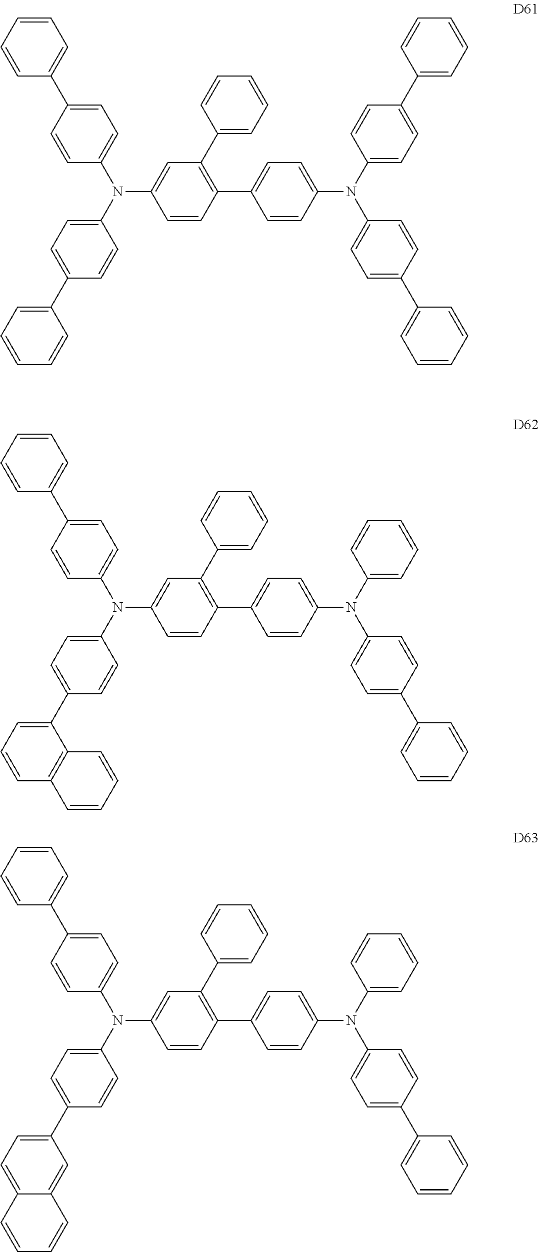

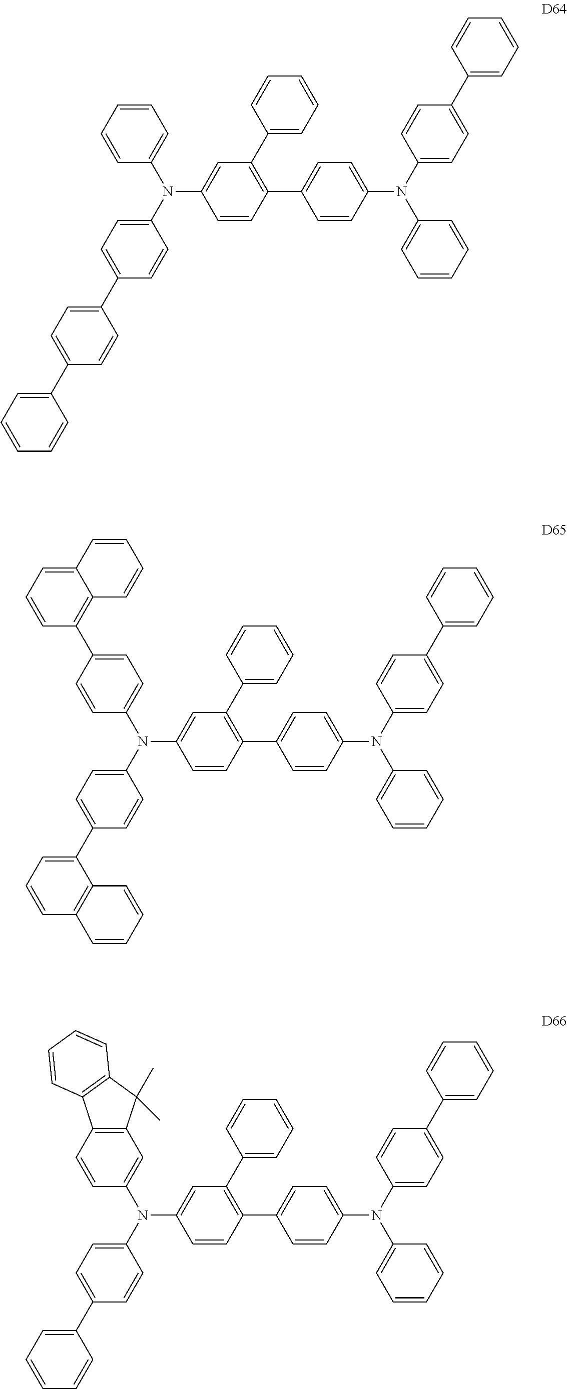 [SMILES: c1ccc(-c2ccc(-c3ccc(N(c4ccccc4)c4ccc(-c5ccc(N(c6ccccc6)c6ccc(-c7ccccc7)cc6)cc5)c(-c5ccccc5)c4)cc3)cc2)cc1 ; c1ccc(-c2ccc(N(c3ccccc3)c3ccc(-c4ccc(N(c5ccc(-c6cccc7ccccc67)cc5)c5ccc(-c6cccc7ccccc67)cc5)cc4-c4ccccc4)cc3)cc2)cc1 ; CC1(C)c2ccccc2-c2ccc(N(c3ccc(-c4ccccc4)cc3)c3ccc(-c4ccc(N(c5ccccc5)c5ccc(-c6ccccc6)cc5)cc4)c(-c4ccccc4)c3)cc21]

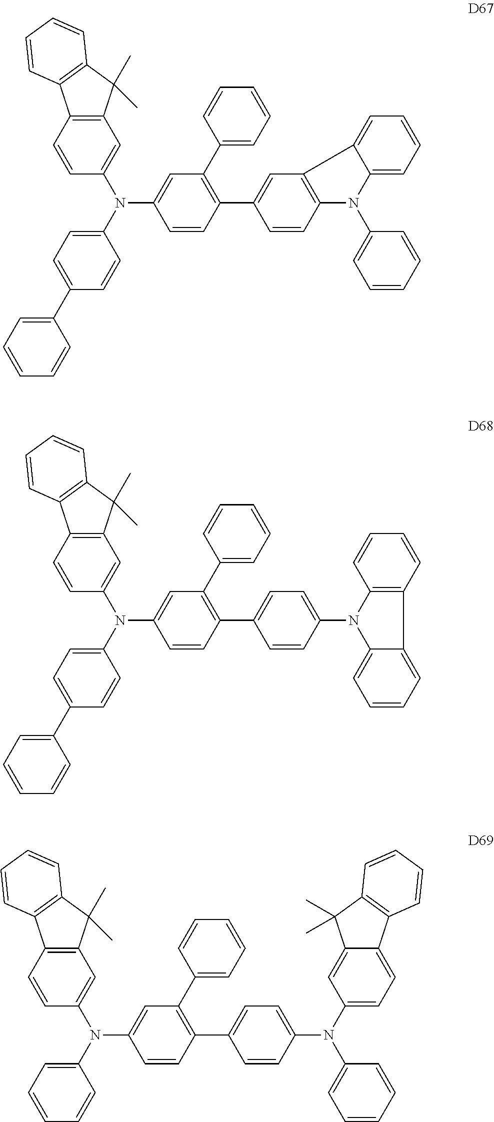 [SMILES: CC1(C)c2ccccc2-c2ccc(N(c3ccc(-c4ccccc4)cc3)c3ccc(-c4ccc5c(c4)c4ccccc4n5-c4ccccc4)c(-c4ccccc4)c3)cc21 ; CC1(C)c2ccccc2-c2ccc(N(c3ccc(-c4ccccc4)cc3)c3ccc(-c4ccc(-n5c6ccccc6c6ccccc65)cc4)c(-c4ccccc4)c3)cc21 ; CC1(C)c2ccccc2-c2ccc(N(c3ccccc3)c3ccc(-c4ccc(N(c5ccccc5)c5ccc6c(c5)C(C)(C)c5ccccc5-6)cc4-c4ccccc4)cc3)cc21]

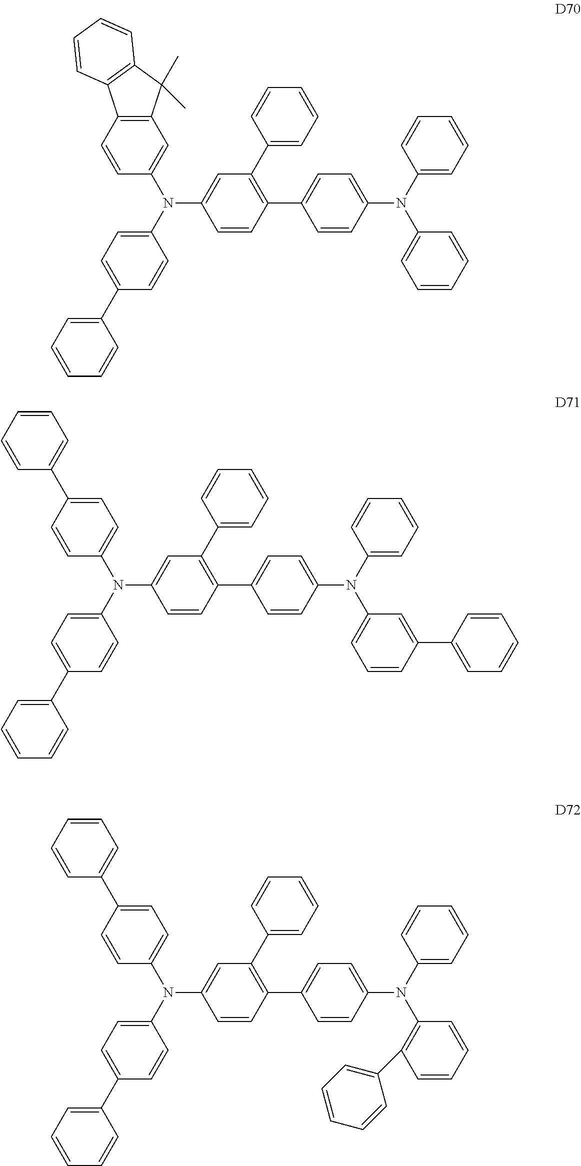

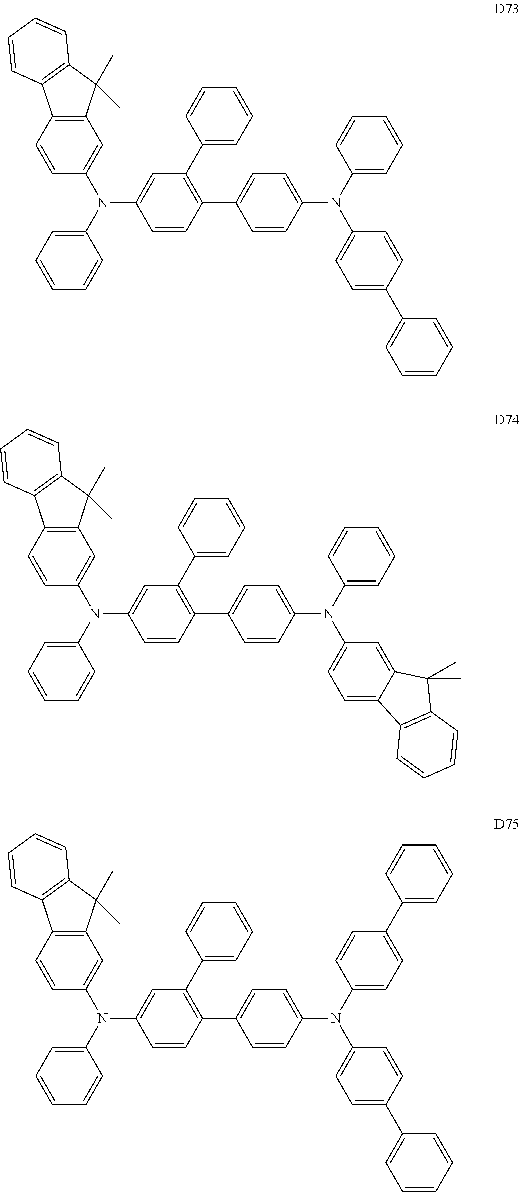 [SMILES: CC1(C)c2ccccc2-c2ccc(N(c3ccccc3)c3ccc(-c4ccc(N(c5ccccc5)c5ccc(-c6ccccc6)cc5)cc4)c(-c4ccccc4)c3)cc21 ; CC1(C)c2ccccc2-c2ccc(N(c3ccccc3)c3ccc(-c4ccc(N(c5ccccc5)c5ccc6c(c5)C(C)(C)c5ccccc5-6)cc4-c4ccccc4)cc3)cc21 ; CC1(C)c2ccccc2-c2ccc(N(c3ccccc3)c3ccc(-c4ccc(N(c5ccc(-c6ccccc6)cc5)c5ccc(-c6ccccc6)cc5)cc4)c(-c4ccccc4)c3)cc21]

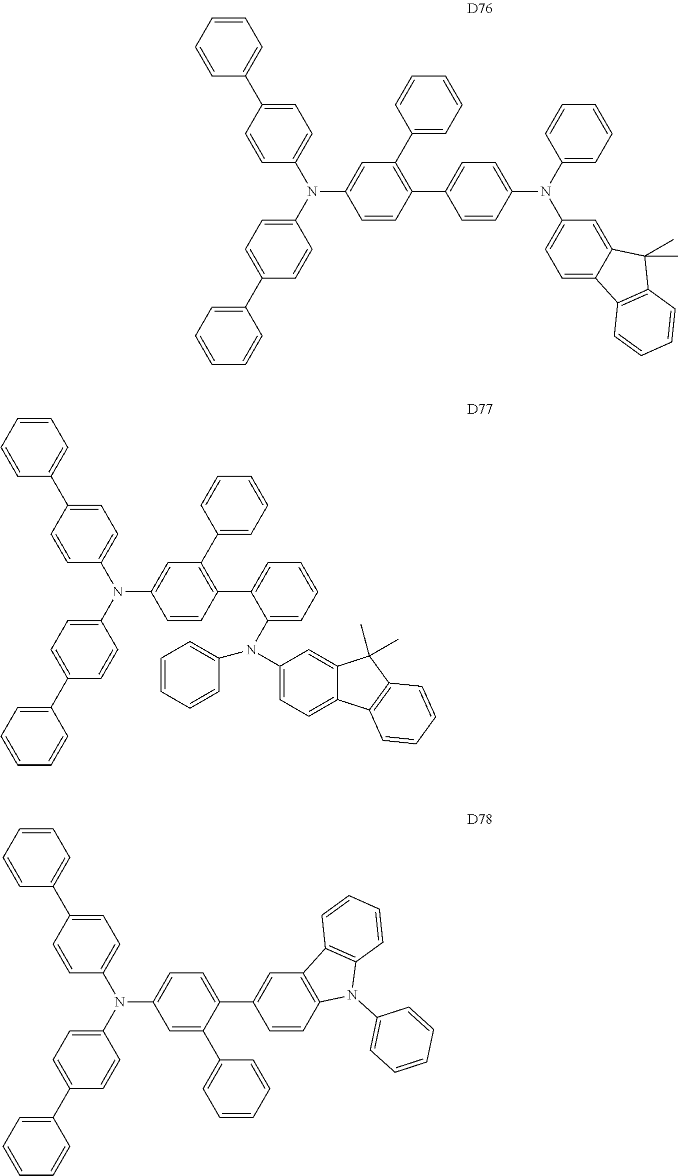 [SMILES: CC1(C)c2ccccc2-c2ccc(N(c3ccccc3)c3ccc(-c4ccc(N(c5ccc(-c6ccccc6)cc5)c5ccc(-c6ccccc6)cc5)cc4-c4ccccc4)cc3)cc21 ; CC1(C)c2ccccc2-c2ccc(N(c3ccccc3)c3ccccc3-c3ccc(N(c4ccc(-c5ccccc5)cc4)c4ccc(-c5ccccc5)cc4)cc3-c3ccccc3)cc21 ; c1ccc(-c2ccc(N(c3ccc(-c4ccccc4)cc3)c3ccc(-c4ccc5c(c4)c4ccccc4n5-c4ccccc4)c(-c4ccccc4)c3)cc2)cc1]

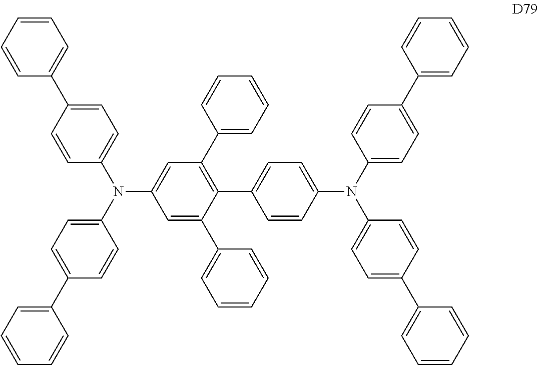 [SMILES: c1ccc(-c2ccc(N(c3ccc(-c4ccccc4)cc3)c3ccc(-c4c(-c5ccccc5)cc(N(c5ccc(-c6ccccc6)cc5)c5ccc(-c6ccccc6)cc5)cc4-c4ccccc4)cc3)cc2)cc1]

The compound of Formula D employed in the organic electroluminescent device of the present invention may be specifically selected from the compounds of Formulae D101 to D145:

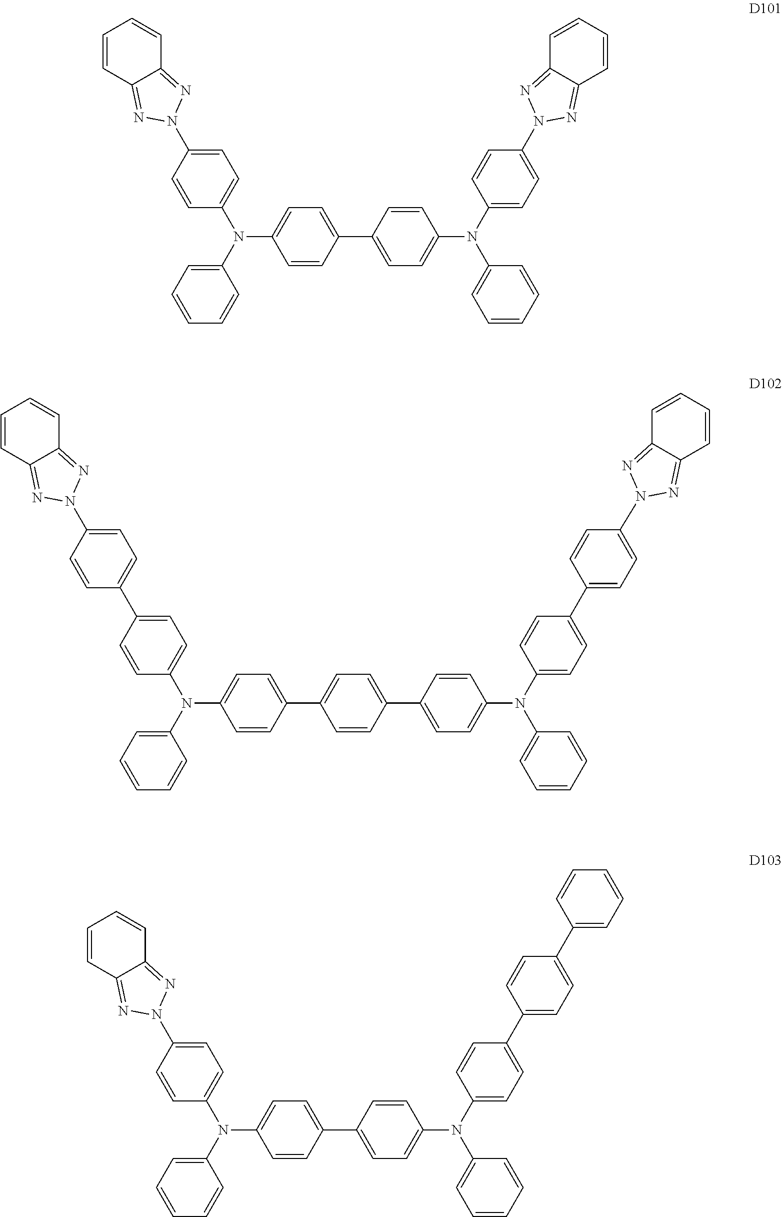 [SMILES: c1ccc(N(c2ccc(-c3ccc(N(c4ccccc4)c4ccc(-n5nc6ccccc6n5)cc4)cc3)cc2)c2ccc(-n3nc4ccccc4n3)cc2)cc1 ; c1ccc(N(c2ccc(-c3ccc(-c4ccc(N(c5ccccc5)c5ccc(-c6ccc(-n7nc8ccccc8n7)cc6)cc5)cc4)cc3)cc2)c2ccc(-c3ccc(-n4nc5ccccc5n4)cc3)cc2)cc1 ; c1ccc(-c2ccc(-c3ccc(N(c4ccccc4)c4ccc(-c5ccc(N(c6ccccc6)c6ccc(-n7nc8ccccc8n7)cc6)cc5)cc4)cc3)cc2)cc1]

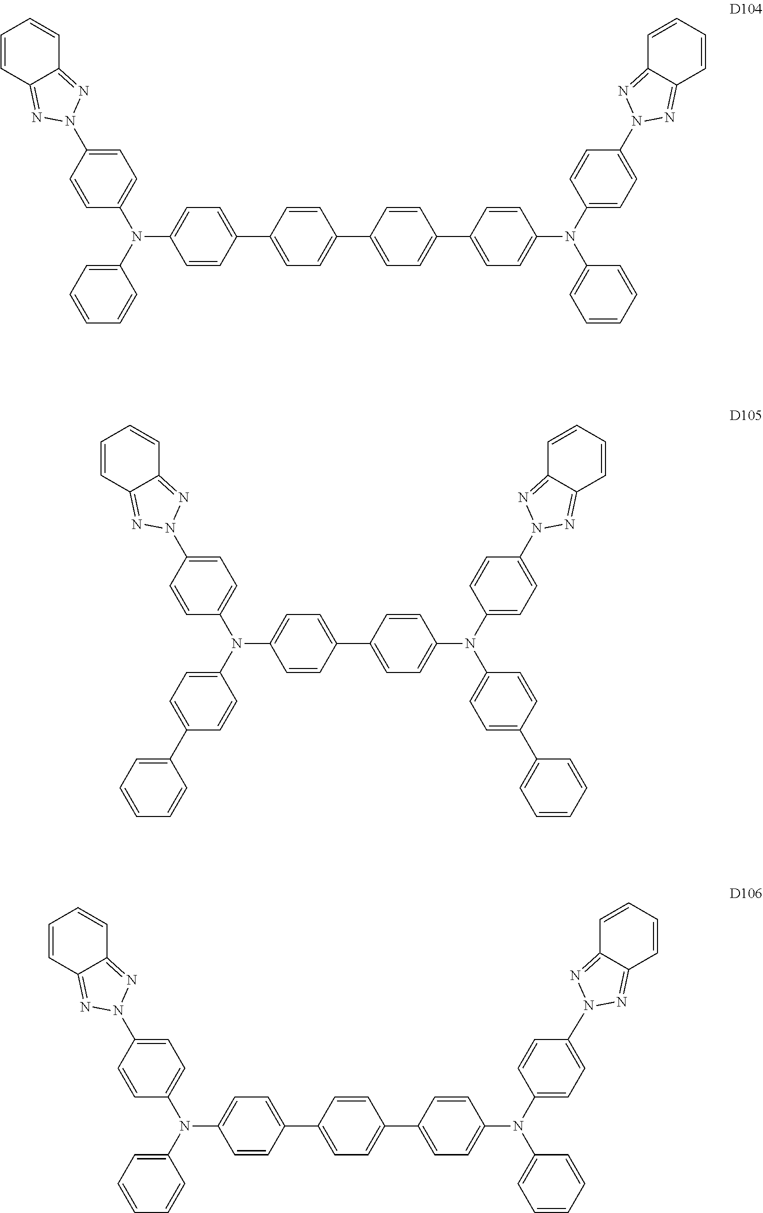 [SMILES: c1ccc(N(c2ccc(-c3ccc(-c4ccc(-c5ccc(N(c6ccccc6)c6ccc(-n7nc8ccccc8n7)cc6)cc5)cc4)cc3)cc2)c2ccc(-n3nc4ccccc4n3)cc2)cc1 ; c1ccc(-c2ccc(N(c3ccc(-c4ccc(N(c5ccc(-c6ccccc6)cc5)c5ccc(-n6nc7ccccc7n6)cc5)cc4)cc3)c3ccc(-n4nc5ccccc5n4)cc3)cc2)cc1 ; c1ccc(N(c2ccc(-c3ccc(-c4ccc(N(c5ccccc5)c5ccc(-n6nc7ccccc7n6)cc5)cc4)cc3)cc2)c2ccc(-n3nc4ccccc4n3)cc2)cc1]

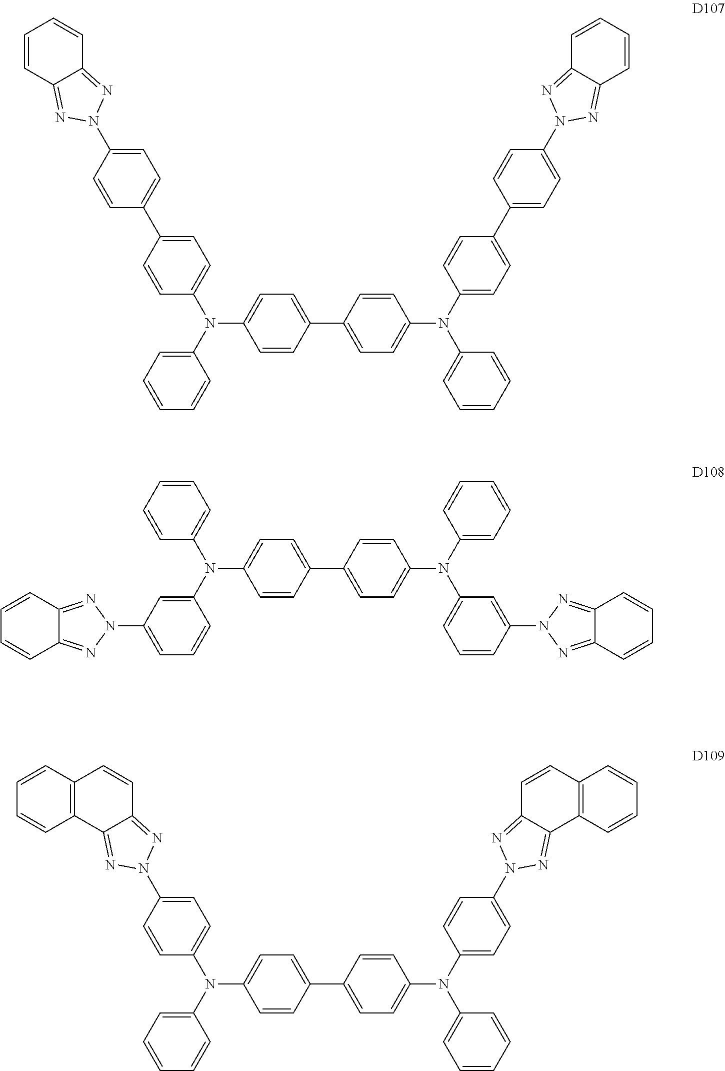 [SMILES: c1ccc(N(c2ccc(-c3ccc(N(c4ccccc4)c4ccc(-c5ccc(-n6nc7ccccc7n6)cc5)cc4)cc3)cc2)c2ccc(-c3ccc(-n4nc5ccccc5n4)cc3)cc2)cc1 ; c1ccc(N(c2ccc(-c3ccc(N(c4ccccc4)c4cccc(-n5nc6ccccc6n5)c4)cc3)cc2)c2cccc(-n3nc4ccccc4n3)c2)cc1 ; c1ccc(N(c2ccc(-c3ccc(N(c4ccccc4)c4ccc(-n5nc6ccc7ccccc7c6n5)cc4)cc3)cc2)c2ccc(-n3nc4ccc5ccccc5c4n3)cc2)cc1]

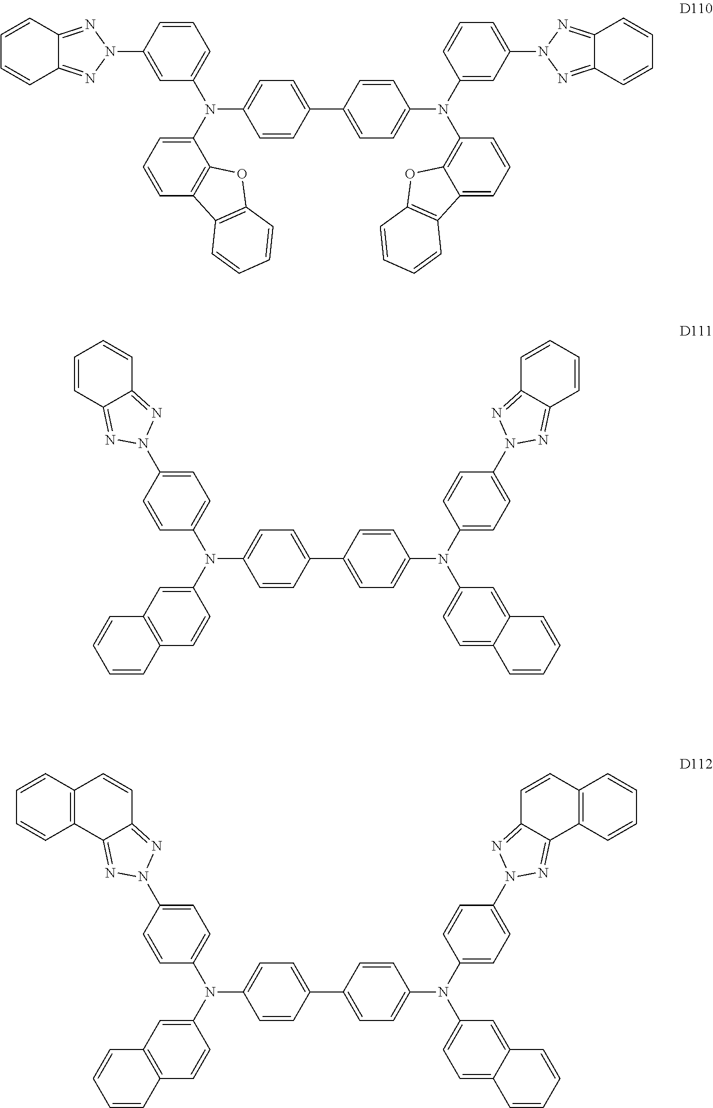 [SMILES: c1cc(N(c2ccc(-c3ccc(N(c4cccc(-n5nc6ccccc6n5)c4)c4cccc5c4oc4ccccc45)cc3)cc2)c2cccc3c2oc2ccccc23)cc(-n2nc3ccccc3n2)c1 ; c1ccc2cc(N(c3ccc(-c4ccc(N(c5ccc(-n6nc7ccccc7n6)cc5)c5ccc6ccccc6c5)cc4)cc3)c3ccc(-n4nc5ccccc5n4)cc3)ccc2c1 ; c1ccc2cc(N(c3ccc(-c4ccc(N(c5ccc(-n6nc7ccc8ccccc8c7n6)cc5)c5ccc6ccccc6c5)cc4)cc3)c3ccc(-n4nc5ccc6ccccc6c5n4)cc3)ccc2c1]

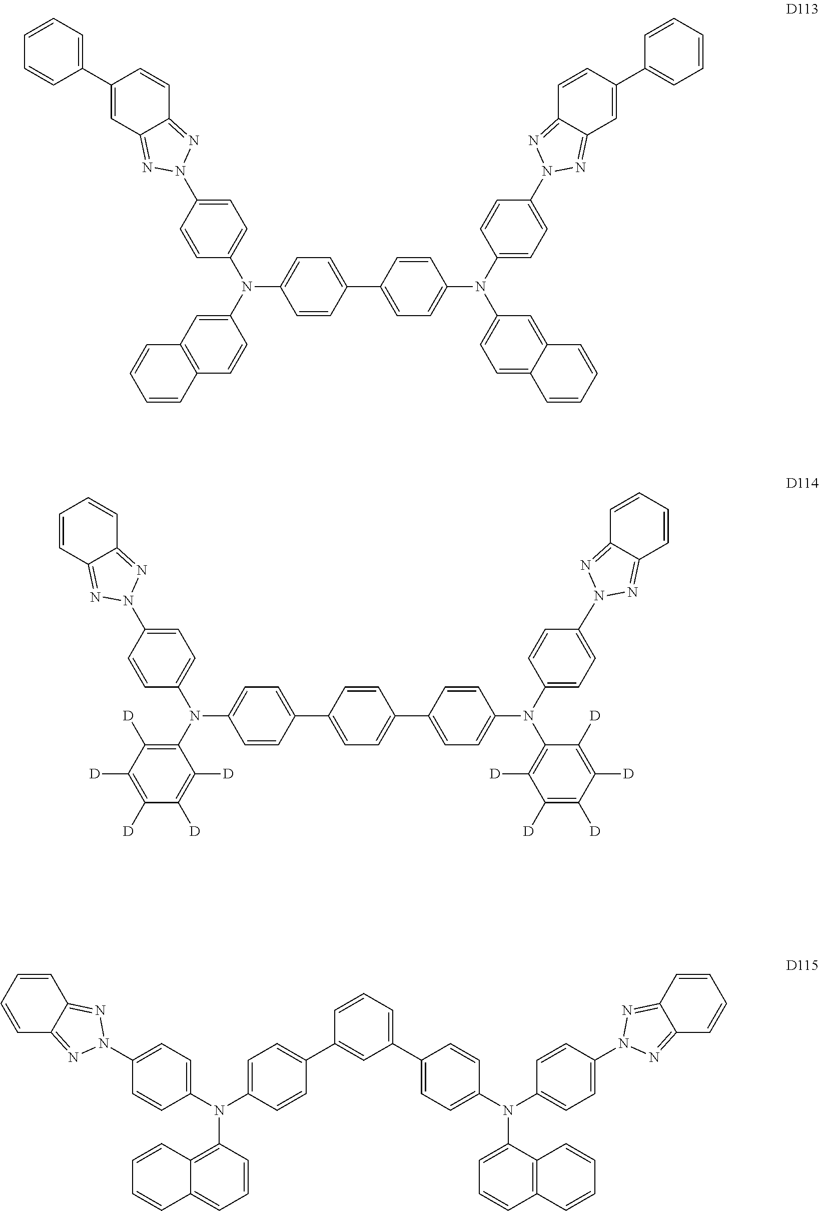 [SMILES: c1ccc(-c2ccc3nn(-c4ccc(N(c5ccc(-c6ccc(N(c7ccc(-n8nc9ccc(-c%10ccccc%10)cc9n8)cc7)c7ccc8ccccc8c7)cc6)cc5)c5ccc6ccccc6c5)cc4)nc3c2)cc1 ; [2H]c1c([2H])c([2H])c(N(c2ccc(-c3ccc(-c4ccc(N(c5ccc(-n6nc7ccccc7n6)cc5)c5c([2H])c([2H])c([2H])c([2H])c5[2H])cc4)cc3)cc2)c2ccc(-n3nc4ccccc4n3)cc2)c([2H])c1[2H] ; c1cc(-c2ccc(N(c3ccc(-n4nc5ccccc5n4)cc3)c3cccc4ccccc34)cc2)cc(-c2ccc(N(c3ccc(-n4nc5ccccc5n4)cc3)c3cccc4ccccc34)cc2)c1]

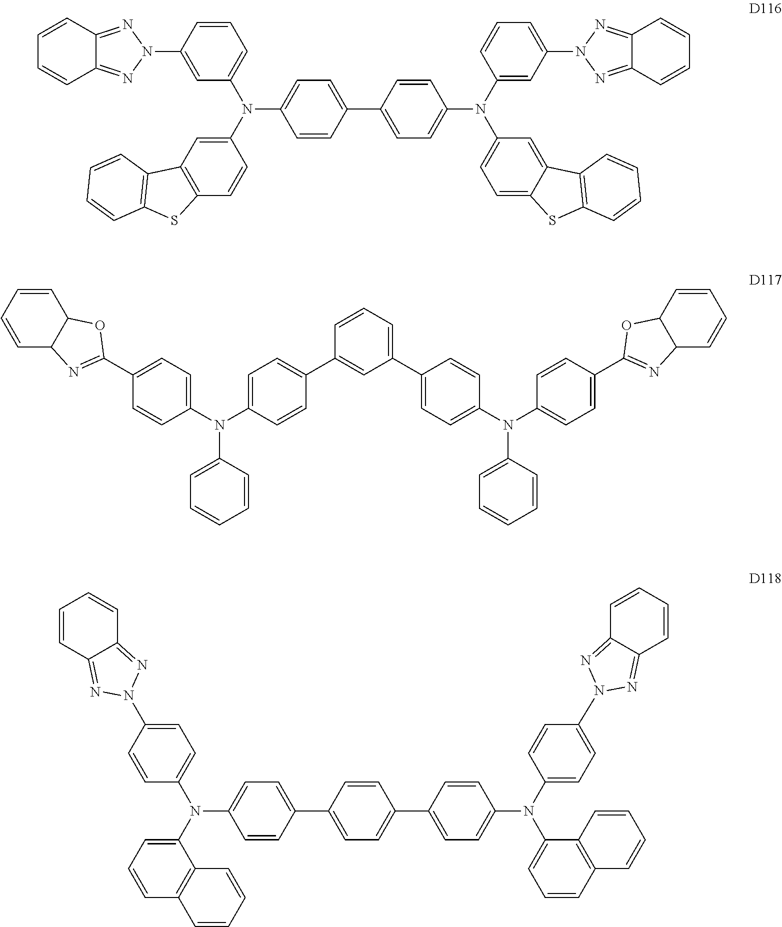 [SMILES: c1cc(N(c2ccc(-c3ccc(N(c4cccc(-n5nc6ccccc6n5)c4)c4ccc5sc6ccccc6c5c4)cc3)cc2)c2ccc3sc4ccccc4c3c2)cc(-n2nc3ccccc3n2)c1 ; C1=CC2N=C(c3ccc(N(c4ccccc4)c4ccc(-c5cccc(-c6ccc(N(c7ccccc7)c7ccc(C8=NC9C=CC=CC9O8)cc7)cc6)c5)cc4)cc3)OC2C=C1 ; c1ccc2c(N(c3ccc(-c4ccc(-c5ccc(N(c6ccc(-n7nc8ccccc8n7)cc6)c6cccc7ccccc67)cc5)cc4)cc3)c3ccc(-n4nc5ccccc5n4)cc3)cccc2c1]

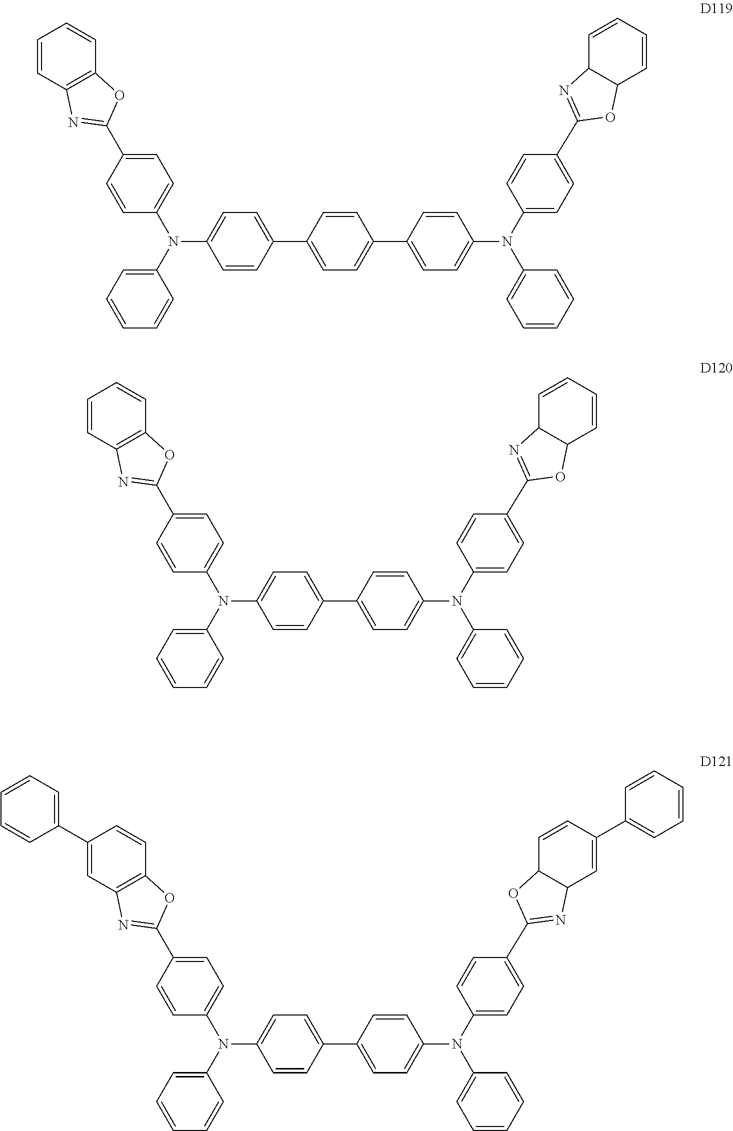 [SMILES: C1=CC2N=C(c3ccc(N(c4ccccc4)c4ccc(-c5ccc(-c6ccc(N(c7ccccc7)c7ccc(-c8nc9ccccc9o8)cc7)cc6)cc5)cc4)cc3)OC2C=C1 ; C1=CC2N=C(c3ccc(N(c4ccccc4)c4ccc(-c5ccc(N(c6ccccc6)c6ccc(-c7nc8ccccc8o7)cc6)cc5)cc4)cc3)OC2C=C1 ; C1=CC2OC(c3ccc(N(c4ccccc4)c4ccc(-c5ccc(N(c6ccccc6)c6ccc(-c7nc8cc(-c9ccccc9)ccc8o7)cc6)cc5)cc4)cc3)=NC2C=C1c1ccccc1]

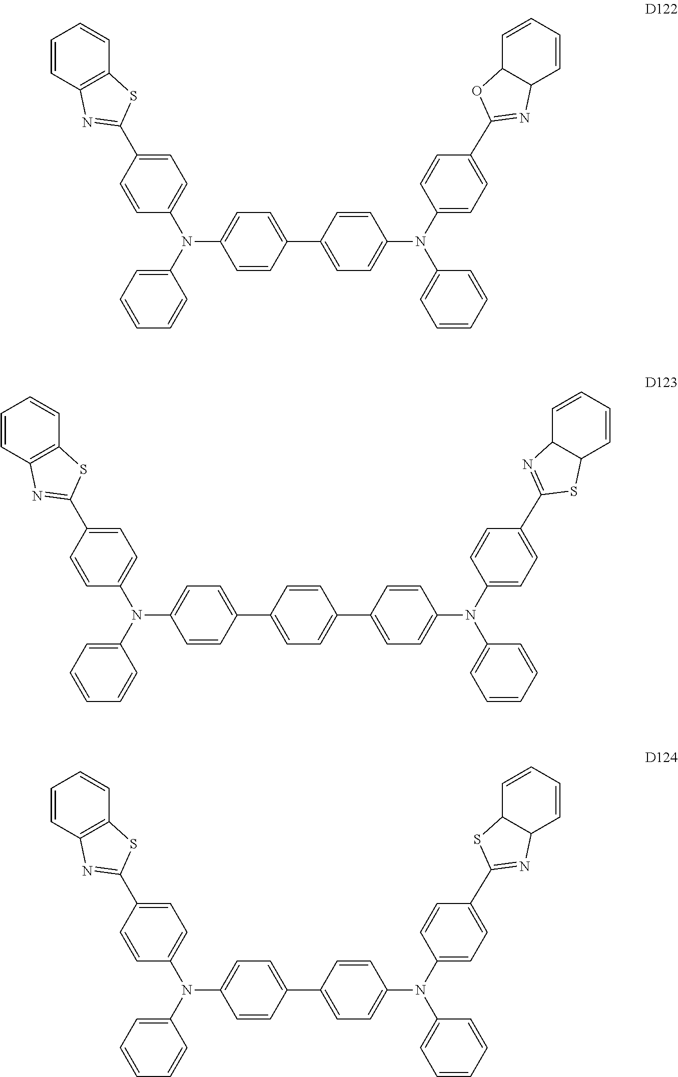 [SMILES: C1=CC2N=C(c3ccc(N(c4ccccc4)c4ccc(-c5ccc(N(c6ccccc6)c6ccc(-c7nc8ccccc8s7)cc6)cc5)cc4)cc3)OC2C=C1 ; C1=CC2N=C(c3ccc(N(c4ccccc4)c4ccc(-c5ccc(-c6ccc(N(c7ccccc7)c7ccc(-c8nc9ccccc9s8)cc7)cc6)cc5)cc4)cc3)SC2C=C1 ; C1=CC2N=C(c3ccc(N(c4ccccc4)c4ccc(-c5ccc(N(c6ccccc6)c6ccc(-c7nc8ccccc8s7)cc6)cc5)cc4)cc3)SC2C=C1]

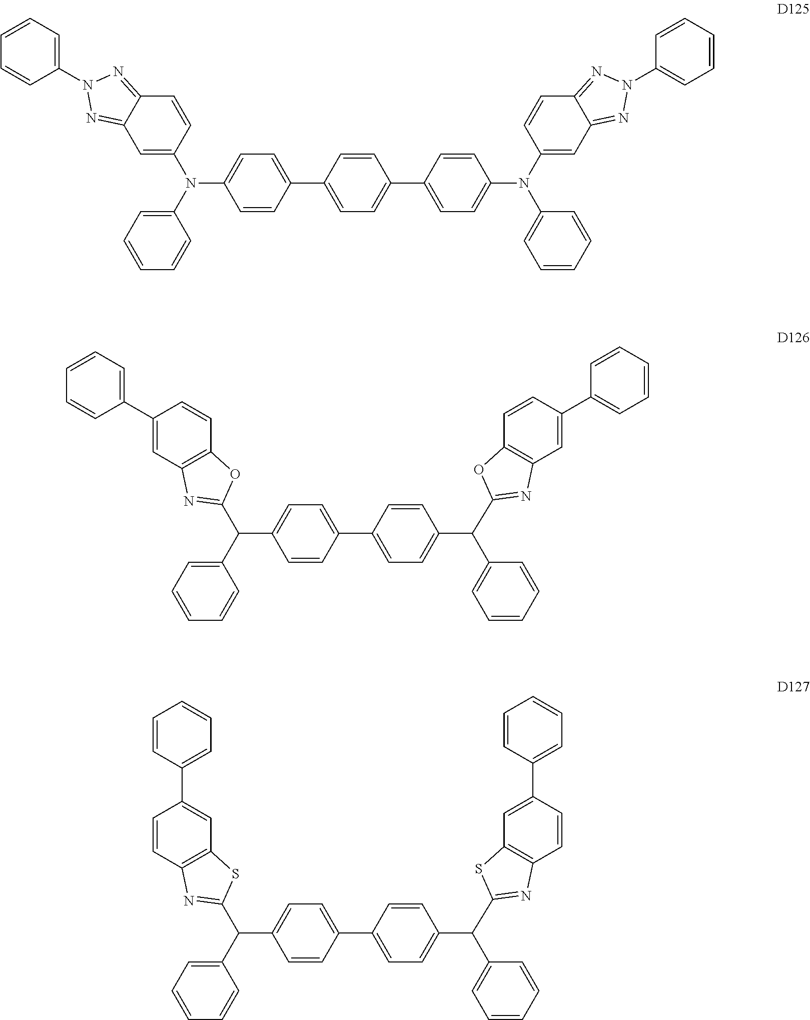 [SMILES: c1ccc(N(c2ccc(-c3ccc(-c4ccc(N(c5ccccc5)c5ccc6nn(-c7ccccc7)nc6c5)cc4)cc3)cc2)c2ccc3nn(-c4ccccc4)nc3c2)cc1 ; c1ccc(-c2ccc3oc(C(c4ccccc4)c4ccc(-c5ccc(C(c6ccccc6)c6nc7cc(-c8ccccc8)ccc7o6)cc5)cc4)nc3c2)cc1 ; c1ccc(-c2ccc3nc(C(c4ccccc4)c4ccc(-c5ccc(C(c6ccccc6)c6nc7ccc(-c8ccccc8)cc7s6)cc5)cc4)sc3c2)cc1]

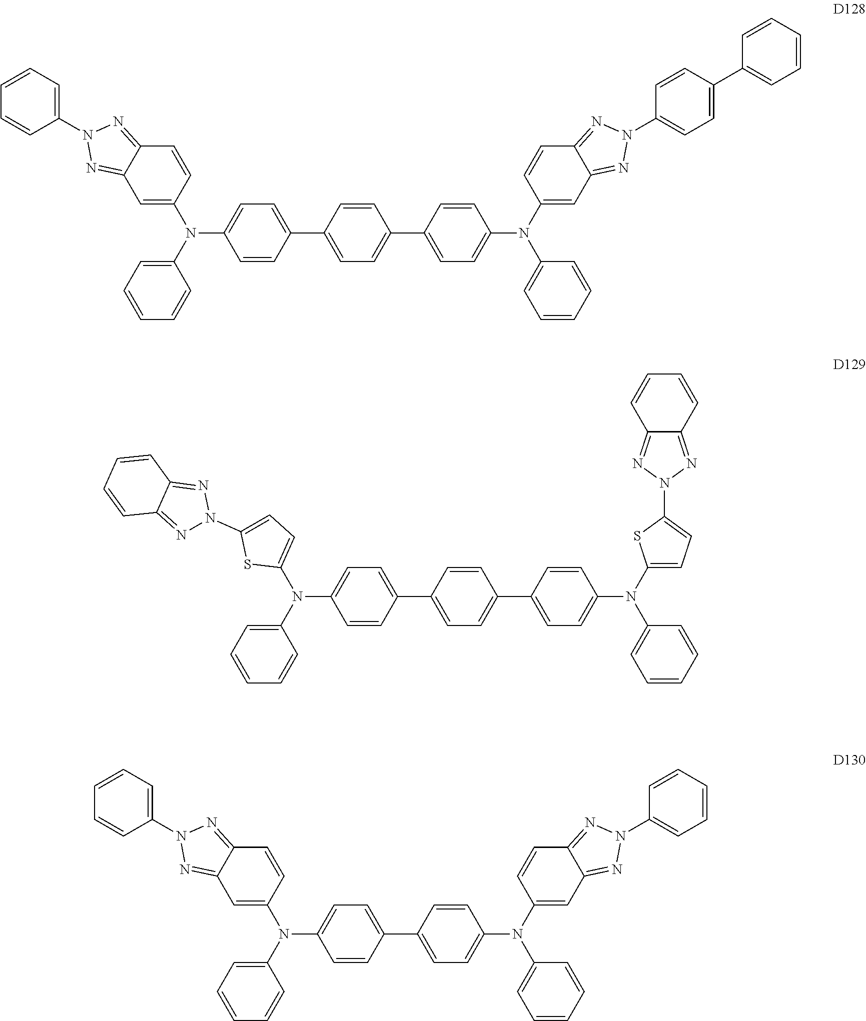 [SMILES: c1ccc(-c2ccc(-n3nc4ccc(N(c5ccccc5)c5ccc(-c6ccc(-c7ccc(N(c8ccccc8)c8ccc9nn(-c%10ccccc%10)nc9c8)cc7)cc6)cc5)cc4n3)cc2)cc1 ; c1ccc(N(c2ccc(-c3ccc(-c4ccc(N(c5ccccc5)c5ccc(-n6nc7ccccc7n6)s5)cc4)cc3)cc2)c2ccc(-n3nc4ccccc4n3)s2)cc1 ; c1ccc(N(c2ccc(-c3ccc(N(c4ccccc4)c4ccc5nn(-c6ccccc6)nc5c4)cc3)cc2)c2ccc3nn(-c4ccccc4)nc3c2)cc1]

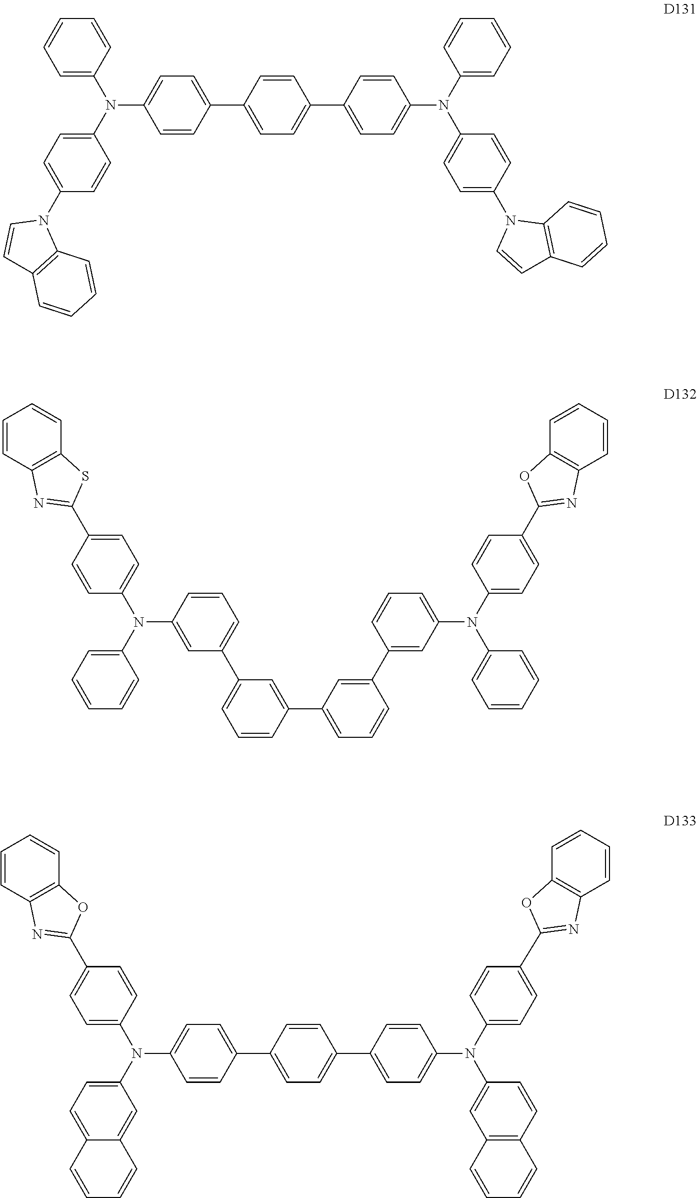 [SMILES: c1ccc(N(c2ccc(-c3ccc(-c4ccc(N(c5ccccc5)c5ccc(-n6ccc7ccccc76)cc5)cc4)cc3)cc2)c2ccc(-n3ccc4ccccc43)cc2)cc1 ; c1ccc(N(c2ccc(-c3nc4ccccc4o3)cc2)c2cccc(-c3cccc(-c4cccc(-c5cccc(N(c6ccccc6)c6ccc(-c7nc8ccccc8s7)cc6)c5)c4)c3)c2)cc1 ; c1ccc2cc(N(c3ccc(-c4ccc(-c5ccc(N(c6ccc(-c7nc8ccccc8o7)cc6)c6ccc7ccccc7c6)cc5)cc4)cc3)c3ccc(-c4nc5ccccc5o4)cc3)ccc2c1]

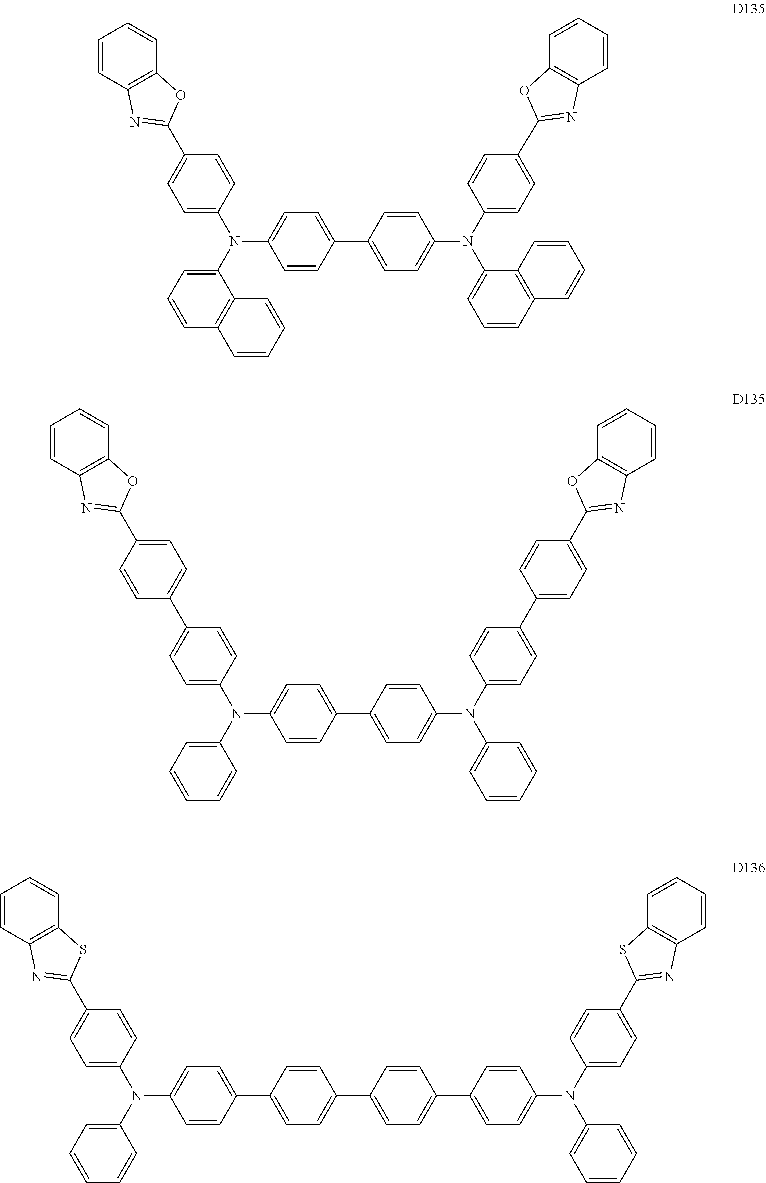 [SMILES: c1ccc2c(N(c3ccc(-c4ccc(N(c5ccc(-c6nc7ccccc7o6)cc5)c5cccc6ccccc56)cc4)cc3)c3ccc(-c4nc5ccccc5o4)cc3)cccc2c1 ; c1ccc(N(c2ccc(-c3ccc(-c4nc5ccccc5o4)cc3)cc2)c2ccc(-c3ccc(N(c4ccccc4)c4ccc(-c5ccc(-c6nc7ccccc7o6)cc5)cc4)cc3)cc2)cc1 ; c1ccc(N(c2ccc(-c3ccc(-c4ccc(-c5ccc(N(c6ccccc6)c6ccc(-c7nc8ccccc8s7)cc6)cc5)cc4)cc3)cc2)c2ccc(-c3nc4ccccc4s3)cc2)cc1]

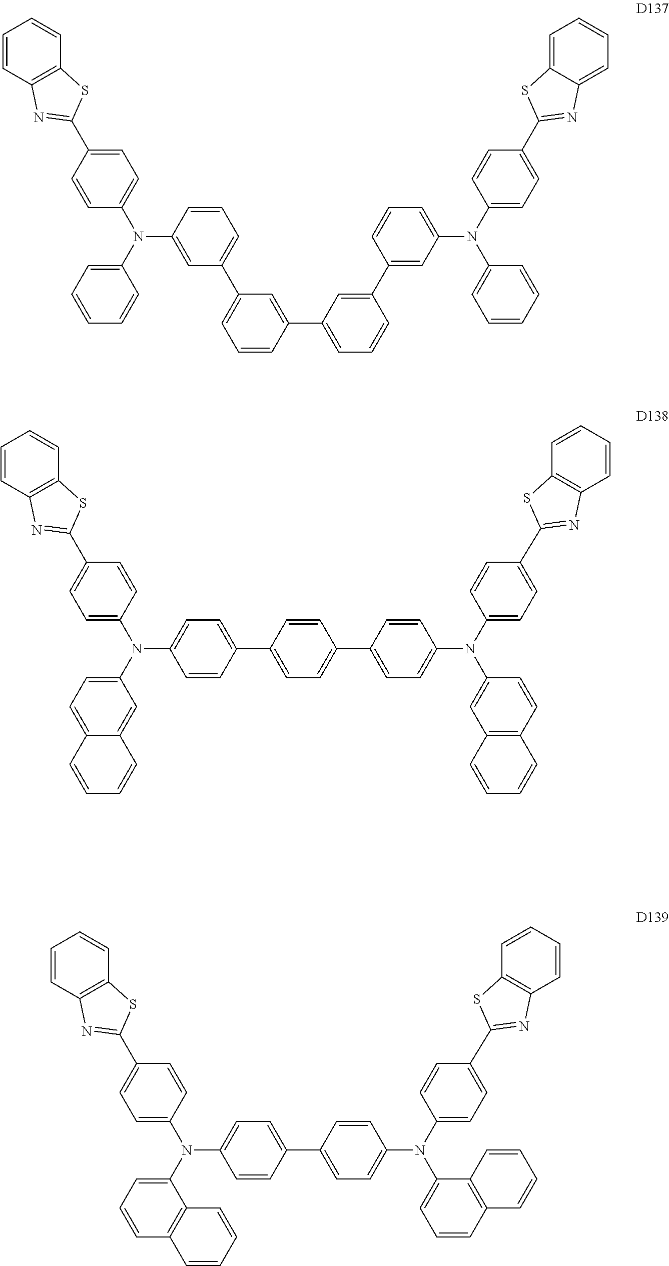 [SMILES: c1ccc(N(c2ccc(-c3nc4ccccc4s3)cc2)c2cccc(-c3cccc(-c4cccc(-c5cccc(N(c6ccccc6)c6ccc(-c7nc8ccccc8s7)cc6)c5)c4)c3)c2)cc1 ; c1ccc2cc(N(c3ccc(-c4ccc(-c5ccc(N(c6ccc(-c7nc8ccccc8s7)cc6)c6ccc7ccccc7c6)cc5)cc4)cc3)c3ccc(-c4nc5ccccc5s4)cc3)ccc2c1 ; c1ccc2c(N(c3ccc(-c4ccc(N(c5ccc(-c6nc7ccccc7s6)cc5)c5cccc6ccccc56)cc4)cc3)c3ccc(-c4nc5ccccc5s4)cc3)cccc2c1]

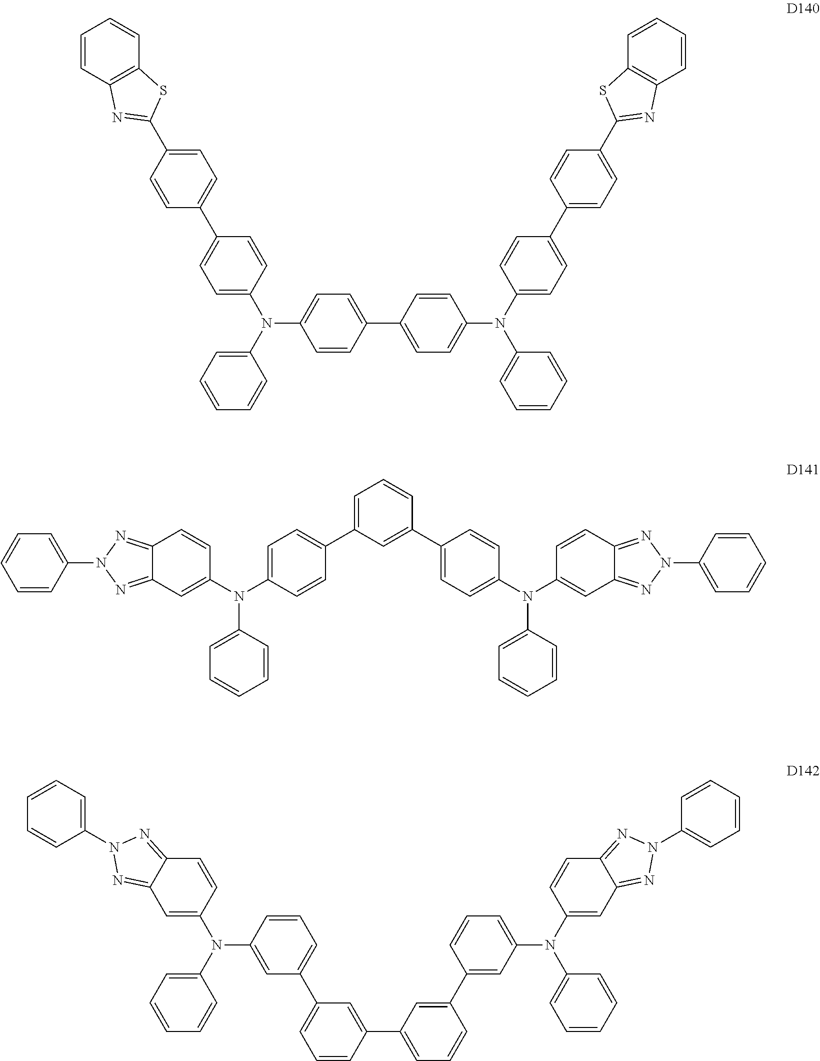 [SMILES: c1ccc(N(c2ccc(-c3ccc(-c4nc5ccccc5s4)cc3)cc2)c2ccc(-c3ccc(N(c4ccccc4)c4ccc(-c5ccc(-c6nc7ccccc7s6)cc5)cc4)cc3)cc2)cc1 ; c1ccc(N(c2ccc(-c3cccc(-c4ccc(N(c5ccccc5)c5ccc6nn(-c7ccccc7)nc6c5)cc4)c3)cc2)c2ccc3nn(-c4ccccc4)nc3c2)cc1 ; c1ccc(N(c2cccc(-c3cccc(-c4cccc(-c5cccc(N(c6ccccc6)c6ccc7nn(-c8ccccc8)nc7c6)c5)c4)c3)c2)c2ccc3nn(-c4ccccc4)nc3c2)cc1]

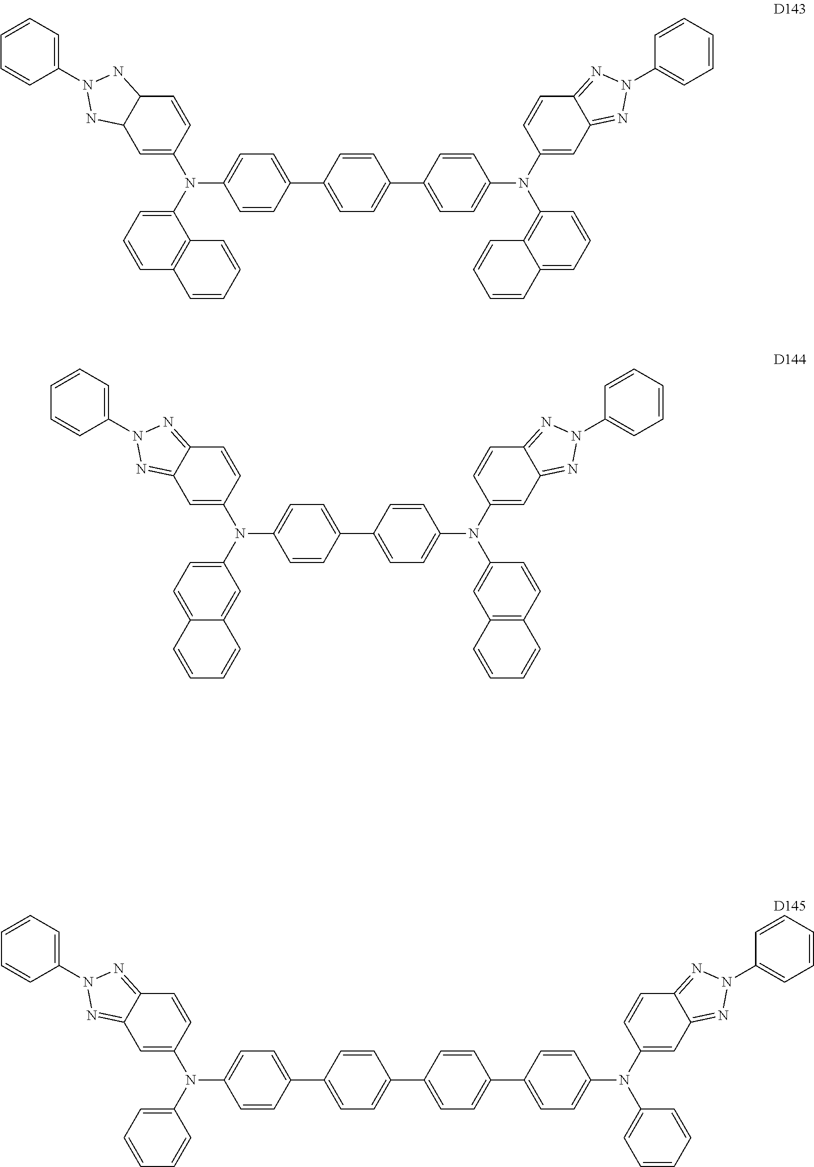 [SMILES: C1=CC2NN(c3ccccc3)NC2C=C1N(c1ccc(-c2ccc(-c3ccc(N(c4ccc5nn(-c6ccccc6)nc5c4)c4cccc5ccccc45)cc3)cc2)cc1)c1cccc2ccccc12 ; c1ccc(-n2nc3ccc(N(c4ccc(-c5ccc(N(c6ccc7ccccc7c6)c6ccc7nn(-c8ccccc8)nc7c6)cc5)cc4)c4ccc5ccccc5c4)cc3n2)cc1 ; c1ccc(N(c2ccc(-c3ccc(-c4ccc(-c5ccc(N(c6ccccc6)c6ccc7nn(-c8ccccc8)nc7c6)cc5)cc4)cc3)cc2)c2ccc3nn(-c4ccccc4)nc3c2)cc1]

The organic electroluminescent device of the present invention may further include a hole transport layer and an electron blocking layer, each of which may include a compound represented by Formula F:

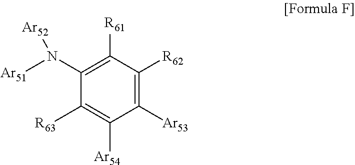

wherein R₆₁ to R₆₃ are identical to or different from each other and are each independently selected from hydrogen, deuterium, substituted or unsubstituted C₁-C₃₀ alkyl, substituted or unsubstituted C₆-C₅₀ aryl, substituted or unsubstituted C₂-C₃₀ alkenyl, substituted or unsubstituted C₂-C₂₀ alkynyl, substituted or unsubstituted C₃-C₃₀ cycloalkyl, substituted or unsubstituted C₅-C₃₀ cycloalkenyl, substituted or unsubstituted C₂-C₅₀ heteroaryl, substituted or unsubstituted C₂-C₃₀ heterocycloalkyl, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₆-C₃₀ arylthioxy, substituted or unsubstituted C₁-C₃₀ alkylamine, substituted or unsubstituted C₆-C₃₀ arylamine, substituted or unsubstituted C₁-C₃₀ alkylsilyl, substituted or unsubstituted C₆-C₃₀ arylsilyl, substituted or unsubstituted C₁-C₃₀ alkylgermanium, substituted or unsubstituted C₁-C₃₀ arylgermanium, cyano, nitro, and halogen, and Arm to Ar₅₄ are identical to or different from each other and are each independently substituted or unsubstituted C₆-C₄₀ aryl or substituted or unsubstituted C₂-C₃₀ heteroaryl.

The compound of Formula F employed in the organic electroluminescent device of the present invention may be specifically selected from the compounds of Formulae F1 to F33:

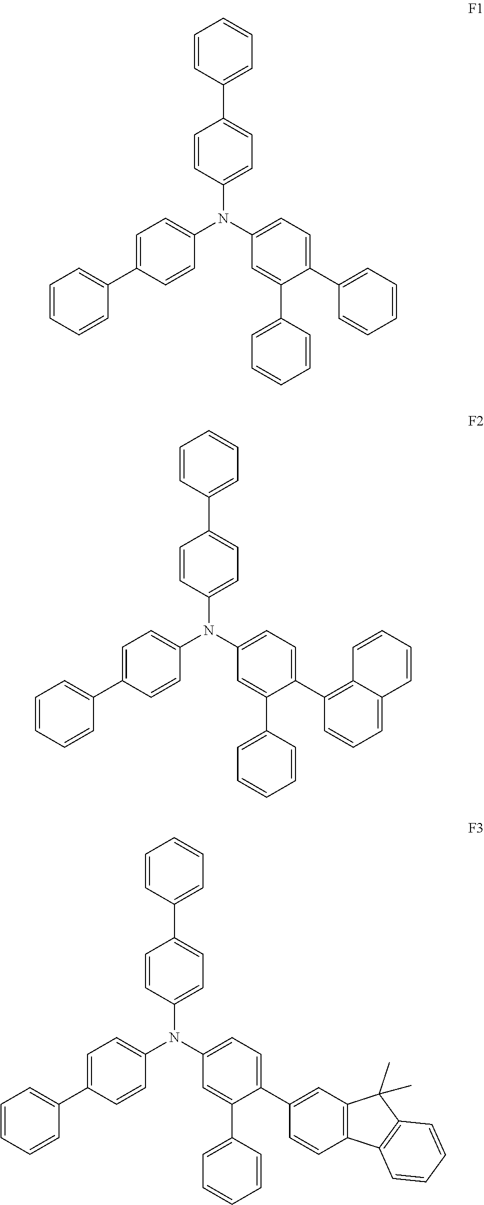 [SMILES: c1ccc(-c2ccc(N(c3ccc(-c4ccccc4)cc3)c3ccc(-c4ccccc4)c(-c4ccccc4)c3)cc2)cc1 ; c1ccc(-c2ccc(N(c3ccc(-c4ccccc4)cc3)c3ccc(-c4cccc5ccccc45)c(-c4ccccc4)c3)cc2)cc1 ; CC1(C)c2ccccc2-c2ccc(-c3ccc(N(c4ccc(-c5ccccc5)cc4)c4ccc(-c5ccccc5)cc4)cc3-c3ccccc3)cc21]

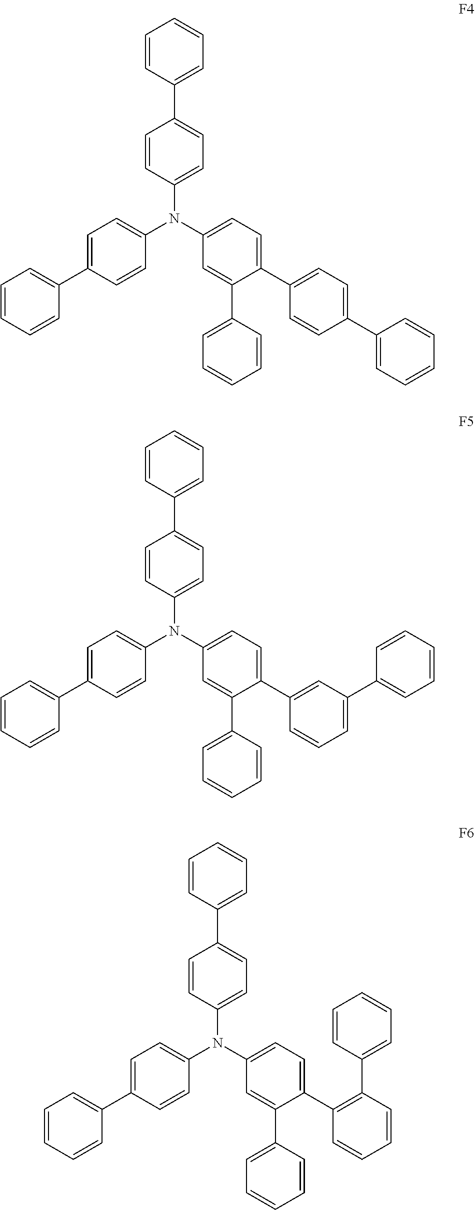 [SMILES: c1ccc(-c2ccc(-c3ccc(N(c4ccc(-c5ccccc5)cc4)c4ccc(-c5ccccc5)cc4)cc3-c3ccccc3)cc2)cc1 ; c1ccc(-c2ccc(N(c3ccc(-c4ccccc4)cc3)c3ccc(-c4cccc(-c5ccccc5)c4)c(-c4ccccc4)c3)cc2)cc1 ; c1ccc(-c2ccc(N(c3ccc(-c4ccccc4)cc3)c3ccc(-c4ccccc4-c4ccccc4)c(-c4ccccc4)c3)cc2)cc1]

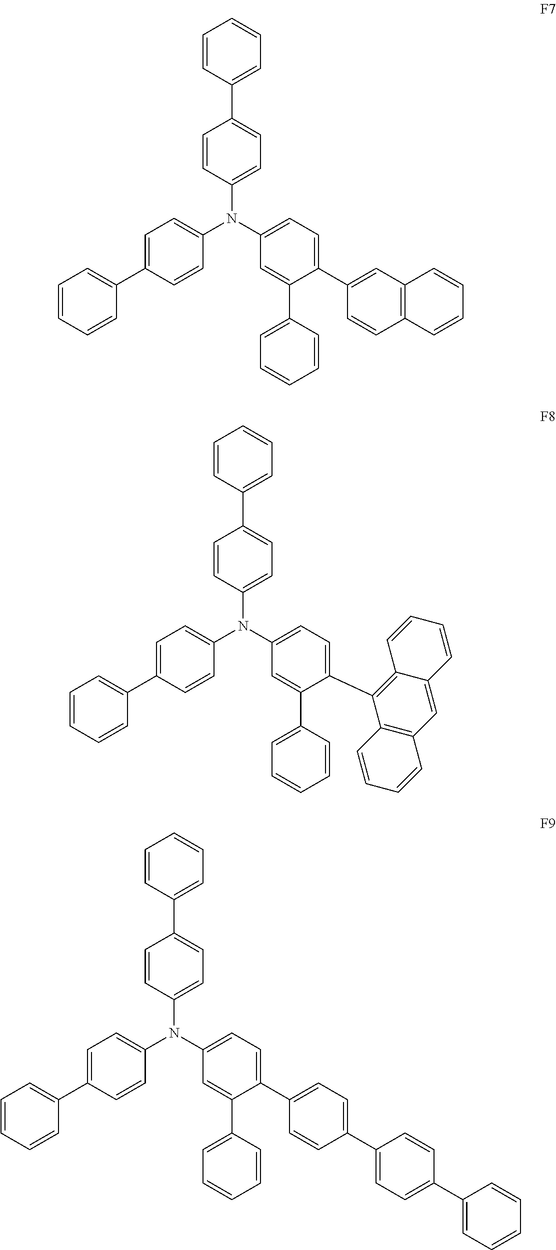 [SMILES: c1ccc(-c2ccc(N(c3ccc(-c4ccccc4)cc3)c3ccc(-c4ccc5ccccc5c4)c(-c4ccccc4)c3)cc2)cc1 ; c1ccc(-c2ccc(N(c3ccc(-c4ccccc4)cc3)c3ccc(-c4c5ccccc5cc5ccccc45)c(-c4ccccc4)c3)cc2)cc1 ; c1ccc(-c2ccc(-c3ccc(-c4ccc(N(c5ccc(-c6ccccc6)cc5)c5ccc(-c6ccccc6)cc5)cc4-c4ccccc4)cc3)cc2)cc1]

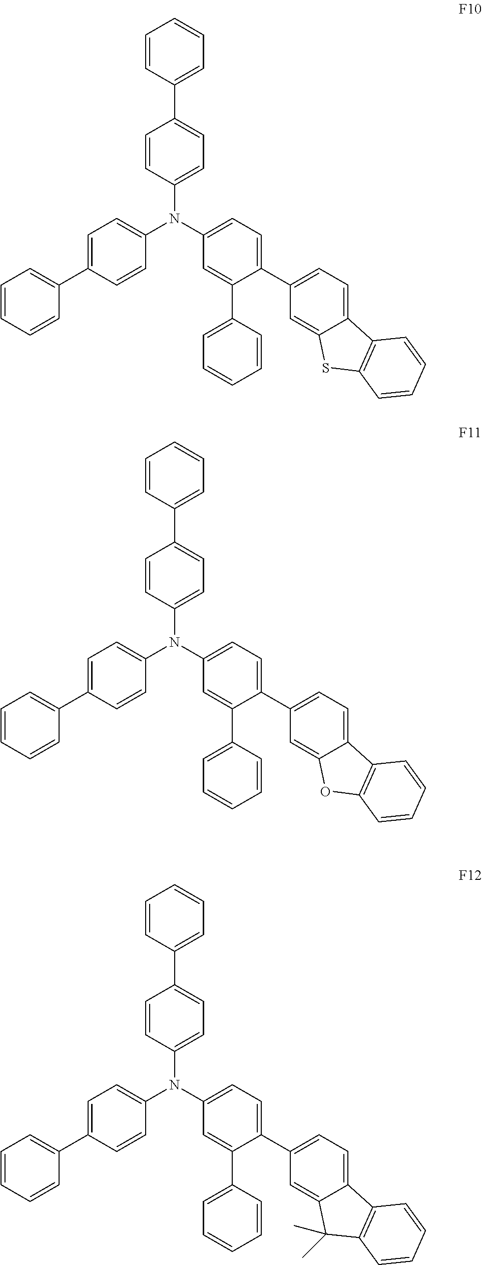 [SMILES: c1ccc(-c2ccc(N(c3ccc(-c4ccccc4)cc3)c3ccc(-c4ccc5c(c4)sc4ccccc45)c(-c4ccccc4)c3)cc2)cc1 ; c1ccc(-c2ccc(N(c3ccc(-c4ccccc4)cc3)c3ccc(-c4ccc5c(c4)oc4ccccc45)c(-c4ccccc4)c3)cc2)cc1 ; CC1(C)c2ccccc2-c2ccc(-c3ccc(N(c4ccc(-c5ccccc5)cc4)c4ccc(-c5ccccc5)cc4)cc3-c3ccccc3)cc21]

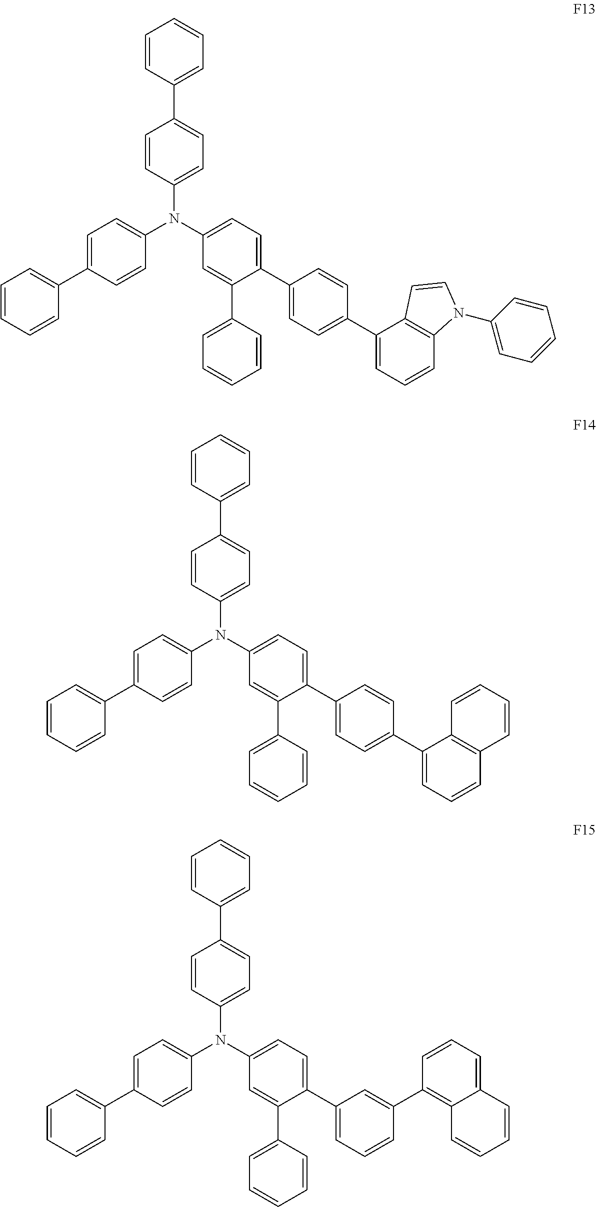 [SMILES: c1ccc(-c2ccc(N(c3ccc(-c4ccccc4)cc3)c3ccc(-c4ccc(-c5cccc6c5ccn6-c5ccccc5)cc4)c(-c4ccccc4)c3)cc2)cc1 ; c1ccc(-c2ccc(N(c3ccc(-c4ccccc4)cc3)c3ccc(-c4ccc(-c5cccc6ccccc56)cc4)c(-c4ccccc4)c3)cc2)cc1 ; c1ccc(-c2ccc(N(c3ccc(-c4ccccc4)cc3)c3ccc(-c4cccc(-c5cccc6ccccc56)c4)c(-c4ccccc4)c3)cc2)cc1]

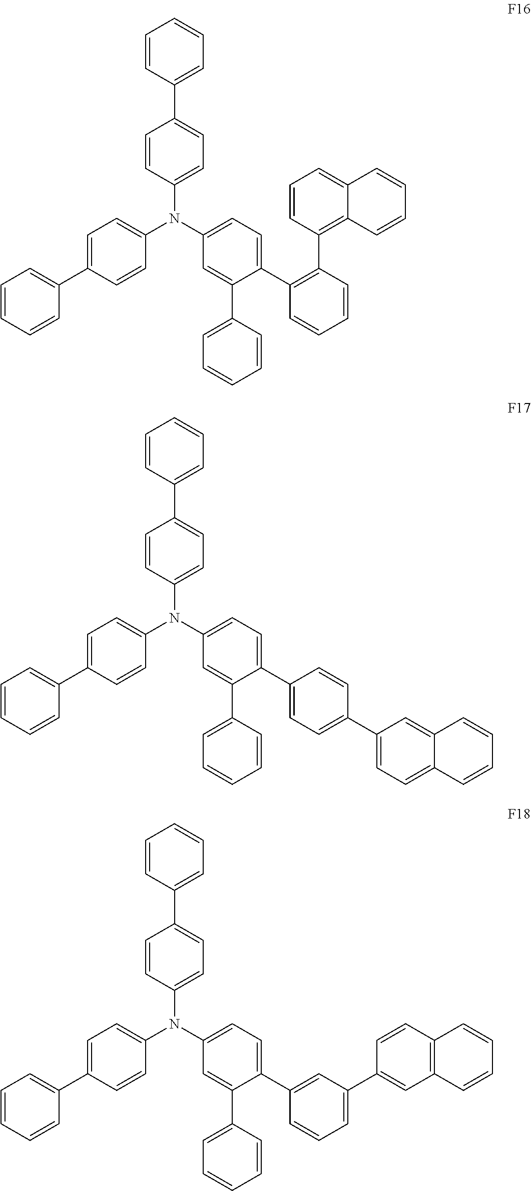 [SMILES: c1ccc(-c2ccc(N(c3ccc(-c4ccccc4)cc3)c3ccc(-c4ccccc4-c4cccc5ccccc45)c(-c4ccccc4)c3)cc2)cc1 ; c1ccc(-c2ccc(N(c3ccc(-c4ccccc4)cc3)c3ccc(-c4ccc(-c5ccc6ccccc6c5)cc4)c(-c4ccccc4)c3)cc2)cc1 ; c1ccc(-c2ccc(N(c3ccc(-c4ccccc4)cc3)c3ccc(-c4cccc(-c5ccc6ccccc6c5)c4)c(-c4ccccc4)c3)cc2)cc1]

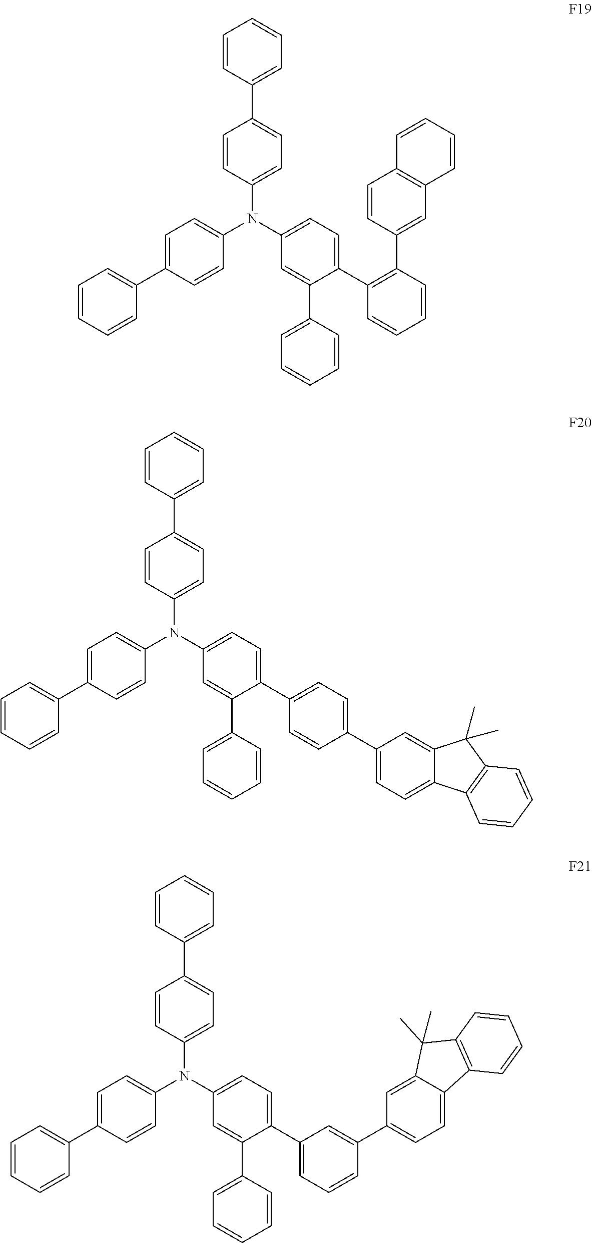 [SMILES: c1ccc(-c2ccc(N(c3ccc(-c4ccccc4)cc3)c3ccc(-c4ccccc4-c4ccc5ccccc5c4)c(-c4ccccc4)c3)cc2)cc1 ; CC1(C)c2ccccc2-c2ccc(-c3ccc(-c4ccc(N(c5ccc(-c6ccccc6)cc5)c5ccc(-c6ccccc6)cc5)cc4-c4ccccc4)cc3)cc21 ; CC1(C)c2ccccc2-c2ccc(-c3cccc(-c4ccc(N(c5ccc(-c6ccccc6)cc5)c5ccc(-c6ccccc6)cc5)cc4-c4ccccc4)c3)cc21]

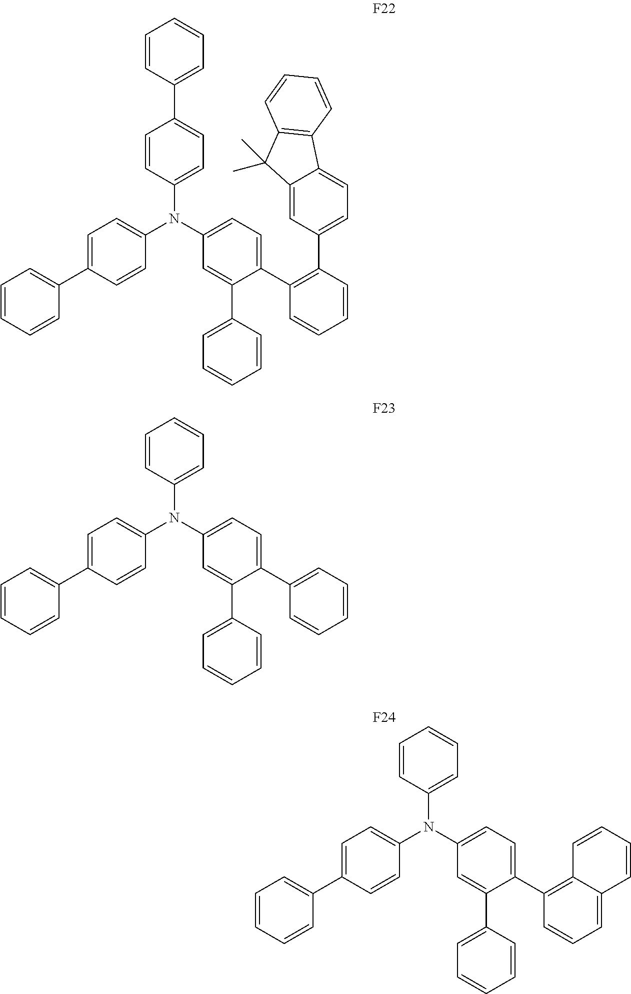 [SMILES: CC1(C)c2ccccc2-c2ccc(-c3ccccc3-c3ccc(N(c4ccc(-c5ccccc5)cc4)c4ccc(-c5ccccc5)cc4)cc3-c3ccccc3)cc21 ; c1ccc(-c2ccc(N(c3ccccc3)c3ccc(-c4ccccc4)c(-c4ccccc4)c3)cc2)cc1 ; c1ccc(-c2ccc(N(c3ccccc3)c3ccc(-c4cccc5ccccc45)c(-c4ccccc4)c3)cc2)cc1]

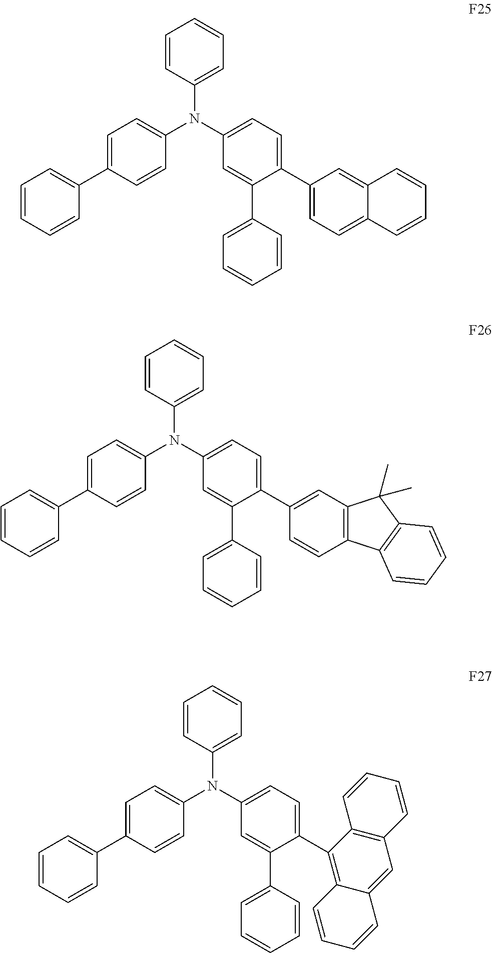 [SMILES: c1ccc(-c2ccc(N(c3ccccc3)c3ccc(-c4ccc5ccccc5c4)c(-c4ccccc4)c3)cc2)cc1 ; CC1(C)c2ccccc2-c2ccc(-c3ccc(N(c4ccccc4)c4ccc(-c5ccccc5)cc4)cc3-c3ccccc3)cc21 ; c1ccc(-c2ccc(N(c3ccccc3)c3ccc(-c4c5ccccc5cc5ccccc45)c(-c4ccccc4)c3)cc2)cc1]

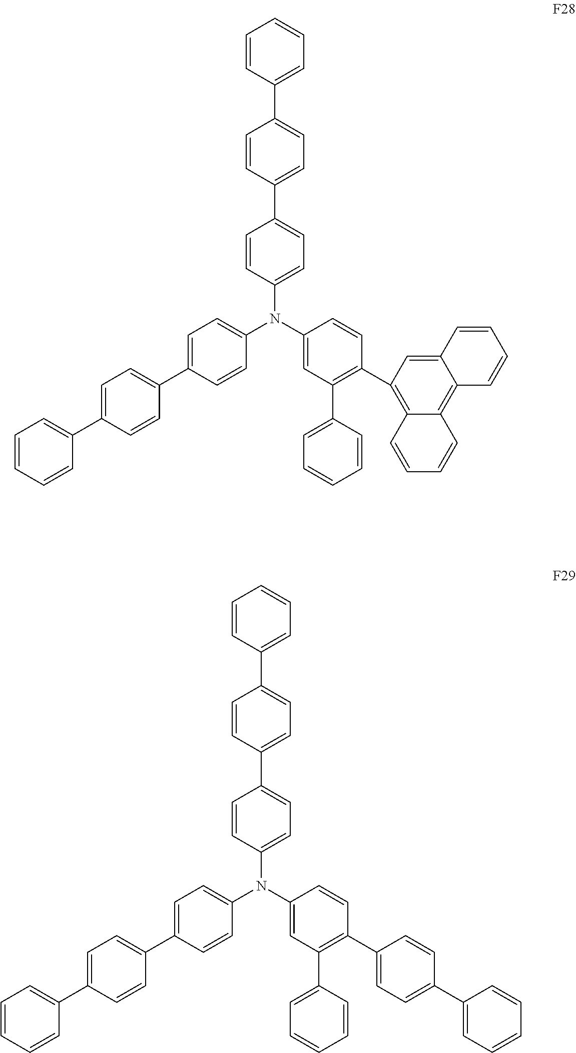 [SMILES: c1ccc(-c2ccc(-c3ccc(N(c4ccc(-c5ccc(-c6ccccc6)cc5)cc4)c4ccc(-c5cc6ccccc6c6ccccc56)c(-c5ccccc5)c4)cc3)cc2)cc1 ; c1ccc(-c2ccc(-c3ccc(N(c4ccc(-c5ccc(-c6ccccc6)cc5)cc4)c4ccc(-c5ccc(-c6ccccc6)cc5)c(-c5ccccc5)c4)cc3)cc2)cc1]

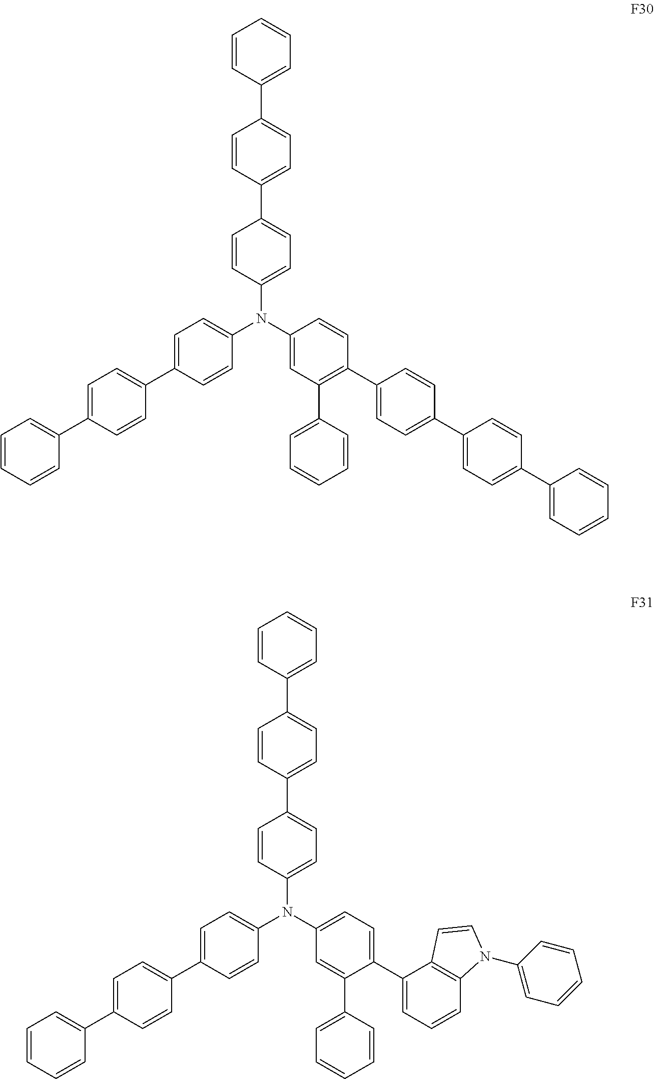 [SMILES: c1ccc(-c2ccc(-c3ccc(-c4ccc(N(c5ccc(-c6ccc(-c7ccccc7)cc6)cc5)c5ccc(-c6ccc(-c7ccccc7)cc6)cc5)cc4-c4ccccc4)cc3)cc2)cc1 ; c1ccc(-c2ccc(-c3ccc(N(c4ccc(-c5ccc(-c6ccccc6)cc5)cc4)c4ccc(-c5cccc6c5ccn6-c5ccccc5)c(-c5ccccc5)c4)cc3)cc2)cc1]

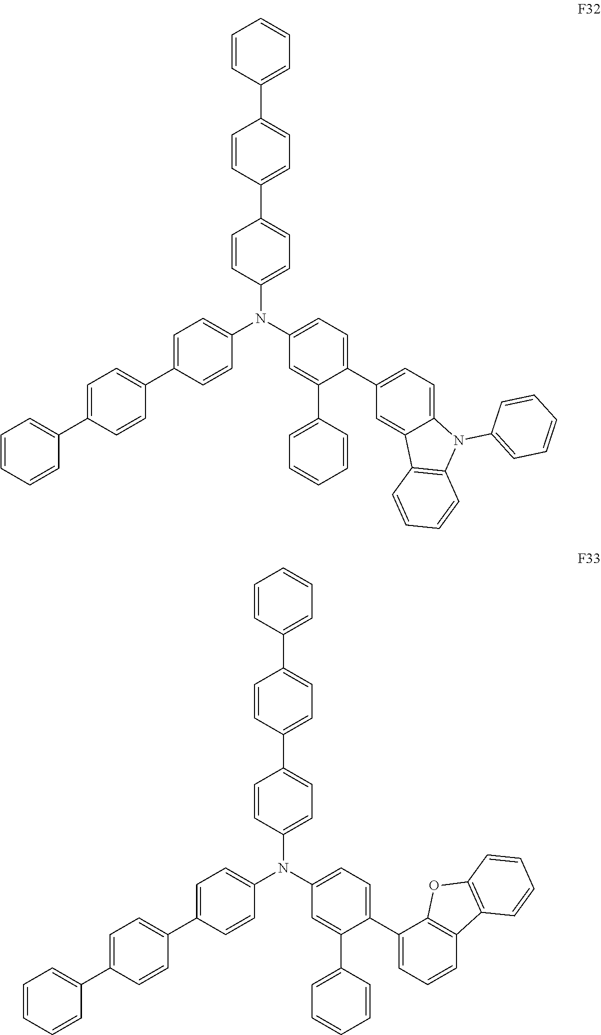 [SMILES: c1ccc(-c2ccc(-c3ccc(N(c4ccc(-c5ccc(-c6ccccc6)cc5)cc4)c4ccc(-c5ccc6c(c5)c5ccccc5n6-c5ccccc5)c(-c5ccccc5)c4)cc3)cc2)cc1 ; c1ccc(-c2ccc(-c3ccc(N(c4ccc(-c5ccc(-c6ccccc6)cc5)cc4)c4ccc(-c5cccc6c5oc5ccccc56)c(-c5ccccc5)c4)cc3)cc2)cc1]

A specific structure of the organic electroluminescent device according to the present invention, a method for fabricating the device, and materials for the organic layers will be described below.

First, an anode material is coated on a substrate to form an anode. The substrate may be any of those used in general electroluminescent devices. The substrate is preferably an organic substrate or a transparent plastic substrate that is excellent in transparency, surface smoothness, ease of handling, and waterproofness. A highly transparent and conductive metal oxide such as indium tin oxide (ITO), indium zinc oxide (IZO), tin oxide (SnO₂) or zinc oxide (ZnO) is used as the anode material.

A hole injecting material is coated on the anode by vacuum thermal evaporation or spin coating to form a hole injecting layer. Then, a hole transport material is coated on the hole injecting layer by vacuum thermal evaporation or spin coating to form a hole transport layer.

The hole injecting material is not specially limited so long as it is usually used in the art. Specific examples of such materials include 4,4′,4″-tris(2-naphthylphenyl-phenylamino)triphenylamine (2-TNATA), N,N′-di(1-naphthyl)-N,N′-diphenylbenzidine (NPD), N,N′-diphenyl-N,N′-bis(3-methylphenyl)- 1,1 ‘-biphenyl-4,4’-diamine (TPD), and N,N′-diphenyl-N,N′-bis(4-(phenyl-m-tolylamino)phenyl)biphenyl-4,4′-diamine (DNTPD).

The hole transport material is not specially limited so long as it is commonly used in the art. Examples of such materials include N,N′-bis(3-methylphenyl)-N,N′-diphenyl-(1,1-biphenyl)-4,4′-diamine (TPD) and N,N′-di(naphthalen-1-yl)-N,N′-diphenylbenzidine (α-NPD).

Subsequently, a hole auxiliary layer and a light emitting layer are sequentially laminated on the hole transport layer. A hole blocking layer may be optionally formed on the light emitting layer by vacuum thermal evaporation or spin coating. The hole blocking layer is formed as a thin film and blocks holes from entering a cathode through the organic light emitting layer. This role of the hole blocking layer prevents the lifetime and efficiency of the device from deteriorating. A material having a very low highest occupied molecular orbital (HOMO) energy level is used for the hole blocking layer. The hole blocking material is not particularly limited so long as it can transport electrons and has a higher ionization potential than the light emitting compound. Representative examples of suitable hole blocking materials include BAlq, BCP, and TPBI.

Examples of materials for the hole blocking layer include, but are not limited to, BAlq, BCP, Bphen, TPBI, NTAZ, BeBq₂, OXD-7, and Liq.

An electron transport layer is deposited on the hole blocking layer by vacuum thermal evaporation or spin coating, and an electron injecting layer is formed thereon. A cathode metal is deposited on the electron injecting layer by vacuum thermal evaporation to form a cathode, completing the fabrication of the organic electroluminescent device.

For example, lithium (Li), magnesium (Mg), aluminum (Al), aluminum-lithium (Al—Li), calcium (Ca), magnesium-indium (Mg—In) or magnesium-silver (Mg—Ag) may be used as the metal for the formation of the cathode. The organic electroluminescent device may be of top emission type. In this case, a transmissive material such as ITO or IZO may be used to form the cathode.

A material for the electron transport layer functions to stably transport electrons injected from the cathode. The electron transport material may be any of those known in the art and examples thereof include, but are not limited to, quinoline derivatives, particularly tris(8-quinolinolate)aluminum (Alq3), TAZ, Balq, beryllium bis(benzoquinolin-10-olate (Bebq2), ADN, and oxadiazole derivatives such as PBD, BMD, and BND.

Each of the organic layers can be formed by a monomolecular deposition or solution process. According to the monomolecular deposition process, the material for each layer is evaporated into a thin film under heat and vacuum or reduced pressure. According to the solution process, the material for each layer is mixed with a suitable solvent, and then the mixture is formed into a thin film by a suitable method such as ink-jet printing, roll-to-roll coating, screen printing, spray coating, dip coating or spin coating.

The organic electroluminescent device of the present invention can be used in a display or lighting system selected from flat panel displays, flexible displays, monochromatic flat panel lighting systems, white flat panel lighting systems, flexible monochromatic lighting systems, and flexible white lighting systems.

### MODE FOR INVENTION

The present invention will be explained more specifically with reference to the following examples. However, it will be obvious to those skilled in the art that these examples are in no way intended to limit the scope of the invention.

### Synthesis Example 1: Synthesis of Compound 1

(1) Preparation of Intermediate 3

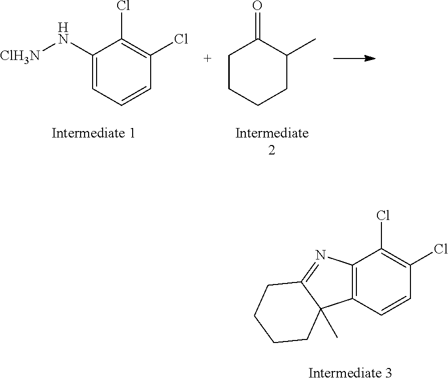

56.3 g (yield 61.3%) of Intermediate 3 was prepared using Intermediate 1 and Intermediate 2 according to the method described in Korean Patent No. 101957902.

MS (ESI) calcd for Chemical Formula: C₁₃H₁₄Cl₂N (Pos) 254.04, found 254.0 (2) Preparation of Intermediate 4

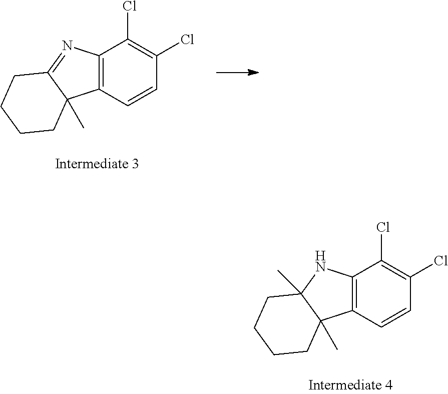 [SMILES: CC12CCCCC1=Nc1c2ccc(Cl)c1Cl ; CC12CCCCC1(C)c1ccc(Cl)c(Cl)c1N2]

26.5 g (yield 72.7%) of Intermediate 4 was prepared using Intermediate 3 and MeLi according to the method described in Korean Patent No. 101957902.

MS (ESI) calcd for Chemical Formula: C₁₄H₁₅Cl₂N (Pos) 270.07, found 270.0

(3) Preparation of Intermediate 5

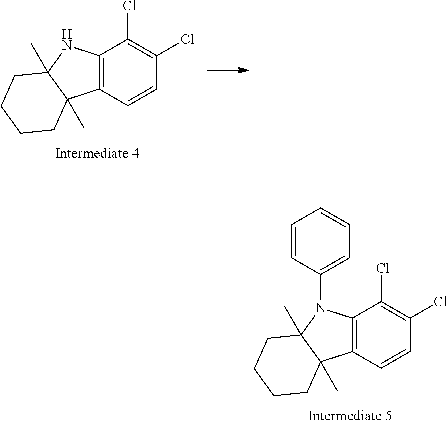 [SMILES: CC12CCCCC1(C)c1ccc(Cl)c(Cl)c1N2 ; CC12CCCCC1(C)N(c1ccccc1)c1c2ccc(Cl)c1Cl]

17.7 g (yield 76.3%) of Intermediate 5 was prepared using Intermediate 4 and iodobenzene according to the method described in Korean Patent No. 101957902.

MS (ESI) calcd for Chemical Formula: C₂₀H₂₂Cl₂N (Pos) 346.11, found 346.1

(4) Preparation of Intermediate 6

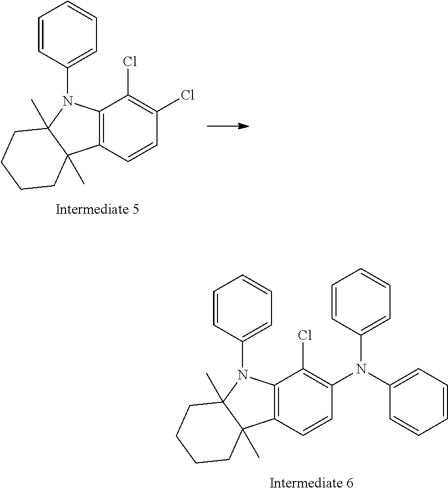 [SMILES: CC12CCCCC1(C)N(c1ccccc1)c1c2ccc(Cl)c1Cl ; CC12CCCCC1(C)N(c1ccccc1)c1c2ccc(N(c2ccccc2)c2ccccc2)c1Cl]

15.0 g of Intermediate 5, 7.3 g of diphenylamine, 0.44 g of bis(tri-tert-butylphosphine)palladium(0), 8.3 g of sodium tert-butoxide, and 150 mL of toluene were placed in a reactor. The mixture was stirred under reflux for 12 h. The reaction mixture was cooled to room temperature and ethyl acetate and water were added thereto. The organic layer was separated and concentrated under reduced pressure. The concentrate was purified by silica gel chromatography to afford Intermediate 6 (14.9 g, yield 71.8%).

MS (ESI) calcd for Chemical Formula: C₃₂H₃₂ClN₂ (Pos) 479.22, found 479.2

(5) Synthesis of Compound 1

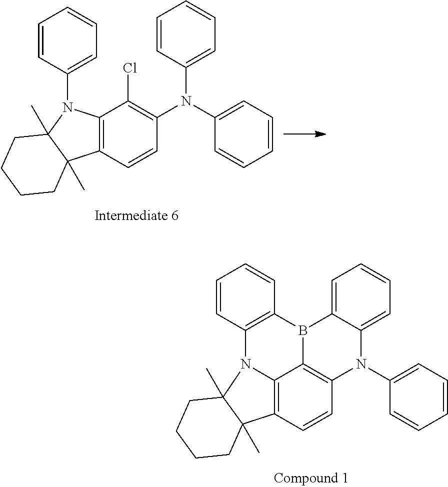 [SMILES: CC12CCCCC1(C)N(c1ccccc1)c1c2ccc(N(c2ccccc2)c2ccccc2)c1Cl ; CC12CCCCC1(C)N1c3ccccc3B3c4ccccc4N(c4ccccc4)c4ccc2c1c43]

10.0 g of Intermediate 6 and 100 mL of tert-butylbenzene were placed in a reactor, and then 24.6 mL of tert-butyllithium was added dropwise thereto at −78° C. The mixture was heated to 60° C., followed by stirring for 3 h. Then, nitrogen at 60° C. was blown into the mixture to completely remove pentane. After cooling to −78° C., 4.0 mL of boron tribromide was added dropwise. The resulting mixture was allowed to warm to room temperature, followed by stirring for 2 h. After cooling to 0° C., 7.3 mL of N,N-diisopropylethylamine was added dropwise. The mixture was heated to 120° C., followed by stirring for 12 h. The reaction mixture was cooled to room temperature and 34 mL of a 10% aqueous sodium acetate solution and ethyl acetate were added thereto. The organic layer was separated and concentrated under reduced pressure. The concentrate was purified by silica gel chromatography to afford Compound 1 (2.1 g, 22.2%).

MS (ESI) calcd for Chemical Formula: C₃₂H₃₀BN₂ (Pos) 453.24, found 453.2

### Synthesis Example 2: Synthesis of Compound 2

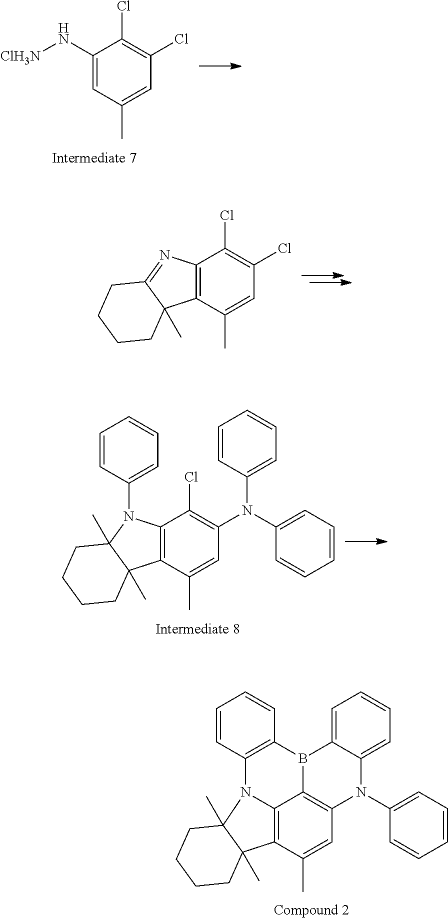

Compound 2 (1.6 g, 23.1%) was synthesized in the same manner as in Synthesis Example 1, except that Intermediate 8 was prepared using Intermediate 7 instead of Intermediate 1.

MS (ESI) calcd for Chemical Formula: C₃₃H₃₂BN₂ (Pos) 466.27, found 466.2

### Synthesis Example 3: Synthesis of Compound 3

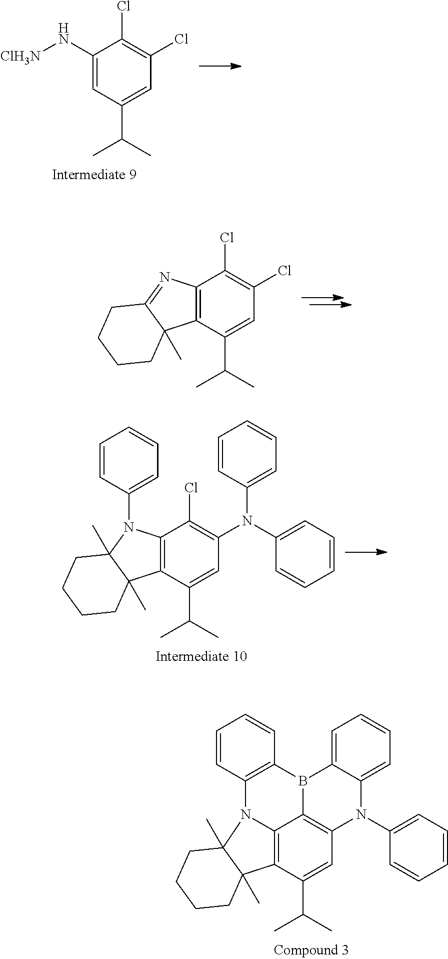

Compound 3 (1.7 g, 17.1%) was synthesized in the same manner as in Synthesis Example 1, except that Intermediate 10 was prepared using Intermediate 9 instead of Intermediate 1.

MS (ESI) calcd for Chemical Formula: C₃₅H₃₆BN₂ (Pos) 495.30, found 495.3

### Synthesis Example 4: Synthesis of Compound 4

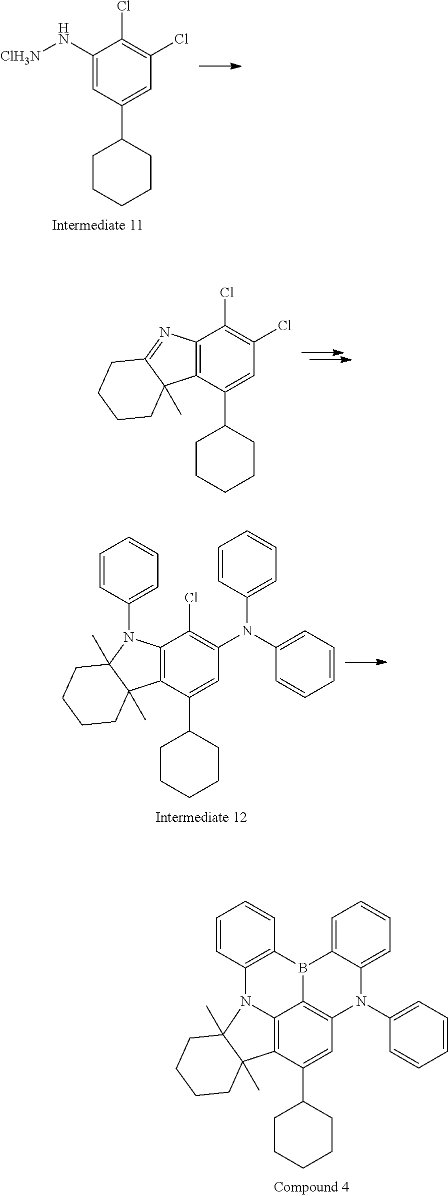

Compound 4 (3.1 g, 19.2%) was synthesized in the same manner as in Synthesis Example 1, except that Intermediate 12 was prepared using Intermediate 11 instead of Intermediate 1.

MS (ESI) calcd for Chemical Formula: C₃₈H₄₀BN₂ (Pos) 535.33, found 535.3

### Synthesis Example 5: Synthesis of Compound 5

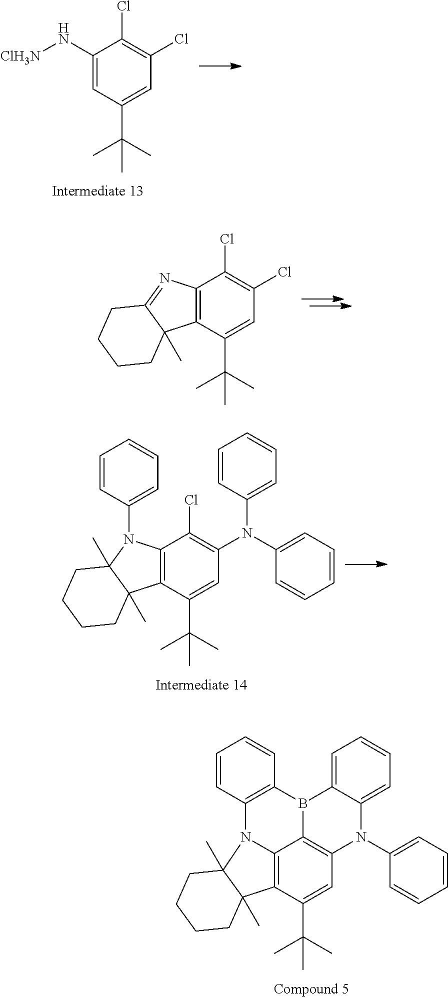

Compound 5 (2.2 g, 23.0%) was synthesized in the same manner as in Synthesis Example 1, except that Intermediate 14 was prepared using Intermediate 13 instead of Intermediate 1.

MS (ESI) calcd for Chemical Formula: C₃₆H₃BN₂ (Pos) 509.31, found 509.3

### Synthesis Example 6: Synthesis of Compound 6

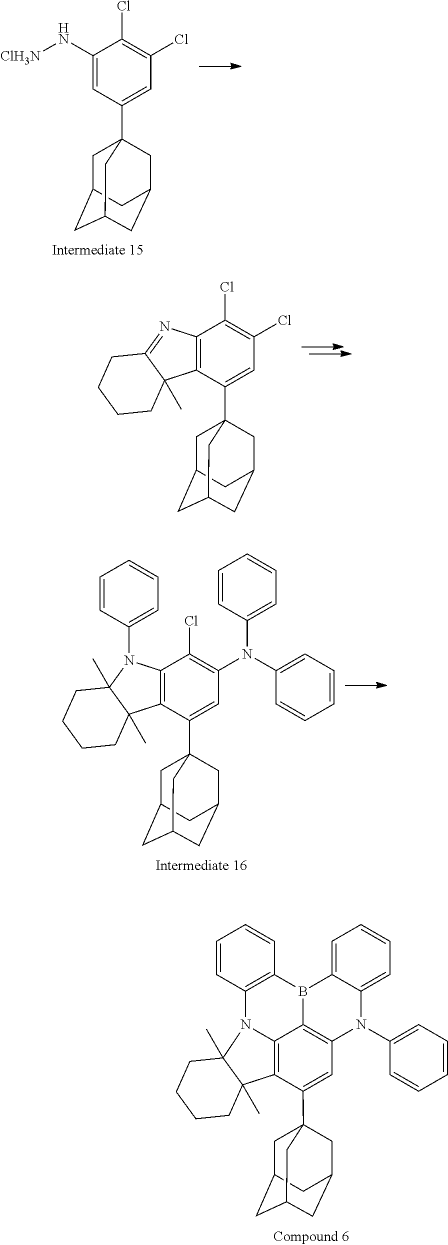

Compound 6 (2.7 g, 21.5%) was synthesized in the same manner as in Synthesis Example 1, except that Intermediate 16 was prepared using Intermediate 15 instead of Intermediate 1.

MS (ESI) calcd for Chemical Formula: C₄₂H₄₄BN₂ (Pos) 587.36, found 587.3

### Synthesis Example 7: Synthesis of Compound 7

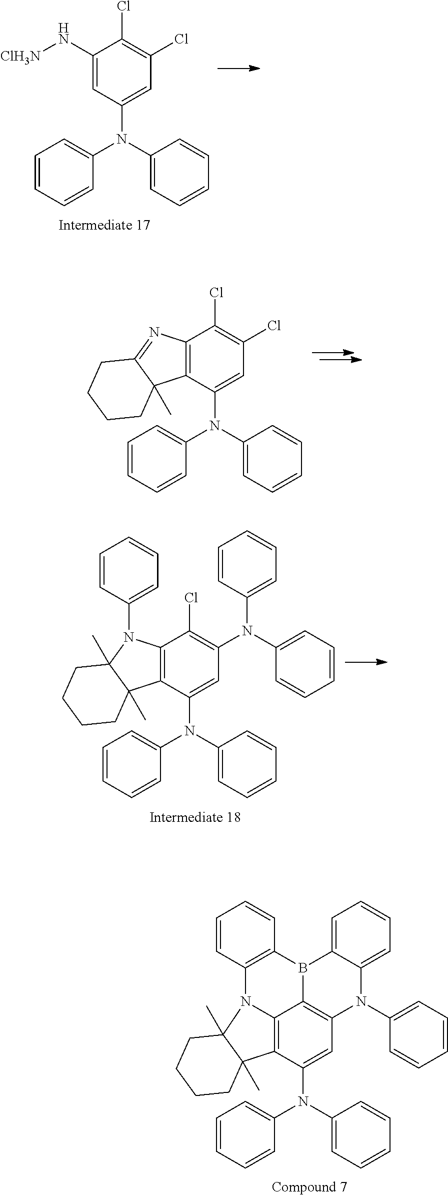

Compound 7 (3.3 g, 28.3%) was synthesized in the same manner as in Synthesis Example 1, except that Intermediate 18 was prepared using Intermediate 17 instead of Intermediate 1.

MS (ESI) calcd for Chemical Formula: C₄₄H₃₉BN₃ (Pos) 620.33, found 620.3

### Synthesis Example 8: Synthesis of Compound 10

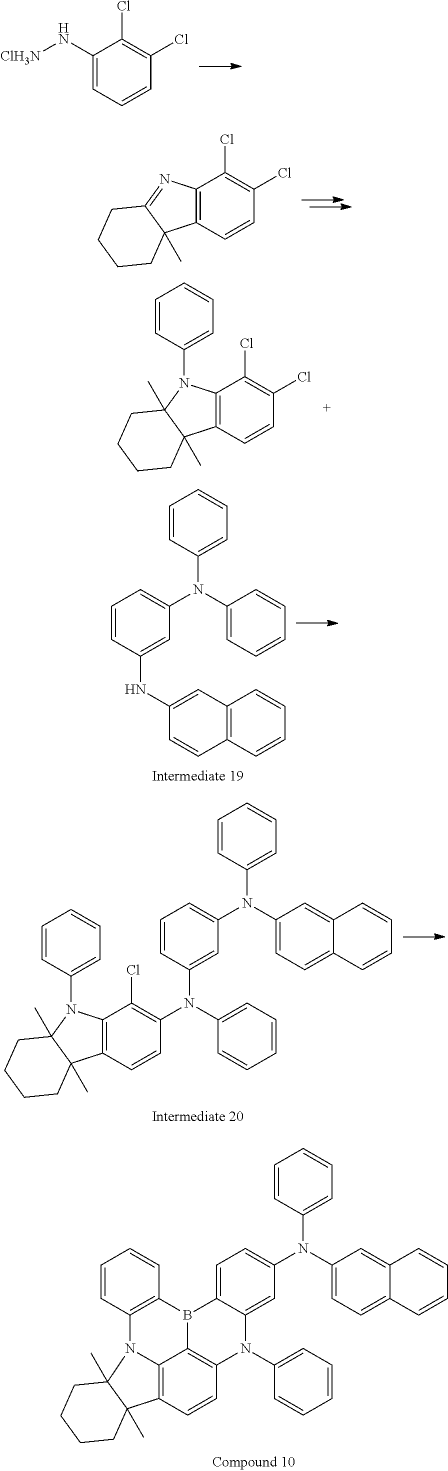

Compound 10 (1.3 g, 11.3%) was synthesized in the same manner as in Synthesis Example 1, except that Intermediate 20 was prepared using Intermediate 19 instead of diphenylamine

MS (ESI) calcd for Chemical Formula: C₄₈H₄₁BN₃ (Pos) 670.34, found 670.3

### Synthesis Example 9: Synthesis of Compound 43

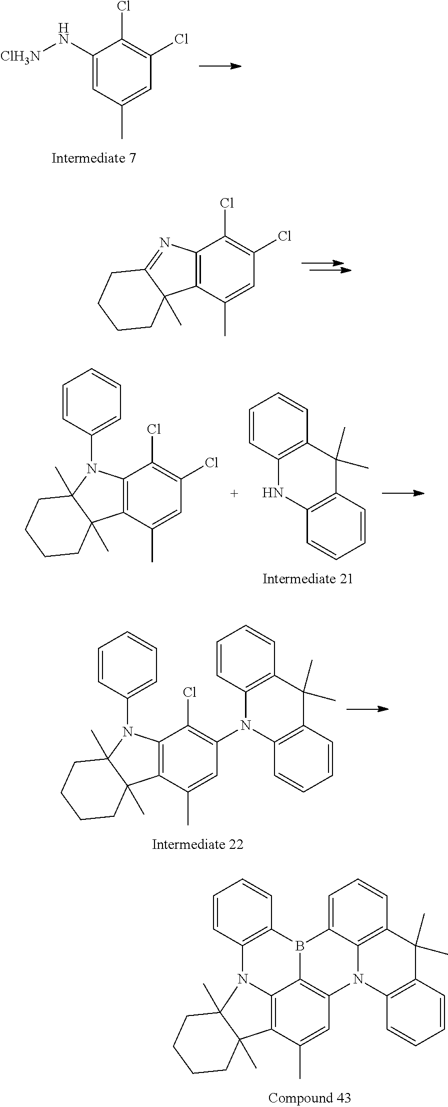

Compound 43 (2.7 g, 13.8%) was synthesized in the same manner as in Synthesis Example 1, except that Intermediate 22 was prepared using Intermediates 7 and 21 instead of Intermediate 1 and diphenylamine, respectively.

MS (ESI) calcd for Chemical Formula: C₃₆H₃₆BN₂ (Pos) 507.30, found 507.3

### Synthesis Example 10: Synthesis of Compound 44

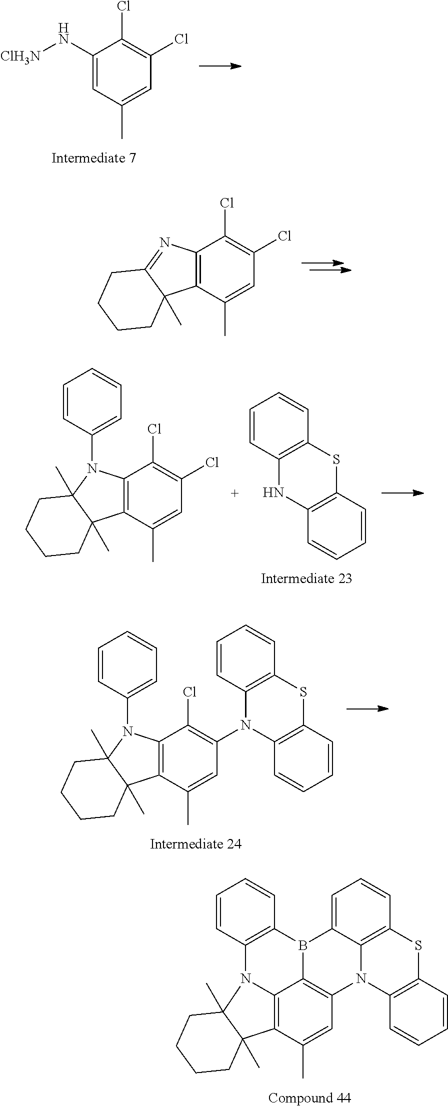

Compound 44 (2.1 g, 22.2%) was synthesized in the same manner as in Synthesis Example 1, except that Intermediate 24 was prepared using Intermediates 7 and 23 instead of Intermediate 1 and diphenylamine, respectively.

MS (ESI) calcd for Chemical Formula: C₃₃H₃₀BN₂S (Pos) 497.22, found 497.2

### Synthesis Example 11: Synthesis of Compound 45

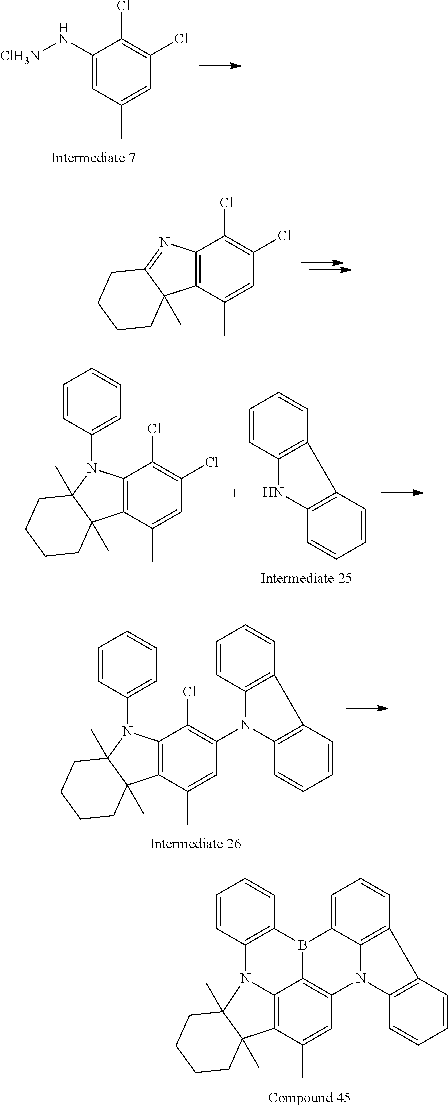

Compound 45 (3.2 g, 23.9%) was synthesized in the same manner as in Synthesis Example 1, except that Intermediate 26 was prepared using Intermediates 7 and 25 instead of Intermediate 1 and diphenylamine, respectively.

MS (ESI) calcd for Chemical Formula: C₃₃H₃₀BN₂ (Pos) 465.25, found 465.2

### Synthesis Example 12: Synthesis of Compound 54

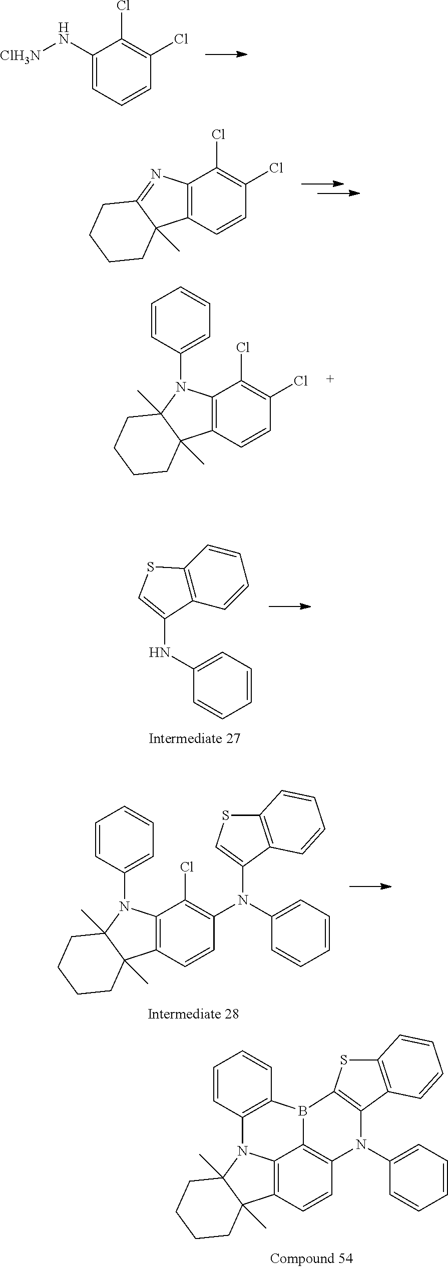

Compound 54 (1.5 g, 9.5%) was synthesized in the same manner as in Synthesis Example 1, except that Intermediate 28 was prepared using Intermediate 27 instead of diphenylamine

MS (ESI) calcd for Chemical Formula: C₃₄H₃₀BN₂S (Pos) 509.22, found 509.2

### Synthesis Example 13: Synthesis of Compound 55

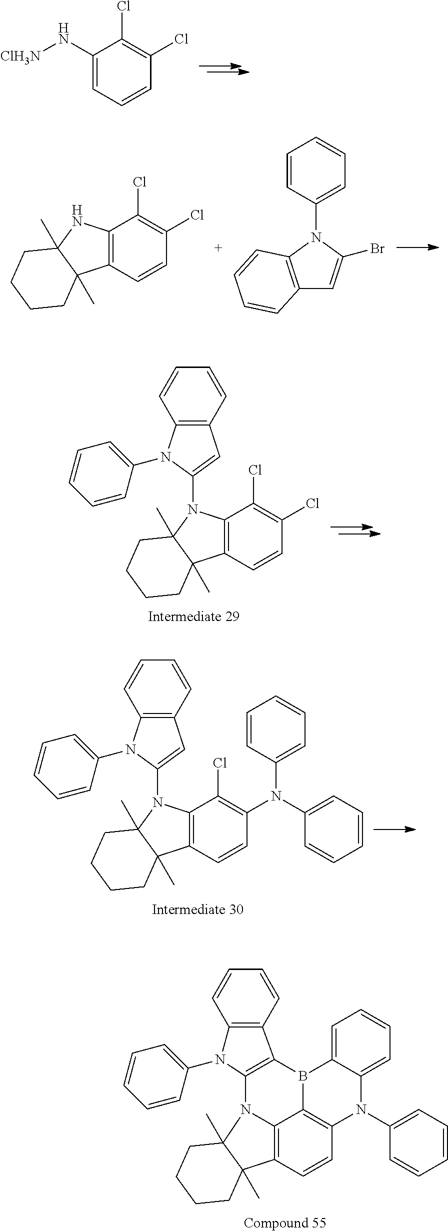

Compound 55 (1.2 g, 7.3%) was synthesized in the same manner as in Synthesis Example 1, except that Intermediate 30 was prepared using Intermediate 29 instead of bromobenzene.

MS (ESI) calcd for Chemical Formula: C₄₀H₃₅BN₃ (Pos) 568.29, found 568.2

### Synthesis Example 14: Synthesis of Compound 56

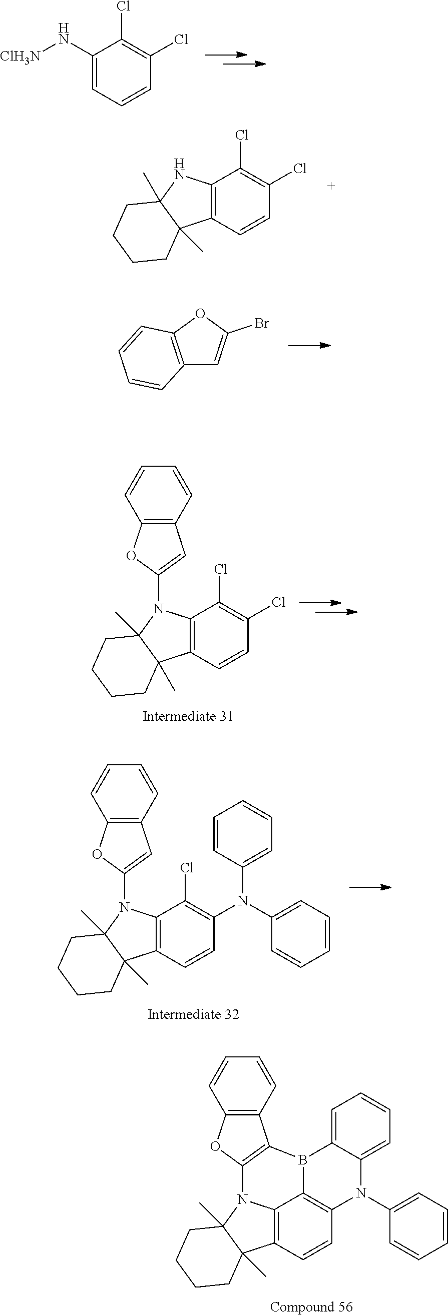

Compound 56 (1.6 g, 7.1%) was synthesized in the same manner as in Synthesis Example 1, except that Intermediate 32 was prepared using Intermediate 31 instead of bromobenzene.

MS (ESI) calcd for Chemical Formula: C₃₄H₃₀BN₂O (Pos) 493.25, found 493.2

### Synthesis Example 15: Synthesis of Compound 57

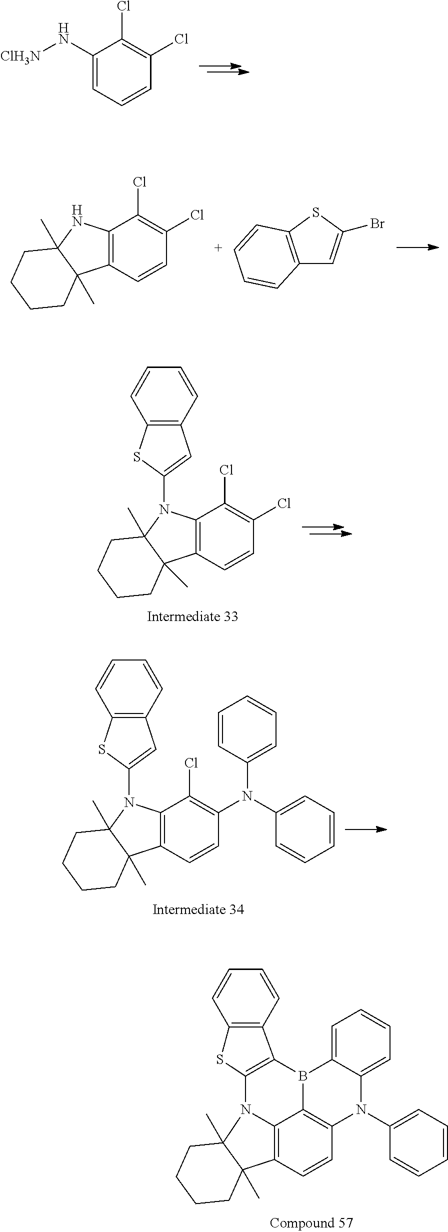

Compound 57 (2.3 g, 8.0%) was synthesized in the same manner as in Synthesis Example 1, except that Intermediate 34 was prepared using Intermediate 33 instead of bromobenzene.

MS (ESI) calcd for Chemical Formula: C₃₄H₃₀BN₂S (Pos) 509.22, found 509.2

### Examples 1-11: Fabrication of organic electroluminescent devices

ITO glass was patterned to have a light emitting area of 2 mm×2 mm, followed by cleaning. After the cleaned ITO glass was mounted in a vacuum chamber, the base pressure was adjusted to 1×10⁻⁷ torr. HATCN (700 Å) and the compound represented by Formula F (250 Å) were deposited in this order on the ITO. A mixture of the host represented by BH1 and the inventive compound (3 wt %) shown in Table 1 was used to form a 250 Å thick light emitting layer. Thereafter, a mixture of the compound represented by Formula E-1 and the compound represented by Formula E-2 in a ratio of 1:1 was used to form a 300 Å thick electron transport layer on the light emitting layer. The compound represented by Formula E-1 was used to form a 5 Å thick electron injecting layer on the electron transport layer. Al was used to form a 1000 Å thick Al electrode on the electron injecting layer, completing the fabrication of an organic electroluminescent device. The luminescent properties of the organic electroluminescent device were measured at 0.4 mA.

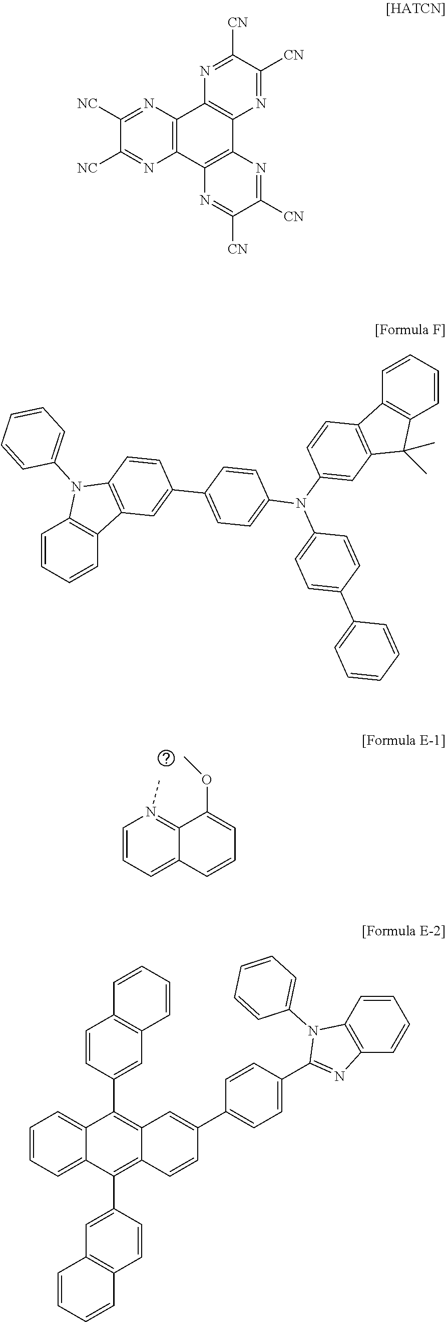

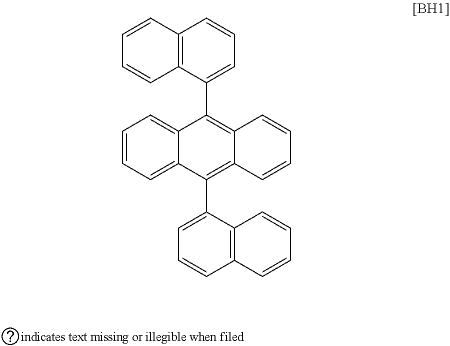 [SMILES: c1ccc2c(-c3c4ccccc4c(-c4cccc5ccccc45)c4ccccc34)cccc2c1]

### Comparative Examples 1-2

Organic electroluminescent devices were fabricated in the same manner as in Examples 1-11, except that BD1 or BD2 was used instead of the inventive compound. The luminescent properties of the organic electroluminescent devices were measured at 0.4 mA. The structures of BD1 and BD2 are as follow:

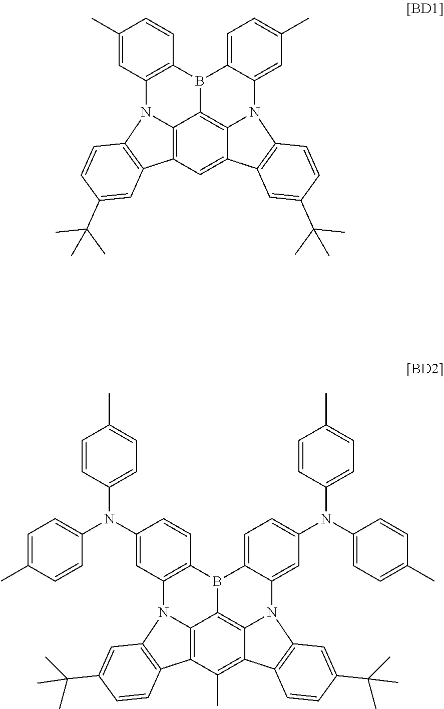

The organic electroluminescent devices of Examples 1-11 and Comparative Examples 1-2 were measured for voltage, efficiency, and lifetime. The results are shown in Table 1.

TABLE 1

| | | Driving | | |
|---|---|---|---|---|
| | | voltage | Efficiency | Lifetime |
| Example No. | Dopant | (V) | (Cd/A) | (LT95) |
| Example 1 | Compound 1 | 3.9 | 7.1 | 130 |
| Example 2 | Compound 24 | 3.9 | 7.0 | 120 |
| Example 3 | Compound 28 | 3.9 | 6.8 | 125 |
| Example 4 | Compound 32 | 4.0 | 6.7 | 116 |
| Example 5 | Compound 37 | 4.0 | 6.6 | 112 |
| Example 6 | Compound 39 | 4.0 | 7.0 | 101 |
| Example 7 | Compound 54 | 3.9 | 7.1 | 110 |
| Example 8 | Compound 55 | 4.1 | 7.0 | 100 |
| Example 9 | Compound 76 | 4.0 | 6.9 | 120 |
| Example 10 | Compound 139 | 3.9 | 7.1 | 115 |
| Example 11 | Compound 154 | 3.9 | 7.4 | 120 |
| Comparative | BD1 | 4.0 | 6.3 | 60 |
| Example 1 | | | | |
| Comparative | BD2 | 4.1 | 6.0 | 80 |
| Example 2 | | | | |

As can be seen from the results in Table 1, the organic electroluminescent devices of Examples 1-11, each of which employed the inventive compound, had high efficiencies and long lifetimes compared to the devices of Comparative Examples 1-2.

### INDUSTRIAL APPLICABILITY

The polycyclic aromatic derivative of the present invention can be employed in an organic layer of an organic electroluminescent device to achieve high efficiency and long lifetime of the device. Due to these advantages, the organic electroluminescent device can find useful industrial application in various displays and lighting systems, including flat panel displays, flexible displays, monochromatic flat panel lighting systems, white flat panel lighting systems, flexible monochromatic lighting systems, and flexible white lighting systems.

1. A compound represented by Formula A-1 or A-2: 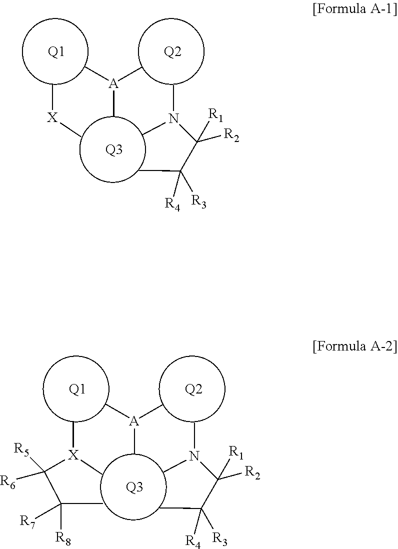
wherein Q1 to Q3 are identical to or different from each other and are each independently selected from substituted or unsubstituted C₆-C₃₀ aromatic hydrocarbon rings, substituted or unsubstituted C₂-C₅₀ aromatic heterocyclic rings, and substituted or unsubstituted C₃-C₃₀ mixed aliphatic-aromatic rings, with the proviso that Q1 and Q2 are optionally linked to each other via a single bond, O, S, Se, NR, CRR, SiRR, S═O, PR, P(═O)R or P(═S)R, X is a single bond or is selected from N—R₉, CR₁₀R₁₁, O, S, Se, and SiR₁₂R₁₃, A is selected from B, P, Al, P═S, and P═O, and R and R₁ to R₁₃ are identical to or different from each other and are each independently selected from hydrogen, deuterium, substituted or unsubstituted C₁-C₃₀ alkyl, substituted or unsubstituted C₆-050 aryl, substituted or unsubstituted C₃-C₃₀ cycloalkyl, substituted or unsubstituted C₂-C₅₀ heteroaryl, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted C₁-C₃₀ alkylamine, substituted or unsubstituted C₅-C₃₀ arylamine, substituted or unsubstituted C₁-C₃₀ alkylsilyl, substituted or unsubstituted C₅-C₃₀ arylsilyl, nitro, cyano, and halogen, with the proviso that adjacent ones of R and R₁ to R₁₃ optionally form an alicyclic or aromatic monocyclic or polycyclic ring.

2. The compound according to claim 1, wherein each of R₉ to R₁₃ optionally forms an alicyclic or aromatic monocyclic or polycyclic ring with one or more of Q1 to Q3.

3. The compound according to claim 1, wherein R₁₀ and R₁₁ together optionally form an alicyclic or aromatic monocyclic or polycyclic ring and R₁₂ and R₁₃ together optionally form an alicyclic or aromatic monocyclic or polycyclic ring.

4. The compound according to claim 1, wherein the compound represented by Formula A-1 is represented by one of Formulae A-3 to A-11: 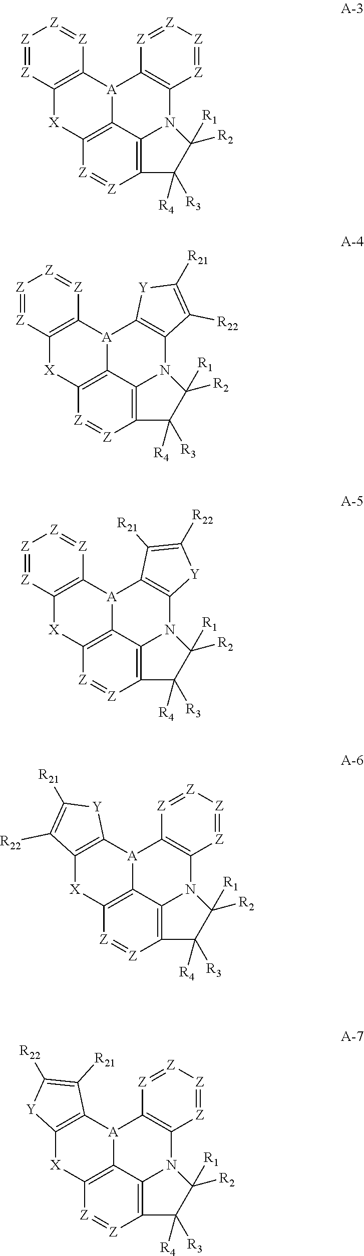 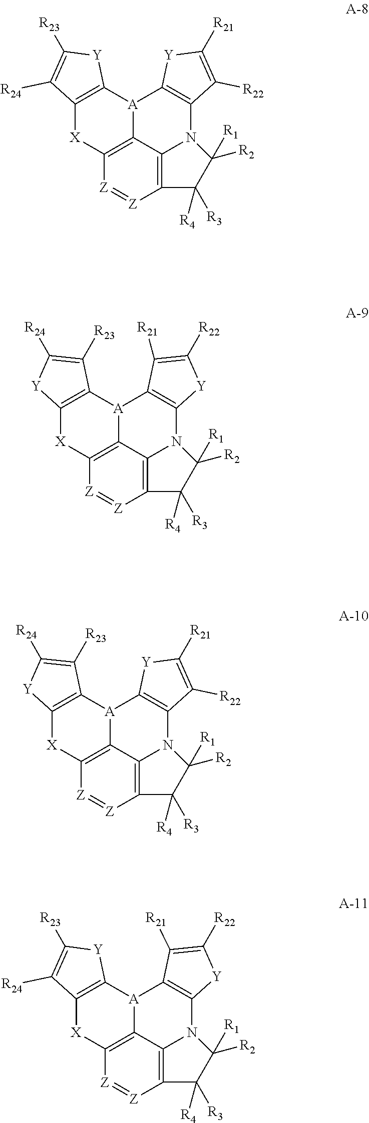
wherein the moieties Z are identical to or different from each other and are each independently CR′ or N, R₁ to R₄, R₂₁ to R₂₄, and R′ are each independently selected from hydrogen, deuterium, substituted or unsubstituted C₁-C₃₀ alkyl, substituted or unsubstituted C₆-C₅₀ aryl, substituted or unsubstituted C₃-C₃₀ cycloalkyl, substituted or unsubstituted C₂-C₅₀ heteroaryl, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted C₁-C₃₀ alkylamine, substituted or unsubstituted C₅-C₃₀ arylamine, substituted or unsubstituted C₁-C₃₀ alkylsilyl, substituted or unsubstituted C₅-C₃₀ arylsilyl, nitro, cyano, and halogen, the groups R′ are identical to or different from each other and are optionally bonded to each other or combined with an adjacent substituent to form an alicyclic or aromatic monocyclic or polycyclic ring optionally substituted with one or more heteroatoms selected from N, S, and O, A and X are as defined in Formula A-1, and the moieties Y are identical to or different from each other and are as defined for X in Formula A-1.

5. The compound according to claim 1, wherein the compound represented by Formula A-2 is represented by one of Formulae A-12 to A-17: 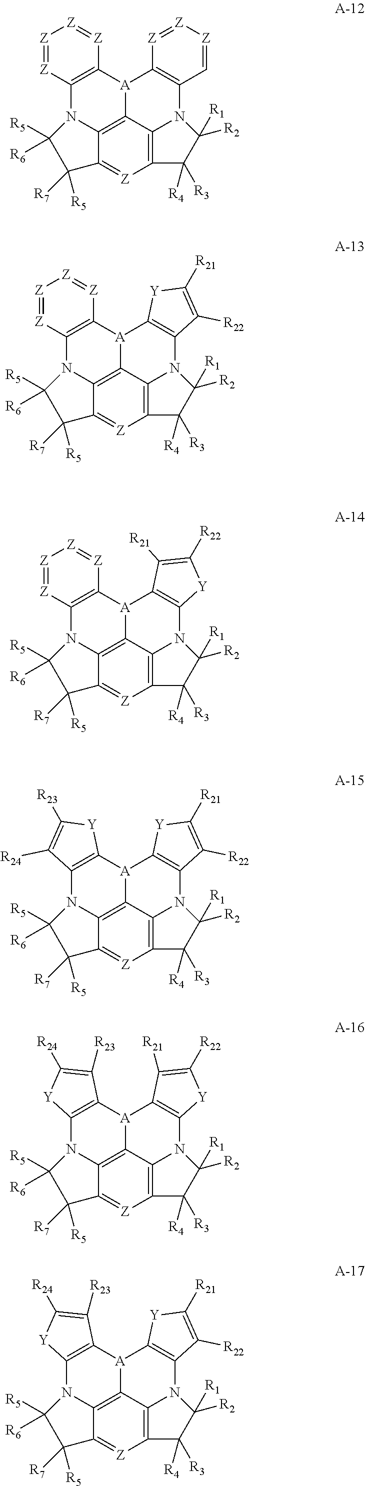
wherein the moieties Z are identical to or different from each other and are each independently CR′ or N, R₁ to R₈, R₂₁ to R₂₄, and R′ are each independently selected from hydrogen, deuterium, substituted or unsubstituted C₁-C₃₀ alkyl, substituted or unsubstituted C₆-C₅₀ aryl, substituted or unsubstituted C₃-C₃₀ cycloalkyl, substituted or unsubstituted C₂-C₅₀ heteroaryl, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted C₁-C₃₀ alkylamine, substituted or unsubstituted C₅-C₃₀ arylamine, substituted or unsubstituted C₁-C₃₀ alkylsilyl, substituted or unsubstituted C₅-C₃₀ arylsilyl, nitro, cyano, and halogen, the groups R′ are identical to or different from each other and are optionally bonded to each other or combined with an adjacent substituent to form an alicyclic or aromatic monocyclic or polycyclic ring optionally substituted with one or more heteroatoms selected from N, S, and O, A and X are as defined in Formula A-1, and the moieties Y are identical to or different from each other and are as defined for X in Formula A-1.

6. The compound according to claim 1, wherein the compound represented by Formula A-1 or A-2 is selected from the following compounds 1 to 183:

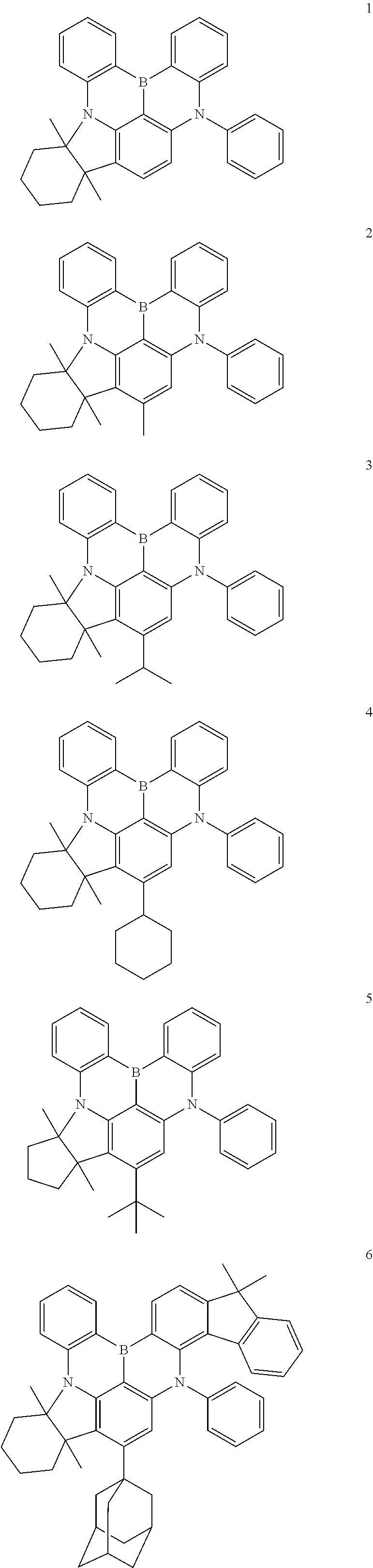

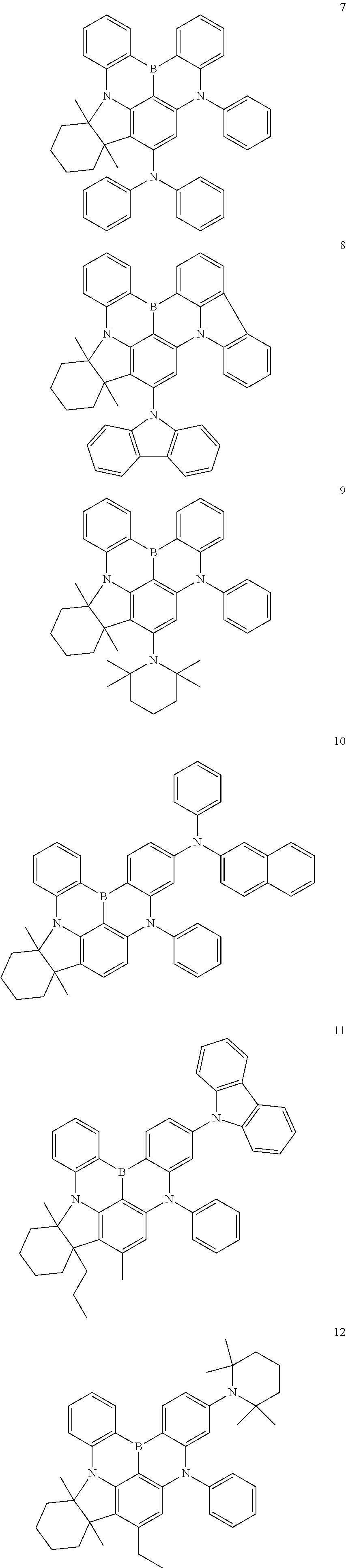

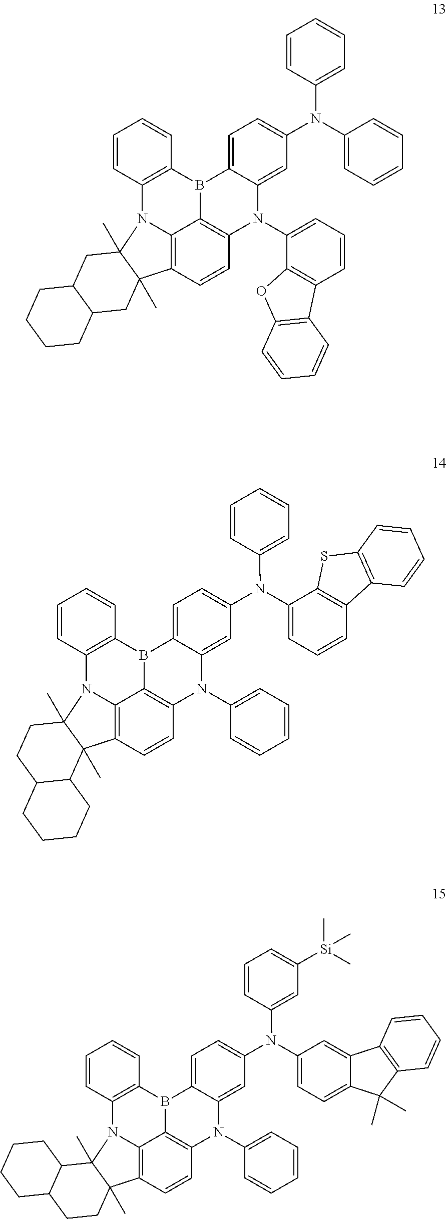 [SMILES: CC12CC3CCCCC3CC1(C)N1c3ccccc3B3c4ccc(N(c5ccccc5)c5ccccc5)cc4N(c4cccc5c4oc4ccccc45)c4ccc2c1c43 ; CC12c3ccc4c5c3N(c3ccccc3B5c3ccc(N(c5ccccc5)c5cccc6c5sc5ccccc56)cc3N4c3ccccc3)C1(C)CCC1CCCCC12 ; CC1(C)c2ccccc2-c2cc(N(c3cccc([Si](C)(C)C)c3)c3ccc4c(c3)N(c3ccccc3)c3ccc5c6c3B4c3ccccc3N6C3(C)C4CCCCC4CCC53C)ccc21]

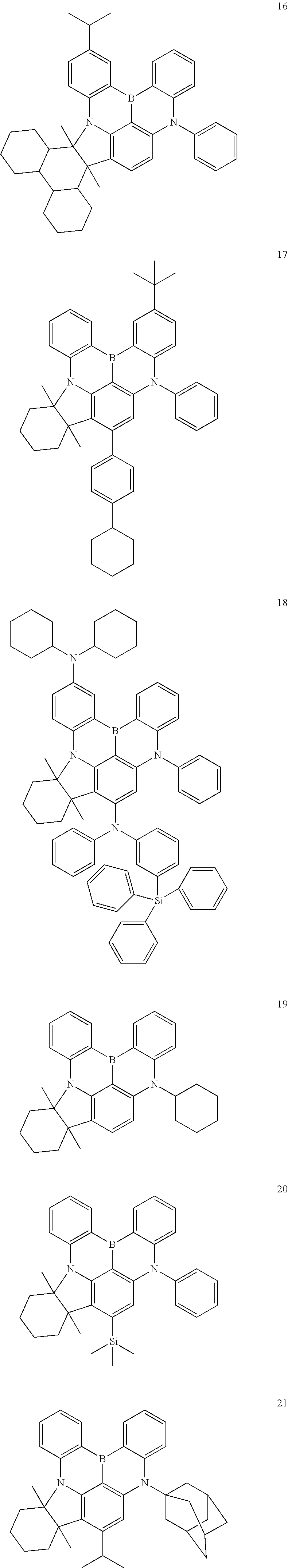

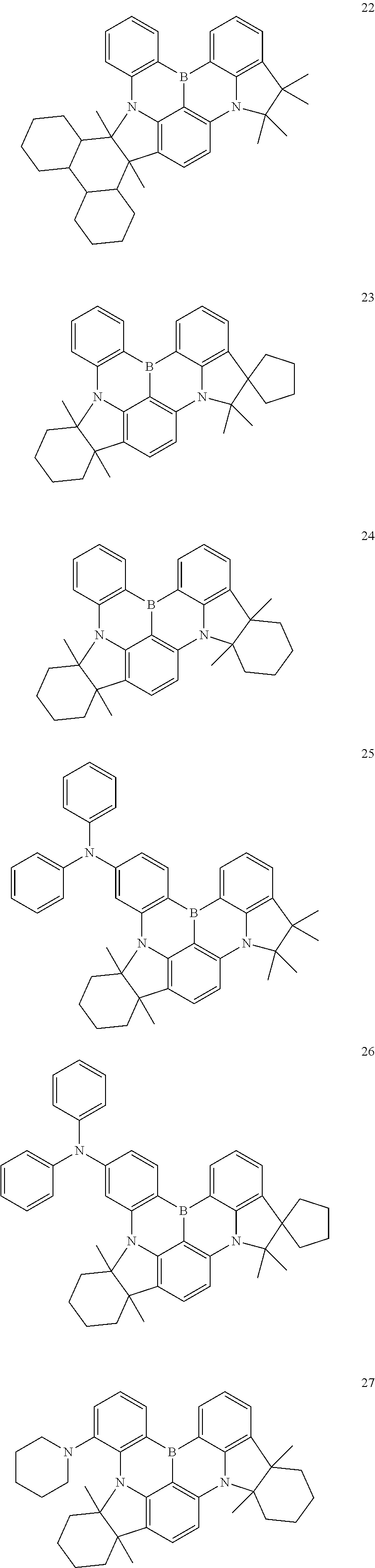

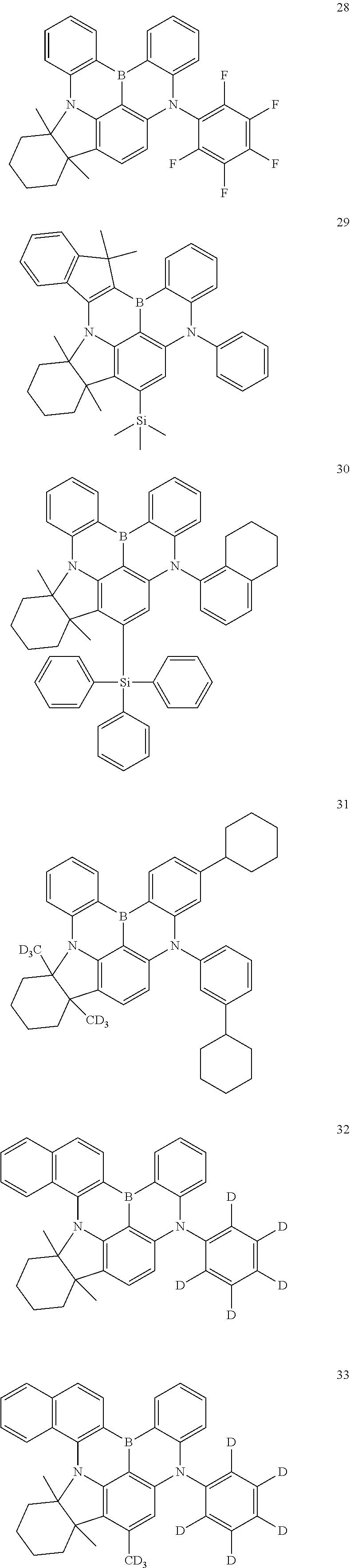

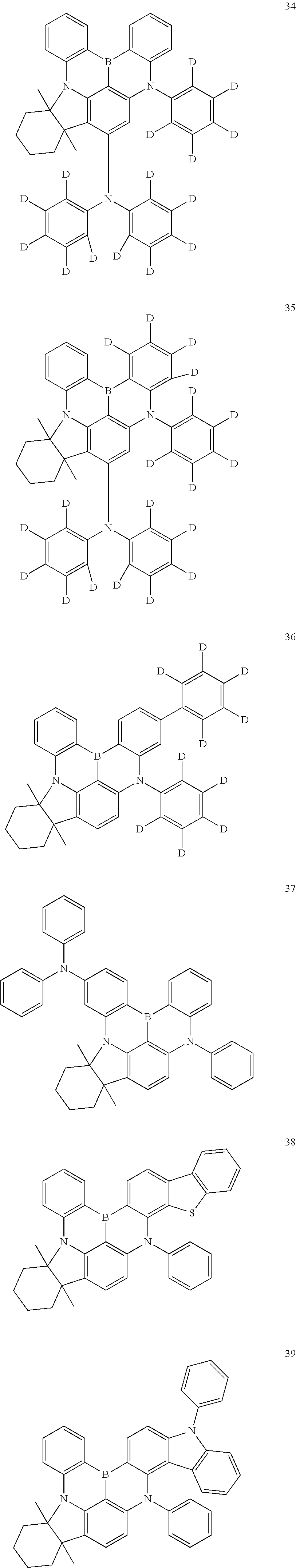

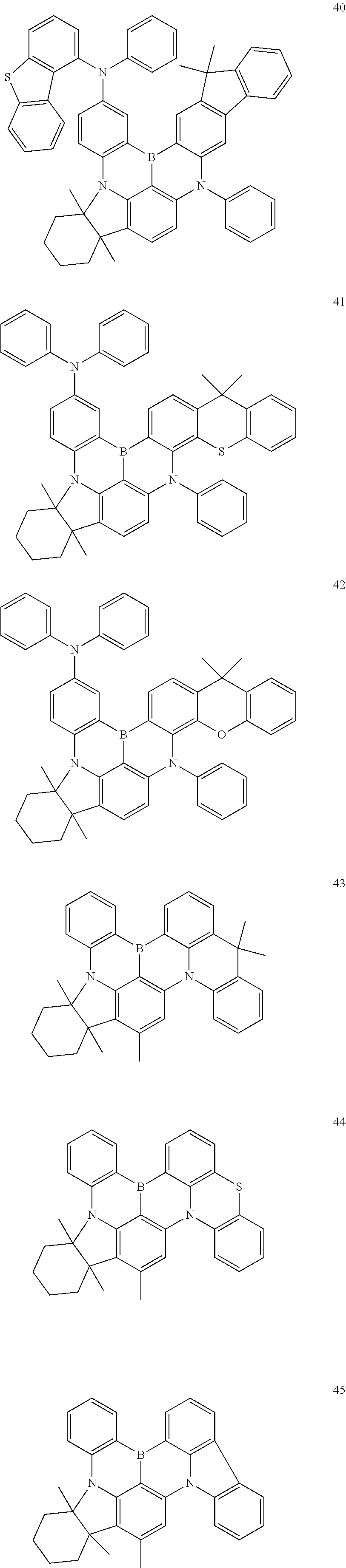

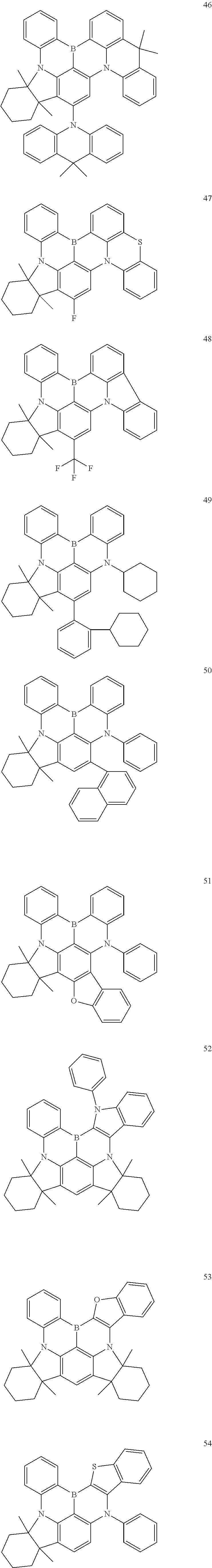

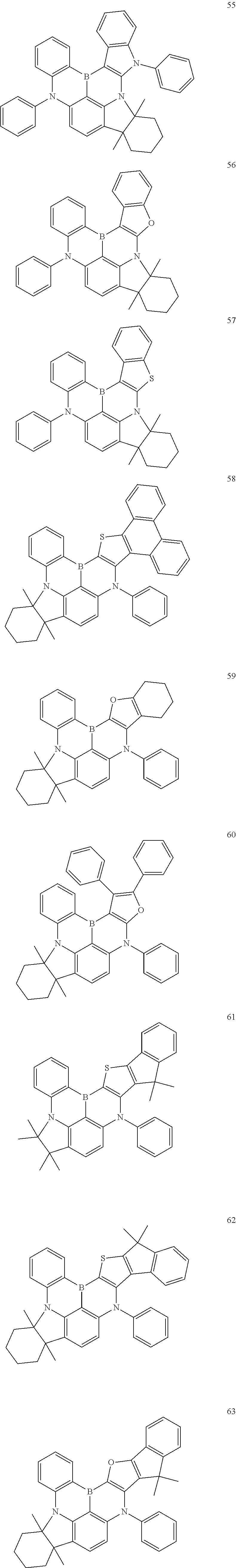

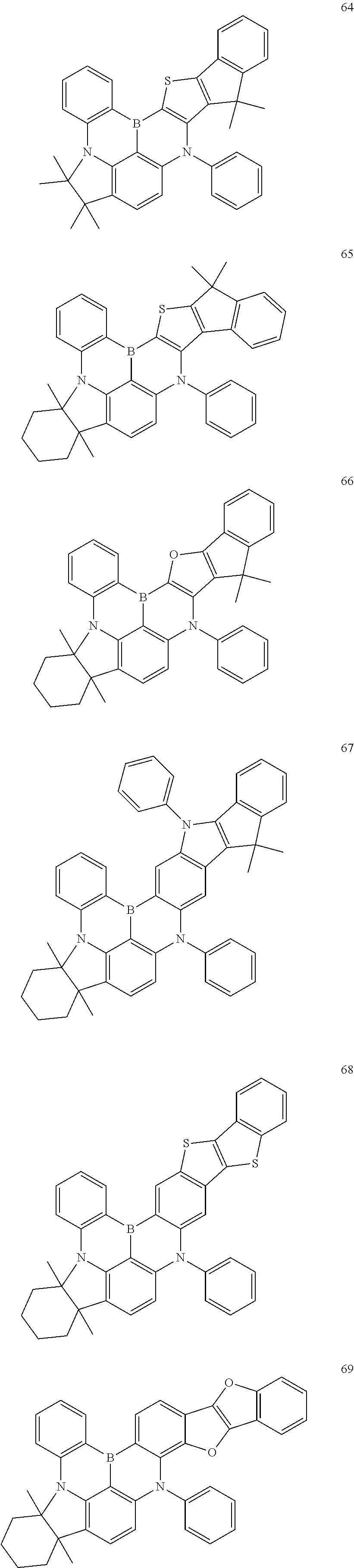 [SMILES: CC1(C)c2ccccc2-c2sc3c(c21)N(c1ccccc1)c1ccc2c4c1B3c1ccccc1N4C(C)(C)C2(C)C ; CC1(C)c2ccccc2-c2c1sc1c2N(c2ccccc2)c2ccc3c4c2B1c1ccccc1N4C1(C)CCCCC31C ; CC1(C)c2ccccc2-c2oc3c(c21)N(c1ccccc1)c1ccc2c4c1B3c1ccccc1N4C1(C)CCCCC21C ; CC1(C)c2ccccc2-c2c1c1cc3c(cc1n2-c1ccccc1)B1c2ccccc2N2c4c(ccc(c41)N3c1ccccc1)C1(C)CCCCC21C ; CC12CCCCC1(C)N1c3ccccc3B3c4cc5sc6c7ccccc7sc6c5cc4N(c4ccccc4)c4ccc2c1c43 ; CC12CCCCC1(C)N1c3ccccc3B3c4ccc5c(oc6c7ccccc7oc56)c4N(c4ccccc4)c4ccc2c1c43]

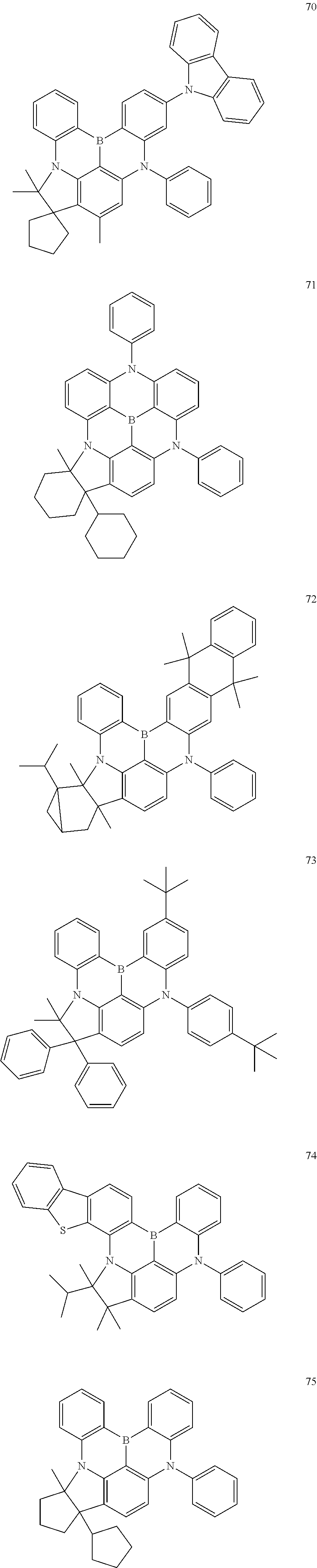 [SMILES: Cc1cc2c3c4c1C1(CCCC1)C(C)(C)N4c1ccccc1B3c1ccc(-n3c4ccccc4c4ccccc43)cc1N2c1ccccc1 ; CC12CCCCC1(C1CCCCC1)c1ccc3c4c1N2c1cccc2c1B4c1c(cccc1N3c1ccccc1)N2c1ccccc1 ; CC(C)C12CC1CC1(C)c3ccc4c5c3N(c3ccccc3B5c3cc5c(cc3N4c3ccccc3)C(C)(C)c3ccccc3C5(C)C)C12C ; CC(C)(C)c1ccc(N2c3ccc(C(C)(C)C)cc3B3c4ccccc4N4c5c(ccc2c53)C(c2ccccc2)(c2ccccc2)C4(C)C)cc1 ; CC(C)C1(C)N2c3c(ccc4c3B(c3ccccc3N4c3ccccc3)c3ccc4c(sc5ccccc54)c32)C1(C)C ; CC12CCCC1(C1CCCC1)c1ccc3c4c1N2c1ccccc1B4c1ccccc1N3c1ccccc1]

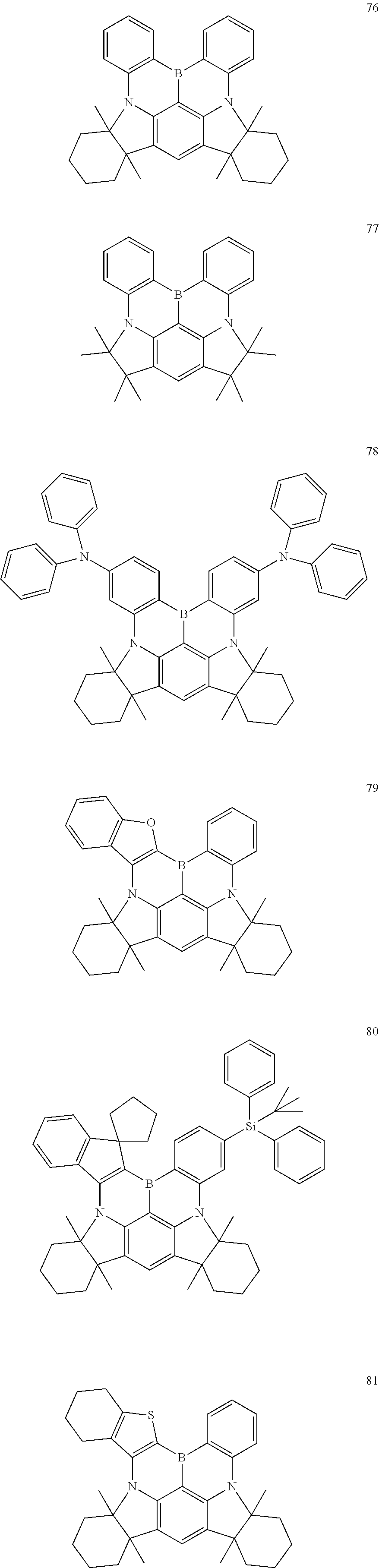

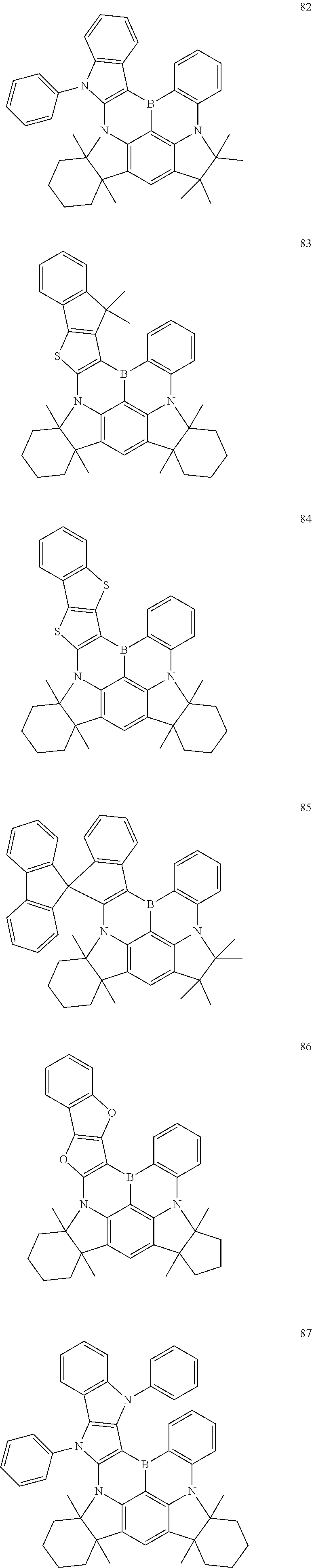 [SMILES: CC1(C)c2cc3c4c5c2N(c2ccccc2B5c2c(n(-c5ccccc5)c5ccccc25)N4C2(C)CCCCC32C)C1(C)C ; CC1(C)c2ccccc2-c2sc3c(c21)B1c2ccccc2N2c4c(cc5c(c41)N3C1(C)CCCCC51C)C1(C)CCCCC21C ; CC12CCCCC1(C)N1c3ccccc3B3c4c1c2cc1c4N(c2sc4c(sc5ccccc54)c23)C2(C)CCCCC12C ; CC1(C)c2cc3c4c5c2N(c2ccccc2B5C2=C(N4C4(C)CCCCC34C)C3(c4ccccc42)c2ccccc2-c2ccccc23)C1(C)C ; CC12CCCC1(C)N1c3ccccc3B3c4c1c2cc1c4N(c2oc4c(oc5ccccc54)c23)C2(C)CCCCC12C ; CC12CCCCC1(C)N1c3ccccc3B3c4c1c2cc1c4N(c2c3c3c(c4ccccc4n3-c3ccccc3)n2-c2ccccc2)C2(C)CCCCC12C]

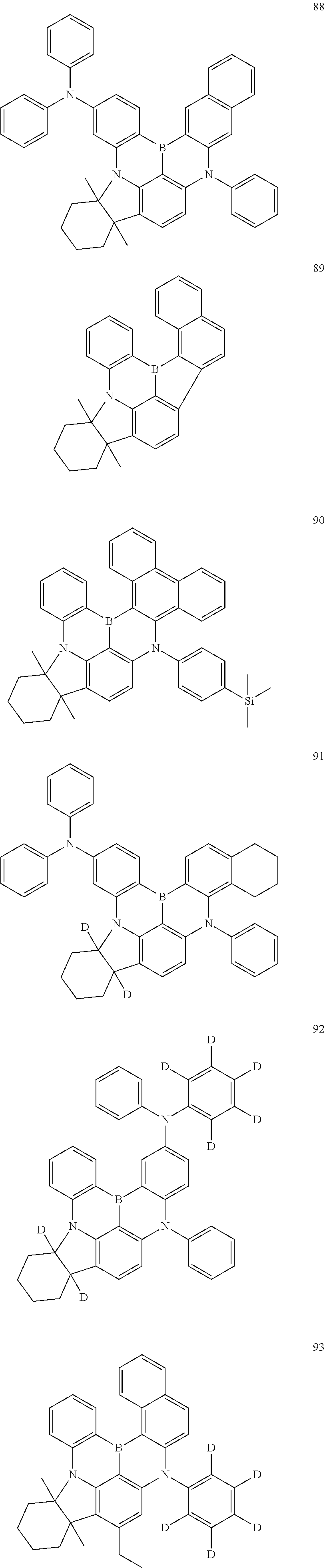

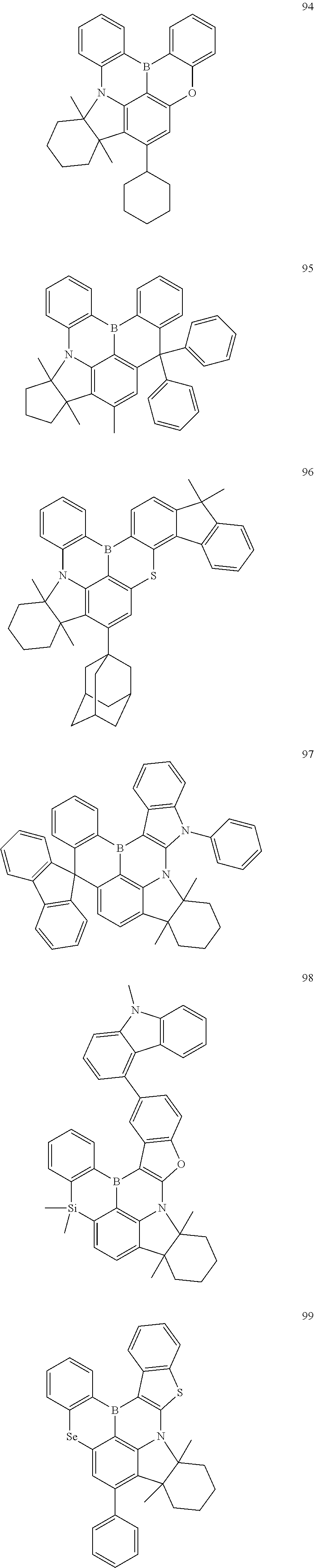 [SMILES: CC12CCCCC1(C)N1c3ccccc3B3c4ccccc4Oc4cc(C5CCCCC5)c2c1c43 ; Cc1cc2c3c4c1C1(C)CCCC1(C)N4c1ccccc1B3c1ccccc1C2(c1ccccc1)c1ccccc1 ; CC1(C)c2ccccc2-c2c1ccc1c2Sc2cc(C34CC5CC(CC(C5)C3)C4)c3c4c2B1c1ccccc1N4C1(C)CCCCC31C ; CC12CCCCC1(C)N1c3c2ccc2c3B(c3ccccc3C23c2ccccc2-c2ccccc23)c2c1n(-c1ccccc1)c1ccccc21 ; Cn1c2ccccc2c2c(-c3ccc4oc5c(c4c3)B3c4ccccc4[Si](C)(C)c4ccc6c(c43)N5C3(C)CCCCC63C)cccc21 ; CC12CCCCC1(C)N1c3sc4ccccc4c3B3c4ccccc4[Se]c4cc(-c5ccccc5)c2c1c43]

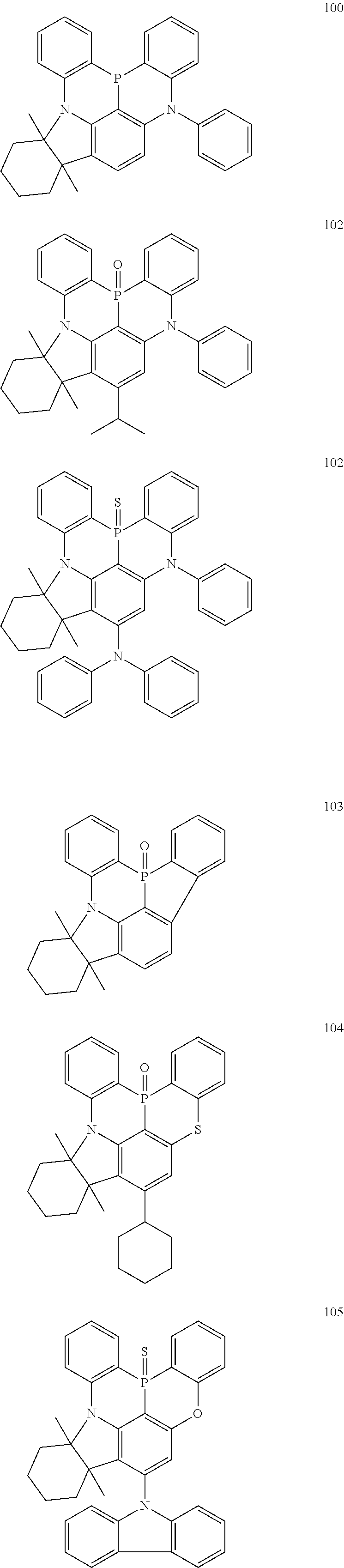 [SMILES: CC12CCCCC1(C)N1c3ccccc3P3c4ccccc4N(c4ccccc4)c4ccc2c1c43 ; CC(C)c1cc2c3c4c1C1(C)CCCCC1(C)N4c1ccccc1P3(=O)c1ccccc1N2c1ccccc1 ; CC12CCCCC1(C)N1c3ccccc3P3(=S)c4ccccc4N(c4ccccc4)c4cc(N(c5ccccc5)c5ccccc5)c2c1c43 ; CC12CCCCC1(C)N1c3ccccc3P3(=O)c4ccccc4-c4ccc2c1c43 ; CC12CCCCC1(C)N1c3ccccc3P3(=O)c4ccccc4Sc4cc(C5CCCCC5)c2c1c43 ; CC12CCCCC1(C)N1c3ccccc3P3(=S)c4ccccc4Oc4cc(-n5c6ccccc6c6ccccc65)c2c1c43]

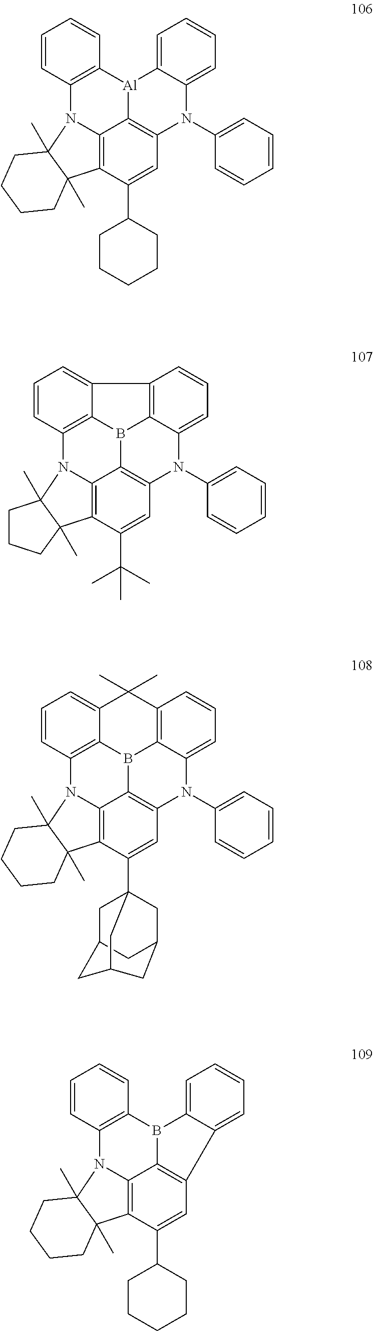

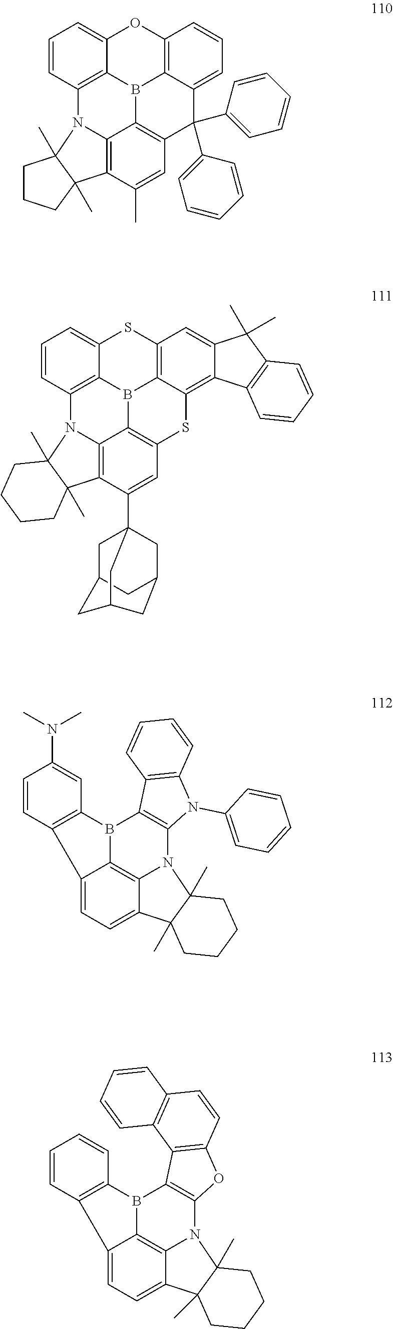 [SMILES: Cc1cc2c3c4c1C1(C)CCCC1(C)N4c1cccc4c1B3c1c(cccc1C2(c1ccccc1)c1ccccc1)O4 ; CC1(C)c2ccccc2-c2c1cc1c3c2Sc2cc(C45CC6CC(CC(C6)C4)C5)c4c5c2B3c2c(cccc2N5C2(C)CCCCC42C)S1 ; CN(C)c1ccc2c(c1)B1c3c-2ccc2c3N(c3c1c1ccccc1n3-c1ccccc1)C1(C)CCCCC21C ; CC12CCCCC1(C)N1c3oc4ccc5ccccc5c4c3B3c4ccccc4-c4ccc2c1c43]

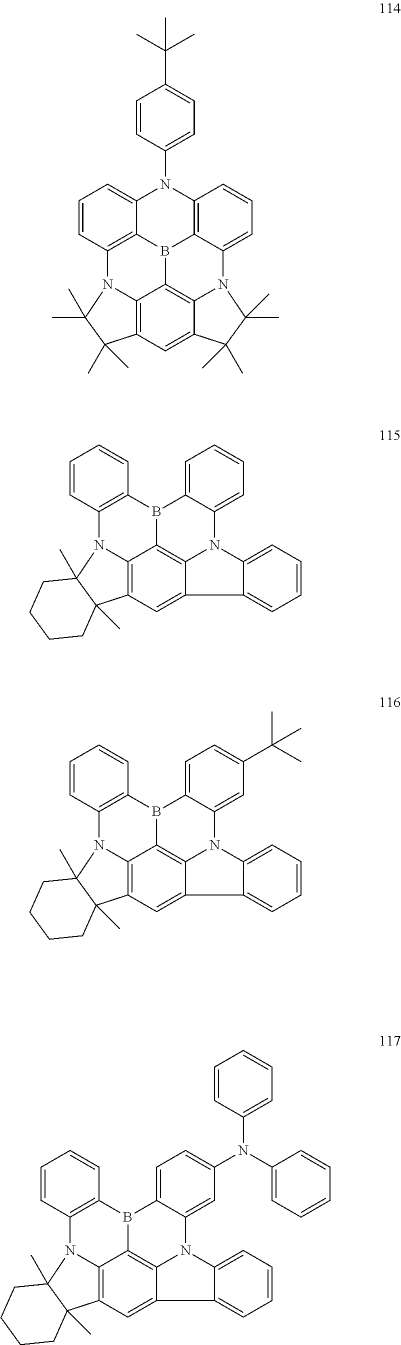

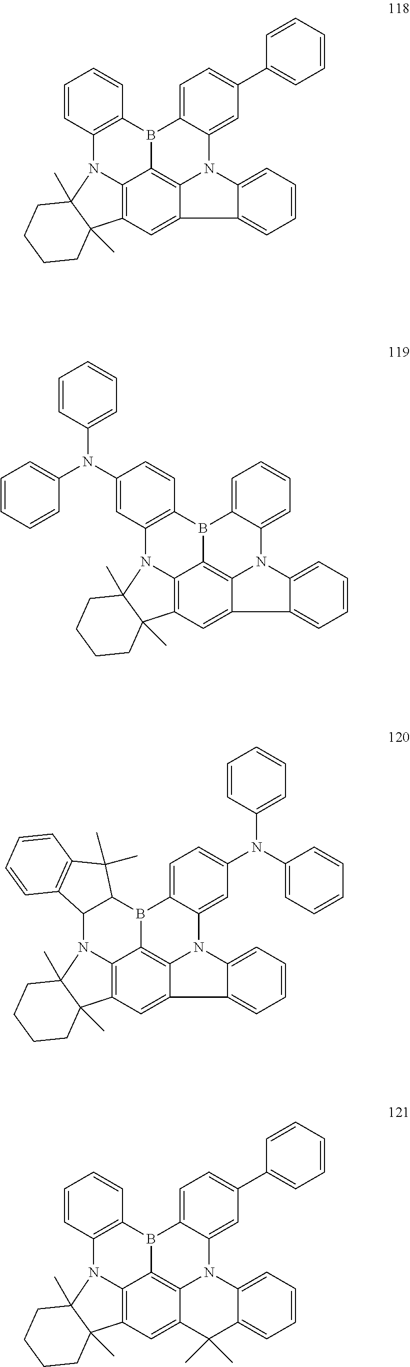 [SMILES: CC12CCCCC1(C)N1c3ccccc3B3c4ccc(-c5ccccc5)cc4-n4c5ccccc5c5cc2c1c3c54 ; CC12CCCCC1(C)N1c3cc(N(c4ccccc4)c4ccccc4)ccc3B3c4ccccc4-n4c5ccccc5c5cc2c1c3c54 ; CC1(C)c2ccccc2C2C1B1c3ccc(N(c4ccccc4)c4ccccc4)cc3-n3c4ccccc4c4cc5c(c1c43)N2C1(C)CCCCC51C ; CC1(C)c2ccccc2N2c3cc(-c4ccccc4)ccc3B3c4ccccc4N4c5c(cc1c2c53)C1(C)CCCCC41C]

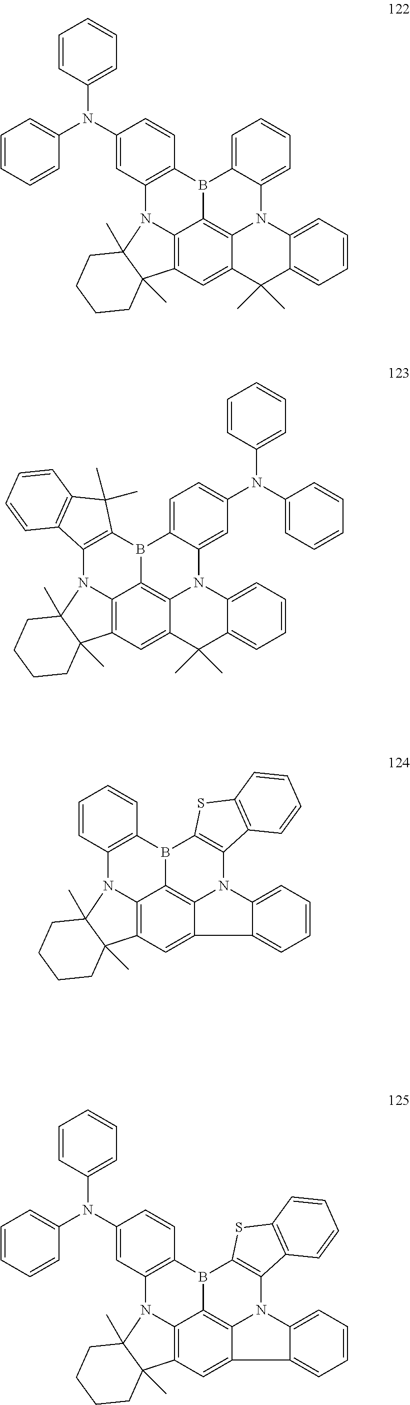 [SMILES: CC1(C)c2ccccc2N2c3ccccc3B3c4ccc(N(c5ccccc5)c5ccccc5)cc4N4c5c(cc1c2c53)C1(C)CCCCC41C ; CC1(C)C2=C(c3ccccc31)N1c3c(cc4c5c3B2c2ccc(N(c3ccccc3)c3ccccc3)cc2N5c2ccccc2C4(C)C)C2(C)CCCCC12C ; CC12CCCCC1(C)N1c3ccccc3B3c4sc5ccccc5c4-n4c5ccccc5c5cc2c1c3c54 ; CC12CCCCC1(C)N1c3cc(N(c4ccccc4)c4ccccc4)ccc3B3c4sc5ccccc5c4-n4c5ccccc5c5cc2c1c3c54]

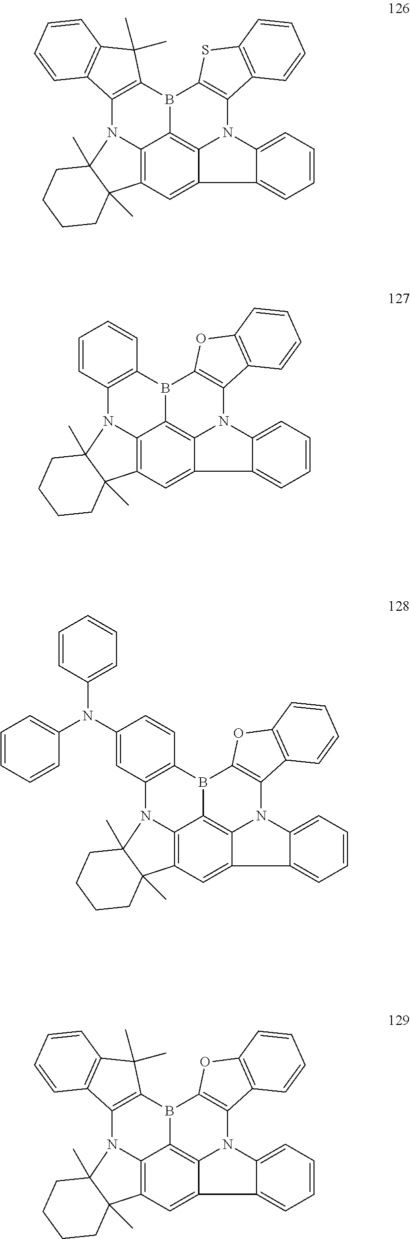 [SMILES: CC1(C)C2=C(c3ccccc31)N1c3c(cc4c5ccccc5n5c4c3B2c2sc3ccccc3c2-5)C2(C)CCCCC12C ; CC12CCCCC1(C)N1c3ccccc3B3c4oc5ccccc5c4-n4c5ccccc5c5cc2c1c3c54 ; CC12CCCCC1(C)N1c3cc(N(c4ccccc4)c4ccccc4)ccc3B3c4oc5ccccc5c4-n4c5ccccc5c5cc2c1c3c54 ; CC1(C)C2=C(c3ccccc31)N1c3c(cc4c5ccccc5n5c4c3B2c2oc3ccccc3c2-5)C2(C)CCCCC12C]

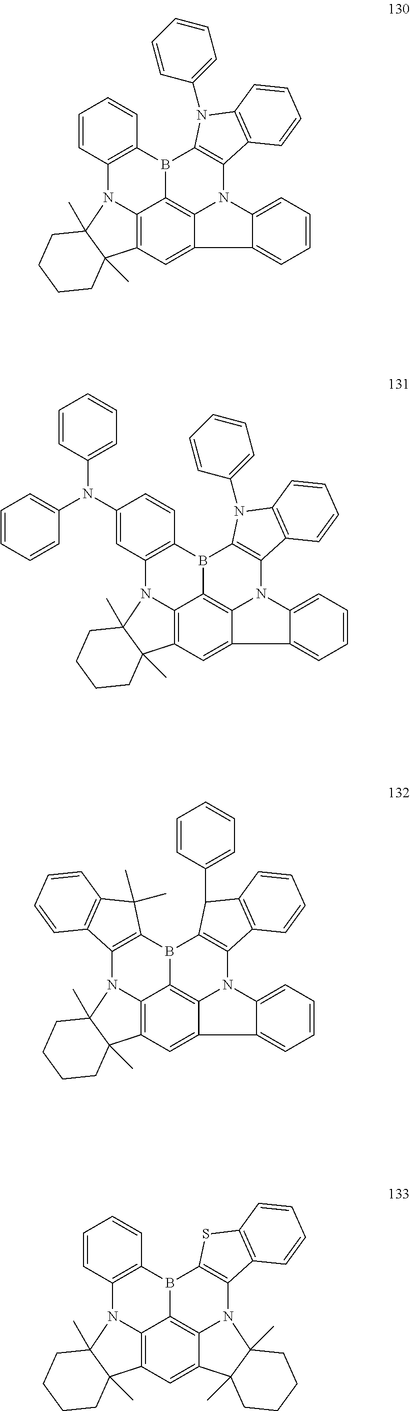 [SMILES: CC12CCCCC1(C)N1c3ccccc3B3c4c1c2cc1c2ccccc2n(c41)-c1c3n(-c2ccccc2)c2ccccc12 ; CC12CCCCC1(C)N1c3cc(N(c4ccccc4)c4ccccc4)ccc3B3c4c1c2cc1c2ccccc2n(c41)-c1c3n(-c2ccccc2)c2ccccc12 ; CC1(C)C2=C(c3ccccc31)N1c3c(cc4c5ccccc5n5c4c3B2C2=C5c3ccccc3C2c2ccccc2)C2(C)CCCCC12C ; CC12CCCCC1(C)N1c3ccccc3B3c4sc5ccccc5c4N4c5c(cc2c1c53)C1(C)CCCCC41C]

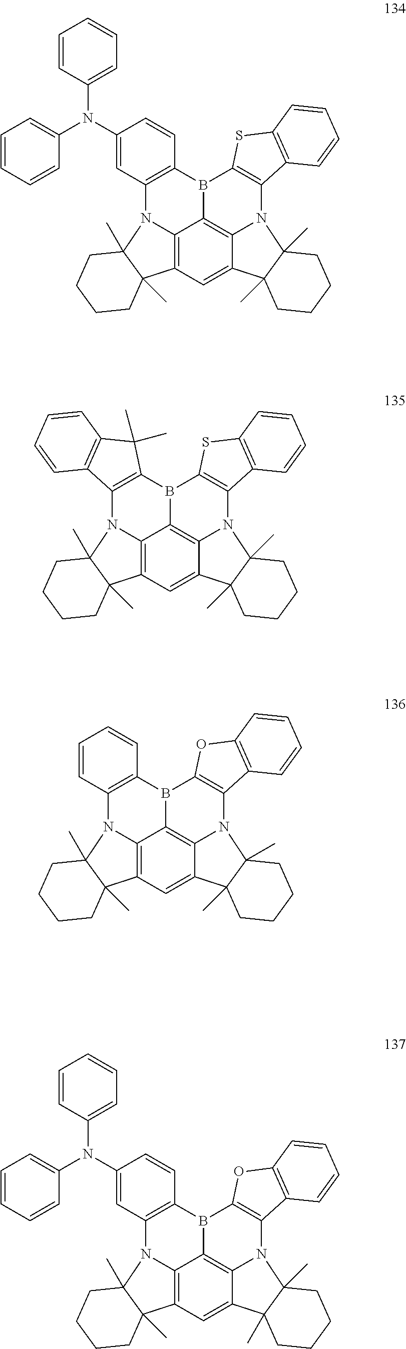 [SMILES: CC12CCCCC1(C)N1c3cc(N(c4ccccc4)c4ccccc4)ccc3B3c4sc5ccccc5c4N4c5c(cc2c1c53)C1(C)CCCCC41C ; CC1(C)C2=C(c3ccccc31)N1c3c(cc4c5c3B2c2sc3ccccc3c2N5C2(C)CCCCC42C)C2(C)CCCCC12C ; CC12CCCCC1(C)N1c3ccccc3B3c4oc5ccccc5c4N4c5c(cc2c1c53)C1(C)CCCCC41C ; CC12CCCCC1(C)N1c3cc(N(c4ccccc4)c4ccccc4)ccc3B3c4oc5ccccc5c4N4c5c(cc2c1c53)C1(C)CCCCC41C]

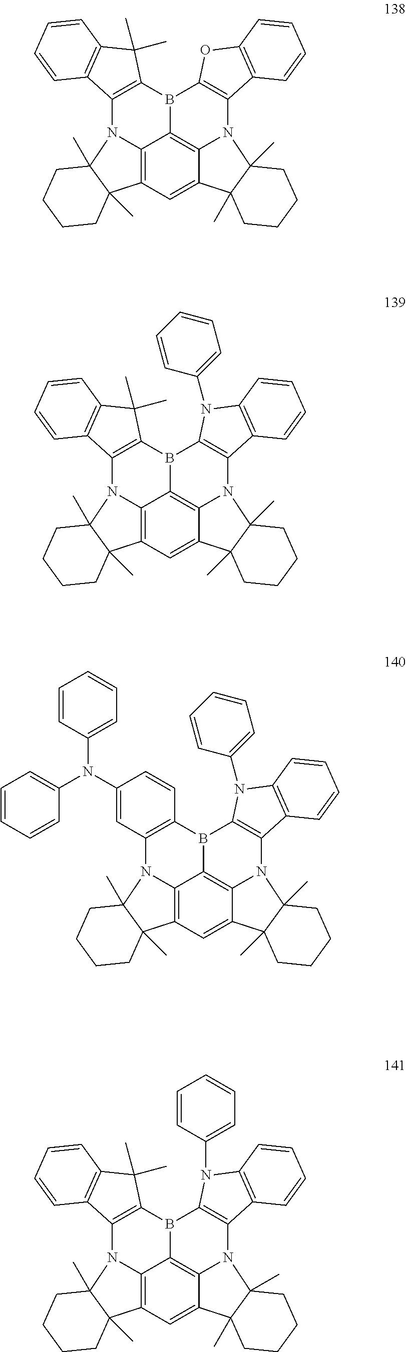 [SMILES: CC1(C)C2=C(c3ccccc31)N1c3c(cc4c5c3B2c2oc3ccccc3c2N5C2(C)CCCCC42C)C2(C)CCCCC12C ; CC1(C)C2=C(c3ccccc31)N1c3c(cc4c5c3B2c2c(c3ccccc3n2-c2ccccc2)N5C2(C)CCCCC42C)C2(C)CCCCC12C ; CC12CCCCC1(C)N1c3cc(N(c4ccccc4)c4ccccc4)ccc3B3c4c1c2cc1c4N(c2c3n(-c3ccccc3)c3ccccc23)C2(C)CCCCC12C ; CC1(C)C2=C(c3ccccc31)N1c3c(cc4c5c3B2c2c(c3ccccc3n2-c2ccccc2)N5C2(C)CCCCC42C)C2(C)CCCCC12C]

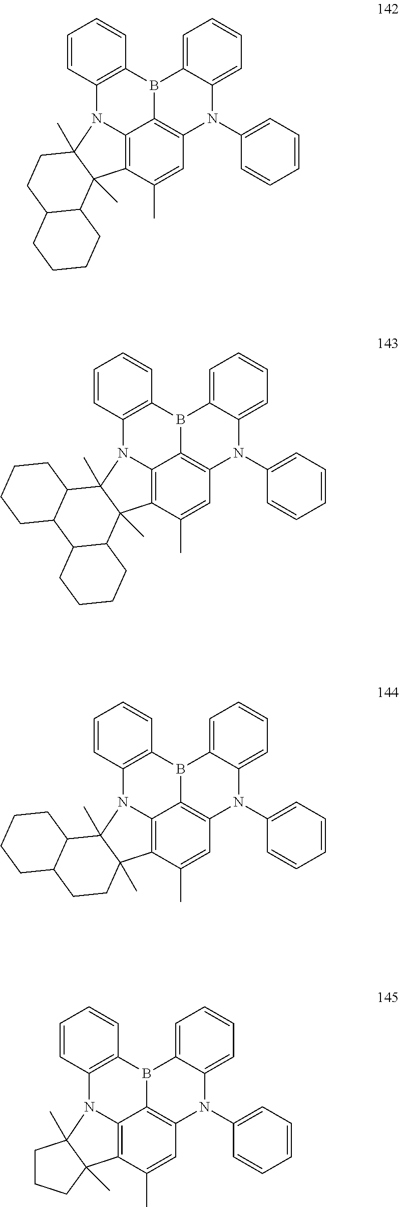 [SMILES: Cc1cc2c3c4c1C1(C)C5CCCCC5CCC1(C)N4c1ccccc1B3c1ccccc1N2c1ccccc1 ; Cc1cc2c3c4c1C1(C)C5CCCCC5C5CCCCC5C1(C)N4c1ccccc1B3c1ccccc1N2c1ccccc1 ; Cc1cc2c3c4c1C1(C)CCC5CCCCC5C1(C)N4c1ccccc1B3c1ccccc1N2c1ccccc1 ; Cc1cc2c3c4c1C1(C)CCCC1(C)N4c1ccccc1B3c1ccccc1N2c1ccccc1]

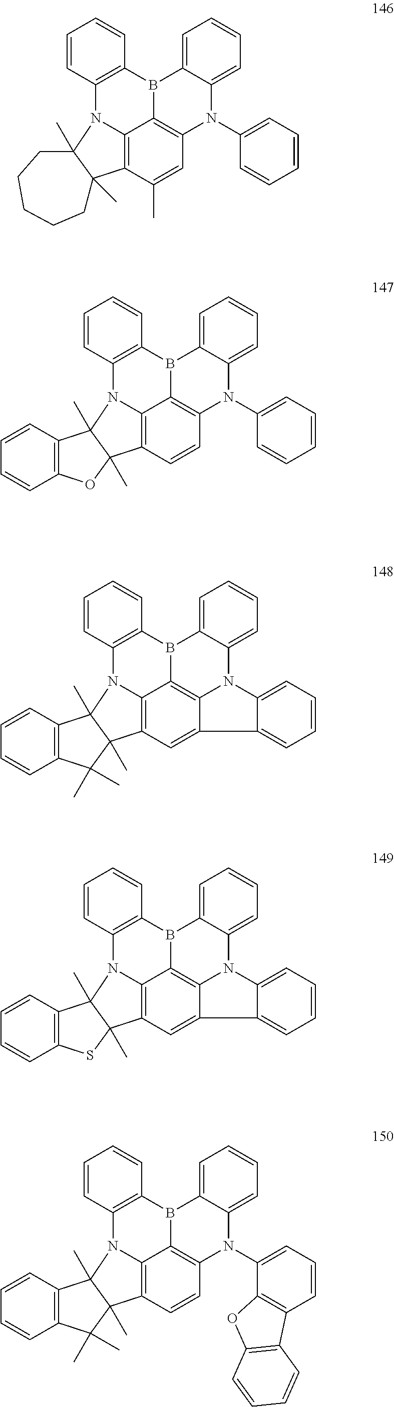 [SMILES: Cc1cc2c3c4c1C1(C)CCCCCC1(C)N4c1ccccc1B3c1ccccc1N2c1ccccc1 ; CC12Oc3ccccc3C1(C)N1c3ccccc3B3c4ccccc4N(c4ccccc4)c4ccc2c1c43 ; CC1(C)c2ccccc2C2(C)N3c4ccccc4B4c5ccccc5-n5c6ccccc6c6cc(c3c4c65)C12C ; CC12Sc3ccccc3C1(C)N1c3ccccc3B3c4ccccc4-n4c5ccccc5c5cc2c1c3c54 ; CC1(C)c2ccccc2C2(C)N3c4ccccc4B4c5ccccc5N(c5cccc6c5oc5ccccc56)c5ccc(c3c54)C12C]

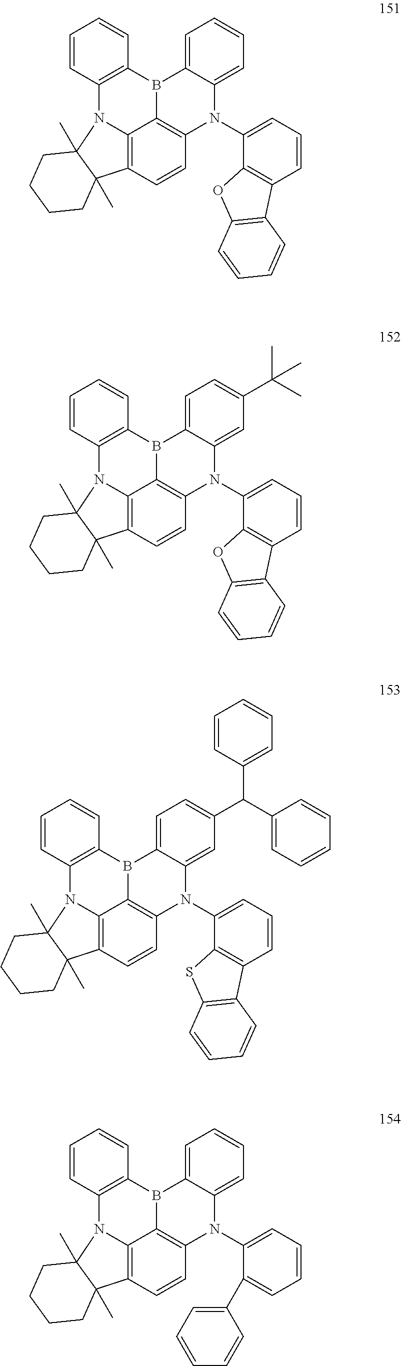 [SMILES: CC12CCCCC1(C)N1c3ccccc3B3c4ccccc4N(c4cccc5c4oc4ccccc45)c4ccc2c1c43 ; CC(C)(C)c1ccc2c(c1)N(c1cccc3c1oc1ccccc13)c1ccc3c4c1B2c1ccccc1N4C1(C)CCCCC31C ; CC12CCCCC1(C)N1c3ccccc3B3c4ccc(C(c5ccccc5)c5ccccc5)cc4N(c4cccc5c4sc4ccccc45)c4ccc2c1c43 ; CC12CCCCC1(C)N1c3ccccc3B3c4ccccc4N(c4ccccc4-c4ccccc4)c4ccc2c1c43]

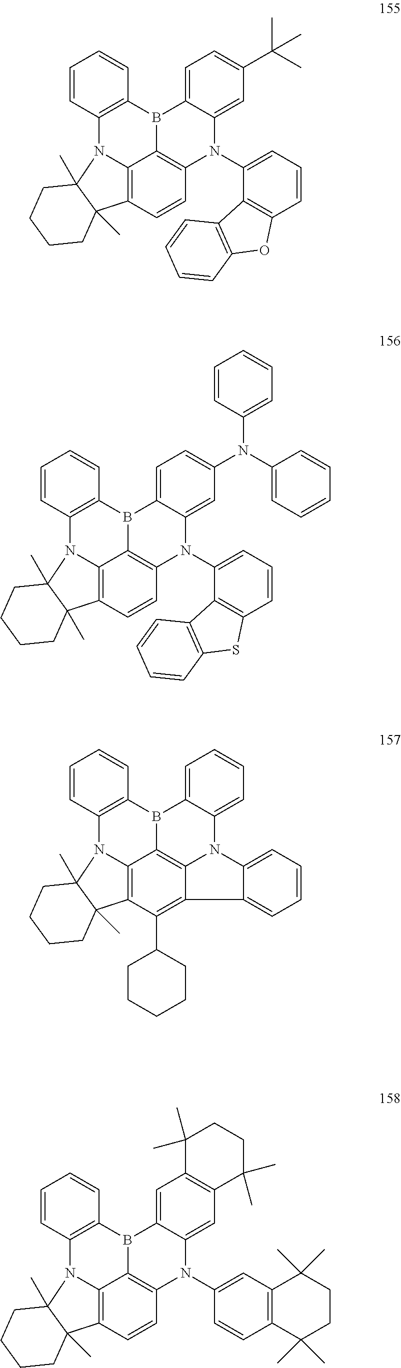 [SMILES: CC(C)(C)c1ccc2c(c1)N(c1cccc3oc4ccccc4c13)c1ccc3c4c1B2c1ccccc1N4C1(C)CCCCC31C ; CC12CCCCC1(C)N1c3ccccc3B3c4ccc(N(c5ccccc5)c5ccccc5)cc4N(c4cccc5sc6ccccc6c45)c4ccc2c1c43 ; CC12CCCCC1(C)N1c3ccccc3B3c4ccccc4-n4c5ccccc5c5c(C6CCCCC6)c2c1c3c54 ; CC1(C)CCC(C)(C)c2cc(N3c4cc5c(cc4B4c6ccccc6N6c7c(ccc3c74)C3(C)CCCCC63C)C(C)(C)CCC5(C)C)ccc21]

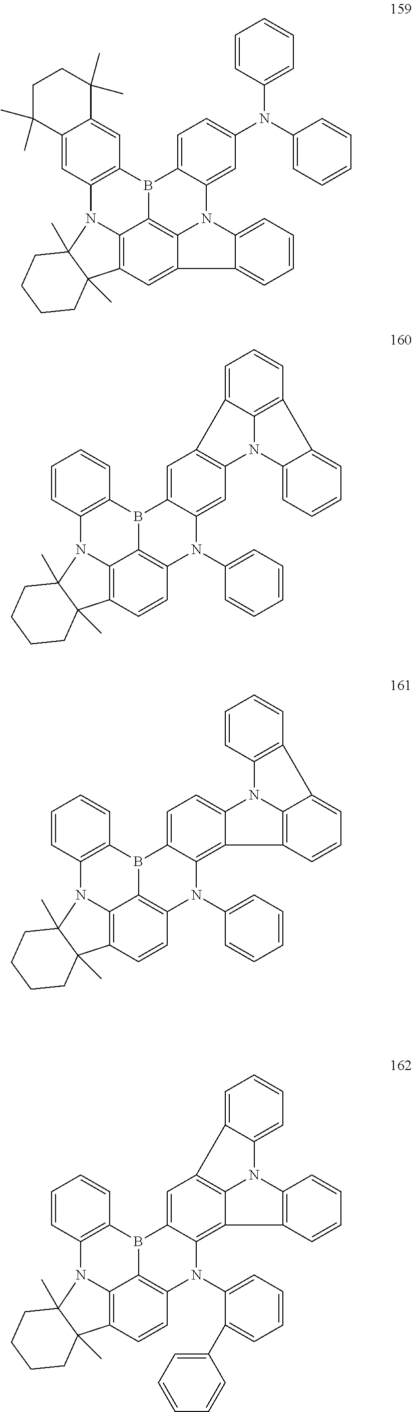 [SMILES: CC1(C)CCC(C)(C)c2cc3c(cc21)B1c2ccc(N(c4ccccc4)c4ccccc4)cc2-n2c4ccccc4c4cc5c(c1c42)N3C1(C)CCCCC51C ; CC12CCCCC1(C)N1c3ccccc3B3c4cc5c6cccc7c8ccccc8n(c5cc4N(c4ccccc4)c4ccc2c1c43)c76 ; CC12CCCCC1(C)N1c3ccccc3B3c4ccc5c(c4N(c4ccccc4)c4ccc2c1c43)c1cccc2c3ccccc3n5c21 ; CC12CCCCC1(C)N1c3ccccc3B3c4cc5c6ccccc6n6c7ccccc7c(c4N(c4ccccc4-c4ccccc4)c4ccc2c1c43)c56]

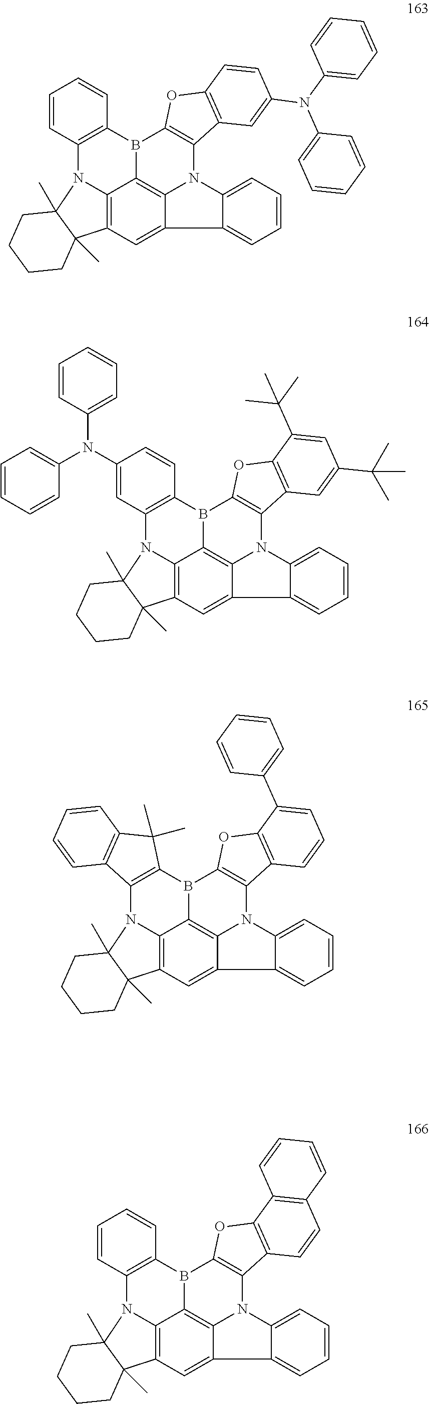 [SMILES: CC12CCCCC1(C)N1c3ccccc3B3c4oc5ccc(N(c6ccccc6)c6ccccc6)cc5c4-n4c5ccccc5c5cc2c1c3c54 ; CC(C)(C)c1cc(C(C)(C)C)c2oc3c(c2c1)-n1c2ccccc2c2cc4c5c(c21)B3c1ccc(N(c2ccccc2)c2ccccc2)cc1N5C1(C)CCCCC41C ; CC1(C)C2=C(c3ccccc31)N1c3c(cc4c5ccccc5n5c4c3B2c2oc3c(-c4ccccc4)cccc3c2-5)C2(C)CCCCC12C ; CC12CCCCC1(C)N1c3ccccc3B3c4oc5c(ccc6ccccc65)c4-n4c5ccccc5c5cc2c1c3c54]

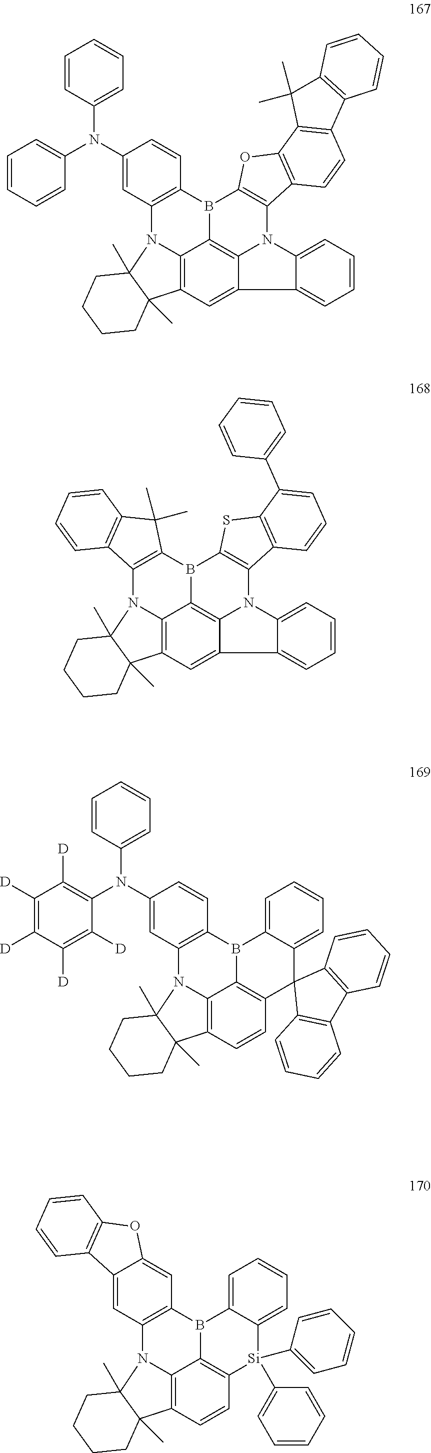 [SMILES: CC1(C)c2ccccc2-c2ccc3c4c(oc3c21)B1c2ccc(N(c3ccccc3)c3ccccc3)cc2N2c3c(cc5c6ccccc6n-4c5c31)C1(C)CCCCC21C ; CC1(C)C2=C(c3ccccc31)N1c3c(cc4c5ccccc5n5c4c3B2c2sc3c(-c4ccccc4)cccc3c2-5)C2(C)CCCCC12C ; [2H]c1c([2H])c([2H])c(N(c2ccccc2)c2ccc3c(c2)N2c4c(ccc5c4B3c3ccccc3C53c4ccccc4-c4ccccc43)C3(C)CCCCC23C)c([2H])c1[2H] ; CC12CCCCC1(C)N1c3cc4c(cc3B3c5ccccc5[Si](c5ccccc5)(c5ccccc5)c5ccc2c1c53)oc1ccccc14]

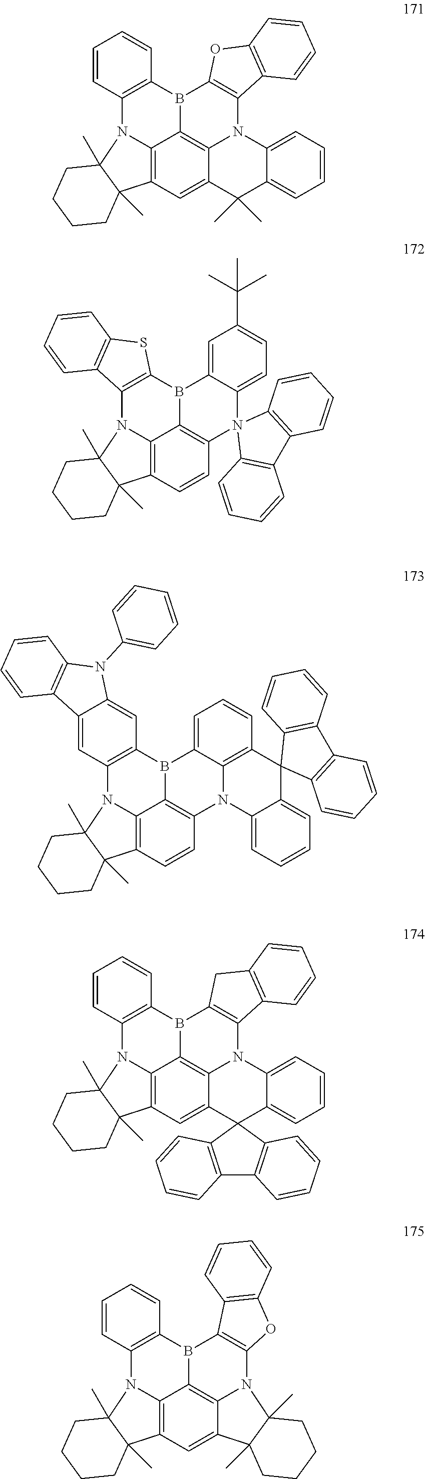

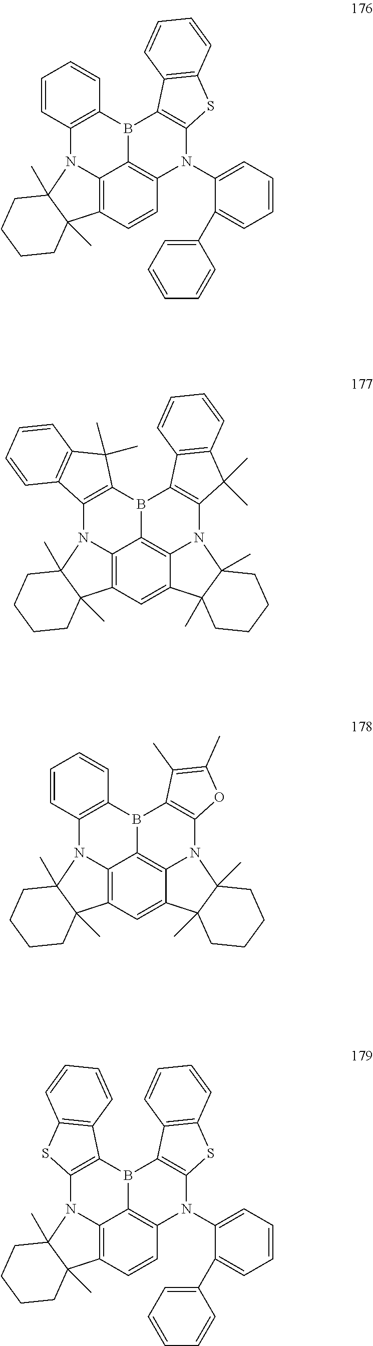 [SMILES: CC12CCCCC1(C)N1c3ccccc3B3c4c(ccc2c41)N(c1ccccc1-c1ccccc1)c1sc2ccccc2c13 ; CC1(C)C2=C(c3ccccc31)N1c3c(cc4c5c3B2C2=C(N5C3(C)CCCCC43C)C(C)(C)c3ccccc32)C2(C)CCCCC12C ; Cc1oc2c(c1C)B1c3ccccc3N3c4c(cc5c(c41)N2C1(C)CCCCC51C)C1(C)CCCCC31C ; CC12CCCCC1(C)N1c3sc4ccccc4c3B3c4c(ccc2c41)N(c1ccccc1-c1ccccc1)c1sc2ccccc2c13]

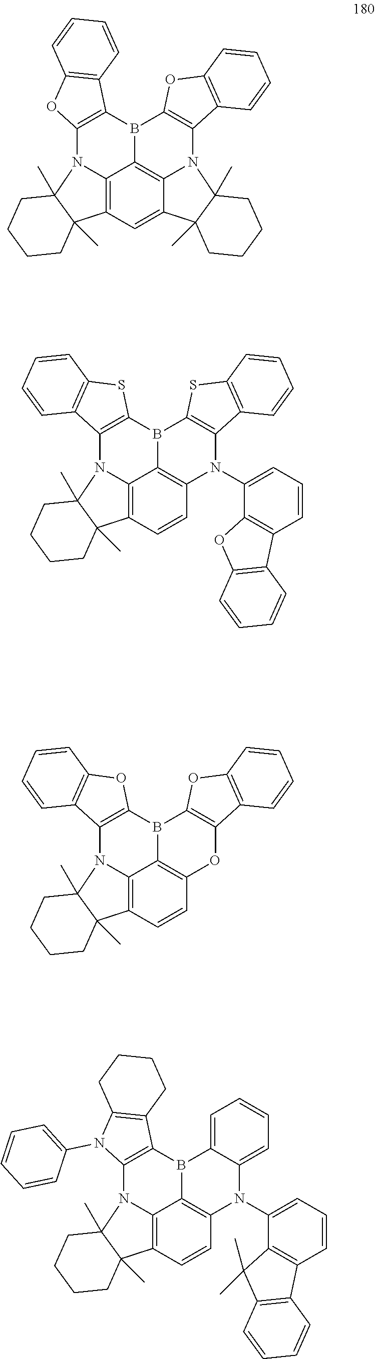 [SMILES: CC12CCCCC1(C)N1c3oc4ccccc4c3B3c4oc5ccccc5c4N4c5c(cc2c1c53)C1(C)CCCCC41C ; CC12CCCCC1(C)N1c3c2ccc2c3B(c3sc4ccccc4c3N2c2cccc3c2oc2ccccc23)c2sc3ccccc3c21 ; CC12CCCCC1(C)N1c3c2ccc2c3B(c3oc4ccccc4c3O2)c2oc3ccccc3c21 ; CC1(C)c2ccccc2-c2cccc(N3c4ccccc4B4c5c3ccc3c5N(c5c4c4c(n5-c5ccccc5)CCCC4)C4(C)CCCCC34C)c21]

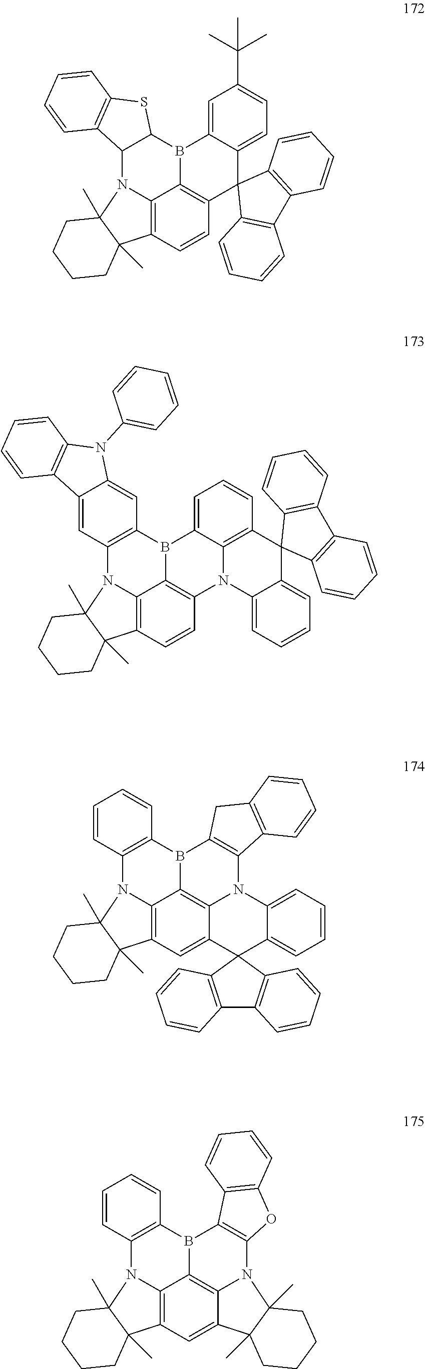 [SMILES: CC(C)(C)c1ccc2c(c1)B1c3c(ccc4c3N(C3c5ccccc5SC13)C1(C)CCCCC41C)C21c2ccccc2-c2ccccc21 ; CC12CCCCC1(C)N1c3cc4c5ccccc5n(-c5ccccc5)c4cc3B3c4cccc5c4N(c4ccccc4C54c5ccccc5-c5ccccc54)c4ccc2c1c43 ; CC12CCCCC1(C)N1c3ccccc3B3C4=C(c5ccccc5C4)N4c5ccccc5C5(c6ccccc6-c6ccccc65)c5cc2c1c3c54 ; CC12CCCCC1(C)N1c3ccccc3B3c4c1c2cc1c4N(c2oc4ccccc4c23)C2(C)CCCCC12C]

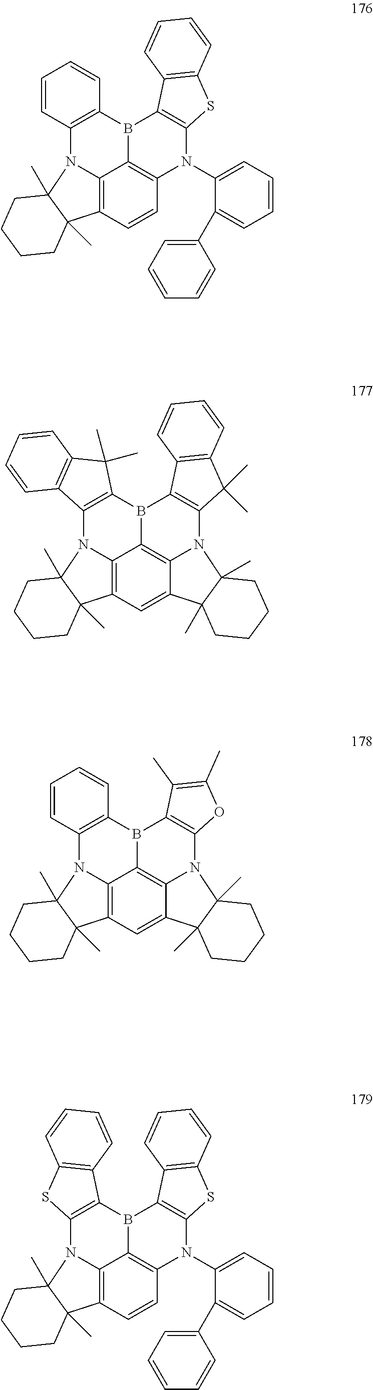 [SMILES: CC12CCCCC1(C)N1c3ccccc3B3c4c(ccc2c41)N(c1ccccc1-c1ccccc1)c1sc2ccccc2c13 ; CC1(C)C2=C(c3ccccc31)N1c3c(cc4c5c3B2C2=C(N5C3(C)CCCCC43C)C(C)(C)c3ccccc32)C2(C)CCCCC12C ; Cc1oc2c(c1C)B1c3ccccc3N3c4c(cc5c(c41)N2C1(C)CCCCC51C)C1(C)CCCCC31C ; CC12CCCCC1(C)N1c3sc4ccccc4c3B3c4c(ccc2c41)N(c1ccccc1-c1ccccc1)c1sc2ccccc2c13]

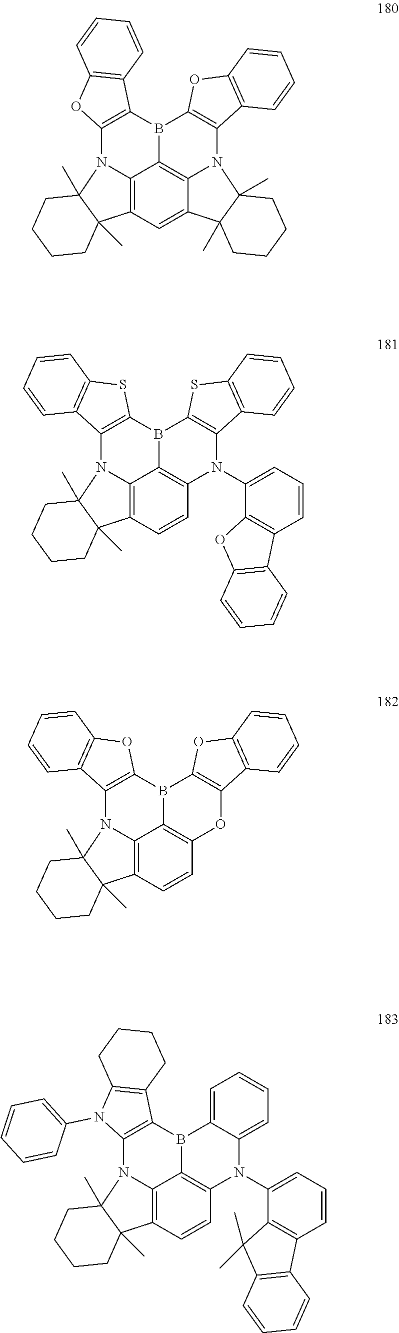 [SMILES: CC12CCCCC1(C)N1c3oc4ccccc4c3B3c4oc5ccccc5c4N4c5c(cc2c1c53)C1(C)CCCCC41C ; CC12CCCCC1(C)N1c3c2ccc2c3B(c3sc4ccccc4c3N2c2cccc3c2oc2ccccc23)c2sc3ccccc3c21 ; CC12CCCCC1(C)N1c3c2ccc2c3B(c3oc4ccccc4c3O2)c2oc3ccccc3c21 ; CC1(C)c2ccccc2-c2cccc(N3c4ccccc4B4c5c3ccc3c5N(c5c4c4c(n5-c5ccccc5)CCCC4)C4(C)CCCCC34C)c21]

7. An organic electroluminescent device comprising a first electrode, a second electrode, and one or more organic layers interposed between the first and second electrodes wherein the one or more of the organic layers comprises the compound represented by Formula A-1 or A-2 of claim 1.

8. The organic electroluminescent device according to claim 7, wherein the one or more organic layers comprise an electron injecting layer, an electron transport layer, a hole injecting layer, a hole transport layer, an electron blocking layer, a hole blocking layer, and/or a light emitting layer, at least one of which comprises the compound represented by Formula A-1 or A-2.

9. The organic electroluminescent device according to claim 8, wherein the light emitting layer comprises, as a host compound, an anthracene derivative represented by Formula C: 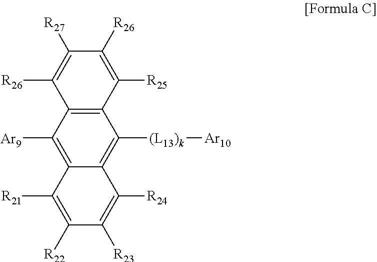
wherein R₂₁ to R₂₈ are identical to or different from each other and are as defined for R₁ to R₁₃ in Formula A-1 or A-2, Ar₉ and Ar₁₀ are identical to or different from each other and are each independently selected from hydrogen, deuterium, substituted or unsubstituted C₁-C₃₀ alkyl, substituted or unsubstituted C₆-C₅₀ aryl, substituted or unsubstituted C₂-C₃₀ alkenyl, substituted or unsubstituted C₂-C₂₀ alkynyl, substituted or unsubstituted C₃-C₃₀ cycloalkyl, substituted or unsubstituted C₅-C₃₀ cycloalkenyl, substituted or unsubstituted C₂-C₅₀ heteroaryl, substituted or unsubstituted C₂-C₃₀ heterocycloalkyl, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₆-C₃₀ arylthioxy, substituted or unsubstituted C₁-C₃₀ alkylamine, substituted or unsubstituted C₆-C₃₀ arylamine, substituted or unsubstituted C₁-C₃₀ alkylsilyl, and substituted or unsubstituted C₆-C₃₀ arylsilyl, L₁₃ is a single bond or is selected from substituted or unsubstituted C₆-C₂₀ arylene and substituted or unsubstituted C₂-C₂₀ heteroarylene, and k is an integer from 1 to 3, provided that when k is 2 or more, the linkers L₁₃ are identical to or different from each other.

10. The organic electroluminescent device according to claim 9, wherein Ar₉ in Formula C is represented by Formula C-1: 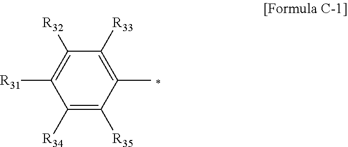
wherein R₃₁ to R₃₅ are identical to or different from each other and are as defined for R₁ to R₁₃ in Formula A-1 or A-2 and each of R₃₁ to R₃₅ is optionally bonded to an adjacent substituent to form a saturated or unsaturated ring.

11. The organic electroluminescent device according to claim 9, wherein Lis is a single bond or substituted or unsubstituted C₆-C₂₀ arylene.

12. The organic electroluminescent device according to claim 9, wherein the compound of Formula C is selected from the compounds of Formulae C1 to C48:

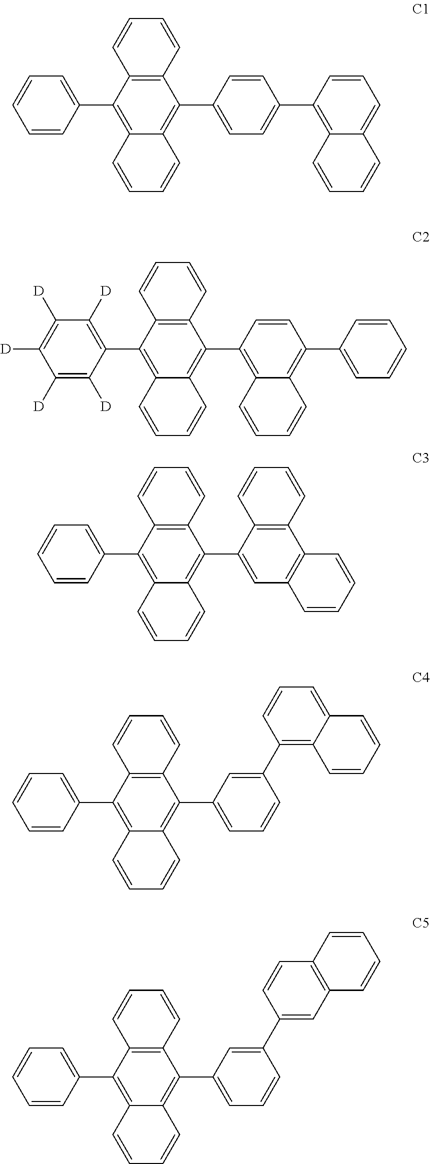

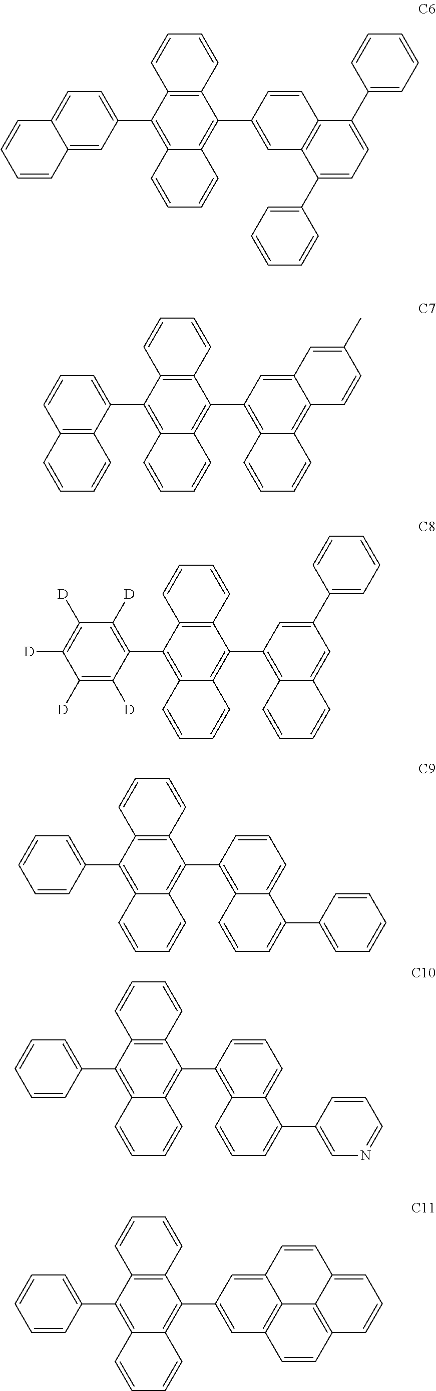

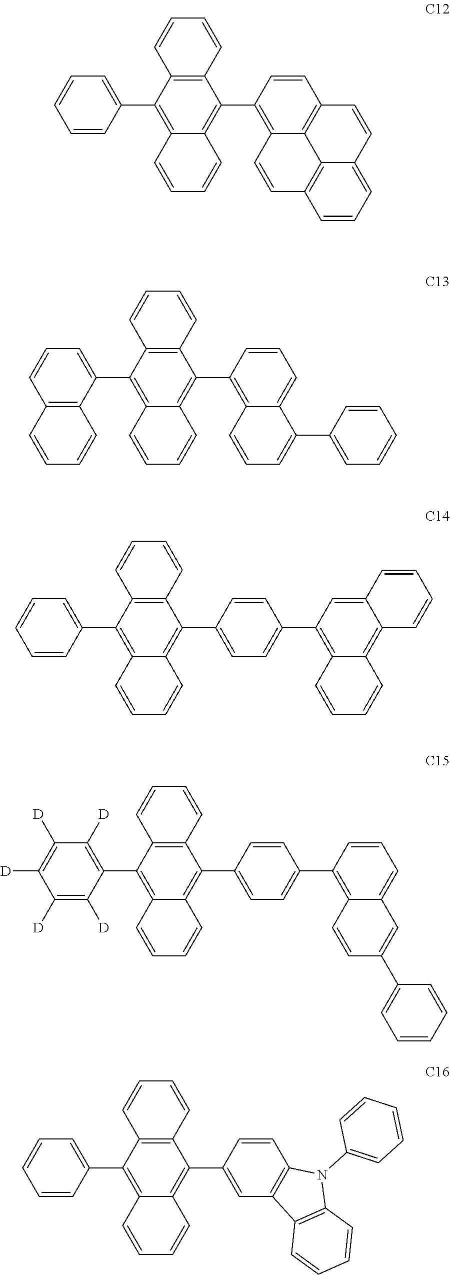

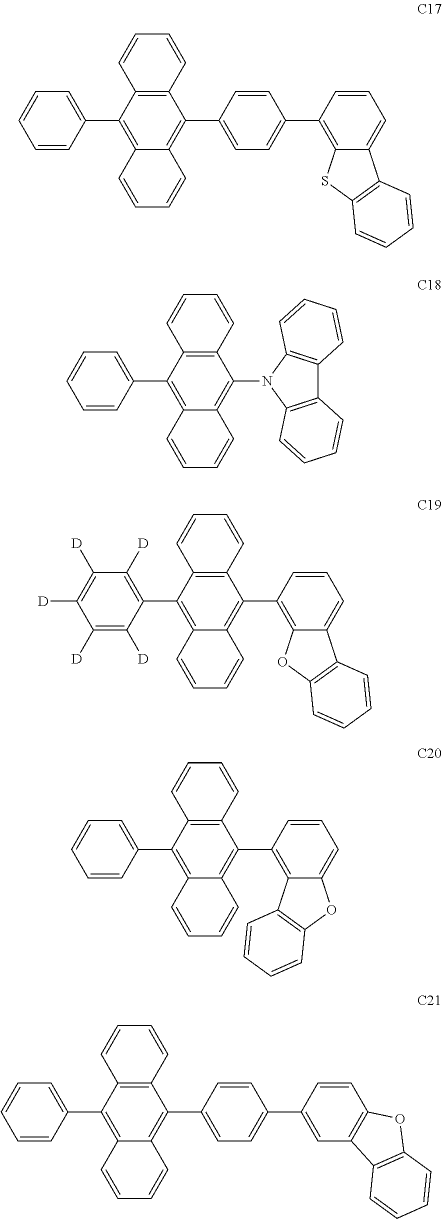 [SMILES: c1ccc(-c2c3ccccc3c(-c3ccc(-c4cccc5c4sc4ccccc45)cc3)c3ccccc23)cc1 ; c1ccc(-c2c3ccccc3c(-n3c4ccccc4c4ccccc43)c3ccccc23)cc1 ; [2H]c1c([2H])c([2H])c(-c2c3ccccc3c(-c3cccc4c3oc3ccccc34)c3ccccc23)c([2H])c1[2H] ; c1ccc(-c2c3ccccc3c(-c3cccc4oc5ccccc5c34)c3ccccc23)cc1 ; c1ccc(-c2c3ccccc3c(-c3ccc(-c4ccc5oc6ccccc6c5c4)cc3)c3ccccc23)cc1]

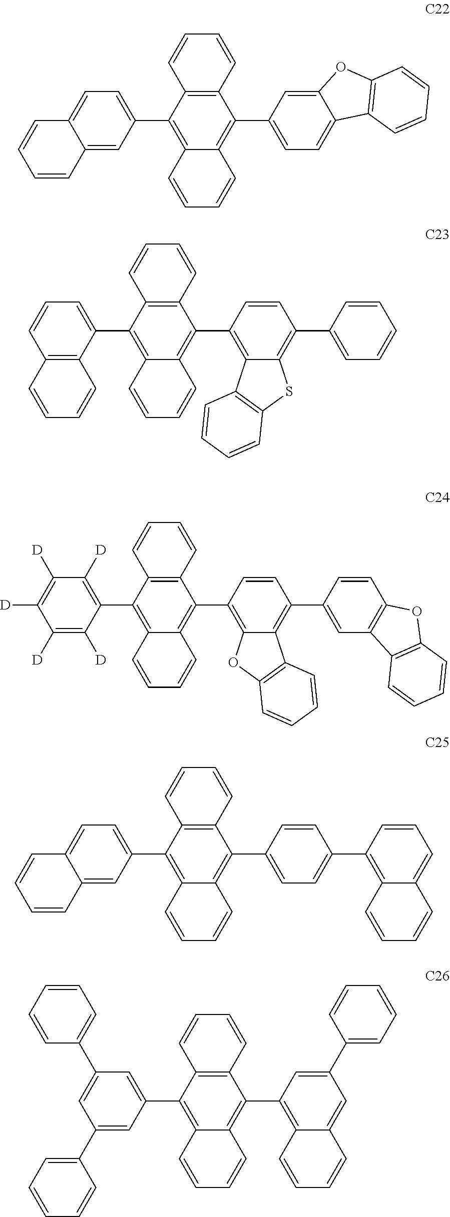

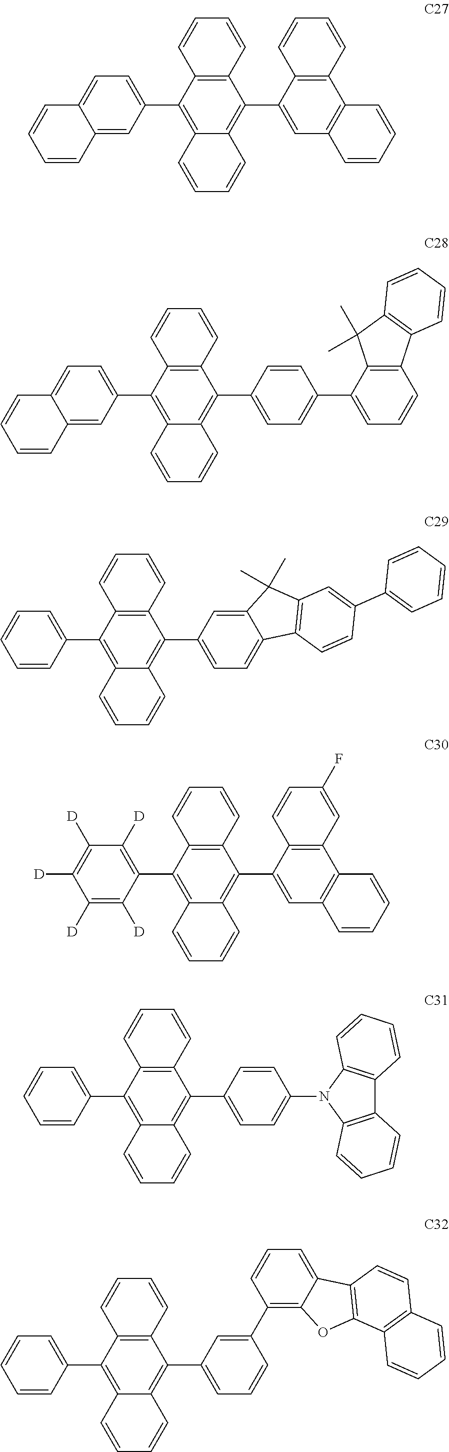

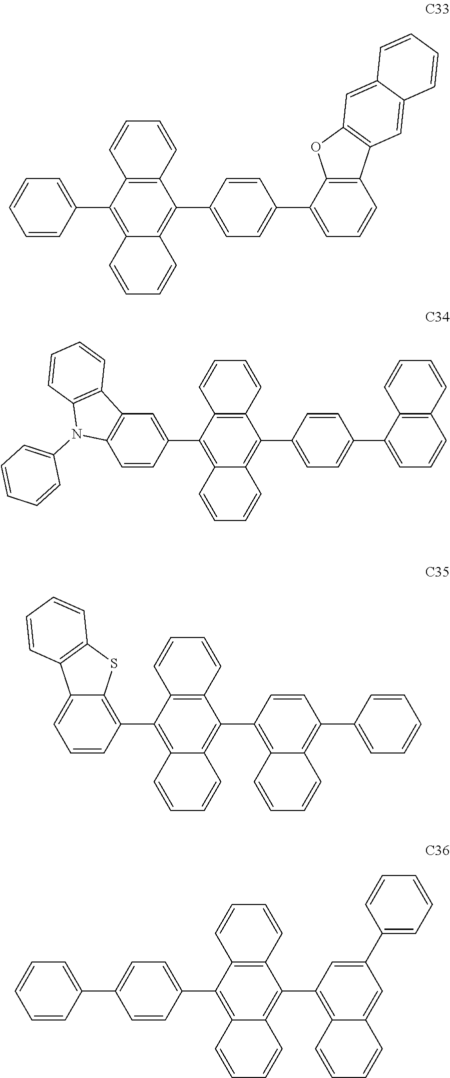

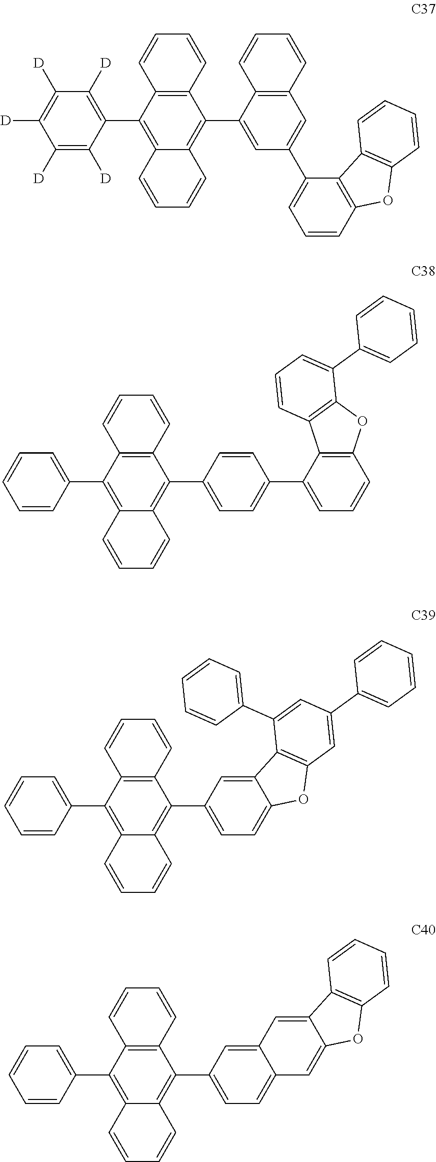 [SMILES: [2H]c1c([2H])c([2H])c(-c2c3ccccc3c(-c3cc(-c4cccc5oc6ccccc6c45)cc4ccccc34)c3ccccc23)c([2H])c1[2H] ; c1ccc(-c2c3ccccc3c(-c3ccc(-c4cccc5oc6c(-c7ccccc7)cccc6c45)cc3)c3ccccc23)cc1 ; c1ccc(-c2cc(-c3ccccc3)c3c(c2)oc2ccc(-c4c5ccccc5c(-c5ccccc5)c5ccccc45)cc23)cc1 ; c1ccc(-c2c3ccccc3c(-c3ccc4cc5oc6ccccc6c5cc4c3)c3ccccc23)cc1]

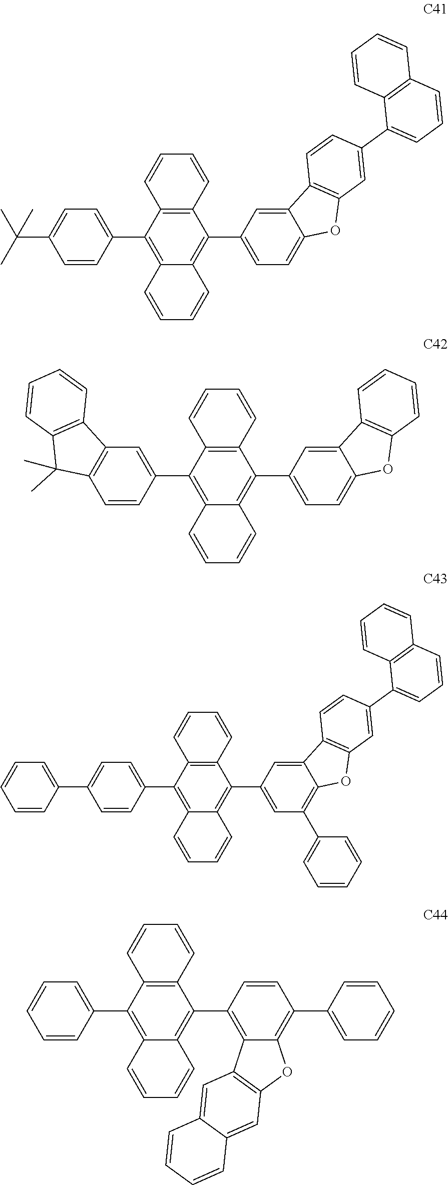 [SMILES: CC(C)(C)c1ccc(-c2c3ccccc3c(-c3ccc4oc5cc(-c6cccc7ccccc67)ccc5c4c3)c3ccccc23)cc1 ; CC1(C)c2ccccc2-c2cc(-c3c4ccccc4c(-c4ccc5oc6ccccc6c5c4)c4ccccc34)ccc21 ; c1ccc(-c2ccc(-c3c4ccccc4c(-c4cc(-c5ccccc5)c5oc6cc(-c7cccc8ccccc78)ccc6c5c4)c4ccccc34)cc2)cc1 ; c1ccc(-c2c3ccccc3c(-c3ccc(-c4ccccc4)c4oc5cc6ccccc6cc5c34)c3ccccc23)cc1]

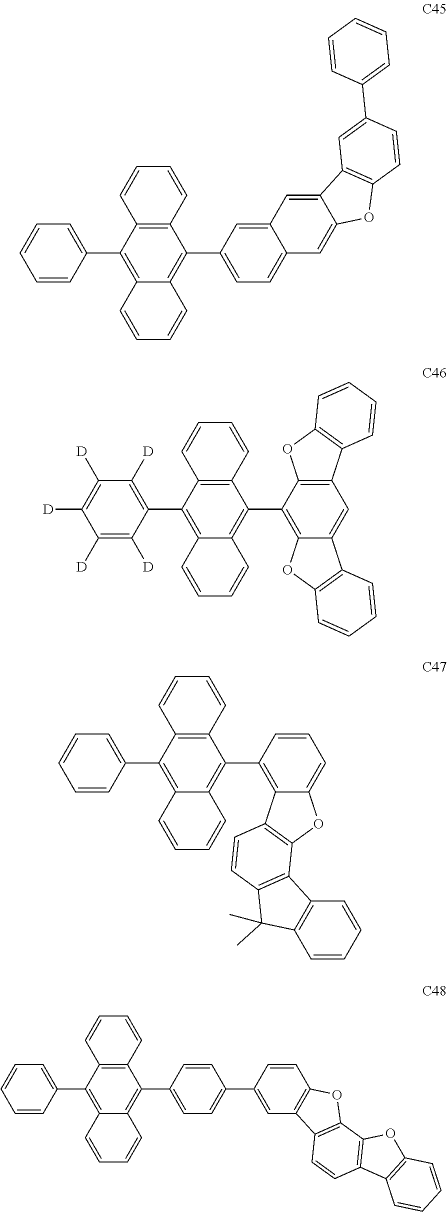 [SMILES: c1ccc(-c2ccc3oc4cc5ccc(-c6c7ccccc7c(-c7ccccc7)c7ccccc67)cc5cc4c3c2)cc1 ; [2H]c1c([2H])c([2H])c(-c2c3ccccc3c(-c3c4oc5ccccc5c4cc4c3oc3ccccc34)c3ccccc23)c([2H])c1[2H] ; CC1(C)c2ccccc2-c2c1ccc1c2oc2cccc(-c3c4ccccc4c(-c4ccccc4)c4ccccc34)c21 ; c1ccc(-c2c3ccccc3c(-c3ccc(-c4ccc5oc6c(ccc7c8ccccc8oc76)c5c4)cc3)c3ccccc23)cc1]

13. The organic electroluminescent device according to claim 8, wherein one or more of the layers are formed by a deposition or solution process.

14. The organic electroluminescent device according to claim 7, wherein the organic electroluminescent device is used in a display or lighting system selected from flat panel displays, flexible displays, monochromatic flat panel lighting systems, white flat panel lighting systems, flexible monochromatic lighting systems, and flexible white lighting systems.
